(19) United States
(12) Patent Application Publication
(10) Pub. No.: US 2026/0304769 A1
(43) Pub. Date: Oct. 1, 2026

(54) THREE-DIMENSIONAL MEMORY DEVICE WITH INTEGRATED WORD LINE AND CONTACT VIA STRUCTURES AND NON-LINEAR DIELECTRIC ISOLATION STRUCTURES

(71) Applicant: Sandisk Technologies, Inc., Milpitas, CA (US)

(72) Inventors: Ryota SUZUKI, Yokkaichi (JP); Yuriko TADANO, Yokkaichi (JP); Masanori TSUTSUMI, Yokkaichi (JP); Koichi MATSUNO, Fremont, CA (US)

(21) Appl. No.: 19/395,435

(22) Filed: Nov. 20, 2025

Related U.S. Application Data
(63) Continuation-in-part of application No. 19/233,860, filed on Jun. 10, 2025.
Application No. 19/233,860 is a continuation-in-part of application No. 19/091,391, filed on Mar. 26, 2025.

(51) Int. Cl. H10B 43/27; H10B 43/10; H10B 43/35

(52) U.S. Cl. CPC H10B 43/27; H10B 43/10; H10B 43/35

(57) ABSTRACT

A device structure includes insulating layers that are vertically spaced apart from each other. The device structure also includes integrated conductive line and via structures, each including an electrically conductive layer and a vertically-extending via portion that vertically extends upward from the electrically conductive layer through a subset of the insulating layers. The electrically conductive layers are vertically interlaced within the insulating layers to provide a vertically alternating sequence of the insulating layers and the electrically conductive layers. Each electrically conductive layer includes a word line located in a memory array region and a contact via structure located in a contact region. Memory opening fill structures vertically extend through the vertically alternating sequence in the memory array region. The vertically alternating sequences are separated from each other by zig-zag or wavy dielectric separation structures in the contact region.

### RELATED APPLICATIONS

This application is a continuation-in-part application of U.S. patent application Ser. No. 19/233,860 filed on Jun. 10, 2025, which is a continuation-in-part application of U.S. patent application Ser. No. 19/091,391 filed on Mar. 26, 2025, the entire contents of which are incorporated herein by reference.

### FIELD

The present disclosure relates generally to the field of semiconductor devices, and particularly to a three-dimensional memory device including integrated word line and via structures and non-linear dielectric isolation structures.

### BACKGROUND

A three-dimensional memory device including a three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a device structure comprises: insulating layers that are vertically spaced apart from each other; integrated conductive line and via structures, wherein each of the integrated conductive line and via structures comprises a respective electrically conductive layer and a respective vertically-extending via portion that vertically extends upward from the respective electrically conductive layer through a respective subset of the insulating layers, wherein the electrically conductive layers of the integrated conductive line and via structures are vertically interlaced within the insulating layers to provide a vertically alternating sequence of the insulating layers and the electrically conductive layers, and wherein each of the electrically conductive layers comprises a respective electrode layer located in a memory array region and a respective lateral connection strip located in a contact region and in a connection region located between the memory array region and the contact region along a first horizontal direction; first and second dielectric isolation structures located in the contact region, extending generally and non-linearly along the first horizontal direction, and spaced apart from each other along the second horizontal direction perpendicular to the first horizontal direction; memory openings vertically extending through the vertically alternating sequence in the memory array region; and memory opening fill structures located in the memory openings, wherein each of the memory opening fill structures comprises a respective vertical semiconductor channel and a vertical stack of memory elements located at levels of the electrically conductive layers.

### BRIEF DESCRIPTION OF THE DRAWINGS

FIG. 1 is a schematic vertical cross-sectional view of a first exemplary structure after formation of an alternating stack of insulating layers and sacrificial material layers over a substrate according to a first embodiment of the present disclosure.

FIG. 2A-2C are various views of the first exemplary structure after formation of memory openings according to the first embodiment of the present disclosure. FIG. 2C is a top-down view. FIG. 2A is a first vertical cross-sectional view along the vertical plane A-A′ in FIG. 2C. FIG. 2B is a second vertical cross-sectional view along the vertical plane B-B′ in FIG. 2C.

FIG. 3A-3F are sequential schematic vertical cross-sectional views of a memory opening within the first exemplary structure during formation of a memory opening fill structure therein according to the first embodiment of the present disclosure.

FIG. 4A-4C are various views of the first exemplary structure after formation of memory opening fill structures according to the first embodiment of the present disclosure. FIG. 4C is a top-down view. FIG. 4A is a first vertical cross-sectional view along the vertical plane A-A′ in FIG. 4C. FIG. 4B is a second vertical cross-sectional view along the vertical plane B-B′ in FIG. 4C.

FIG. 5A-5C are various views of the first exemplary structure after formation of dual-width lateral isolation trenches and access lateral isolation trenches according to the first embodiment of the present disclosure. FIG. 5C is a top-down view. FIG. 5A is a first vertical cross-sectional view along the vertical plane A-A′ in FIG. 5C. FIG. 5B is a second vertical cross-sectional view along the vertical plane B-B′ in FIG. 5C.

FIGS. 6A and 6B are vertical cross-sectional views of the first exemplary structure after formation of a sacrificial barrier liner and a sacrificial fill material layer according to the first embodiment of the present disclosure. FIG. 6A is a first vertical cross-sectional view along the vertical plane A-A′ in FIG. 5C. FIG. 6B is a second vertical cross-sectional view along the vertical plane B-B′ in FIG. 5C.

FIGS. 7A and 7B are vertical cross-sectional views of the first exemplary structure after isotropically recessing the sacrificial fill material layer and the sacrificial barrier liner according to the first embodiment of the present disclosure.

FIGS. 8A and 8B are vertical cross-sectional views of the first exemplary structure after formation of wide lateral isolation trench fill structures according to the first embodiment of the present disclosure.

FIG. 9A-9C are various views of the first exemplary structure after formation of contact via openings according to the first embodiment of the present disclosure. FIG. 9C is a top-down view. FIG. 9A is a first vertical cross-sectional view along the vertical plane A-A′ in FIG. 9C. FIG. 9B is a second vertical cross-sectional view along the vertical plane B-B′ in FIG. 9C.

FIGS. 10A and 10B are vertical cross-sectional views of the first exemplary structure after formation of tubular insulating spacers and vertical extension of contact via cavities according to the first embodiment of the present disclosure.

FIGS. 11A and 11B are vertical cross-sectional views of the first exemplary structure after removal of sacrificial isolation trench fill structures according to the first embodiment of the present disclosure.

FIGS. 12A and 12B are vertical cross-sectional views of the first exemplary structure after formation of a sacrificial barrier liner according to the first embodiment of the present disclosure.

FIGS. 13A and 13B are vertical cross-sectional views of the first exemplary structure after formation of a sacrificial dielectric liner according to the first embodiment of the present disclosure.

FIGS. 14A and 14B are vertical cross-sectional views of the first exemplary structure after patterning the sacrificial dielectric liner according to the first embodiment of the present disclosure.

FIGS. 15A and 15B are vertical cross-sectional views of the first exemplary structure after removal of a patterned photoresist layer according to the first embodiment of the present disclosure.

FIGS. 16A and 16B are vertical cross-sectional views of the first exemplary structure after removal of the sacrificial dielectric liner according to the first embodiment of the present disclosure.

FIG. 17A-17D are various views of the first exemplary structure after a first selective isotropic etch process that laterally recesses physically exposed portions of the sacrificial material layers by a first etch distance according to the first embodiment of the present disclosure. FIG. 17C is a top-down view. FIG. 17A is a first vertical cross-sectional view along the vertical plane A-A′ in FIG. 17C. FIG. 17B is a second vertical cross-sectional view along the vertical plane B-B′ in FIG. 17C. FIG. 17D is a horizontal cross-sectional view along the horizontal plane D-D′ of FIGS. 17A and 17B.

FIGS. 18A and 18B are vertical cross-sectional views of the first exemplary structure after removal of the sacrificial barrier liner according to the first embodiment of the present disclosure.

FIG. 19A-19E are various views of the first exemplary structure after a second selective isotropic etch process that laterally recesses physically exposed portions of the sacrificial material layers by a second etch distance according to the first embodiment of the present disclosure. FIG. 19C is a top-down view. FIG. 19A is a first vertical cross-sectional view along the vertical plane A-A′ in FIG. 19C. FIG. 19B is a second vertical cross-sectional view along the vertical plane B-B′ in FIG. 19C. FIG. 19D is a horizontal cross-sectional view along the horizontal plane D-D′ of FIGS. 19A and 19B. FIG. 19E is a horizontal cross-sectional view along the horizontal plane E-E′ of FIGS. 19A and 19B.

FIG. 20A-20E are various views of the first exemplary structure after formation of a continuous electrically conductive layer according to the first embodiment of the present disclosure. FIG. 20C is a top-down view. FIG. 20A is a first vertical cross-sectional view along the vertical plane A-A′ in FIG. 20C. FIG. 20B is a second vertical cross-sectional view along the vertical plane B-B′ in FIG. 20C. FIG. 20D is a horizontal cross-sectional view along the horizontal plane D-D′ of FIGS. 20A and 20B. FIG. 20E is a horizontal cross-sectional view along the horizontal plane E-E′ of FIGS. 20A and 20B.

FIG. 21A-21E are various views of the first exemplary structure after removing unmasked portions of the continuous electrically conductive layer according to the first embodiment of the present disclosure. FIG. 21C is a top-down view. FIG. 21A is a first vertical cross-sectional view along the vertical plane A-A′ in FIG. 21C. FIG. 21B is a second vertical cross-sectional view along the vertical plane B-B′ in FIG. 21C. FIG. 21D is a horizontal cross-sectional view along the horizontal plane D-D′ of FIGS. 21A and 21B. FIG. 21E is a horizontal cross-sectional view along the horizontal plane E-E′ of FIGS. 21A and 21B.

FIGS. 22A and 22B are vertical cross-sectional views of the first exemplary structure after formation of a continuous dielectric material portion including a contact-level dielectric layer and lateral isolation trench fill structures according to the first embodiment of the present disclosure.

FIG. 23A-23C are various views of the first exemplary structure after formation of drain contact via structures and connection via structures according to the first embodiment of the present disclosure. FIG. 23C is a top-down view. FIG. 23A is a first vertical cross-sectional view along the vertical plane A-A′ in FIG. 23C. FIG. 23B is a second vertical cross-sectional view along the vertical plane B-B′ in FIG. 23C.

FIG. 24A is a top-down view of an alternative configuration of the first exemplary structure according to the first embodiment of the present disclosure. FIG. 24B is a horizontal cross-sectional view of the alternative configuration of the first exemplary structure according to the first embodiment of the present disclosure.

FIG. 25A-25C are vertical cross-sectional views of a second exemplary structure after isotropically recessing the sacrificial fill material layer and the sacrificial barrier liner according to a second embodiment of the present disclosure. FIG. 25C is a top-down view. FIG. 25A is a first vertical cross-sectional view along the vertical plane A-A′ in FIG. 25C. FIG. 25B is a second vertical cross-sectional view along the vertical plane B-B′ in FIG. 25C.

FIG. 26 is a horizontal cross-sectional view of the second exemplary structure after conversion of surface portions of sacrificial narrow lateral isolation trench fill structures into dielectric liners according to the second embodiment of the present disclosure.

FIG. 27A-27C are vertical cross-sectional views of the second exemplary structure after formation of a first sacrificial trench liner, a second sacrificial trench liner, and wide sacrificial trench fill structures according to the second embodiment of the present disclosure. FIG. 27C is a top-down view. FIG. 27A is a first vertical cross-sectional view along the vertical plane A-A′ in FIG. 27C. FIG. 27B is a second vertical cross-sectional view along the vertical plane B-B′ in FIG. 27C.

FIG. 28A-28C are various views of the second exemplary structure after formation of contact via openings according to the second embodiment of the present disclosure. FIG. 28C is a top-down view. FIG. 28A is a first vertical cross-sectional view along the vertical plane A-A′ in FIG. 28C. FIG. 28B is a second vertical cross-sectional view along the vertical plane B-B′ in FIG. 28C.

FIGS. 29A and 29B are vertical cross-sectional views of the second exemplary structure after formation of tubular insulating spacers and vertical extension of contact via cavities according to the second embodiment of the present disclosure.

FIGS. 30A and 30B are vertical cross-sectional views of the second exemplary structure after formation of a sacrificial barrier liner and a sacrificial dielectric liner according to the second embodiment of the present disclosure.

FIGS. 31A and 31B are vertical cross-sectional views of the second exemplary structure after patterning the sacrificial dielectric liner according to the second embodiment of the present disclosure.

FIGS. 32A and 32B are vertical cross-sectional views of the second exemplary structure after removal of unmasked portions of the sacrificial barrier liner, narrow sacrificial lateral isolation trench fill structures, and wide sacrificial lateral isolation trench fill structures according to the second embodiment of the present disclosure.

FIGS. 33A and 33B are vertical cross-sectional views of the second exemplary structure after removal of a patterned photoresist layer, the sacrificial dielectric liner, and the second sacrificial trench liner according to the second embodiment of the present disclosure.

FIG. 34A-34D are various views of the second exemplary structure after a first selective isotropic etch process that laterally recesses physically exposed portions of the sacrificial material layers by a second etch distance according to the second embodiment of the present disclosure. FIG. 34C is a top-down view. FIG. 34A is a first vertical cross-sectional view along the vertical plane A-A′ in FIG. 34C. FIG. 34B is a second vertical cross-sectional view along the vertical plane B-B′ in FIG. 34C. FIG. 34D is a horizontal cross-sectional view along the horizontal plane D-D′ of FIGS. 34A and 34B.

FIGS. 35A and 35B are vertical cross-sectional views of the second exemplary structure after removal of the first sacrificial trench liner according to the second embodiment of the present disclosure.

FIG. 36A-36E are various views of the second exemplary structure after a second selective isotropic etch process that laterally recesses physically exposed portions of the sacrificial material layers by a second etch distance according to the second embodiment of the present disclosure. FIG. 36C is a top-down view. FIG. 36A is a first vertical cross-sectional view along the vertical plane A-A′ in FIG. 36C. FIG. 36B is a second vertical cross-sectional view along the vertical plane B-B′ in FIG. 36C. FIG. 36D is a horizontal cross-sectional view along the horizontal plane D-D′ of FIGS. 36A and 36B. FIG. 36E is a horizontal cross-sectional view along the horizontal plane E-E′ of FIGS. 36A and 36B.

FIG. 37A-37E are various views of the second exemplary structure after formation of integrated word line and contact via structures, a continuous dielectric material portion including a contact-level dielectric layer and lateral isolation trench fill structures, and drain contact via structures and connection via structures according to the second embodiment of the present disclosure. FIG. 37C is a top-down view. FIG. 37A is a first vertical cross-sectional view along the vertical plane A-A′ in FIG. 37C. FIG. 37B is a second vertical cross-sectional view along the vertical plane B-B′ in FIG. 37C. FIG. 37D is a horizontal cross-sectional view along the horizontal plane D-D′ of FIGS. 37A and 37B. FIG. 37E is a horizontal cross-sectional view along the horizontal plane E-E′ of FIGS. 37A and 37B.

FIG. 38A-38E are various views of a first alternative configuration of the second exemplary structure after formation of integrated word line and contact via structures, a continuous dielectric material portion including a contact-level dielectric layer and lateral isolation trench fill structures, and drain contact via structures and connection via structures according to the second embodiment of the present disclosure. FIG. 38C is a top-down view. FIG. 38A is a first vertical cross-sectional view along the vertical plane A-A′ in FIG. 38C. FIG. 38B is a second vertical cross-sectional view along the vertical plane B-B′ in FIG. 38C. FIG. 38D is a horizontal cross-sectional view along the horizontal plane D-D′ of FIGS. 38A and 38B. FIG. 38E is a horizontal cross-sectional view along the horizontal plane E-E′ of FIGS. 38A and 38B.

FIG. 39A-39E are various views of a second alternative configuration of the second exemplary structure after formation of integrated word line and contact via structures, a continuous dielectric material portion including a contact-level dielectric layer and lateral isolation trench fill structures, and drain contact via structures and connection via structures according to the second embodiment of the present disclosure. FIG. 39C is a top-down view. FIG. 39A is a first vertical cross-sectional view along the vertical plane A-A′ in FIG. 39C. FIG. 39B is a second vertical cross-sectional view along the vertical plane B-B′ in FIG. 39C. FIG. 39D is a horizontal cross-sectional view along the horizontal plane D-D′ of FIGS. 39A and 39B. FIG. 39E is a horizontal cross-sectional view along the horizontal plane E-E′ of FIGS. 39A and 39B.

FIGS. 40, 41, 42 and 43 are horizontal cross-sectional views of third, fourth, fifth and sixth alternative configurations of the second exemplary structure according to the second embodiment of the present disclosure.

FIG. 44A-44D are various views of a third exemplary structure after formation of an alternating stack of insulating layers and sacrificial material layers, memory openings, dummy memory openings, discrete access openings, connection-region isolation openings, and memory-region isolation openings according to a third embodiment of the present disclosure. FIG. 44A is a horizontal cross-sectional view along the horizontal plane A-A′ of FIG. 44D. FIG. 44B is a vertical cross-sectional view along the vertical plane B-B′ of FIG. 44A. FIG. 44C is a vertical cross-sectional view along the vertical plane C-C′ in FIG. 44A. FIG. 44D is a vertical cross-sectional view along the vertical plane D-D′ in FIG. 44A.

FIG. 45A-45D are various views of the third exemplary structure after formation of various sacrificial opening fill structures according to the third embodiment of the present disclosure. FIG. 45A is a horizontal cross-sectional view along the horizontal plane A-A′ of FIG. 45D. FIG. 45B is a vertical cross-sectional view along the vertical plane B-B′ of FIG. 45A. FIG. 45C is a vertical cross-sectional view along the vertical plane C-C′ in FIG. 45A. FIG. 45D is a vertical cross-sectional view along the vertical plane D-D′ in FIG. 45A.

FIG. 46A-46D are various views of the third exemplary structure after removal of sacrificial memory opening fill structures and sacrificial dummy memory opening fill structures according to the third embodiment of the present disclosure. FIG. 46A is a horizontal cross-sectional view along the horizontal plane A-A′ of FIG. 46D. FIG. 46B is a vertical cross-sectional view along the vertical plane B-B′ of FIG. 46A. FIG. 46C is a vertical cross-sectional view along the vertical plane C-C′ in FIG. 46A. FIG. 46D is a vertical cross-sectional view along the vertical plane D-D′ in FIG. 46A.

FIG. 47A-47D are various views of the third exemplary structure after formation of memory opening fill structures and dummy memory opening fill structures according to the third embodiment of the present disclosure. FIG. 47A is a horizontal cross-sectional view along the horizontal plane A-A′ of FIG. 47D. FIG. 47B is a vertical cross-sectional view along the vertical plane B-B′ of FIG. 47A. FIG. 47C is a vertical cross-sectional view along the vertical plane C-C′ in FIG. 47A. FIG. 47D is a vertical cross-sectional view along the vertical plane D-D′ in FIG. 47A.

FIG. 48A-48D are various views of the third exemplary structure after formation of voids in the connection-region isolation openings according to the third embodiment of the present disclosure. FIG. 48A is a horizontal cross-sectional view along the horizontal plane A-A′ of FIG. 48D. FIG. 48B is a vertical cross-sectional view along the vertical plane B-B′ of FIG. 48A. FIG. 48C is a vertical cross-sectional view along the vertical plane C-C′ in FIG. 48A. FIG. 48D is a vertical cross-sectional view along the vertical plane D-D′ in FIG. 48A.

FIG. 49A-49D are various views of the third exemplary structure after formation of connection-region isolation trenches according to the third embodiment of the present disclosure. FIG. 49A is a horizontal cross-sectional view along the horizontal plane A-A′ of FIG. 49D. FIG. 49B is a vertical cross-sectional view along the vertical plane B-B′ of FIG. 49A. FIG. 49C is a vertical cross-sectional view along the vertical plane C-C′ in FIG. 49A. FIG. 49D is a vertical cross-sectional view along the vertical plane D-D′ in FIG. 49A.

FIG. 50A-50D are various views of the third exemplary structure after formation of finned dielectric wall structures according to the third embodiment of the present disclosure. FIG. 50A is a horizontal cross-sectional view along the horizontal plane A-A′ of FIG. 50D. FIG. 50B is a vertical cross-sectional view along the vertical plane B-B′ of FIG. 50A. FIG. 50C is a vertical cross-sectional view along the vertical plane C-C′ in FIG. 50A. FIG. 50D is a vertical cross-sectional view along the vertical plane D-D′ in FIG. 50A.

FIG. 51A-51D are various views of the third exemplary structure after formation of voids in the discrete access openings according to the third embodiment of the present disclosure. FIG. 51A is a horizontal cross-sectional view along the horizontal plane A-A′ of FIG. 51D. FIG. 51B is a vertical cross-sectional view along the vertical plane B-B′ of FIG. 51A. FIG. 51C is a vertical cross-sectional view along the vertical plane C-C′ in FIG. 51A. FIG. 51D is a vertical cross-sectional view along the vertical plane D-D′ in FIG. 51A.

FIG. 52A-52D are various views of the third exemplary structure after formation of annular recesses around the discrete access openings according to the third embodiment of the present disclosure. FIG. 52A is a horizontal cross-sectional view along the horizontal plane A-A′ of FIG. 52D. FIG. 52B is a vertical cross-sectional view along the vertical plane B-B′ of FIG. 52A. FIG. 52C is a vertical cross-sectional view along the vertical plane C-C′ in FIG. 52A. FIG. 52D is a vertical cross-sectional view along the vertical plane D-D′ in FIG. 52A.

FIG. 53A-53D are various views of the third exemplary structure after deposition of a first etch-stop material layer according to the third embodiment of the present disclosure. FIG. 53A is a horizontal cross-sectional view along the horizontal plane A-A′ of FIG. 53D. FIG. 53B is a vertical cross-sectional view along the vertical plane B-B′ of FIG. 53A. FIG. 53C is a vertical cross-sectional view along the vertical plane C-C′ in FIG. 53A. FIG. 53D is a vertical cross-sectional view along the vertical plane D-D′ in FIG. 53A.

FIG. 54A-54D are various views of the third exemplary structure after formation of voids in the array-region isolation openings according to the third embodiment of the present disclosure. FIG. 54A is a horizontal cross-sectional view along the horizontal plane A-A′ of FIG. 54D. FIG. 54B is a vertical cross-sectional view along the vertical plane B-B′ of FIG. 54A. FIG. 54C is a vertical cross-sectional view along the vertical plane C-C′ in FIG. 54A. FIG. 54D is a vertical cross-sectional view along the vertical plane D-D′ in FIG. 54A.

FIG. 55A-55D are various views of the third exemplary structure after formation of array-region isolation trenches according to the third embodiment of the present disclosure. FIG. 55A is a horizontal cross-sectional view along the horizontal plane A-A′ of FIG. 55D. FIG. 55B is a vertical cross-sectional view along the vertical plane B-B′ of FIG. 55A. FIG. 55C is a vertical cross-sectional view along the vertical plane C-C′ in FIG. 55A. FIG. 55D is a vertical cross-sectional view along the vertical plane D-D′ in FIG. 55A.

FIG. 56A-56D are various views of the third exemplary structure after removal of the first etch-stop material layer and formation of dielectric isolation liners according to the third embodiment of the present disclosure. FIG. 56A is a horizontal cross-sectional view along the horizontal plane A-A′ of FIG. 56D. FIG. 56B is a vertical cross-sectional view along the vertical plane B-B′ of FIG. 56A. FIG. 56C is a vertical cross-sectional view along the vertical plane C-C′ in FIG. 56A. FIG. 56D is a vertical cross-sectional view along the vertical plane D-D′ in FIG. 56A.

FIG. 57A-57D are various views of the third exemplary structure after formation of etch-stop rings according to the third embodiment of the present disclosure. FIG. 57A is a horizontal cross-sectional view along the horizontal plane A-A′ of FIG. 57D. FIG. 57B is a vertical cross-sectional view along the vertical plane B-B′ of FIG. 57A. FIG. 57C is a vertical cross-sectional view along the vertical plane C-C′ in FIG. 57A. FIG. 57D is a vertical cross-sectional view along the vertical plane D-D′ in FIG. 57A.

FIG. 58A-58D are various views of the third exemplary structure after formation of interim access opening liners, interim access opening fill structures, interim isolation trench liners, and interim isolation trench fill structures according to the third embodiment of the present disclosure. FIG. 58A is a horizontal cross-sectional view along the horizontal plane A A′ of FIG. 58D. FIG. 58B is a vertical cross-sectional view along the vertical plane B-B′ of FIG. 58A. FIG. 58C is a vertical cross-sectional view along the vertical plane C-C′ in FIG. 58A. FIG. 58D is a vertical cross-sectional view along the vertical plane D-D′ in FIG. 58A.

FIG. 59A-59D are various views of the third exemplary structure after formation of a sacrificial liner, an etch mask layer, and contact via openings according to the third embodiment of the present disclosure. FIG. 59A is a horizontal cross-sectional view along the horizontal plane A-A′ of FIG. 59D. FIG. 59B is a vertical cross-sectional view along the vertical plane B-B′ of FIG. 59A. FIG. 59C is a vertical cross-sectional view along the vertical plane C-C′ in FIG. 59A. FIG. 59D is a vertical cross-sectional view along the vertical plane D-D′ in FIG. 59A.

FIG. 60A-60D are various views of the third exemplary structure after removal of the etch mask layer according to the third embodiment of the present disclosure. FIG. 60A is a horizontal cross-sectional view along the horizontal plane A-A′ of FIG. 60D. FIG. 60B is a vertical cross-sectional view along the vertical plane B-B′ of FIG. 60A. FIG. 60C is a vertical cross-sectional view along the vertical plane C-C′ in FIG. 60A. FIG. 60D is a vertical cross-sectional view along the vertical plane D-D′ in FIG. 60A.

FIG. 61A-61D are various views of the third exemplary structure after formation of tubular insulating spacers according to the third embodiment of the present disclosure. FIG. 61A is a horizontal cross-sectional view along the horizontal plane A-A′ of FIG. 61D. FIG. 61B is a vertical cross-sectional view along the vertical plane B-B′ of FIG. 61A. FIG. 61C is a vertical cross-sectional view along the vertical plane C-C′ in FIG. 61A. FIG. 61D is a vertical cross-sectional view along the vertical plane D-D′ in FIG. 61A.

FIG. 62A-62D are various views of the third exemplary structure after removing portions of the sacrificial material layers that underlie contact via cavities according to the third embodiment of the present disclosure. FIG. 62A is a horizontal cross-sectional view along the horizontal plane A-A′ of FIG. 62D. FIG. 62B is a vertical cross-sectional view along the vertical plane B-B′ of FIG. 62A. FIG. 62C is a vertical cross-sectional view along the vertical plane C-C′ in FIG. 62A. FIG. 62D is a vertical cross-sectional view along the vertical plane D-D′ in FIG. 62A.

FIG. 63A-63D are various views of the third exemplary structure after removal of the interim access opening fill structures and the interim isolation trench fill structures according to the third embodiment of the present disclosure. FIG. 63A is a horizontal cross-sectional view along the horizontal plane A-A′ of FIG. 63D. FIG. 63B is a vertical cross-sectional view along the vertical plane B-B′ of FIG. 63A. FIG. 63C is a vertical cross-sectional view along the vertical plane C-C′ in FIG. 63A. FIG. 63D is a vertical cross-sectional view along the vertical plane D-D′ in FIG. 63A.

FIG. 64A-64D are various views of the third exemplary structure after formation of via-bottom annular etch-stop structures according to the third embodiment of the present disclosure. FIG. 64A is a horizontal cross-sectional view along the horizontal plane A-A′ of FIG. 64D. FIG. 64B is a vertical cross-sectional view along the vertical plane B-B′ of FIG. 64A. FIG. 64C is a vertical cross-sectional view along the vertical plane C-C′ in FIG. 64A. FIG. 64D is a vertical cross-sectional view along the vertical plane D-D′ in FIG. 64A.

FIG. 65A-65D are various views of the third exemplary structure after performing a first selective isotropic etch process that forms laterally-extending cavities according to the third embodiment of the present disclosure. FIG. 65A is a horizontal cross-sectional view along the horizontal plane A-A′ of FIG. 65D. FIG. 65B is a vertical cross-sectional view along the vertical plane B-B′ of FIG. 65A. FIG. 65C is a vertical cross-sectional view along the vertical plane C-C′ in FIG. 65A. FIG. 65D is a vertical cross-sectional view along the vertical plane D-D′ in FIG. 65A.

FIG. 66A-66D are various views of the third exemplary structure after removing etch-stop rings and via-bottom annular etch-stop structures according to the third embodiment of the present disclosure. FIG. 66A is a horizontal cross-sectional view along the horizontal plane A A′ of FIG. 66D. FIG. 66B is a vertical cross-sectional view along the vertical plane B-B′ of FIG. 66A. FIG. 66C is a vertical cross-sectional view along the vertical plane C-C′ in FIG. 66A. FIG. 66D is a vertical cross-sectional view along the vertical plane D-D′ in FIG. 66A.

FIG. 67A-67D are various views of the third exemplary structure after performing a second selective isotropic etch process that forms strip-shaped cavities according to the third embodiment of the present disclosure. FIG. 67A is a horizontal cross-sectional view along the horizontal plane A-A′ of FIG. 67D. FIG. 67B is a vertical cross-sectional view along the vertical plane B-B′ of FIG. 67A. FIG. 67C is a vertical cross-sectional view along the vertical plane C-C′ in FIG. 67A. FIG. 67D is a vertical cross-sectional view along the vertical plane D-D′ in FIG. 67A.

FIG. 68A-68D are various views of the third exemplary structure after depositing a continuous conductive material layer according to the third embodiment of the present disclosure. FIG. 68A is a horizontal cross-sectional view along the horizontal plane A-A′ of FIG. 68D. FIG. 68B is a vertical cross-sectional view along the vertical plane B-B′ of FIG. 68A. FIG. 68C is a vertical cross-sectional view along the vertical plane C-C′ in FIG. 68A. FIG. 68D is a vertical cross-sectional view along the vertical plane D-D′ in FIG. 68A.

FIG. 69A-69D are various views of the third exemplary structure after depositing a continuous semiconductor material layer according to the third embodiment of the present disclosure. FIG. 69A is a horizontal cross-sectional view along the horizontal plane A-A′ of FIG. 69D. FIG. 69B is a vertical cross-sectional view along the vertical plane B-B′ of FIG. 69A. FIG. 69C is a vertical cross-sectional view along the vertical plane C-C′ in FIG. 69A. FIG. 69D is a vertical cross-sectional view along the vertical plane D-D′ in FIG. 69A.

FIG. 70A-70D are various views of the third exemplary structure after depositing a dielectric fill material layer and performing a planarization process according to the third embodiment of the present disclosure. FIG. 70A is a horizontal cross-sectional view along the horizontal plane A-A′ of FIG. 70D. FIG. 70B is a vertical cross-sectional view along the vertical plane B-B′ of FIG. 70A. FIG. 70C is a vertical cross-sectional view along the vertical plane C-C′ in FIG. 70A. FIG. 70D is a vertical cross-sectional view along the vertical plane D-D′ in FIG. 70A.

FIG. 71A-71D are various views of the third exemplary structure after removing semiconductor fill material portions according to the third embodiment of the present disclosure. FIG. 71A is a horizontal cross-sectional view along the horizontal plane A-A′ of FIG. 71D. FIG. 71B is a vertical cross-sectional view along the vertical plane B-B′ of FIG. 71A. FIG. 71C is a vertical cross-sectional view along the vertical plane C-C′ in FIG. 71A. FIG. 71D is a vertical cross-sectional view along the vertical plane D-D′ in FIG. 71A.

FIG. 72A-72D are various views of the third exemplary structure after removing conductive fill material portions according to the third embodiment of the present disclosure. FIG. 72A is a horizontal cross-sectional view along the horizontal plane A-A′ of FIG. 72D. FIG. 72B is a vertical cross-sectional view along the vertical plane B-B′ of FIG. 72A. FIG. 72C is a vertical cross-sectional view along the vertical plane C-C′ in FIG. 72A. FIG. 72D is a vertical cross-sectional view along the vertical plane D-D′ in FIG. 72A.

FIG. 73A-73D are various views of the third exemplary structure after formation of a continuous dielectric material structure according to the third embodiment of the present disclosure. FIG. 73A is a horizontal cross-sectional view along the horizontal plane A-A′ of FIG. 73D. FIG. 73B is a vertical cross-sectional view along the vertical plane B-B′ of FIG. 73A. FIG. 73C is a vertical cross-sectional view along the vertical plane C-C′ in FIG. 73A. FIG. 73D is a vertical cross-sectional view along the vertical plane D-D′ in FIG. 73A.

FIG. 74A-74E are vertical cross-sectional views illustrating a first alternative configuration of the third exemplary structure during formation of strip-shaped cavities according to the third embodiment of the present disclosure.

FIG. 75A-75F are vertical cross-sectional views illustrating a second alternative configuration of the third exemplary structure during formation of strip-shaped cavities according to the third embodiment of the present disclosure.

FIG. 76A-76F are vertical cross-sectional views illustrating a third alternative configuration of the third exemplary structure during formation of capped tubular metallic structures according to the third embodiment of the present disclosure.

FIG. 77A-77D are various views of a fourth exemplary structure after formation of an alternating stack of insulating layers and sacrificial material layers, memory openings, dummy memory openings, discrete access openings, and connection-region isolation openings according to a fourth embodiment of the present disclosure. FIG. 77A is a horizontal cross-sectional view along the horizontal plane A-A′ of FIG. 77D. FIG. 77B is a vertical cross-sectional view along the vertical plane B-B′ of FIG. 77A. FIG. 77C is a vertical cross-sectional view along the vertical plane C-C′ in FIG. 77A. FIG. 77D is a vertical cross-sectional view along the vertical plane D-D′ in FIG. 77A.

FIG. 78A-78D are various views of the fourth exemplary structure after formation of various sacrificial opening fill structures according to the fourth embodiment of the present disclosure. FIG. 78A is a horizontal cross-sectional view along the horizontal plane A-A′ of FIG. 78D. FIG. 78B is a vertical cross-sectional view along the vertical plane B-B′ of FIG. 78A. FIG. 78C is a vertical cross-sectional view along the vertical plane C-C′ in FIG. 78A. FIG. 78D is a vertical cross-sectional view along the vertical plane D-D′ in FIG. 78A.

FIG. 79A-79D are various views of the fourth exemplary structure after removal of sacrificial memory opening fill structures and sacrificial dummy memory opening fill structures according to the fourth embodiment of the present disclosure. FIG. 79A is a horizontal cross-sectional view along the horizontal plane A-A′ of FIG. 79D. FIG. 79B is a vertical cross-sectional view along the vertical plane B-B′ of FIG. 79A. FIG. 79C is a vertical cross-sectional view along the vertical plane C-C′ in FIG. 79A. FIG. 79D is a vertical cross-sectional view along the vertical plane D-D′ in FIG. 79A.

FIG. 80A-80D are various views of the fourth exemplary structure after formation of memory opening fill structures and dummy memory opening fill structures and a capping dielectric layer according to the fourth embodiment of the present disclosure. FIG. 80A is a horizontal cross-sectional view along the horizontal plane A-A′ of FIG. 80D. FIG. 80B is a vertical cross-sectional view along the vertical plane B-B′ of FIG. 80A. FIG. 80C is a vertical cross-sectional view along the vertical plane C-C′ in FIG. 80A. FIG. 80D is a vertical cross-sectional view along the vertical plane D-D′ in FIG. 80A.

FIG. 81A-81D are various views of the fourth exemplary structure after formation of voids in the connection-region isolation openings according to the fourth embodiment of the present disclosure. FIG. 81A is a horizontal cross-sectional view along the horizontal plane A-A′ of FIG. 81D. FIG. 81B is a vertical cross-sectional view along the vertical plane B-B′ of FIG. 81A. FIG. 81C is a vertical cross-sectional view along the vertical plane C-C′ in FIG. 81A. FIG. 81D is a vertical cross-sectional view along the vertical plane D-D′ in FIG. 81A.

FIG. 82A-82D are various views of the fourth exemplary structure after formation of connection-region isolation trenches according to the fourth embodiment of the present disclosure. FIG. 82A is a horizontal cross-sectional view along the horizontal plane A-A′ of FIG. 82D. FIG. 82B is a vertical cross-sectional view along the vertical plane B-B′ of FIG. 82A. FIG. 82C is a vertical cross-sectional view along the vertical plane C-C′ in FIG. 82A. FIG. 82D is a vertical cross-sectional view along the vertical plane D-D′ in FIG. 82A.

FIG. 83A-83D are various views of the fourth exemplary structure after formation of finned dielectric wall structures according to the fourth embodiment of the present disclosure. FIG. 83A is a horizontal cross-sectional view along the horizontal plane A-A′ of FIG. 83D. FIG. 83B is a vertical cross-sectional view along the vertical plane B-B′ of FIG. 83A. FIG. 83C is a vertical cross-sectional view along the vertical plane C-C′ in FIG. 83A. FIG. 83D is a vertical cross-sectional view along the vertical plane D-D′ in FIG. 83A.

FIG. 84A-84D are various views of the fourth exemplary structure after formation of voids in the discrete access openings according to the fourth embodiment of the present disclosure. FIG. 84A is a horizontal cross-sectional view along the horizontal plane A-A′ of FIG. 84D. FIG. 84B is a vertical cross-sectional view along the vertical plane B-B′ of FIG. 84A. FIG. 84C is a vertical cross-sectional view along the vertical plane C-C′ in FIG. 84A. FIG. 84D is a vertical cross-sectional view along the vertical plane D-D′ in FIG. 84A.

FIG. 85A-85D are various views of the fourth exemplary structure after formation of annular recesses around the discrete access openings according to the fourth embodiment of the present disclosure. FIG. 85A is a horizontal cross-sectional view along the horizontal plane A A′ of FIG. 85D. FIG. 85B is a vertical cross-sectional view along the vertical plane B-B′ of FIG. 85A. FIG. 85C is a vertical cross-sectional view along the vertical plane C-C′ in FIG. 85A. FIG. 85D is a vertical cross-sectional view along the vertical plane D-D′ in FIG. 85A.

FIG. 86A-86D are various views of the fourth exemplary structure after formation of array-region isolation trenches according to the fourth embodiment of the present disclosure. FIG. 86A is a horizontal cross-sectional view along the horizontal plane A-A′ of FIG. 86D. FIG. 86B is a vertical cross-sectional view along the vertical plane B-B′ of FIG. 86A. FIG. 86C is a vertical cross-sectional view along the vertical plane C-C′ in FIG. 86A. FIG. 86D is a vertical cross-sectional view along the vertical plane D-D′ in FIG. 86A.

FIG. 87A-87D are various views of the fourth exemplary structure after formation of etch-stop rings according to the fourth embodiment of the present disclosure. FIG. 87A is a horizontal cross-sectional view along the horizontal plane A-A′ of FIG. 87D. FIG. 87B is a vertical cross-sectional view along the vertical plane B-B′ of FIG. 87A. FIG. 87C is a vertical cross-sectional view along the vertical plane C-C′ in FIG. 87A. FIG. 87D is a vertical cross-sectional view along the vertical plane D-D′ in FIG. 87A.

FIG. 88A-88D are various views of the fourth exemplary structure after formation of interim access opening liners, interim access opening fill structures, interim isolation trench liners, and interim isolation trench fill structures according to the fourth embodiment of the present disclosure. FIG. 88A is a horizontal cross-sectional view along the horizontal plane A-A′ of FIG. 88D. FIG. 88B is a vertical cross-sectional view along the vertical plane B-B′ of FIG. 88A. FIG. 88C is a vertical cross-sectional view along the vertical plane C-C′ in FIG. 88A. FIG. 88D is a vertical cross-sectional view along the vertical plane D-D′ in FIG. 88A.

FIG. 89A-89D are various views of the fourth exemplary structure after formation of a sacrificial liner, an etch mask layer, and contact via openings according to the fourth embodiment of the present disclosure. FIG. 89A is a horizontal cross-sectional view along the horizontal plane A-A′ of FIG. 89D. FIG. 89B is a vertical cross-sectional view along the vertical plane B-B′ of FIG. 89A. FIG. 89C is a vertical cross-sectional view along the vertical plane C-C′ in FIG. 89A. FIG. 89D is a vertical cross-sectional view along the vertical plane D-D′ in FIG. 89A.

FIG. 90A-90D are various views of the fourth exemplary structure after removal of the etch mask layer according to the fourth embodiment of the present disclosure. FIG. 90A is a horizontal cross-sectional view along the horizontal plane A-A′ of FIG. 90D. FIG. 90B is a vertical cross-sectional view along the vertical plane B-B′ of FIG. 90A. FIG. 90C is a vertical cross-sectional view along the vertical plane C-C′ in FIG. 90A. FIG. 90D is a vertical cross-sectional view along the vertical plane D-D′ in FIG. 90A.

FIG. 91A-91D are various views of the fourth exemplary structure after formation of tubular insulating spacers according to the fourth embodiment of the present disclosure. FIG. 91A is a horizontal cross-sectional view along the horizontal plane A-A′ of FIG. 91D. FIG. 91B is a vertical cross-sectional view along the vertical plane B-B′ of FIG. 91A. FIG. 91C is a vertical cross-sectional view along the vertical plane C-C′ in FIG. 91A. FIG. 91D is a vertical cross-sectional view along the vertical plane D-D′ in FIG. 91A.

FIG. 92A-92D are various views of the fourth exemplary structure after removing portions of the sacrificial material layers that underlie contact via cavities according to the fourth embodiment of the present disclosure. FIG. 92A is a horizontal cross-sectional view along the horizontal plane A-A′ of FIG. 92D. FIG. 92B is a vertical cross-sectional view along the vertical plane B-B′ of FIG. 92A. FIG. 92C is a vertical cross-sectional view along the vertical plane C-C′ in FIG. 92A. FIG. 92D is a vertical cross-sectional view along the vertical plane D-D′ in FIG. 92A.

FIG. 93A-93D are various views of the fourth exemplary structure after removal of the interim access opening fill structures and the interim isolation trench fill structures according to the fourth embodiment of the present disclosure. FIG. 93A is a horizontal cross-sectional view along the horizontal plane A-A′ of FIG. 93D. FIG. 93B is a vertical cross-sectional view along the vertical plane B-B′ of FIG. 93A. FIG. 93C is a vertical cross-sectional view along the vertical plane C-C′ in FIG. 93A. FIG. 93D is a vertical cross-sectional view along the vertical plane D-D′ in FIG. 93A.

FIG. 94A-94D are various views of the fourth exemplary structure after formation of via-bottom annular etch-stop structures according to the fourth embodiment of the present disclosure. FIG. 94A is a horizontal cross-sectional view along the horizontal plane A-A′ of FIG. 94D. FIG. 94B is a vertical cross-sectional view along the vertical plane B-B′ of FIG. 94A. FIG. 94C is a vertical cross-sectional view along the vertical plane C-C′ in FIG. 94A. FIG. 94D is a vertical cross-sectional view along the vertical plane D-D′ in FIG. 94A.

FIG. 95A-95D are various views of the fourth exemplary structure after performing a first selective isotropic etch process that forms laterally-extending cavities according to the fourth embodiment of the present disclosure. FIG. 95A is a horizontal cross-sectional view along the horizontal plane A-A′ of FIG. 95D. FIG. 95B is a vertical cross-sectional view along the vertical plane B-B′ of FIG. 95A. FIG. 95C is a vertical cross-sectional view along the vertical plane C-C′ in FIG. 95A. FIG. 95D is a vertical cross-sectional view along the vertical plane D-D′ in FIG. 95A.

FIG. 96A-96D are various views of the fourth exemplary structure after removing etch-stop rings and via-bottom annular etch-stop structures according to the fourth embodiment of the present disclosure. FIG. 96A is a horizontal cross-sectional view along the horizontal plane A-A′ of FIG. 96D. FIG. 96B is a vertical cross-sectional view along the vertical plane B -B′ of FIG. 96A. FIG. 96C is a vertical cross-sectional view along the vertical plane C-C′ in FIG. 96A. FIG. 96D is a vertical cross-sectional view along the vertical plane D-D′ in FIG. 96A.

FIG. 97A-97D are various views of the fourth exemplary structure after performing a second selective isotropic etch process that forms strip-shaped cavities according to the fourth embodiment of the present disclosure. FIG. 97A is a horizontal cross-sectional view along the horizontal plane A-A′ of FIG. 97D. FIG. 97B is a vertical cross-sectional view along the vertical plane B-B′ of FIG. 97A. FIG. 97C is a vertical cross-sectional view along the vertical plane C-C′ in FIG. 97A. FIG. 97D is a vertical cross-sectional view along the vertical plane D-D′ in FIG. 97A.

FIG. 98A-98D are various views of the fourth exemplary structure after depositing a continuous conductive material layer according to the fourth embodiment of the present disclosure. FIG. 98A is a horizontal cross-sectional view along the horizontal plane A-A′ of FIG. 98D. FIG. 98B is a vertical cross-sectional view along the vertical plane B-B′ of FIG. 98A. FIG. 98C is a vertical cross-sectional view along the vertical plane C-C′ in FIG. 98A. FIG. 98D is a vertical cross-sectional view along the vertical plane D-D′ in FIG. 98A.

FIG. 99A-99D are various views of the fourth exemplary structure after depositing a continuous semiconductor material layer according to the fourth embodiment of the present disclosure. FIG. 99A is a horizontal cross-sectional view along the horizontal plane A-A′ of FIG. 99D. FIG. 99B is a vertical cross-sectional view along the vertical plane B-B′ of FIG. 99A. FIG. 99C is a vertical cross-sectional view along the vertical plane C-C′ in FIG. 99A. FIG. 99D is a vertical cross-sectional view along the vertical plane D-D′ in FIG. 99A.

FIG. 100A-100D are various views of the fourth exemplary structure after depositing a dielectric fill material layer and performing a planarization process according to the fourth embodiment of the present disclosure. FIG. 100A is a horizontal cross-sectional view along the horizontal plane A-A′ of FIG. 100D. FIG. 100B is a vertical cross-sectional view along the vertical plane B-B′ of FIG. 100A. FIG. 100C is a vertical cross-sectional view along the vertical plane C-C′ in FIG. 100A. FIG. 100D is a vertical cross-sectional view along the vertical plane D-D′ in FIG. 100A.

FIG. 101A-101D are various views of the fourth exemplary structure after removing semiconductor fill material portions according to the fourth embodiment of the present disclosure. FIG. 101A is a horizontal cross-sectional view along the horizontal plane A-A′ of FIG. 101D. FIG. 101B is a vertical cross-sectional view along the vertical plane B-B′ of FIG. 101A. FIG. 101C is a vertical cross-sectional view along the vertical plane C-C′ in FIG. 101A. FIG. 101D is a vertical cross-sectional view along the vertical plane D-D′ in FIG. 101A.

FIG. 102A-102D are various views of the fourth exemplary structure after removing conductive fill material portions according to the fourth embodiment of the present disclosure. FIG. 102A is a horizontal cross-sectional view along the horizontal plane A-A′ of FIG. 102D. FIG. 102B is a vertical cross-sectional view along the vertical plane B-B′ of FIG. 102A. FIG. 102C is a vertical cross-sectional view along the vertical plane C-C′ in FIG. 102A. FIG. 102D is a vertical cross-sectional view along the vertical plane D-D′ in FIG. 102A.

FIG. 103A-103D are various views of the fourth exemplary structure after formation of a continuous dielectric material structure according to the fourth embodiment of the present disclosure. FIG. 103A is a horizontal cross-sectional view along the horizontal plane A-A′ of FIG. 103D. FIG. 103B is a vertical cross-sectional view along the vertical plane B-B′ of FIG. 103A. FIG. 103C is a vertical cross-sectional view along the vertical plane C-C′ in FIG. 103A. FIG. 103D is a vertical cross-sectional view along the vertical plane D-D′ in FIG. 103A.

FIG. 104A-104H are sequential vertical cross-sectional views of a fifth exemplary structure during formation of connection-region dielectric wall structures and contact via cavities according to a fifth embodiment of the present disclosure.

FIGS. 105A and 105B are respective perspective and vertical cross-sectional views of power connections according to a various embodiments of the present disclosure.

FIG. 106 is a horizontal cross-sectional view of a sixth exemplary structure according to a sixth embodiment of the present disclosure.

FIGS. 107A and 107B are horizontal cross-sectional views of a comparative embodiment lateral isolation trench fill structure and a seventh exemplary lateral isolation trench fill structure according to a seventh embodiment of the present disclosure, respectively.

FIGS. 108A, 108B and 108C are horizontal cross-sectional views of alternative dielectric isolation structures according to the seventh embodiment of the present disclosure.

FIG. 109 is a horizontal cross-sectional view an alternative configuration of the seventh exemplary structure according to the seventh embodiment of the present disclosure.

### DETAILED DESCRIPTION

As discussed above, the embodiments of the present disclosure are directed to a three-dimensional memory device including integrated word line and via structures and methods for forming the same, the various aspects of which are described below. The embodiments of the present disclosure can be used to form various structures including a multilevel memory structure, non-limiting examples of which include semiconductor devices such as three-dimensional memory array devices comprising a plurality of NAND memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are used merely to identify similar elements, and different ordinals may be used across the specification and the claims of the instant disclosure. The same reference numerals refer to the same element or similar element. Unless otherwise indicated, elements having the same reference numerals are presumed to have the same composition. Unless otherwise indicated, a “contact” between elements refers to a direct contact between elements that provides an edge or a surface shared by the elements. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a “prototype” structure or an “in-process” structure refers to a transient structure that is subsequently modified in the shape or composition of at least one component therein. As used herein, a first electrical component is electrically connected to a second electrical component if there exists an electrically conductive path between the first electrical component and the second electrical component.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that can be attached to a circuit board through a set of pins or solder balls. A semiconductor package may include a semiconductor chip (or a “chip”) or a plurality of semiconductor chips that are bonded thereamongst, for example, by flip-chip bonding or another chip-to-chip bonding. A package or a chip may include a single semiconductor die (or a “die”) or a plurality of semiconductor dies. A die is the smallest unit that can independently execute external commands or report status. Typically, a package or a chip with multiple dies is capable of simultaneously executing as many external commands as the total number of dies therein. Each die includes one or more planes. Identical concurrent operations can be executed in each plane within a same die, although there may be some restrictions. In case a die is a memory die, i.e., a die including memory elements, concurrent read operations, concurrent write operations, or concurrent erase operations can be performed in each plane within a same memory die. Each plane contains a number of memory blocks (or “blocks”), which are the smallest unit that can be erased by in a single erase operation. Each memory block contains a number of pages, which are the smallest units that can be selected for programming.

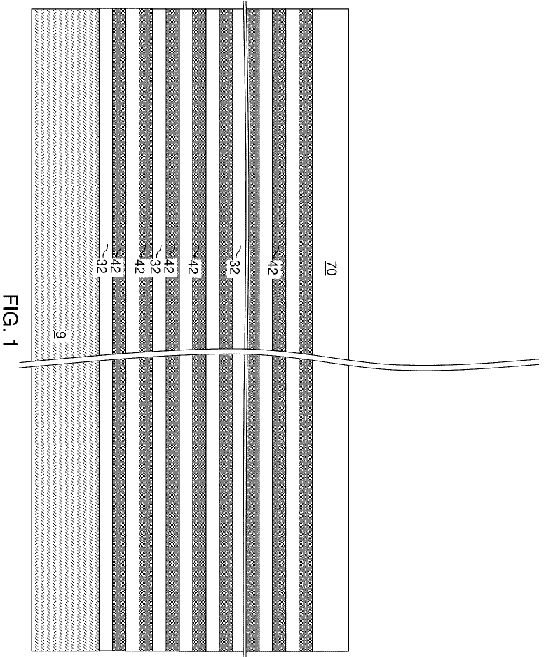

Referring to FIG. 1, a first exemplary structure according to the first embodiment of the present disclosure is illustrated, which can be used, for example, to fabricate a device structure containing vertical NAND memory devices. The first exemplary structure includes a substrate including a semiconductor material layer at least at an upper portion thereof. The semiconductor material layer 9 includes at least one elemental semiconductor material (e.g., a doped well in a single crystal silicon wafer or a deposited silicon layer), at least one III-V compound semiconductor material, at least one II-VI compound semiconductor material, at least one organic semiconductor material, or other semiconductor materials known in the art. In one embodiment, the semiconductor material layer may comprise a semiconductor material having a doping of a first conductivity type.

A stack of an alternating plurality of insulating layers 32 and sacrificial material layers 42 can be formed over the semiconductor material layer 9. The stack of the alternating plurality is herein referred to as an alternating stack (32, 42). In one embodiment, the alternating stack (32, 42) can include insulating layers 32 composed of the first material, and sacrificial material layers 42 composed of a second material different from that of insulating layers 32. The first material of the insulating layers 32 can be at least one insulating material. As such, each insulating layer 32 can be an insulating material layer. Insulating materials that can be used for the insulating layers 32 include, but are not limited to, silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the insulating layers 32 can be silicon oxide.

The second material of the sacrificial material layers 42 is a sacrificial material that can be removed selective to the first material of the insulating layers 32. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The sacrificial material layers 42 may comprise a dielectric material. In one embodiment, the sacrificial material layers 42 may comprise, and/or may consist essentially of, silicon nitride. The insulating layers 32 can be deposited, for example, by chemical vapor deposition (CVD). For example, if silicon oxide is used for the insulating layers 32, tetraethyl orthosilicate (TEOS) can be used as the precursor material for the CVD process. The sacrificial material layers 42 can be formed, for example, CVD or atomic layer deposition (ALD).

The thicknesses of the insulating layers 32 and the sacrificial material layers 42 can be in a range from 20 nm to 50 nm, although lesser and greater thicknesses can be used for each insulating layer 32 and for each sacrificial material layer 42. The number of repetitions of the pairs of an insulating layer 32 and a sacrificial material layer (e.g., a control gate electrode or a sacrificial material layer) 42 can be in a range from 2 to 1,024, and typically from 8 to 256, although a greater number of repetitions can also be used. The top and bottom gate electrodes in the stack may function as the select gate electrodes. In one embodiment, each sacrificial material layer 42 in the alternating stack (32, 42) can have a uniform thickness that is substantially invariant within each respective sacrificial material layer 42.

Optionally, an insulating cap layer 70 can be formed over the alternating stack (32, 42). The insulating cap layer 70 includes a dielectric material that is different from the material of the sacrificial material layers 42. In one embodiment, the insulating cap layer 70 can include a dielectric material that can be used for the insulating layers 32 as described above. The insulating cap layer 70 can have a greater thickness than each of the insulating layers 32. The insulating cap layer 70 can be deposited, for example, by chemical vapor deposition. In one embodiment, the insulating cap layer 70 can be a silicon oxide layer.

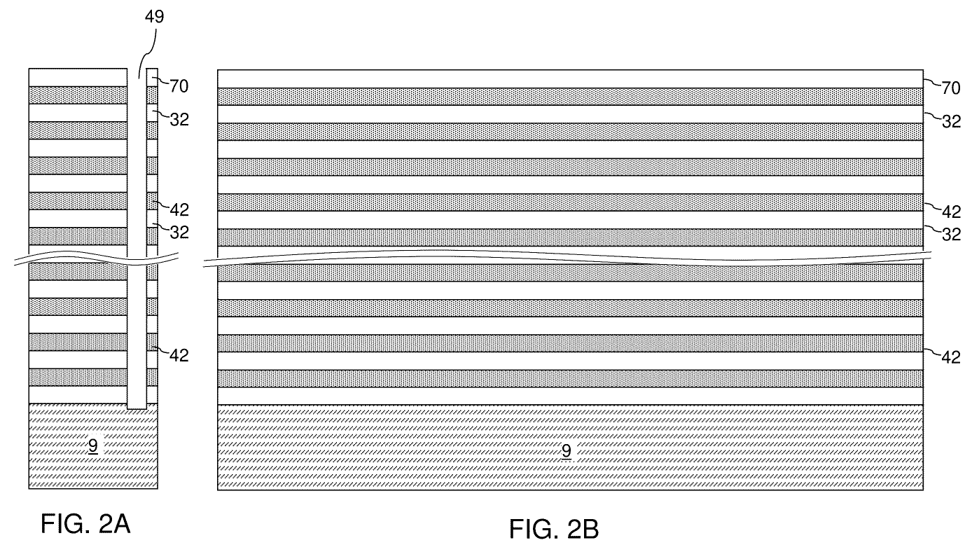

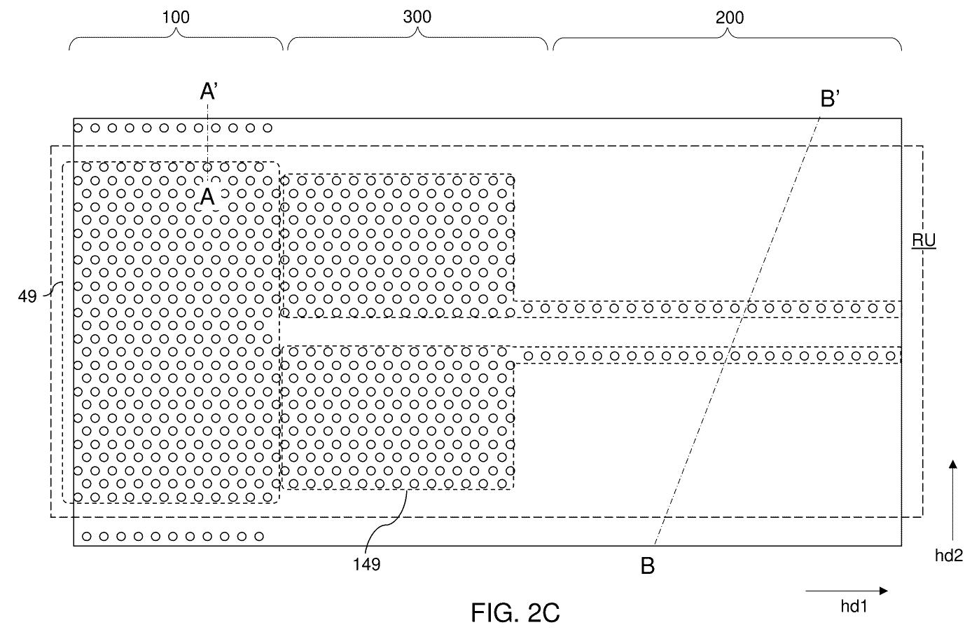

Referring to FIG. 2A-2C, a lithographic material stack (not shown) including at least a photoresist layer can be formed over the insulating cap layer 70, and can be lithographically patterned to form openings therein. The pattern in the lithographic material stack can be transferred through the insulating cap layer 70 and through the alternating stack (32, 42) by at least one anisotropic etch that uses the patterned lithographic material stack as an etch mask. Memory openings 49 are formed in a memory array region 100. As used herein, a “memory opening” refers to a structure in which memory elements, such as a memory stack structure, is subsequently formed. In one embodiment, the memory openings 49 may have a horizontal cross-sectional shape of a circle. In one embodiment, no openings are formed in a contact region 200, which is laterally spaced from the memory array region 100, and is subsequently employed to form contact via structures. The contact region 200 may be laterally spaced from the memory array region 100 along a first horizontal direction (e.g., word line direction) hd1. Dummy memory openings 149 can be formed in the contact region 200 and in a connection region 300. The connection region 300 may be located between the memory array region 100 and the contact region 200. The pattern of the dummy memory openings 149 in the contact region 300 may be selected so that dummy memory opening fill structures that are subsequently formed in the dummy memory openings 149 vertically extend through strip-shaped cavities to support overlying and underlying portions of the insulating layers 32.

In one embodiment, the pattern of the memory openings 49 and the dummy memory openings 149 may be a periodic pattern that is repeated along a second horizontal direction (e.g., bit line direction) hd2 that is perpendicular to the first horizontal direction hd1. The unit of repetition for the pattern of the memory openings 49 and the dummy memory openings 149 is herein referred to as a repetition unit RU. Each repetition unit RU may correspond to a memory block or to a portion of a memory block. Each repetition unit RU may comprise a two-dimensional array of memory openings 49 in the memory array region 100. The two-dimensional array of memory openings 49 may comprise a plurality of rows of memory openings 49, and each row of memory openings 49 may be arranged along the first horizontal direction hd2. Each repetition unit RU may comprise at least one two-dimensional array of dummy memory openings 149 in the connection region 300. In one embodiment, the number of rows of the memory openings 49 may be greater than the number of rows of dummy memory openings 149. In one embodiment, a width along the second horizontal direction hd2 of an area occupied by the memory openings 49 may be greater than the width along the second horizontal direction hd2 of an area occupied by the dummy memory openings 149.

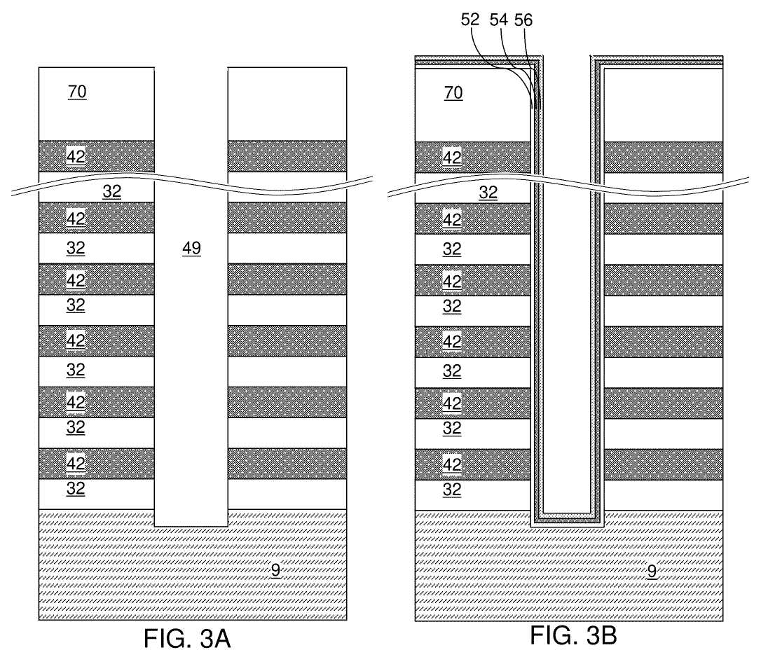

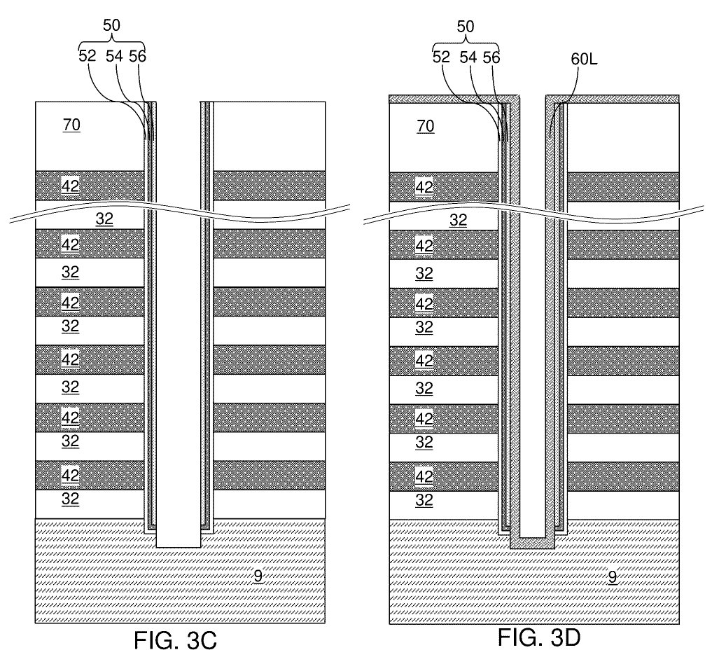

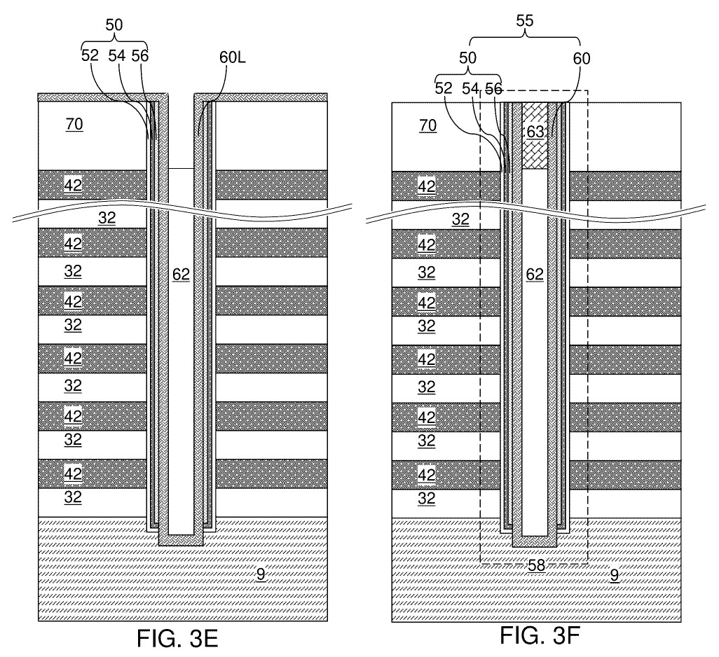

FIG. 3A-3F are sequential schematic vertical cross-sectional views of a memory opening 49 within the first exemplary structure during formation of a memory opening fill structure 58 therein according to the first embodiment of the present disclosure.

Referring to FIG. 3A, a memory opening 49 is illustrated after the processing steps described with reference to FIG. 2A-2C.

Referring to FIG. 3B, a set of material layers can be conformally deposited, which may include an optional blocking dielectric layer 52, a memory material layer 54, and an optional dielectric liner 56. The blocking dielectric layer 52 may comprise at least one blocking dielectric material such as silicon oxide and/or a dielectric metal oxide. The memory material layer 54 may comprise any memory material that can store memory bits therein. For example, the memory material layer 54 may comprise a charge storage layer, such as a silicon nitride layer. Alternatively, the memory material layer 54 may comprise a ferroelectric memory material, a resistive memory material, a phase change memory material, or any other memory material known in the art. In some embodiments, the memory material layer 54 may comprise a vertical stack of discrete memory material portions that are formed at levels of the electrically conductive layers 46. Generally, the memory material layer 54 may comprise a vertical stack of memory elements that are formed at the levels of the electrically conductive layers 46. In one embodiment, the vertical stack of memory elements comprises portions of the memory material layer 54 located at the levels of the electrically conductive layers 46. The optional dielectric liner 56, if present, can provide electrical isolation between the memory material layer 54 and a semiconductor channel to be subsequently formed. In case the memory material layer 54 comprises a charge storage material, the optional dielectric liner 56 may comprise a tunneling dielectric layer.

Referring to FIG. 3C, an anisotropic etch process may be performed to remove horizontally-extending portions of the optional blocking dielectric layer 52, the memory material layer 54, and the optional dielectric liner 56. The combination of vertically-extending portions of the optional blocking dielectric layer 52, the memory material layer 54, and the optional dielectric liner 56 that remain in a respective memory opening 49 constitutes a memory film 50.

Referring to FIG. 3D, a semiconductor channel layer 60L can be deposited over the memory films 50. The semiconductor channel layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel layer 60L includes amorphous silicon or polysilicon. The semiconductor channel layer 60L can be formed by a conformal deposition method such as low pressure chemical vapor deposition (LPCVD). In one embodiment, the semiconductor channel layer 60L can be deposited as an amorphous semiconductor material. The thickness of the semiconductor channel layer 60L can be in a range from 2 nm to 10 nm, although lesser and greater thicknesses can also be used. A memory cavity is formed in the volume of each memory opening 49 that is not filled with the deposited material layers (52, 54, 56, 60L).

Referring to FIG. 3E, a dielectric core layer can be deposited to fill any remaining portion of the memory cavity within each memory opening. The dielectric core layer includes a dielectric material, such as silicon oxide or organosilicate glass. The dielectric core layer can be deposited by a conformal deposition method such as low pressure chemical vapor deposition (LPCVD), or by a self-planarizing deposition process such as spin coating. The dielectric core layer can be subsequently recessed selective to the material of the semiconductor channel layer 60L, for example, by a recess etch. The material of the dielectric core layer is vertically recessed below the horizontal plane including the top surface of the insulating cap layer 70. Each remaining portion of the dielectric core layer constitutes a dielectric core 62.

Referring to FIG. 3F, a doped semiconductor material having a doping of a second conductivity type can be deposited within each recess cavity located above the dielectric cores 62. The second conductivity type is the opposite of the first conductivity type. For example, if the first conductivity type is p-type, the second conductivity type is n-type, and vice versa. In one embodiment, the doped semiconductor material may be deposited as an amorphous semiconductor material. The dopant concentration in the doped semiconductor material having a doping of the second conductivity type can be in a range from 5.0×10¹⁸/cm³ to 2.0×10²¹/cm³, although lesser and greater dopant concentrations can also be used.

A planarization process can be performed to remove portions of the doped semiconductor material having a doping of the second conductivity type and the semiconductor channel layer 60L from above the top surface of the insulating cap layer 70, for example, by chemical mechanical planarization (CMP) or a recess etch to form drain regions 63. Each remaining portion of the semiconductor material having a doping of the second conductivity type constitutes a drain region 63. Each remaining portion of the semiconductor channel layer 60L constitutes a vertical semiconductor channel 60. Electrical current can flow through each vertical semiconductor channel 60 when a vertical NAND device including the vertical semiconductor channel 60 is turned on. Within each memory opening 49, a dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which can store electrical charges with a macroscopic retention time. In some embodiments, a blocking dielectric layer 52 may not be present in the memory film 50 at this step, and a blocking dielectric layer may be subsequently formed after formation of laterally-extending cavities. As used herein, a macroscopic retention time refers to a retention time suitable for operation of a memory device as a permanent memory device such as a retention time in excess of 24 hours. Each combination of a memory film 50 and a vertical semiconductor channel 60 constitutes a memory stack structure 55.

Each contiguous combination of a vertical semiconductor channel 60 and a memory film 50 constitutes a memory stack structure 55. Thus, each memory stack structure 55 can include a vertical semiconductor channel 60, a dielectric liner 56, a plurality of memory elements comprising portions of the memory material layer 54, and an optional blocking dielectric layer 52. Each combination of a memory stack structure 55, a dielectric core 62, and a drain region 63 within a memory opening 49 is herein referred to as a memory opening fill structure 58.

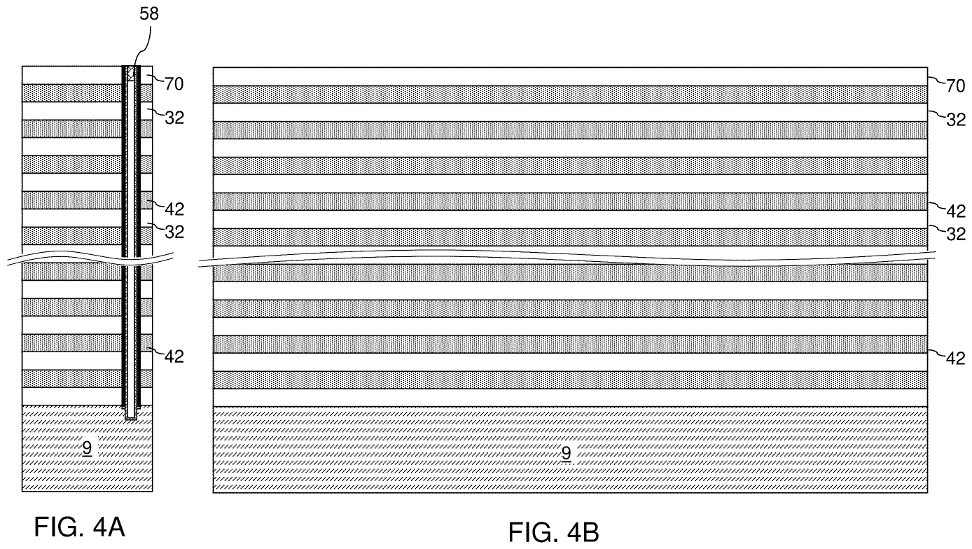

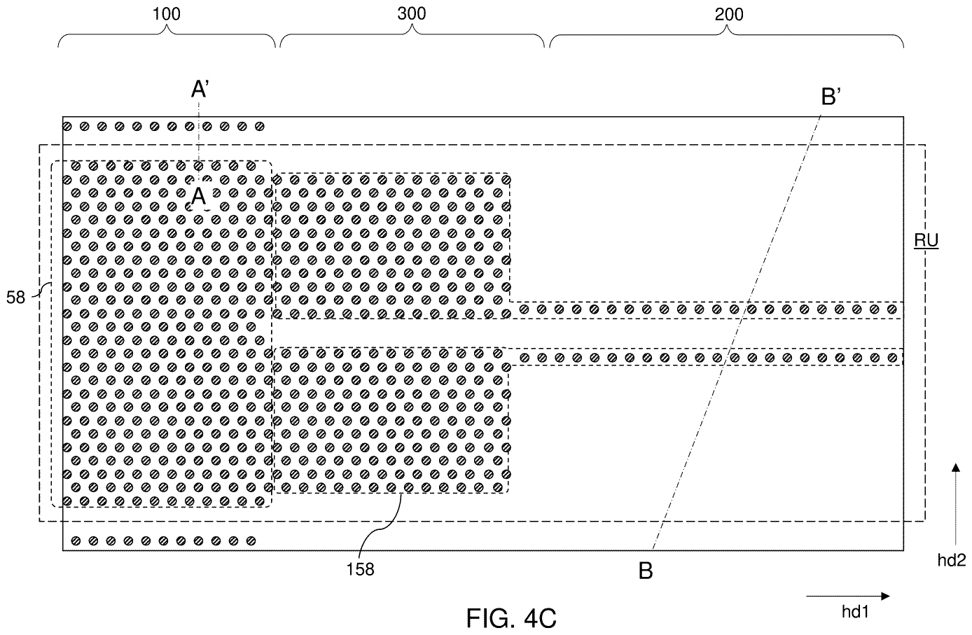

Referring to FIG. 4A-4C, the first exemplary structure is illustrated after the processing steps described with reference to FIG. 3F. Memory opening fill structures 58 are formed in the memory openings 49 in the memory array region 100. Generally, an alternating stack of insulating layers 32 and sacrificial material layers 42 is formed over a substrate, and memory openings 49 are formed through the alternating stack (32, 42). Memory opening fill structures 58 are formed in the memory openings 49. Each of the memory opening fill structures 58 comprises a respective vertical stack of memory elements (which may comprise portions of the respective memory material layer 54), a vertical semiconductor channel 60 and a drain region 63. Dummy memory opening fill structures 158 are formed in the dummy memory openings 149 in the connection region 300 and in the contact region 200. Dummy memory opening fill structures 158 may have the same composition as the memory opening fill structures 58, except that the dummy drain regions of the dummy memory opening fill structures 158 are not electrically connected to subsequently formed bit lines, and therefore the dummy memory opening fill structures 158 do not store data during operation of the memory device. In one embodiment, the number of rows of the memory opening fill structures 58 may be greater than the number of rows of dummy memory opening fill structures 158. In one embodiment, a width along the second horizontal direction hd2 of an area occupied by the memory opening fill structures 58 may be greater than the width along the second horizontal direction hd2 of an area occupied by the dummy memory opening fill structures 158.

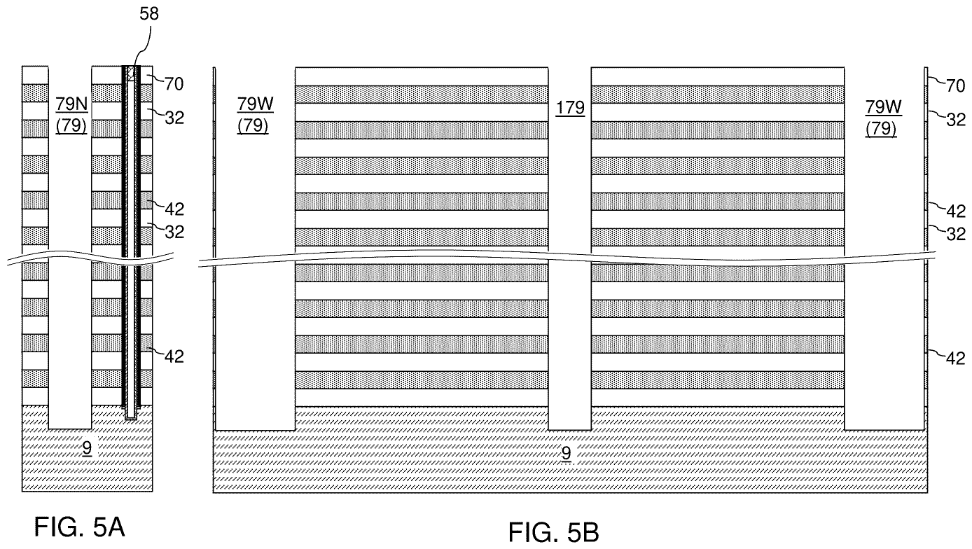

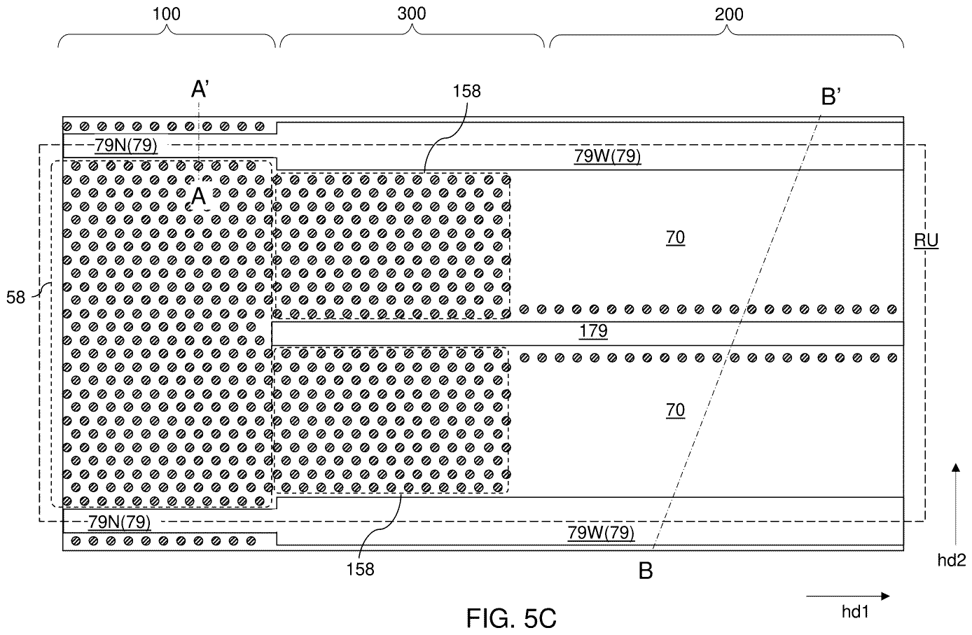

Referring to FIG. 5A-5C, a photoresist layer (not shown) can be applied over the insulating cap layer 70, and can be lithographically patterned to form elongated openings that laterally extend along the first horizontal direction hd1. An anisotropic etch process is performed to etch through unmasked portions of the insulating cap layer 70 and the alternating stack (32, 42) to form various trenches, which are herein referred to as lateral isolation trenches (79, 179). The photoresist layer can be subsequently removed, for example, by ashing.

According to an aspect of the present disclosure, the lateral isolation trenches (79, 179) include dual-width lateral isolation trenches 79 and access lateral isolation trenches 179 that are interlaced along the second horizontal direction hd2 with a uniform pitch along the second horizontal direction hd2. The uniform pitch may be the same as the width of each repetition unit RU (e.g., memory block width) along the second horizontal direction (e.g., bit line direction) hd2. Each dual-width lateral isolation trench 79 comprises a respective wide lateral isolation trench section 79W having a first width and a narrow lateral isolation trench section 79N having a second width. The first width is greater than the second width. In one embodiment, the second width is greater than the thickness of each sacrificial material layer 42. In one embodiment, the second width may be greater than the thickness of each sacrificial material layer 42 at least by a factor of 2, and preferably by a factor of 4, and more preferably by a factor of 10. The first width is greater than the second width at least by the thickness of each sacrificial material layer 42, and preferably by twice, and/or four times, and/or 8 times, the thickness of each sacrificial material layer 42. Each access lateral isolation trench 179 may have a uniform width that is the same as or about the same as the second width.

In one embodiment, each wide lateral isolation trench section 79W and each access lateral isolation trench 179 laterally extend through the contact region 200 and the connection region 300, and do not extend into the memory array region 100. Each narrow lateral isolation trench section 79N laterally extends through the memory array region 100. Each narrow lateral isolation trench section 79N may be adjoined to a respective wide lateral isolation trench section 79W at or adjacent to a boundary between the memory array region 100 and the connection region 300. Generally, the dual-width lateral isolation trenches 79 and the access lateral isolation trenches 179 may be formed simultaneously employing an anisotropic etch process. The dual-width lateral isolation trenches 79 and the access lateral isolation trenches 179 laterally extend along the first horizontal direction hd1, and are interlaced along the second horizontal direction hd2 such that the dual-width lateral isolation trenches 79 and the access lateral isolation trenches 179 alternate along the second horizontal direction hd2.

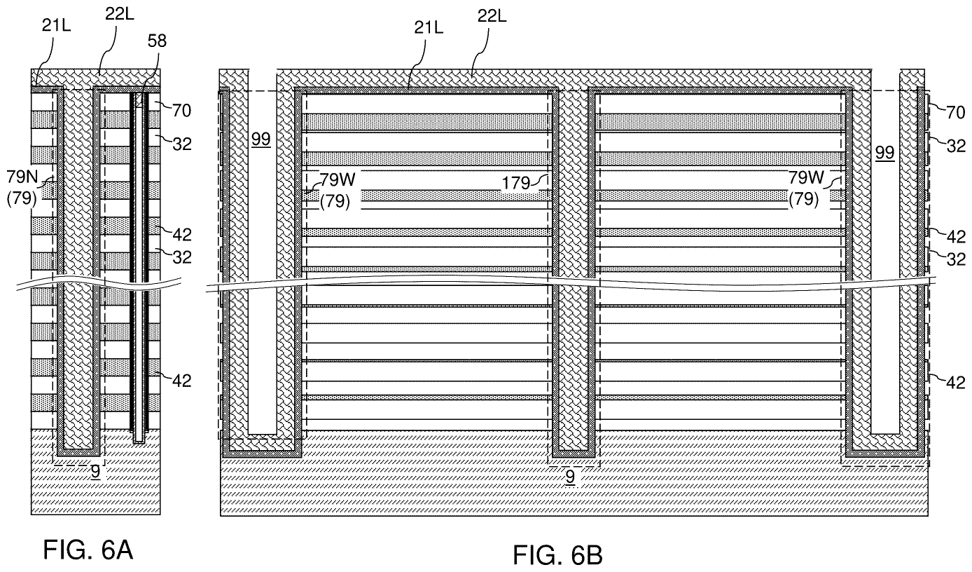

Referring to FIGS. 6A and 6B, a sacrificial barrier liner 21L may be conformally deposited on the first exemplary structure. The sacrificial barrier liner 21L may comprise a dielectric material, such as silicon nitride, and may have a thickness in a range from 5 nm to 30 nm, although lesser or greater thicknesses may also be employed.

A sacrificial fill material layer 22L can be conformally deposited over the sacrificial barrier liner 21L. The sacrificial fill material layer 22L comprises a sacrificial fill material that may be subsequently removed selectively to the material of the sacrificial barrier liner 21L. For example, the sacrificial fill material layer 22L may comprise amorphous silicon or polysilicon. The thickness of the sacrificial fill material layer 22L can be selected such that the sacrificial fill material layer 22L fills the volumes of the cavities in the narrow lateral isolation trench sections 79N and the access lateral isolation trenches 179 without completely filing the volumes of the cavities in the wide lateral isolation trench sections 79W. Thus, elongated wall-shaped voids 99 are present within the volumes of the wide lateral isolation trench sections 79W.

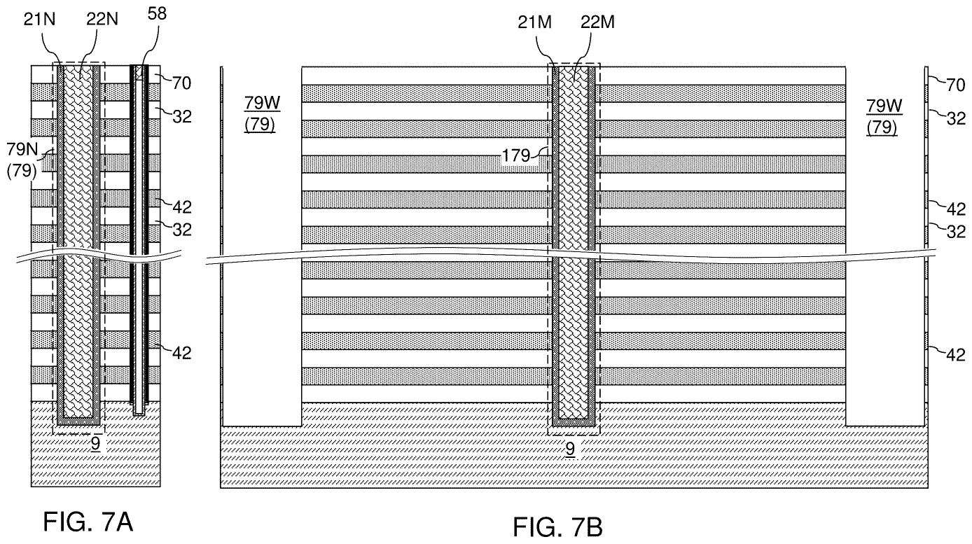

Referring to FIGS. 7A and 7B, a first selective isotropic etch process can be performed to isotropically etch back physically exposed portions of the sacrificial fill material layer 22L. The duration of the first selective isotropic etch back process can be selected such that the material of the sacrificial fill material layer 22L is completely removed from inside the wide lateral isolation trench sections 79W, while portions of the sacrificial fill material layer 22L located within the narrow lateral isolation trench sections 79N and the access lateral isolation trenches 179 are not removed. Each remaining portion of the sacrificial fill material layer 22L that remains in a narrow lateral isolation trench section 79N is herein referred to as a sacrificial narrow isolation trench fill structure 22N. Each remaining portion of the sacrificial fill material layer 22L that remains in an access lateral isolation trench 179 is herein referred to as a sacrificial access lateral isolation trench fill structure 22M.

A second selective isotropic etch process can be performed to isotropically etch back physically exposed portions of the sacrificial barrier liner 21L. The duration of the second selective isotropic etch back process can be selected such that the material of the sacrificial barrier liner 21L is completely removed from inside the wide lateral isolation trench sections 79W, while the covered portions of the sacrificial barrier liner 21L located within the narrow lateral isolation trench sections 79N and the access lateral isolation trenches 179 are not removed. Each remaining portion of the sacrificial barrier liner 21L that remains in a narrow lateral isolation trench section 79N is herein referred to as a sacrificial narrow trench liner 21N. Each remaining portion of the sacrificial barrier liner 21L that remains in an access lateral isolation trench 179 is herein referred to as a sacrificial access lateral isolation trench liner 21M.

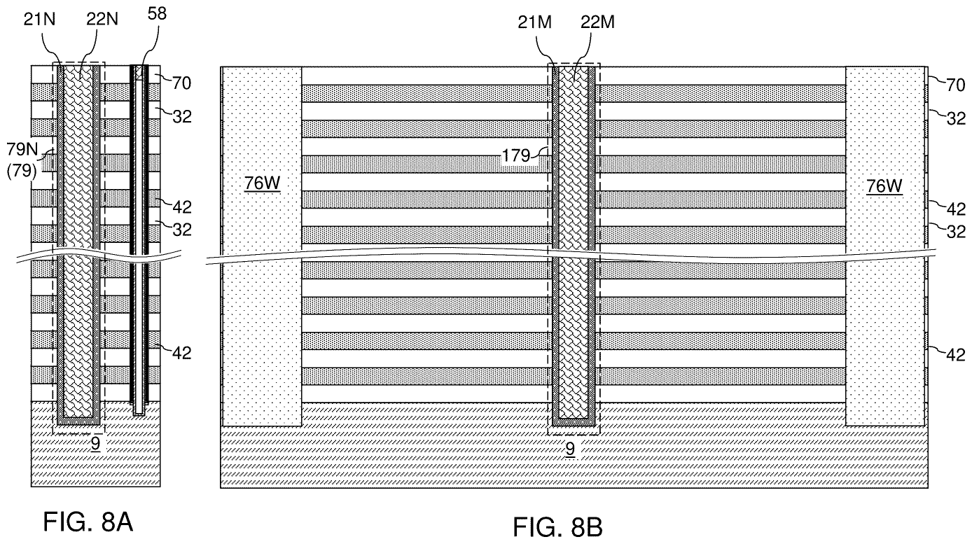

Referring to FIGS. 8A and 8B, a first dielectric fill material, such as undoped silicate glass (i.e., silicon oxide) or a doped silicate glass can be deposited in the volumes of the voids in the wide lateral isolation trench sections 79W. A planarization process, such as a chemical mechanical polishing process, can be performed to remove portions of the first dielectric fill material from above the horizontal plane including the top surface of the insulating cap layer 70. Each remaining portion of the first dielectric fill material that fills a respective wide lateral isolation trench section 79W constitutes a wide lateral isolation trench fill structure 76W. Top surfaces of the lateral isolation trench fill structure 76W may be formed within the horizontal plane including the top surface of the insulating cap layer 70. Each wide lateral isolation trench fill structure 76W may have a uniform width along the second horizontal direction hd2, which may be the first width.

Generally, neighboring pairs of alternating stacks (32, 42) of insulating layers 32 and sacrificial material layers 42 may be laterally spaced apart from each other by a respective dual-width lateral isolation trench 79 having a wide lateral isolation trench section 79W and a narrow lateral isolation trench section 79N. The wide lateral isolation trench section 79W is filled with a wide lateral isolation trench fill structure 76W that comprises the first dielectric fill material.

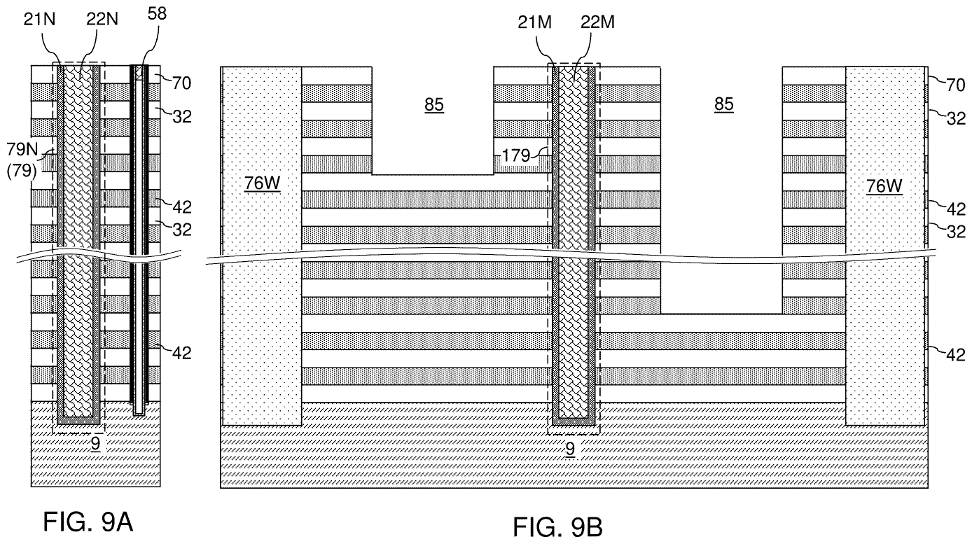

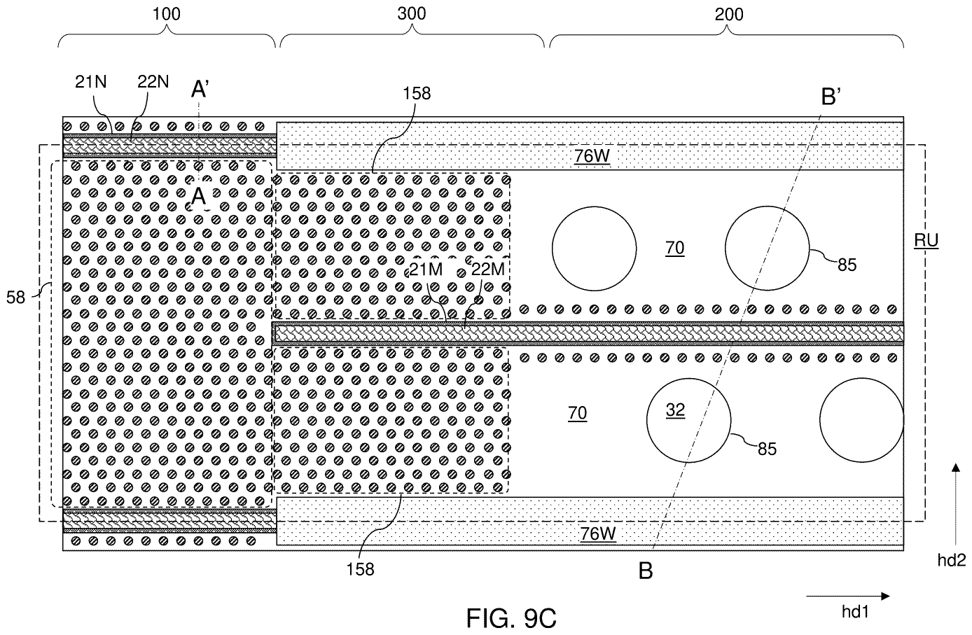

Referring to FIG. 9A-9C, contact via openings 85 are formed within the contact region 200. Each of the contact via openings 85 can vertically extend through the insulating cap layer 70 and optionally through a respective subset of the sacrificial material layers 42 and the insulating layers 32 such that a top surface of an insulating layer 32 is physically exposed at the bottom of each contact via opening 85. In one embodiment, the contact via openings 85 may have different depths from each other. In one embodiment, a contact via opening 85 may be provided for each insulating layer 32 such that a top surface segment of the insulating layer 32 is physically exposed underneath a respective one of the contact via openings 85.

The contact via openings 85 having different depths may be formed employing a plurality of masked anisotropic etch processes. In an illustrative example, a patterned hard mask layer (not shown) including openings therethrough may be formed over the insulating cap layer 70. The patterned hard mask layer may comprise a dielectric material such as silicon nitride, a semiconductor material such as polysilicon or amorphous silicon, and/or a metallic material such as TiN. The openings in the patterned hard mask layer may have the pattern of all of the contact via openings 85 to be subsequently formed. An anisotropic etch process may be performed to transfer the pattern of the openings in the patterned hard mask layer through the insulating cap layer 70.

Subsequently, multiple iterations of a combination of a respective masking process and a respective anisotropic etch process may be performed to etch through a respective subset of the sacrificial material layers 42 and the insulating layers 32. Each masking process forms a respective patterned photoresist layer that masks a respective subset of the openings in the patterned hard mask layer without masking a respective complementary subset of the openings. Each anisotropic etch process etches a respective number of sacrificial material layers 42 and a respective number of insulating layers 32 underneath each opening in the pattered hard mask layer that is not masked by a respective patterned photoresist layer. In one embodiment, the number of etched sacrificial material layers 42 and etched insulating layers 32 underneath unmasked openings in the patterned hard mask layer may be a non-negative integer power of 2, i.e., 1, 2, 4, 8, 16, 32, 64, etc. By employing a combination of various masking patterns for the patterned photoresist layers, the total depths of the contact via openings 85 can be varied to enable physical exposure of the top surfaces of sacrificial material layers 42 at each level of the electrically conductive layers 46. The patterned hard mask layer can be subsequently removed. The lateral dimensions (such as diameters) of the contact via openings 85 may be in a range from 30 nm to 300 nm, although lesser and greater lateral dimensions may also be employed. Generally, a contact via opening 85 may vertically extend through an alternating stack of insulating layers 32 and sacrificial material layers 42.

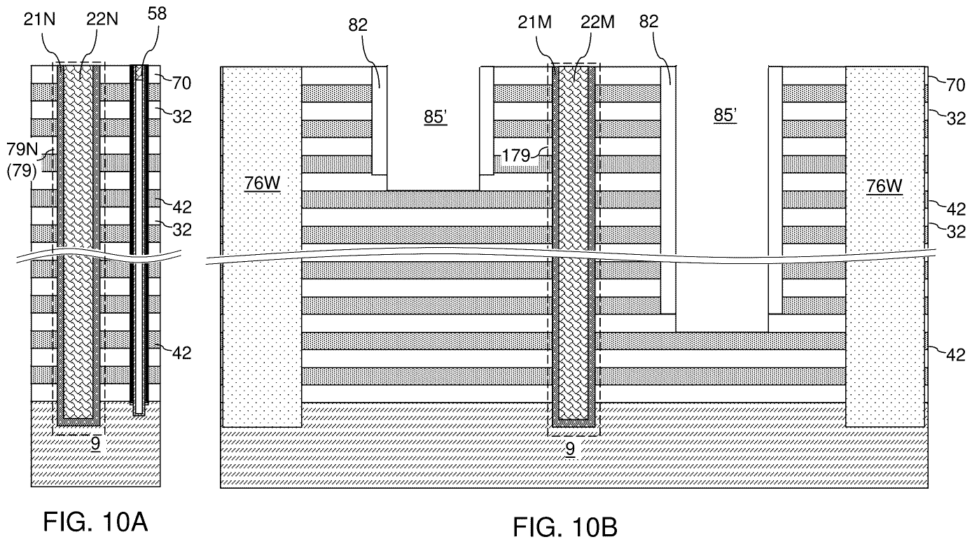

Referring to FIGS. 10A and 10B, tubular insulating spacers 82 may be formed in peripheral regions of the contact via openings 85 by depositing a conformal insulating material layer, such as a silicon oxide layer, and by performing an anisotropic etch process that etches horizontally-extending portions of the conformal insulating material layer. Remaining tubular portions of the conformal insulating material layer constitute the tubular insulating spacers 82. The anisotropic etch process can be prolonged to etch through unmasked portions of the insulating layers 32 such that contact via cavities 85′ laterally surrounded by the tubular insulating spacers 82 are vertically extended. A top surface segment of a respective underlying sacrificial material layer 42 may be physically exposed underneath each contact via cavity 85′.

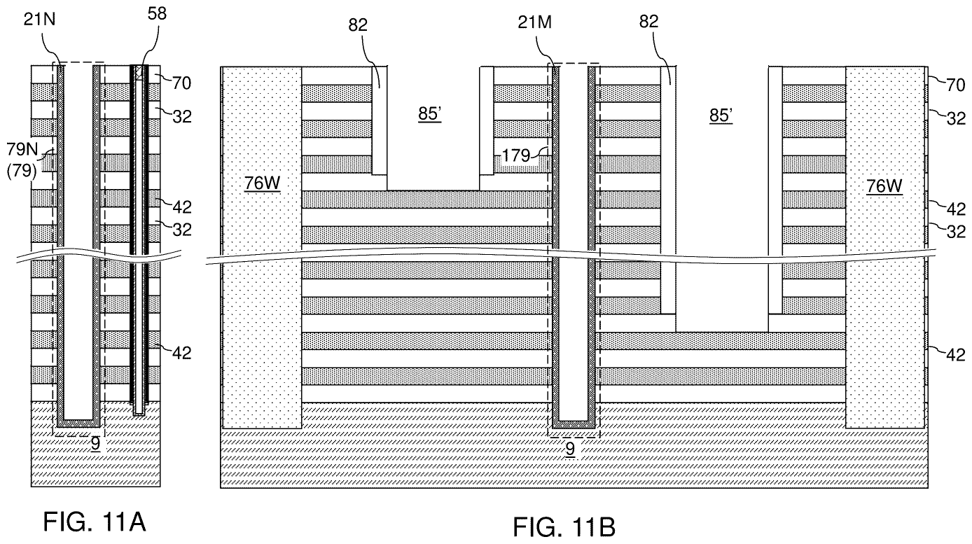

Referring to FIGS. 11A and 11B, a selective etch process can be performed to remove sacrificial narrow lateral isolation trench fill structures 22N and sacrificial access lateral isolation trench fill structures 22M. Voids are formed in the volumes from which the sacrificial narrow lateral isolation trench fill structures 22N and the sacrificial access lateral isolation trench fill structures 22M are removed.

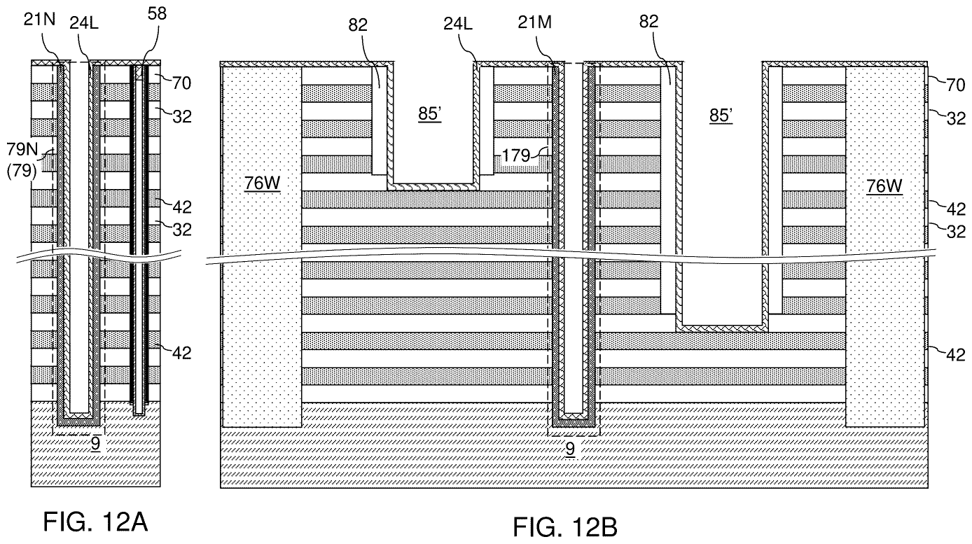

Referring to FIGS. 12A and 12B, a sacrificial barrier liner 24L can be deposited in the voids and over the insulating cap layer 70 by performing a first conformal deposition process. The sacrificial barrier liner 24L comprises a sacrificial barrier material that may be subsequently removed selectively to the material of the sacrificial narrow trench liners 21N and the sacrificial access lateral isolation trench liners 21M. For example, the sacrificial barrier liner 24L may comprise amorphous silicon or polysilicon having thickness in a range from 30 nm to 100 nm, although lesser or greater thicknesses may also be employed.

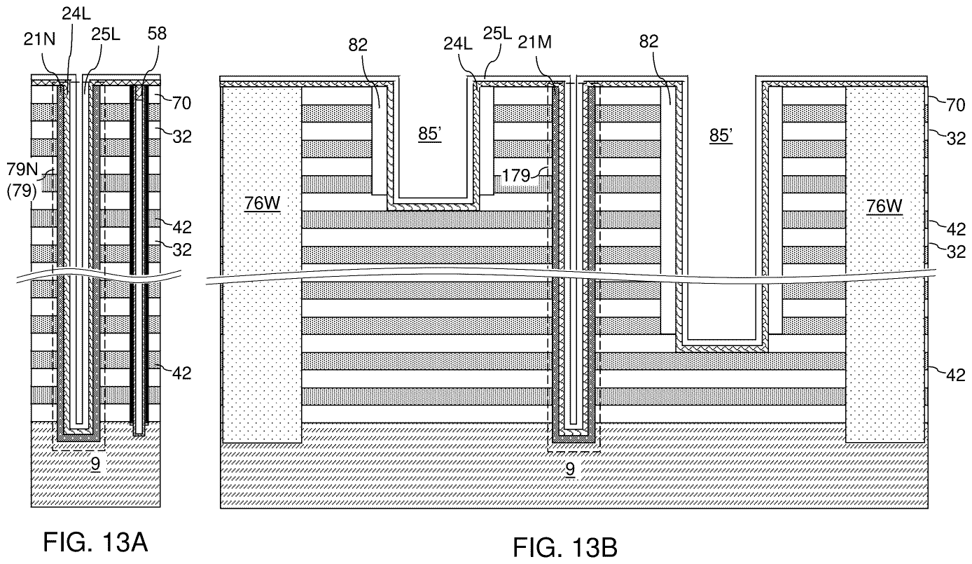

Referring to FIGS. 13A and 13B, a sacrificial dielectric liner 25L can be deposited by performing a second conformal deposition process. The sacrificial dielectric liner 25L comprises a sacrificial dielectric material that may be subsequently removed selectively to the material of the sacrificial barrier liner 24L. For example, the sacrificial dielectric liner 25L may comprise silicon oxide having thickness in a range from 5 nm to 30 nm, although lesser or greater thicknesses may also be employed.

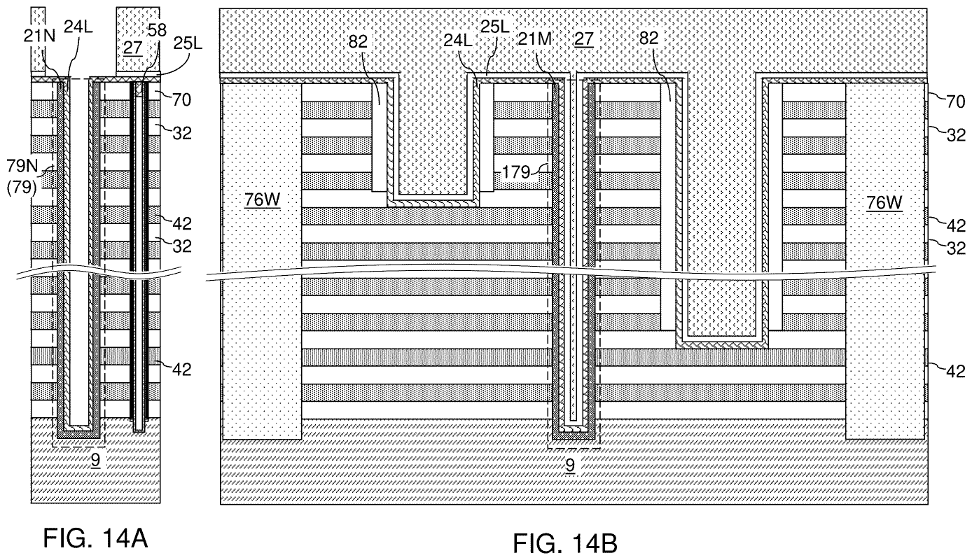

Referring to FIGS. 14A and 14B, a photoresist layer 27 can be applied over the first exemplary structure, and can be lithographically patterned to form openings over the areas of the narrow lateral isolation trench sections 79N while covering areas outside of the narrow lateral isolation trench sections 79N in a plan view. A first etch process can be performed to remove unmasked portions of the sacrificial dielectric liner 25L selectively to the material of the sacrificial barrier liner 24L. Each portion of the sacrificial dielectric liner 25L located within the narrow lateral isolation trench sections 79N may be removed, and surfaces of the sacrificial barrier liner 24L may be physically exposed around the wall-shaped cavities within the volumes of the narrow lateral isolation trench sections 79N.

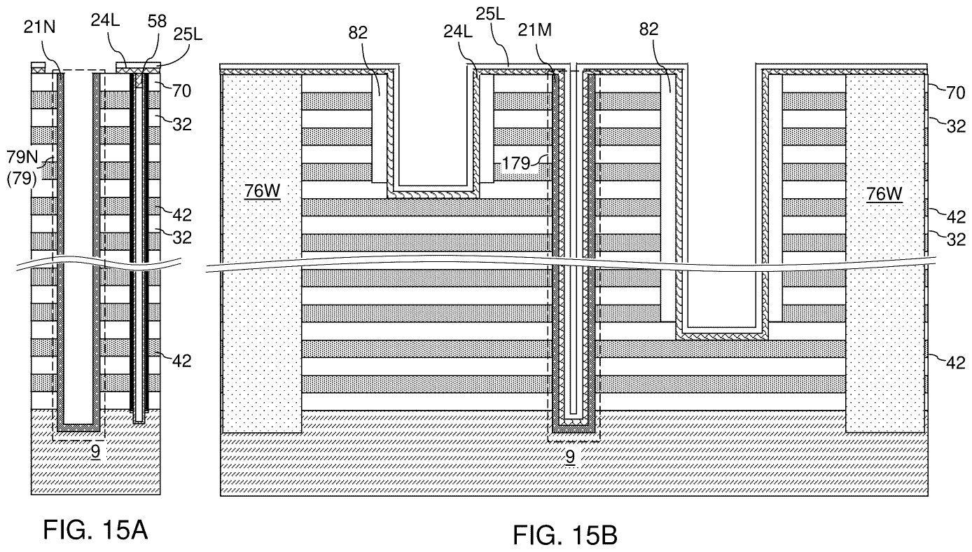

Referring to FIGS. 15A and 15B, a second etch process can be performed to remove unmasked portions of the sacrificial barrier liner 24L selectively to the materials of the sacrificial dielectric liner 25L and the sacrificial narrow trench liners 21N. Surfaces of the sacrificial narrow trench liners 21N are physically exposed in the narrow lateral isolation trench sections 79N. The photoresist layer 27 can be subsequently removed, for example, by ashing.

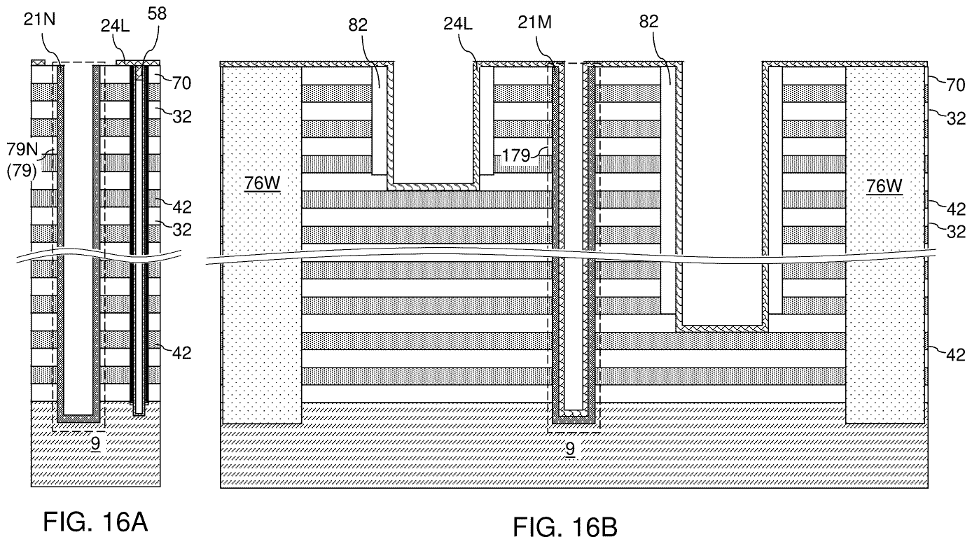

Referring to FIGS. 16A and 16B, remaining portions of the sacrificial dielectric liner 25L can be removed selectively to the material of the sacrificial barrier liner 24L. For example, if the sacrificial dielectric liner 25L comprises silicon oxide, a wet etch process employing dilute hydrofluoric acid may be performed to remove the sacrificial dielectric liner 25L.

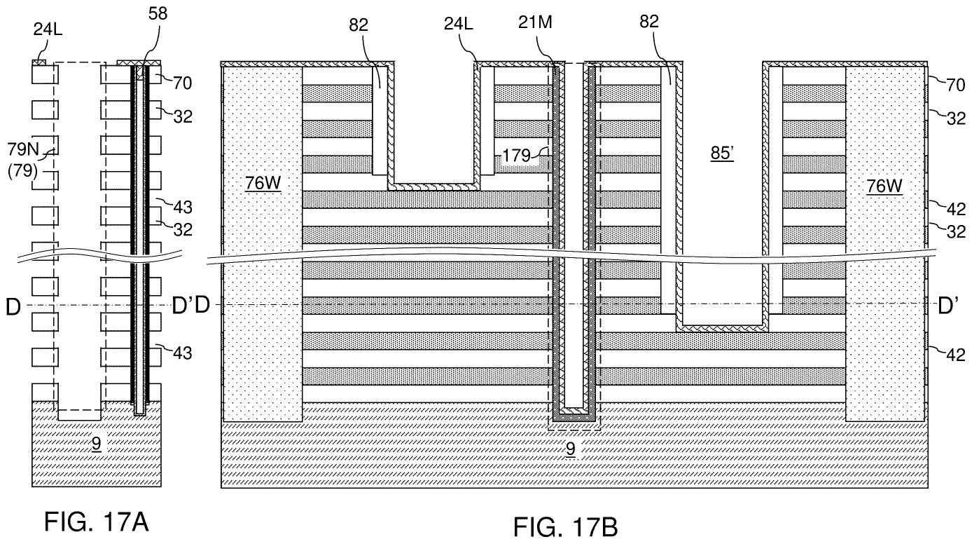

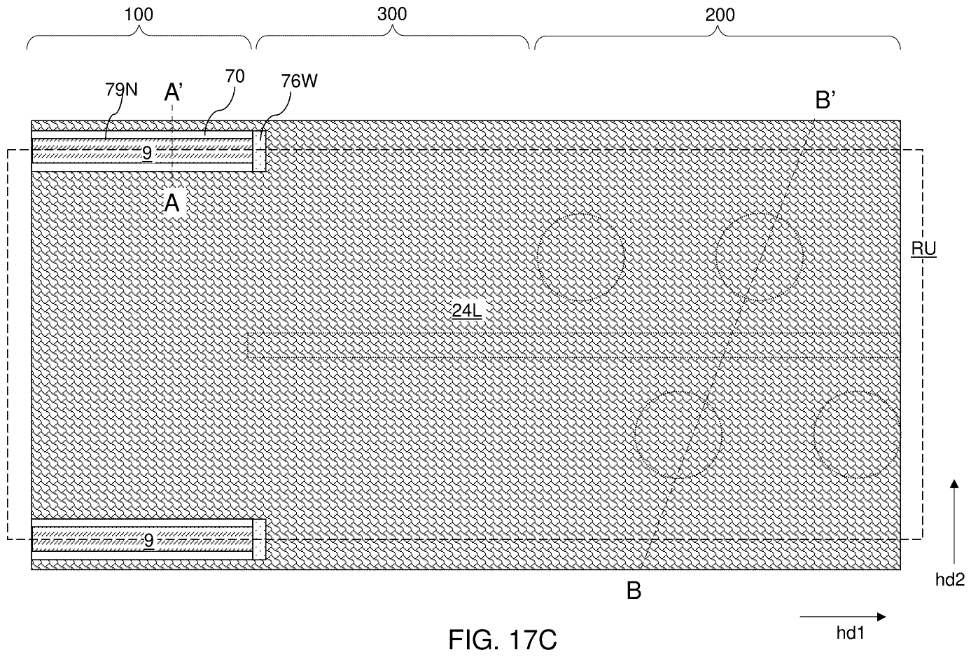

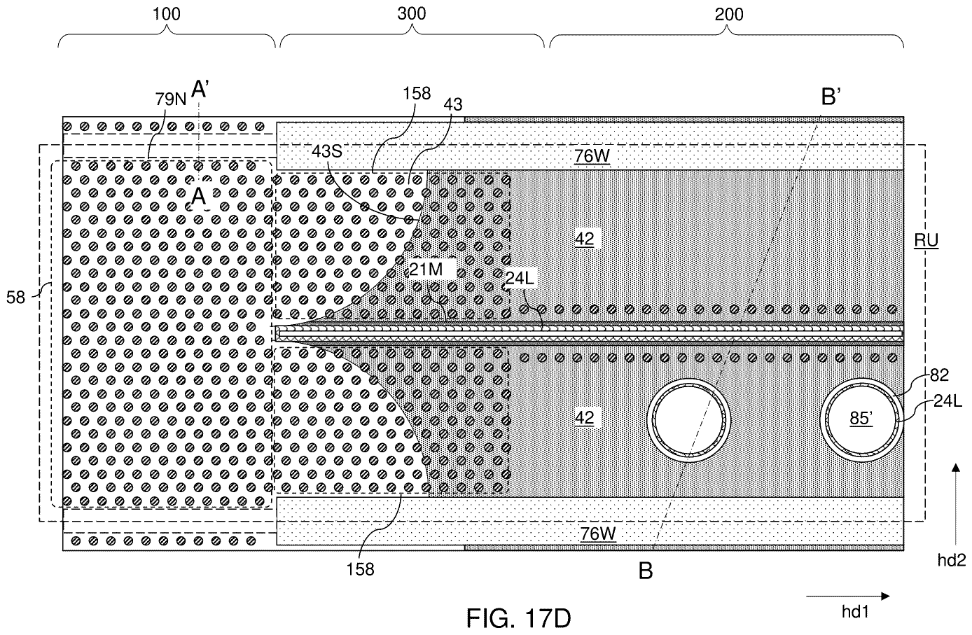

Referring to FIG. 17A-17D, a first selective isotropic etch process can be performed, which etches the materials of the sacrificial narrow trench liners 21N and the sacrificial material layers 42. In one embodiment, the sacrificial narrower trench liners 21N, the sacrificial access lateral isolation trench liners 21M, and the sacrificial material layers 42 may comprise the same material, such as silicon nitride. The first selective isotropic etch process removes the entirety of the sacrificial narrow trench liners 21N and laterally recesses physically exposed portions of the sacrificial material layers 42 by a first etch distance, but does not etch the sacrificial access lateral isolation trench liners 21M that are covered by the sacrificial barrier liner 24L.

Generally, the sacrificial material layers 42 are isotropically recessed from around the narrow lateral isolation trench sections 79N by the first lateral etch distance selectively to the materials of the insulating layers 32, the insulating cap layer 70, the tubular insulating spacers 82, the semiconductor material layer 9, and the material of the outermost layers of the memory films 50. Laterally-extending cavities 43 are formed in volumes from which the sacrificial material layers 42 are removed. The first lateral etch distance is greater than the lateral spacing between neighboring pairs of narrow lateral isolation trench sections 79N. Thus, a continuous void that laterally extends through all of the repetition units RU can be formed in the memory array region 100 at each level of the sacrificial material layers 42.

The first selective isotropic etch process may comprise a wet etch process employing a wet etch solution, and/or may comprise a gas phase (dry) etch process in which the etchant is introduced in a vapor phase into the narrow lateral isolation trench sections 79N. For example, if the sacrificial material layers 42 include silicon nitride, the etch process can be a wet etch process in which the first exemplary structure is immersed within a wet etch tank including phosphoric acid, which etches silicon nitride selective to silicon oxide, silicon, and various other materials employed in the art. The memory opening fill structures 58 provide structural support while the laterally-extending cavities 43 are present within volumes previously occupied by the sacrificial material layers 42.

The laterally-extending cavities 43 expand laterally from around the narrow lateral isolation trench sections 79N until the laterally-extending cavities 43 merge into continuous laterally-extending void that continuously extend between neighboring pairs of narrow lateral isolation trench sections 79N within the areas of the memory array region 100. The first selective isotropic etch process isotropically recesses the sacrificial material layers 42 employing the narrow lateral isolation trench sections 79N as first conduits for a first selective isotropic etchant while the wide lateral isolation trench fill structures 76W prevent isotropic etchant access to the sacrificial material layers 42 through the wide lateral isolation trench sections 79W. In this case, the wide lateral isolation trench sections 79W are filled with the wide lateral isolation trench fill structures 76W during the first selective isotropic etch process.

In one embodiment shown in FIG. 17D, each of the laterally-extending cavities 43 may have a pair of laterally-convex sidewall sections 43S in a connection region 300 that is located between the memory array region 100 and the contact region 200. Each laterally-extending cavity 43 may have a portion located within the memory array region 100 and laterally extending between a respective pair of narrow lateral isolation trench sections 79N along the second horizontal direction hd2. The lateral extent of this portion along the second horizontal direction hd2 is herein referred to as a uniform word-line width, which is the width of a word line to be subsequently formed. In one embodiment, the uniform word-line width may correspond to a width of a memory block along the second horizontal direction hd2. In one embodiment, each of the laterally-extending cavities 43 has a variable width in the connection region 300 that changes from the uniform word-line width to zero with a lateral distance along the first horizontal direction hd1 from the memory array region 100 toward the contact region 200.

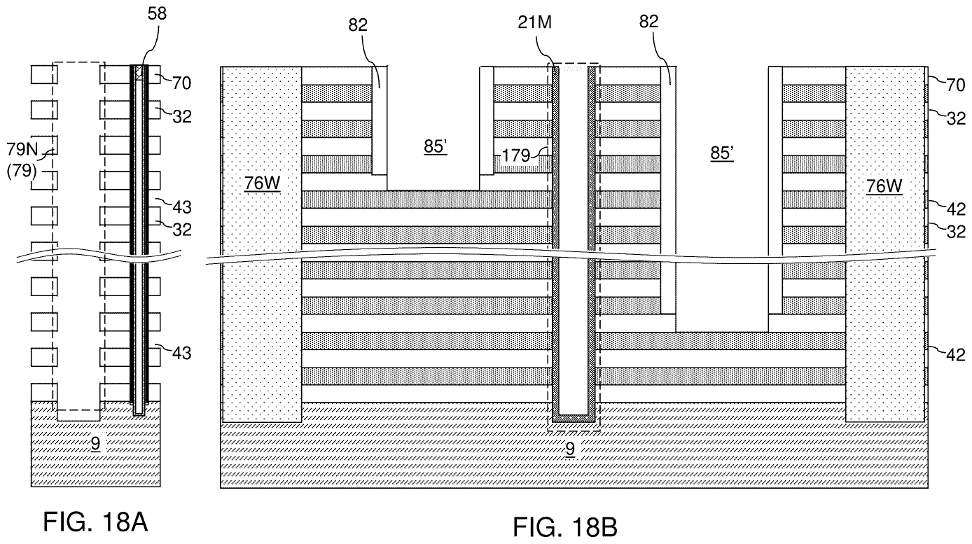

Referring to FIGS. 18A and 18B, an isotropic etch process can be performed to etch the sacrificial barrier liner 24L selectively to the material of the sacrificial access lateral isolation trench liners 21M. Sidewalls of the sacrificial access lateral isolation trench liners 21M can be physically exposed around the elongated voids within the access lateral isolation trenches 179. Further, top surface segments of the sacrificial material layers 42 may be exposed underneath the contact via cavities 85′.

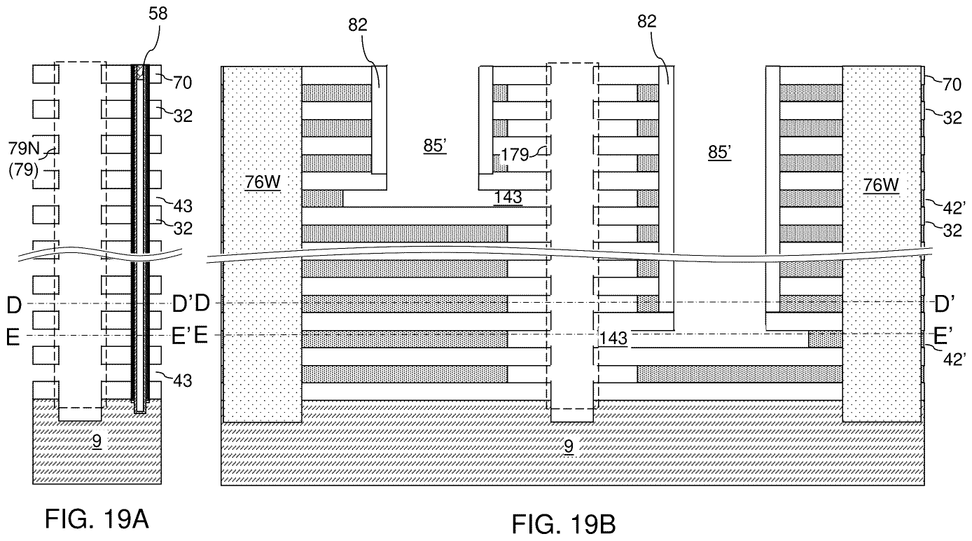

Referring to FIG. 19A-19E, a second selective isotropic etch process can be performed, which etches the materials of the sacrificial access lateral isolation trench liners 21M and the sacrificial material layers 42. The second selective isotropic etch process removes the entirety of the sacrificial access lateral isolation trench liners 21M, and laterally recesses physically exposed portions of the sacrificial material layers 42 by a second etch distance, which is less than the first etch distance and is less than the lateral distance between a neighboring pair of an access lateral isolation trench 179 and a wide lateral isolation trench fill structure 76W. Further, the second selective isotropic etch process etches portions of the sacrificial material layers 42 that are proximal to the contact via cavities 85′. Thus, the second selective isotropic etch process employs the access lateral isolation trenches 179 and the contact via cavities 85′ as conduits for an isotropic etchant that etches the materials of the sacrificial access lateral isolation trench liners 21M and the sacrificial material layers 42 in the contact region 200. The lateral recessing of the portions of the sacrificial material layers 42 from underneath the contact via cavities 85′ is isotropic. The duration of the second selective isotropic etch process is selected such that each of the cavities formed by removal of portions of the sacrificial material layers 42 from underneath the contact via cavities 85′ merges with a respective cavity that is formed by removal of a strip portion of a sacrificial material layer 42 around an access lateral isolation trench 179.

Generally, the sacrificial material layers 42 are isotropically recessed from around the access lateral isolation trenches 179 and the contact via cavities 85′ by the second lateral etch distance selectively to the materials of the insulating layers 32, the insulating cap layer 70, the tubular insulating spacers 82, the semiconductor material layer 9, and the material of the outermost layers of the memory films 50. Further, the laterally-extending cavities 43 can be laterally expanded during the second selective isotropic etch process. Strip-shaped cavities 143 are formed in volumes from which the sacrificial material layers 42 are removed around the access lateral isolation trenches 179 and the contact via cavities 85′. The second lateral etch distance is less than the lateral spacing between neighboring pairs of a respective access lateral isolation trench 179 and a wide lateral isolation trench fill structure 76W along the second horizontal direction hd2. Remaining portions of the sacrificial material layers 42 comprise dielectric material plates 42′.

The second selective isotropic etch process may comprise a wet etch process employing a wet etch solution, and/or may comprise a gas phase (dry) etch process in which the etchant is introduced in a vapor phase into the access lateral isolation trenches 179 and the contact via cavities 85′. For example, if the sacrificial material layers 42 include silicon nitride, the etch process can be a wet etch process in which the second exemplary structure is immersed within a wet etch tank including phosphoric acid, which etches silicon nitride selective to silicon oxide, silicon, and various other materials employed in the art. The memory opening fill structures 58 provide structural support while the laterally-extending cavities 43 are present within volumes previously occupied by the sacrificial material layers 42. The dielectric material plates 42′ provide structural support to remaining portions of the insulating layers 32 in the contact region 200. According to an aspect of the present disclosure, formation of support pillar structures in the contact region 200 is not necessary because the dielectric material plates 42′ provide structural support during the second selective isotropic etch process. Alternatively, support pillar structures (e.g., silicon oxide pillars) can be formed around the contact via cavities 85′ to provide additional support.

Each laterally-extending cavities 43 may be adjoined to a respective pair of strip-shaped cavities 143. The second selective isotropic etch process isotropically recesses the sacrificial material layers 42 employing the access lateral isolation trenches 179 and the contact via cavities 85′ as second conduits for a second selective isotropic etchant while the wide lateral isolation trench fill structures 76W prevent access by the isotropic etchant to the sacrificial material layers 42 through the wide lateral isolation trench sections 79W. In this case, the wide lateral isolation trench sections 79W are filled with the wide lateral isolation trench fill structures 76W during the second selective isotropic etch process.

In one embodiment, each of the laterally-extending cavities 43 may have a pair of laterally-convex sidewall sections 43S in a connection region 300 that is located between the memory array region 100 and the contact region 200. Each laterally-extending cavity 43 may have a portion located within the memory array region 100 and laterally extending between a respective pair of narrow lateral isolation trench sections 79N along the second horizontal direction hd2.

As shown in FIG. 19E, each of the strip-shaped cavities 143 may comprise a strip cavity portion 143S laterally extending along the first horizontal direction hd1 and having a uniform strip width along the second horizontal direction hd2 in the contact region 200. The uniform strip width is less than the uniform word line width. Further, each of the strip-shaped cavities 143 may comprise a disc-shaped cavity portion 143D that underlies a respective contact via cavity 85′ and is adjoined to the strip cavity portion 143S. A vertical stack of dielectric material plates 42′ may be vertically interlaced with the insulating layers 32. Each of the dielectric material plates 42′ may be laterally bounded by a respective laterally-extending cavity 43, a respective strip-shaped cavity 143, and a respective wide lateral isolation trench fill structure 76W.

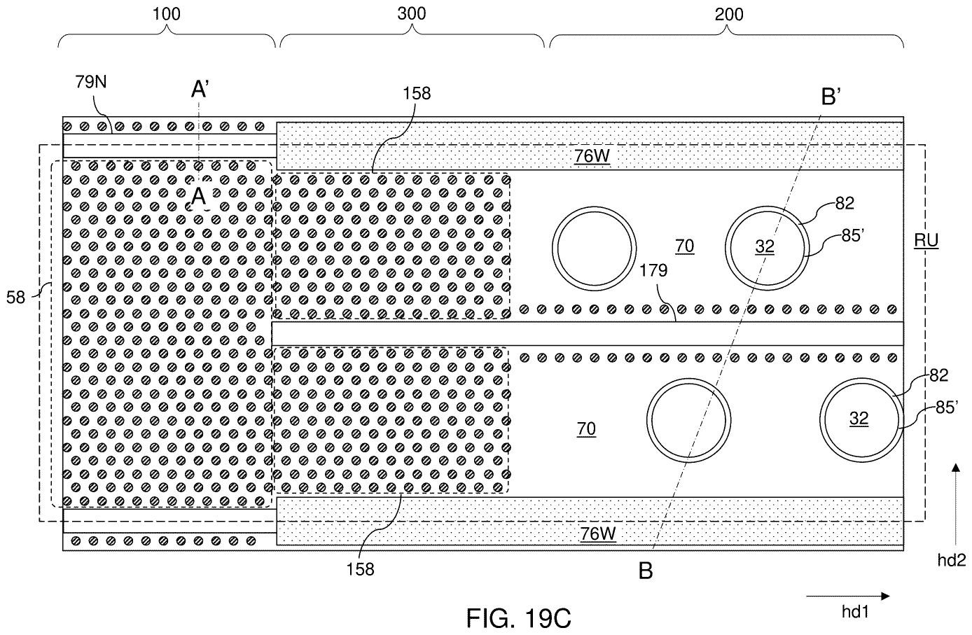

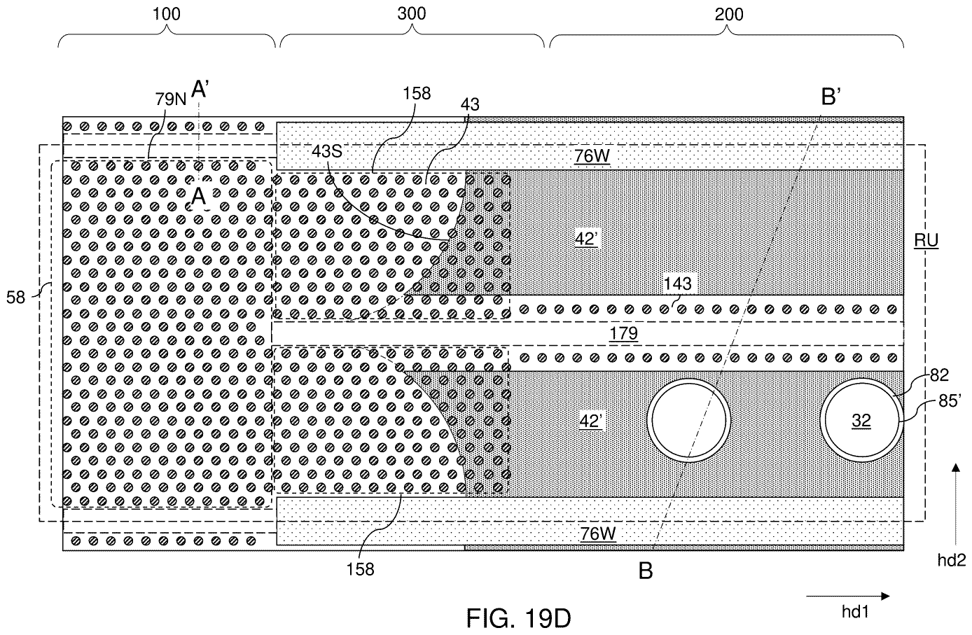

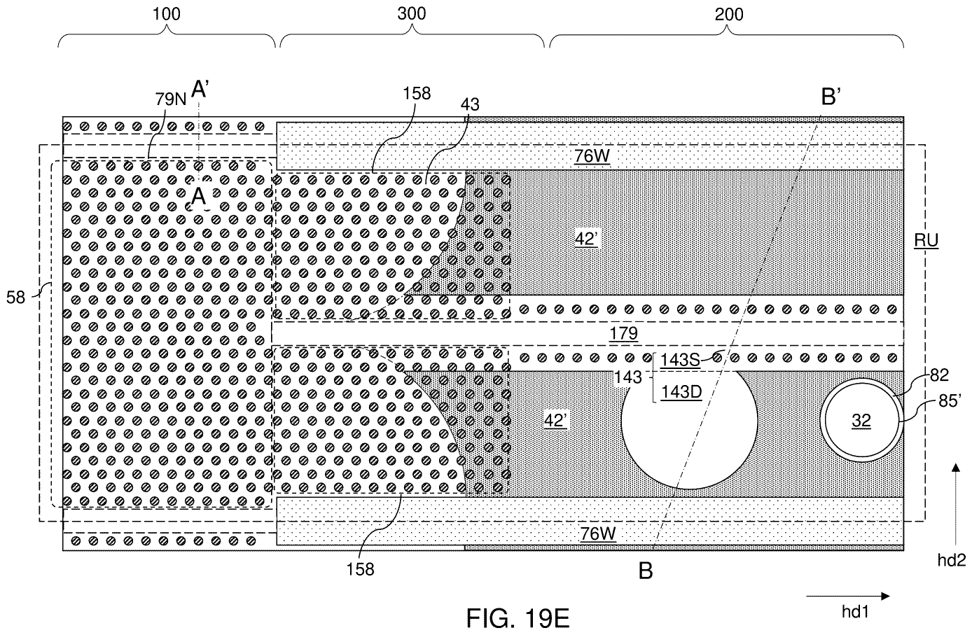

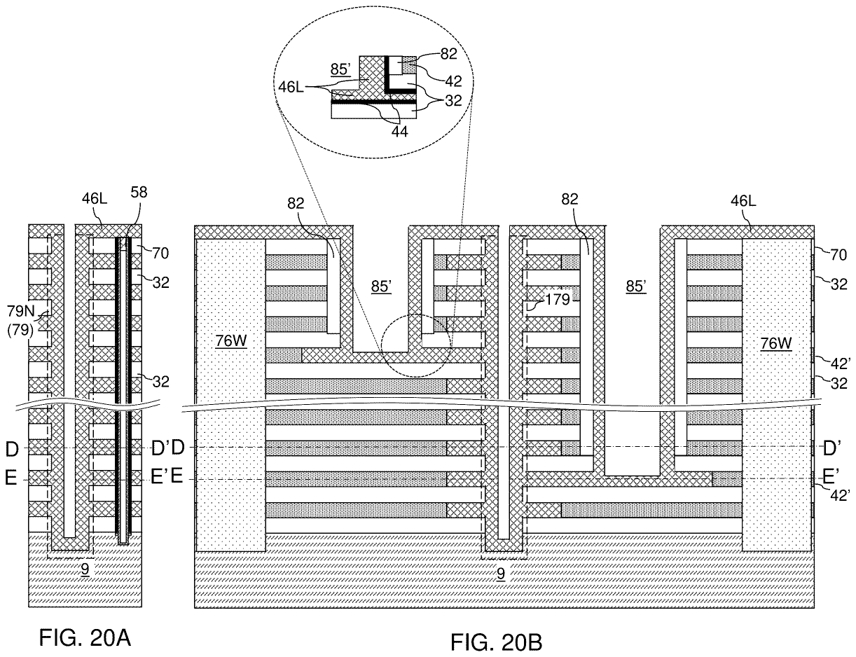

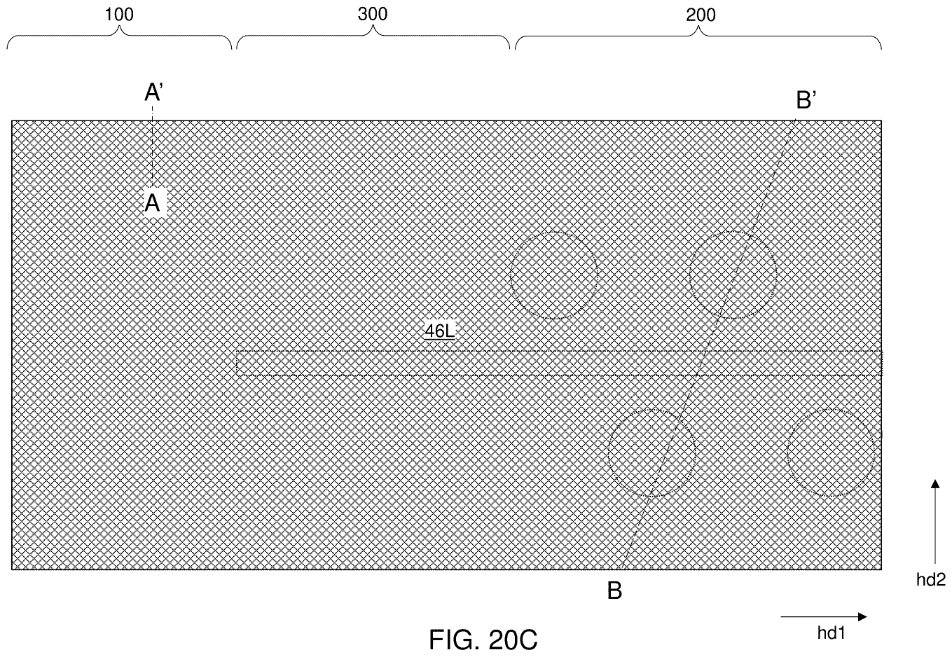

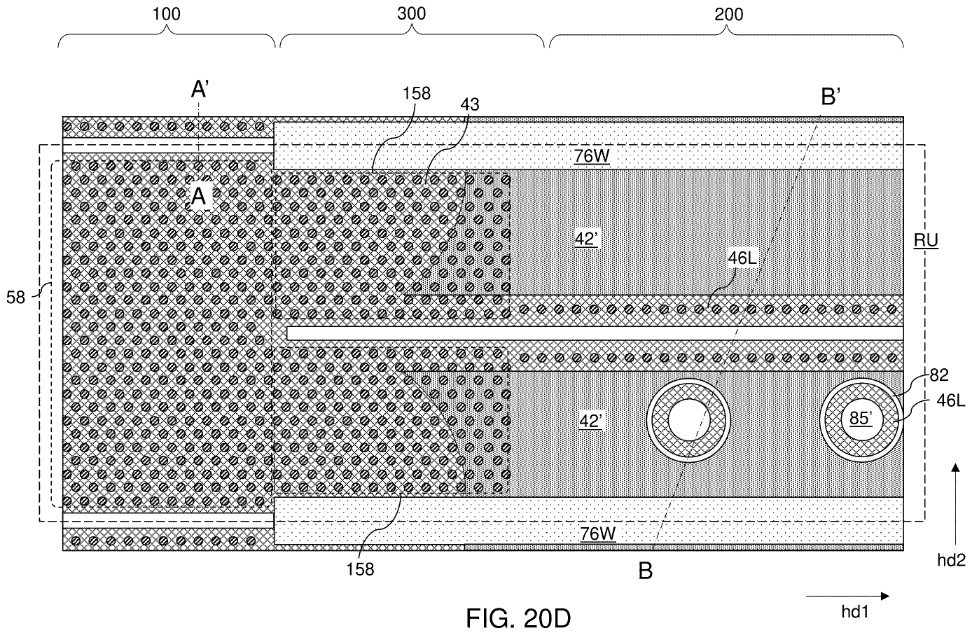

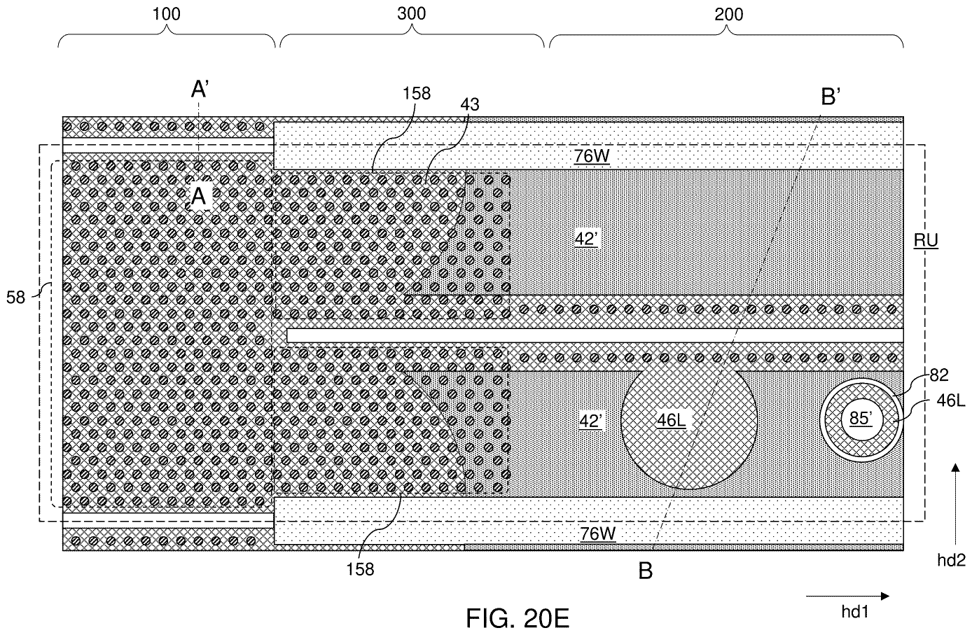

Referring to FIG. 20A-20E, an optional continuous outer blocking dielectric layer 44 may be conformally deposited into peripheral portions of the laterally-extending cavities 43, the strip-shaped cavities 143 and the contact via cavities 85′, as shown in the inset of FIG. 20B. The outer blocking dielectric layer 44 does not completely fill the cavities (43, 143, 85′). The outer blocking dielectric layer 44 may comprise any suitable dielectric material, such as a metal oxide dielectric layer, for example an aluminum oxide layer. At least one conductive material, such as a combination of a metallic barrier liner material and a metal fill material, may be conformally deposited in the laterally-extending cavities 43, the strip-shaped cavities 143, peripheral portions of the contact via cavities 85′, and over the insulating cap layer 70 to form a continuous electrically conductive layer 46L. If the continuous outer blocking dielectric layer 44 is present, then the continuous electrically conductive layer 46L is formed on the outer blocking dielectric layer 44. The metallic barrier liner material may comprise a conductive metallic compound material such as TiN, TaN, WN, MoN, TiC, TaC, WC, alloys thereof, or a combination thereof. The metal fill material may comprise W, Ti, Ta, Mo, Co, Ru, Cu, alloys thereof, or combinations thereof. The total thickness of the at least one conductive material in regions that are not vertically bounded by a pair of an overlying insulating layer 32 and an underlying insulating layer 32 is greater than one half of the height of the laterally-extending cavities 43 and the strip-shaped cavities 143.

In one embodiment, each portion of the continuous electrically conductive layer 46L that is exposed to an overlying contact via cavity 85′ may have the same thickness as a tubular portion of the continuous electrically conductive layer 46L that is formed in the periphery of the overlying contact via cavity 85′. This thickness is greater than one half of the vertical spacing between vertically neighboring pairs of insulating layers 32, and may be less than or may be greater than the vertical spacing between vertically neighboring pairs of insulating layers 32. Generally, the continuous electrically conductive layer 46L comprises at least one electrically conductive material having a unform material composition throughout and is free of any material interface therein. As used herein, a material interface refers to an interface at which two different material are in direct contact with each other. For example, the metallic barrier liner material may have a unform material composition throughout and may be free of any material interface therein. Likewise, the metal fill material may have a unform material composition throughout and may be free of any material interface therein.

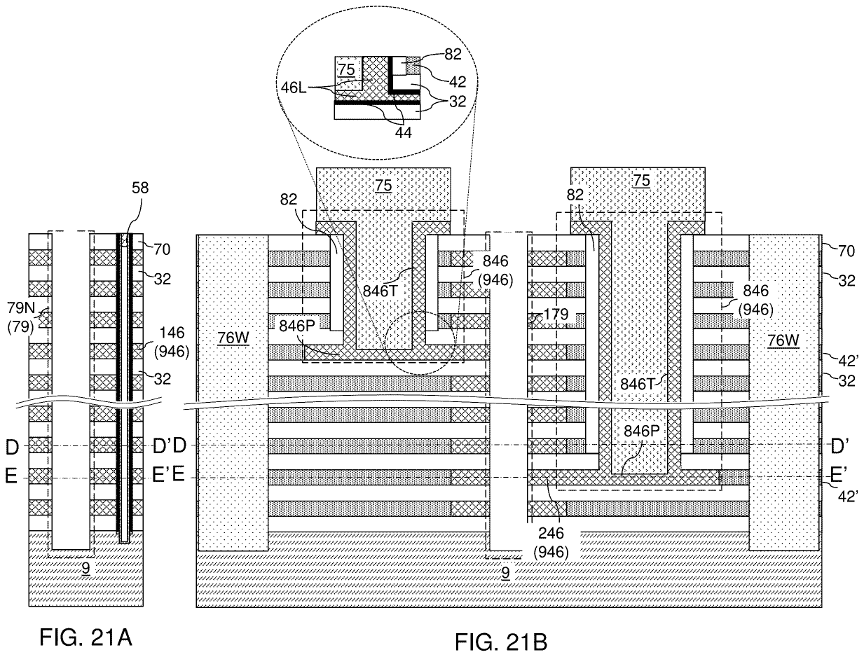

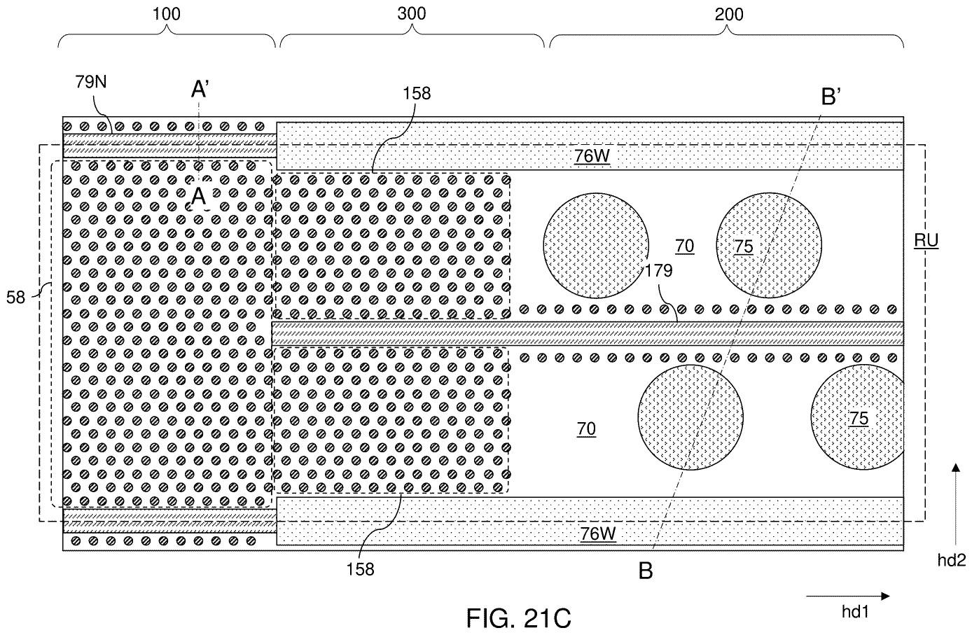

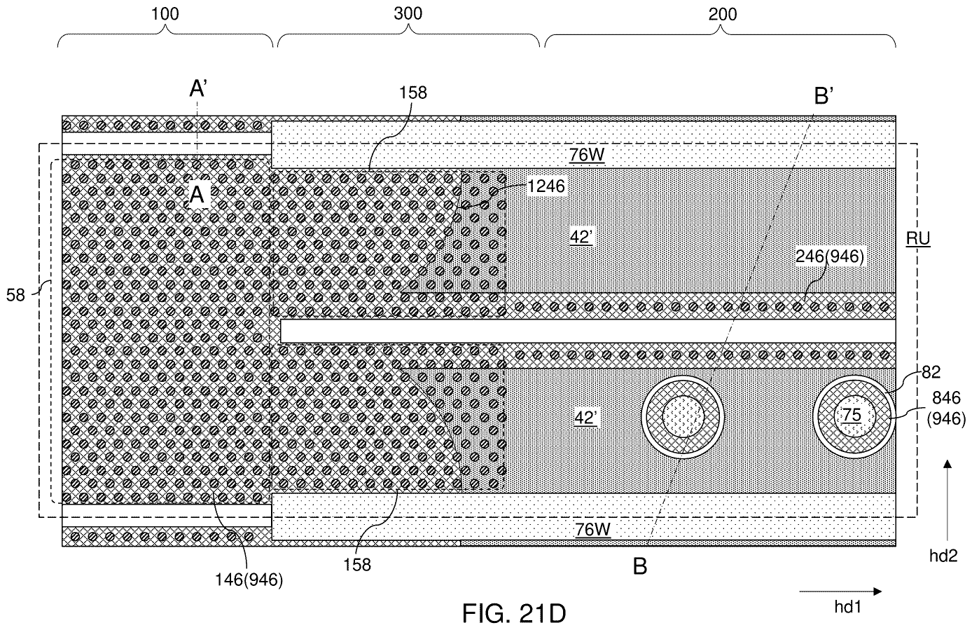

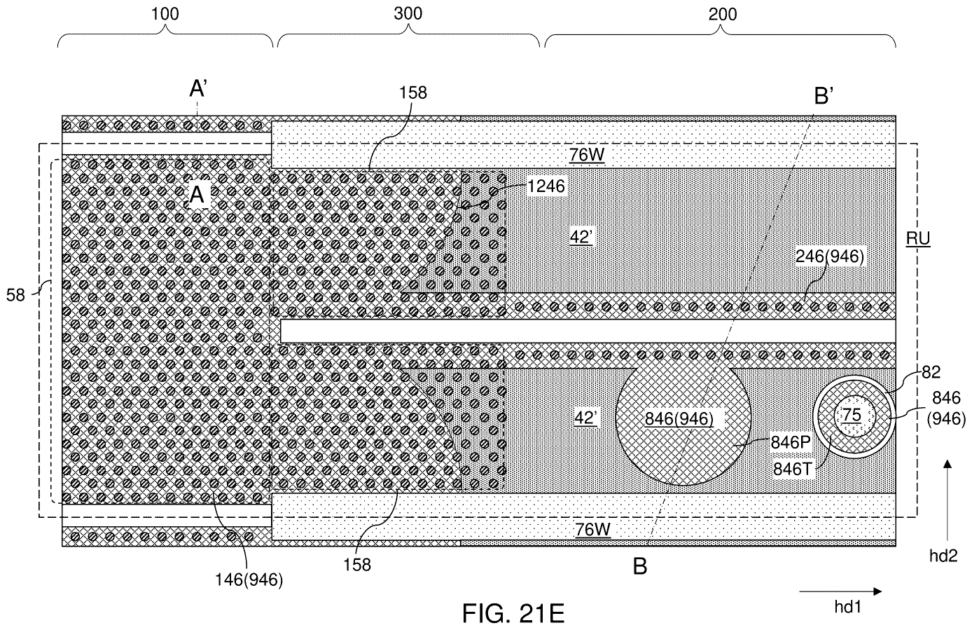

Referring to FIG. 21A-21E, a photoresist layer may be applied over the first exemplary structure, and may be lithographically patterned to form photoresist material portions 75 covering the areas of the contact via openings 85′. Unmasked portions of the continuous electrically conductive layer 46L can be isotropically etched to pattern the continuous electrically conductive layer 46L. Specifically, portions of the continuous electrically conductive layer 46L that are present in the narrow lateral isolation trench sections 79N, in the access lateral isolation trenches 179, or above the horizontal plane including the top surface of the insulating cap layer 70 and not covered by the photoresist material portions 75 can be removed during a selective etch process that etches materials of the continuous electrically conductive layer 46L selectively to the materials of the insulating layers 32, the insulating cap layer 70, and the semiconductor material layer 9.

The patterned portions of the continuous electrically conductive layer 46L comprise integrated word line and contact via structures 946. The integrated word line and contact via structures 946 are formed in the cavities (43, 143) that are formed by the first selective isotropic etch process and the second selective isotropic etch process. As shown in FIG. 21E, each of the integrated word line and contact via structures 946 comprises a respective electrode layer (e.g., word line/control gate electrode layer or select gate electrode layer) 146, a respective contact via structure 846, and a respective lateral connection strip 246 connecting the respective electrode layer 146 and the respective contact via structure 846.

If the continuous outer blocking dielectric layer 44 is present, then it is separated into separate outer blocking dielectric layers 44, as shown in the inset in FIG. 21B. Since the outer blocking dielectric layers 44 are not removed at the intersections of the word lines 146, the connection strips 246 and the contact via structures 846, the probability of word line breakdown (i.e., unwanted electrical shorts between neighboring pairs of word lines) is reduced.

As shown in FIG. 21B, the contact via structure 846 includes an vertically-extending tubular portion 846T and an underlying horizontally-extending bottom plate 846P which extends beyond the sidewall of the vertically-extending tubular portion 846T and contacts the lateral connection strip 246. The respective vertically-extending tubular portion 846T has a bottom end that is connected to the respective bottom plate 846P. In one embodiment, a center portion of the respective bottom plate 846P has a uniform inner bottom plate thickness; the respective vertically-extending tubular portion 846T has a uniform lateral thickness between an inner sidewall and an outer sidewall; and the uniform lateral thickness is the same as the uniform inner bottom plate thickness.

The insulating layers 32 are vertically spaced apart from each other and are interlaced with the electrode layers 146 (and optionally with the outer blocking dielectric layers 44) to provide a vertically alternating sequence (32, 146) of the insulating layers 32 and the electrode layers 146. Each of the electrode layers 146 laterally extend along a first horizontal direction hd1 and have a uniform word-line width along a second horizontal direction hd2 in a memory array region 100. The lateral connection strips 246 laterally extend along the first horizontal direction hd1 and have a uniform strip width along the second horizontal direction hd2 in a contact region 200. The uniform strip width is less than the uniform word line width. Drain side select gate electrodes may overlie the word lines 146 and source side select gate electrodes may underlies the word lines 146.

In one embodiment shown in FIGS. 21D and 21E, each of the electrode layers 146 has a laterally-convex sidewall section 146S in a connection region 300 that is located between the memory array region 100 and the contact region 200. In one embodiment, each of the electrode layers 146 has a variable width that changes from the uniform word-line width to the uniform strip width within the connection region 300 containing the laterally-convex sidewall sections 146S.

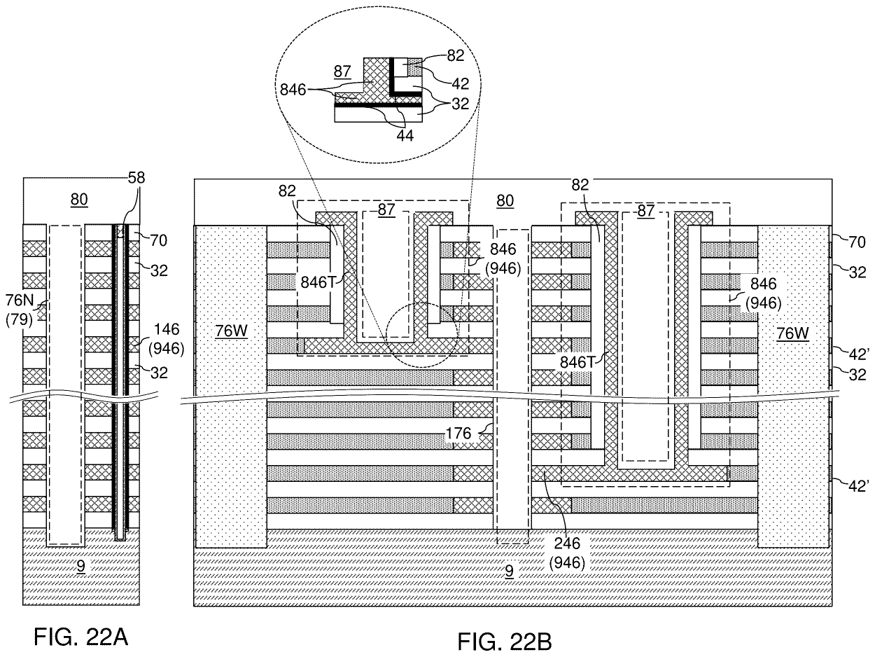

Referring to FIGS. 22A and 22B, a second dielectric fill material may be conformally deposited in the narrow lateral isolation trench sections 79N, in the access lateral isolation trenches 179, and over the insulating cap layer 70 to form a continuous dielectric material portion. The continuous dielectric material portion includes a contact-level dielectric layer 80 that is located above the insulating cap layer 79, lateral isolation trench fill structures (76N, 176) filling the lateral isolation trenches (79N, 179), and dielectric pillar material portions 87 that are laterally surrounded by the contact via structures 846. Each of the vertically-extending tubular portions 846T of the contact via structures 846 laterally encloses a respective dielectric pillar material portion 87.

In one embodiment, the contact-level dielectric layer 80 overlies the vertically alternating sequence (32, 146) and the vertically-extending tubular portions 846T of the contact via structures 846. The contact-level dielectric layer 80 and the dielectric pillar material portions 87 are portions of a dielectric material having a uniform material composition throughout. Additional portions of the dielectric material comprise lateral isolation trench fill structures (76N, 176) contacting sidewalls of each of the insulating layers 32 and each of the electrode layers 146. The lateral isolation trench fill structures (76N, 176) comprise narrow lateral isolation trench fill structures 76N that are formed in the narrow lateral isolation trench sections 79N and access lateral isolation trench fill structures 176 that are formed in the access lateral isolation trenches 179. Thus, the continuous dielectric material portion having a uniform material composition throughout may comprise: a contact-level dielectric layer 80 overlying each of the vertically alternating sequences (32, 146); and narrow lateral isolation trench fill structures 76N which are vertically-extending portions that vertically extend downward from the contact-level dielectric layer 80 and filling at least the narrow lateral isolation trench sections 79N. In one embodiment, the lateral connection strips 246 of the integrated word line and contact via structures 846 are in direct contact with the vertically-extending portions of the continuous dielectric material portion.

In one embodiment, the wide lateral isolation trench fill structures 76W may comprise the same or a different dielectric material than the continuous dielectric material portion. In one embodiment, each access lateral isolation trench 179 is laterally spaced from the dual-width lateral isolation trenches 79. Access isolation trench fill structures 176 can fill the access lateral isolation trenches 179. The lateral connection strips 246 of the integrated word line and contact via structures 946 are in contact with a sidewall of a respective one of the access isolation trench fill structures 176.

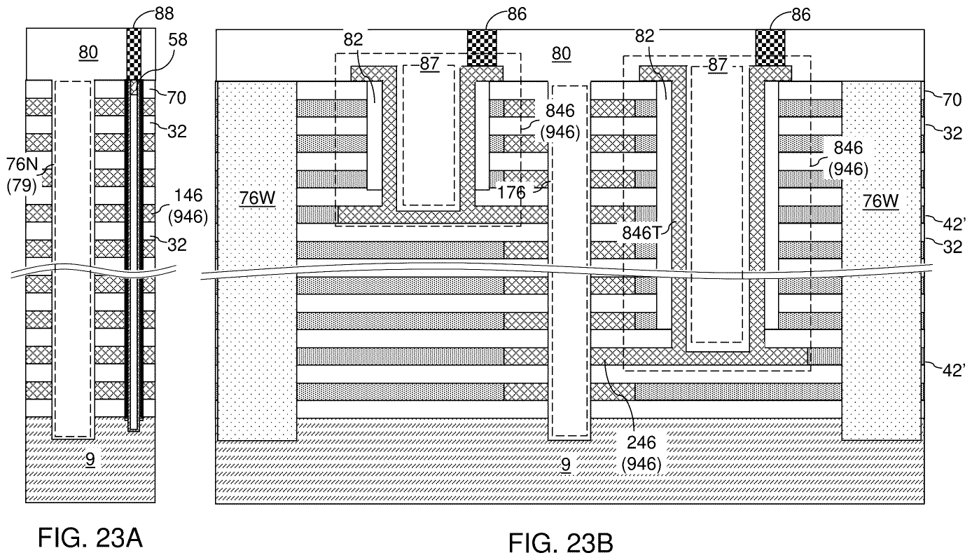

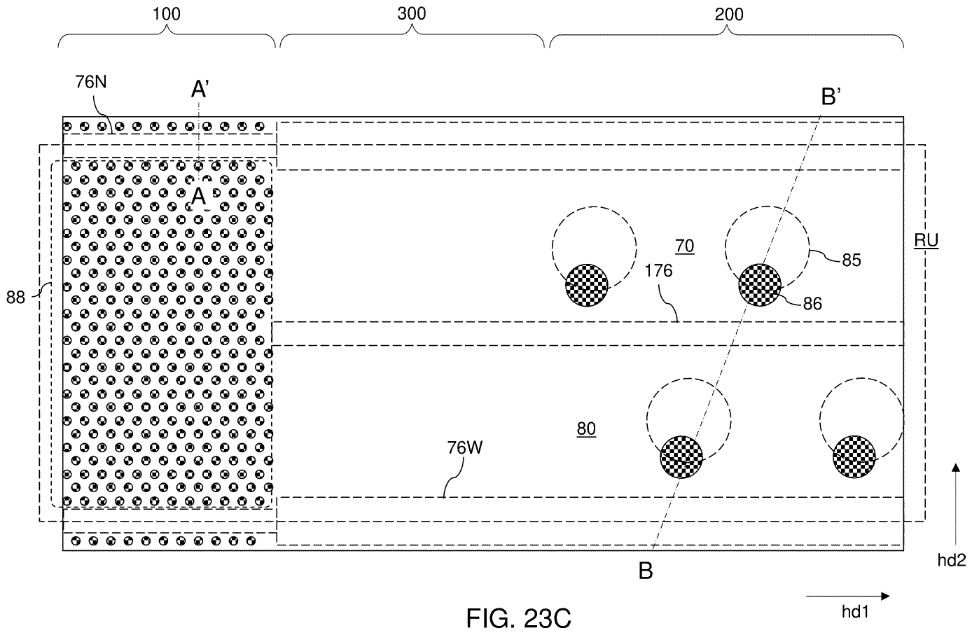

Referring to FIG. 23A-23C, various conductive via structures (88, 86) can be formed through the contact-level dielectric layer 80. For example, drain contact via structures 88 can be formed through the contact-level dielectric layer 80 on the drain regions 63 of the memory opening fill structures 58. Drain contact via structures preferably do not contact the dummy memory opening fill structures 158. Connection via structures 86 may be formed through the contact-level dielectric layer 80 on an annular top portion (e.g., the vertically-extending tubular portion 846T) of a respective one of the contact via structures 846 that overlies the horizontal plane including the top surface of the insulating cap layer 70.

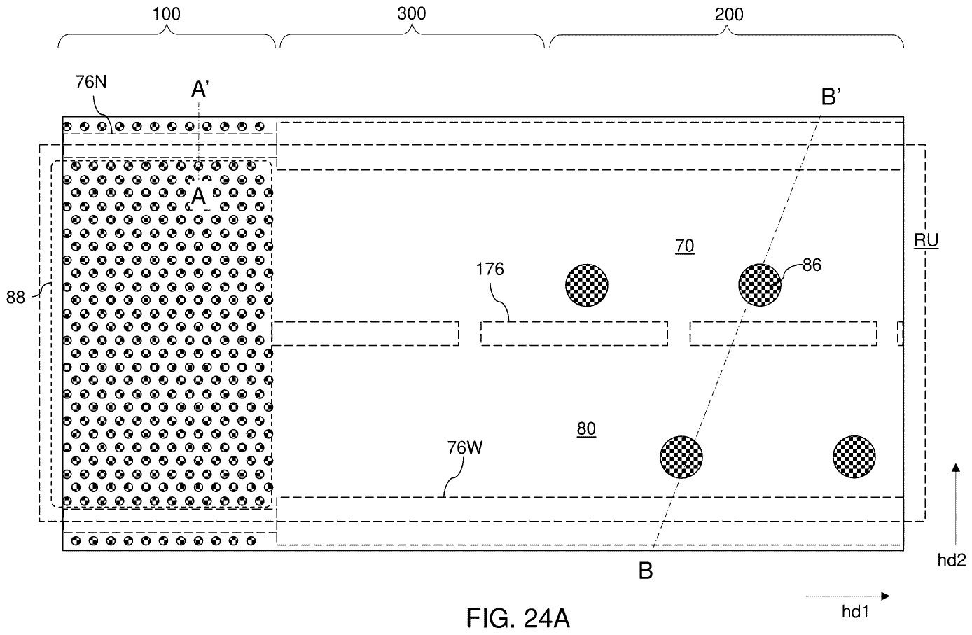

Referring to FIGS. 24A and 24B, an alternative configuration of the first exemplary structure is illustrated, which can be derived from the first exemplary structure by forming a plurality of access lateral isolation trenches 179 that are arranged along the first horizontal direction hd1 instead of each single continuous access lateral isolation trench 179 located between a respective neighboring pair of dual-width lateral isolation trenches 79. In this case, a row of access lateral isolation trench fill structures 176 may be formed between each neighboring pair of wide lateral isolation trench fill structures 76W.

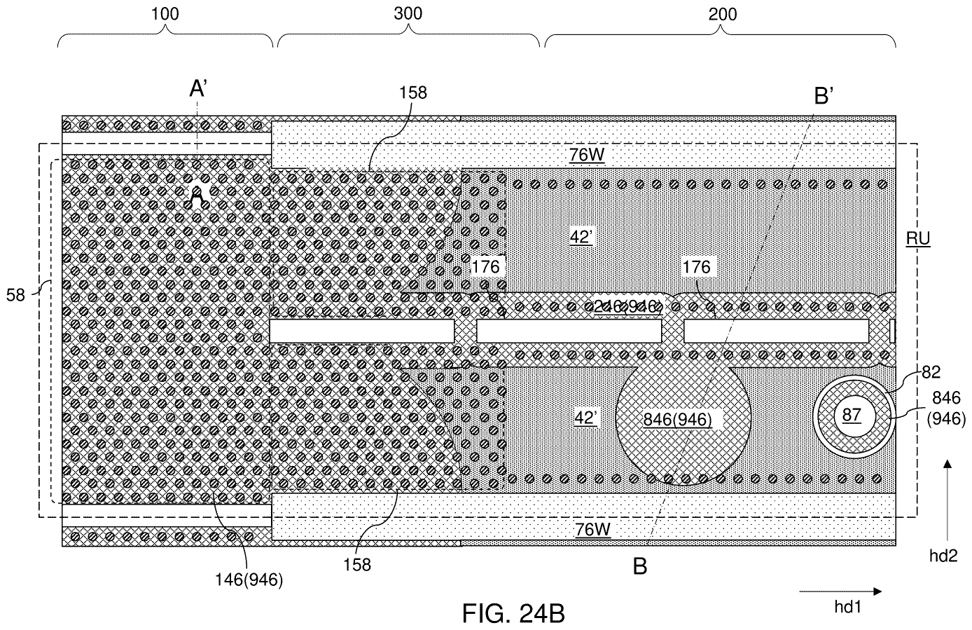

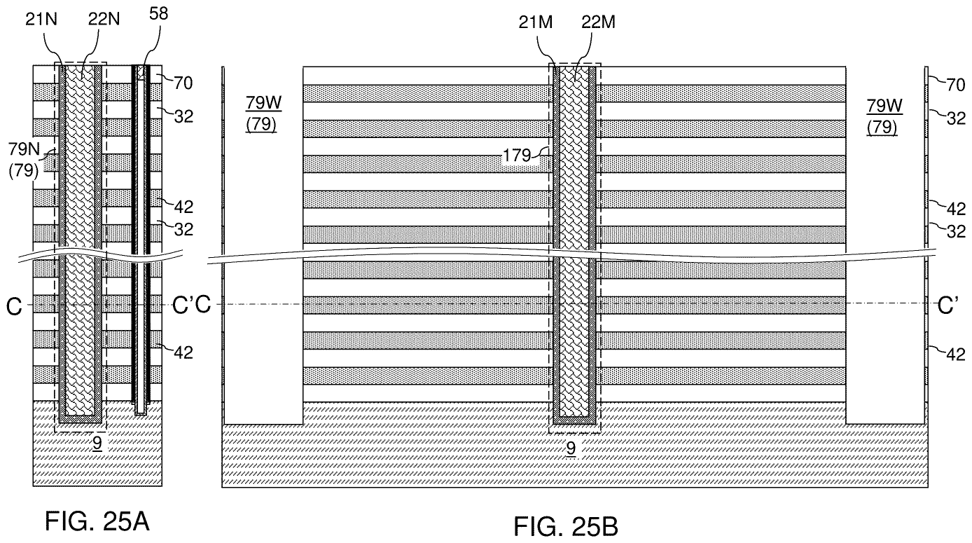

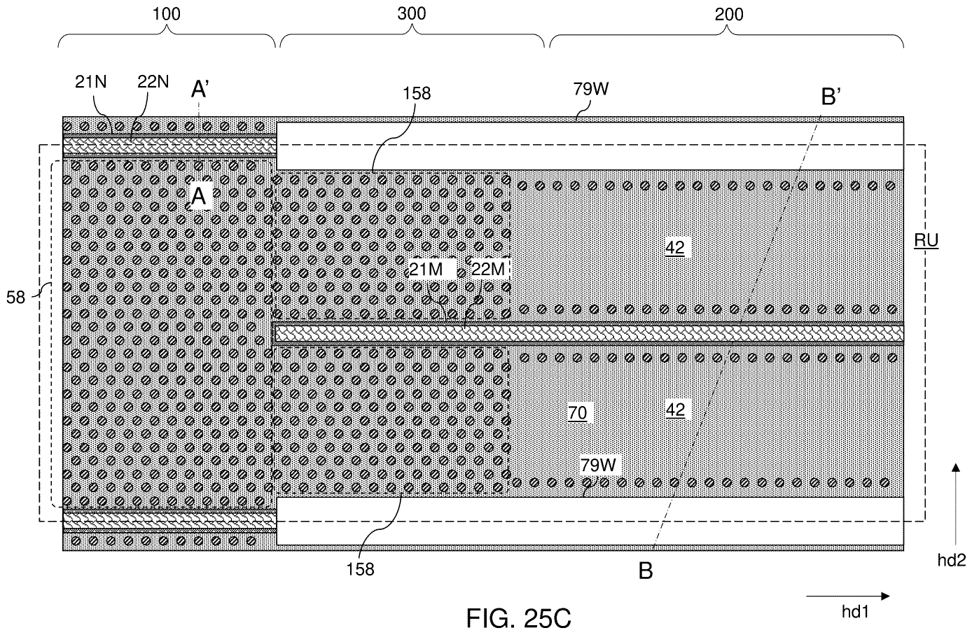

Referring to FIG. 25A-25C, a second exemplary structure according to a second embodiment of the present disclosure is illustrated, which may be the same as the first exemplary structure illustrated in FIGS. 7A and 7B.

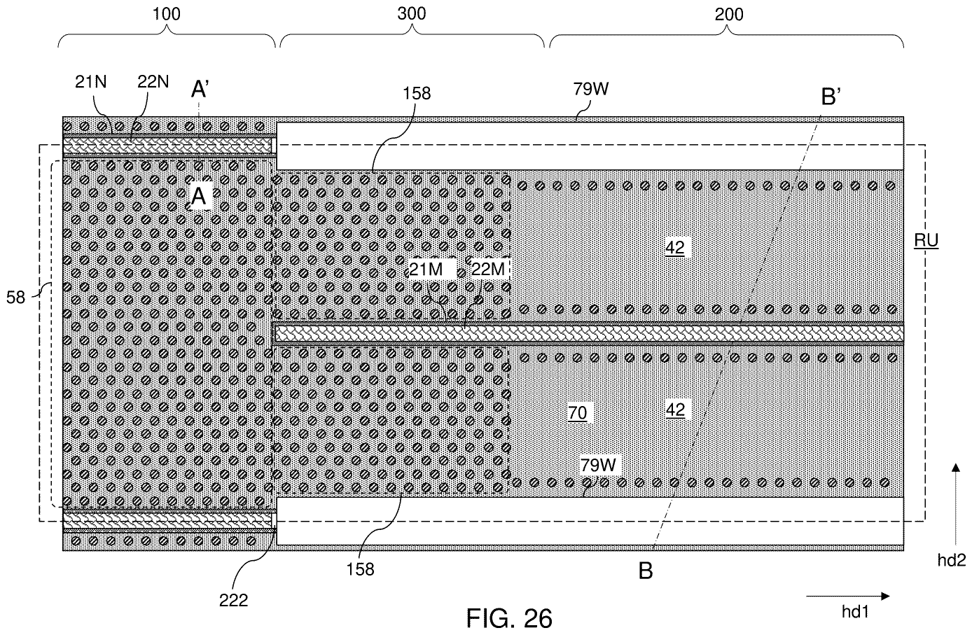

Referring to FIG. 26, an oxidation process may be performed to convert exposed surface portions (i.e., sidewalls) of the sacrificial narrow isolation trench fill structures 22N into sacrificial oxide liners 222. If the sacrificial narrow isolation trench fill structure 22N comprises amorphous silicon or polysilicon, then the sacrificial oxide liners 222 comprise silicon oxide liners that are formed by oxidation of the exposed sidewalls of the silicon structures 22N in the wide lateral isolation trench sections 79W.

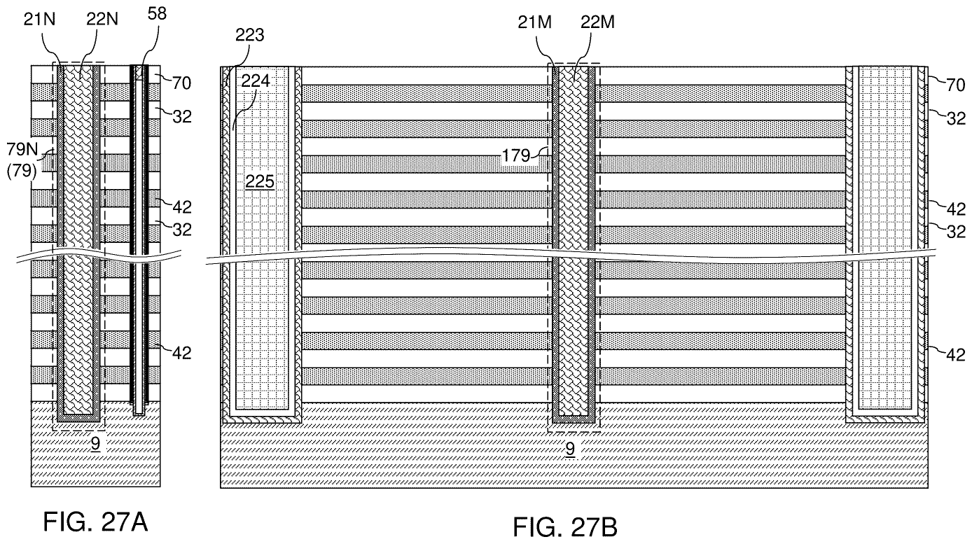

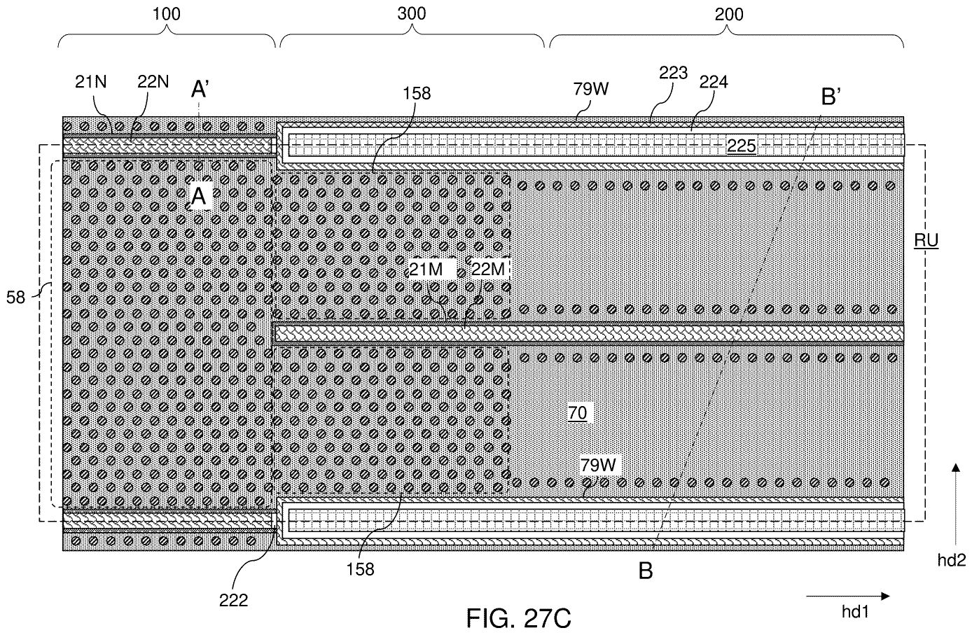

Referring to FIG. 27A-27C, a first sacrificial trench liner 223, a second sacrificial trench liner 224, and a wide sacrificial trench fill structure 225 may be formed within each wide lateral isolation trench section 79W. For example, a first continuous sacrificial trench liner including a first sacrificial trench liner material (such as amorphous silicon or polysilicon), a second continuous sacrificial trench liner including a second sacrificial trench liner material (such as silicon nitride), and a sacrificial trench fill material (such as amorphous silicon or polysilicon) may be sequentially deposited to fill the entire volumes of the wide lateral isolation trench sections 79W, and portions of the first continuous sacrificial trench liner, the second continuous sacrificial trench liner, and the sacrificial trench fill material that overlie the horizontal plane including the top surface of the insulating cap layer 70 may be removed by performing a chemical mechanical polishing process. Top surfaces of the sacrificial narrow isolation trench fill structure 22N may be physically exposed after the chemical mechanical polishing process. Remaining portions of the first continuous sacrificial trench liner, the second continuous sacrificial trench liner, and the sacrificial trench fill material comprise the first sacrificial trench liners (e.g., silicon liners) 223, the second sacrificial trench liners (e.g., silicon nitride liners) 224, and the wide sacrificial trench fill structures (e.g., silicon structures) 225.

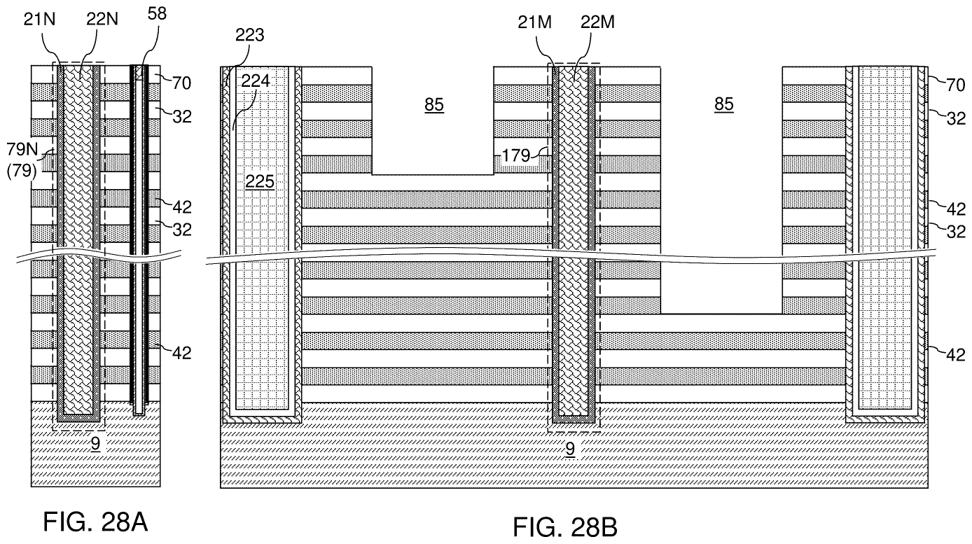

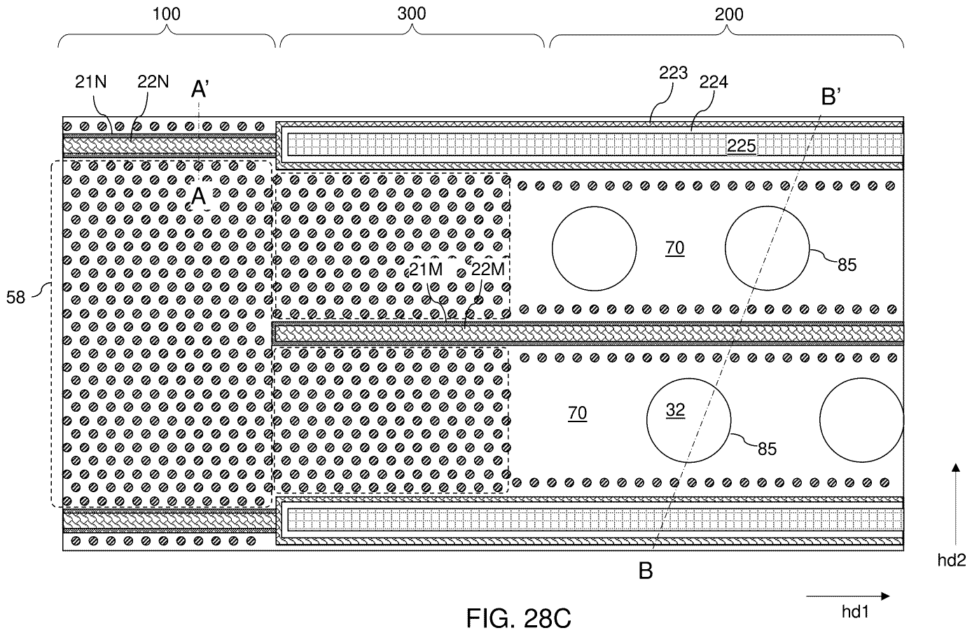

Referring to FIG. 28A-28C, the processing steps described with reference to FIGS. 9A-9C can be performed to form the contact via openings 85.

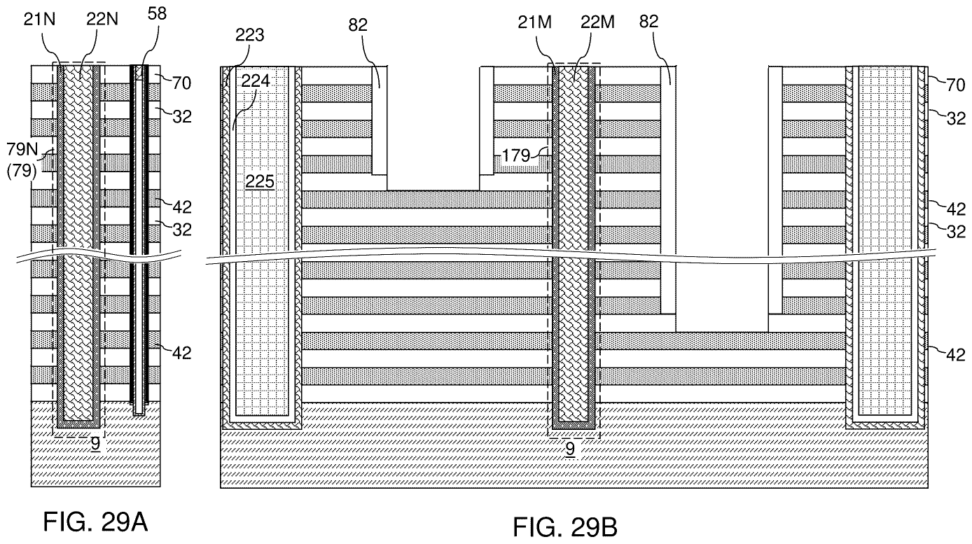

Referring to FIGS. 29A and 29B, the processing steps described with reference to FIGS. 10A and 10B can be performed to form tubular insulating spacers 82 and to vertically extend contact via cavities 85′.

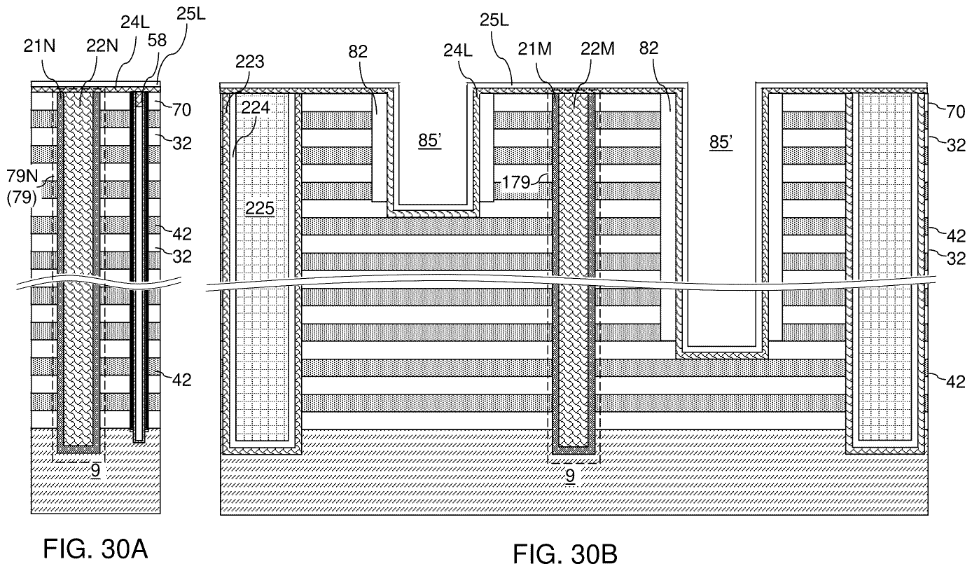

Referring to FIGS. 30A and 30B, the processing steps described with reference to FIGS. 12A, 12B, 13A, and 13B can be performed to form a sacrificial barrier liner 24L and a sacrificial dielectric liner 25L.

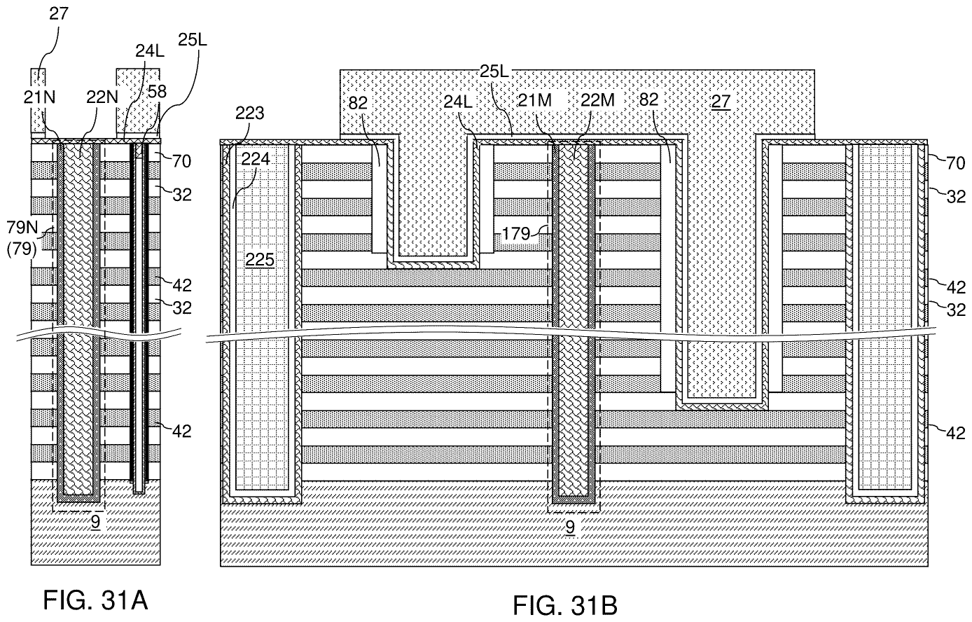

Referring to FIGS. 31A and 31B, the processing steps described with reference to FIGS. 14A and 14B can be performed with a modification in the pattern of the photoresist layer 27. Specifically, the photoresist layer 27 can be applied over the second exemplary structure, and can be lithographically patterned to form openings over the areas of the dual-width lateral isolation trenches 79 while covering areas outside of the dual-width lateral isolation trenches 79 in a plan view. A first etch process can be performed to remove unmasked portions of the sacrificial dielectric liner 25L selectively to the material of the sacrificial barrier liner 24L. Each portion of the sacrificial dielectric liner 25L overlying the dual-width lateral isolation trenches 79 may be removed, and surfaces of the sacrificial barrier liner 24L may be physically exposed within the areas of the dual-width lateral isolation trenches 79.

Referring to FIGS. 32A and 32B, a second etch process can be performed to remove unmasked portions of the sacrificial barrier liner 24L, the sacrificial narrow isolation trench fill structure 22N, and the wide sacrificial trench fill structure 225 selectively to the materials of the sacrificial narrow trench liners 21N and the second sacrificial trench liner 224. Surfaces of the sacrificial narrow trench liners 21N are physically exposed in the narrow lateral isolation trench sections 79N, and surfaces of the second sacrificial trench liners 224 are physically exposed in the wide lateral isolation trench sections 79W.

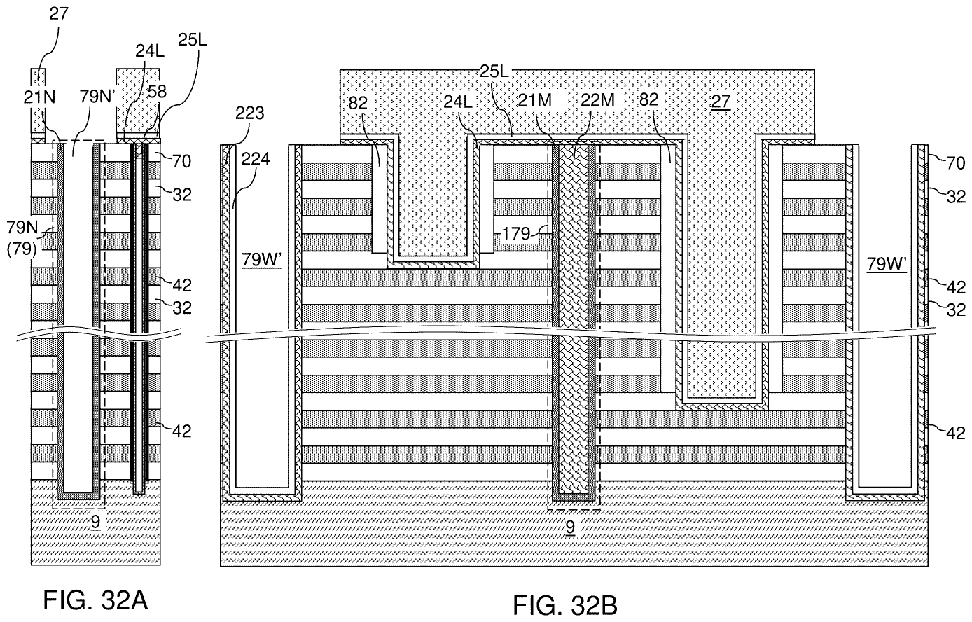

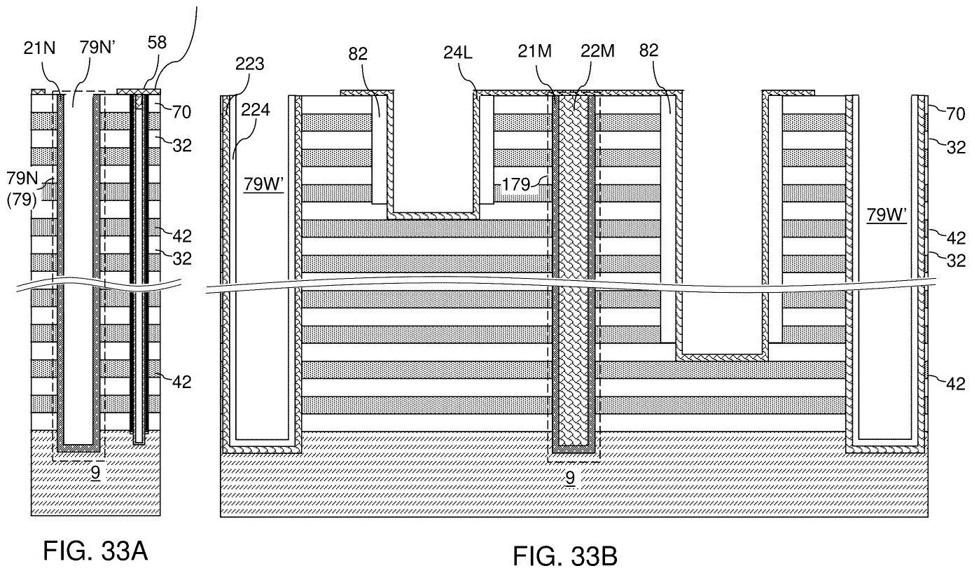

Referring to FIGS. 33A and 33B, the photoresist layer 27 can be subsequently removed, for example, by ashing. Remaining portions of the sacrificial dielectric liner 25L and sacrificial oxide liners 222 (e.g., the silicon oxide liners 25L and 222) may be removed by selective etching relative to the sacrificial narrow trench liners 21N and the second sacrificial trench liners 224 (e.g., the silicon nitride liners 21N and 224).

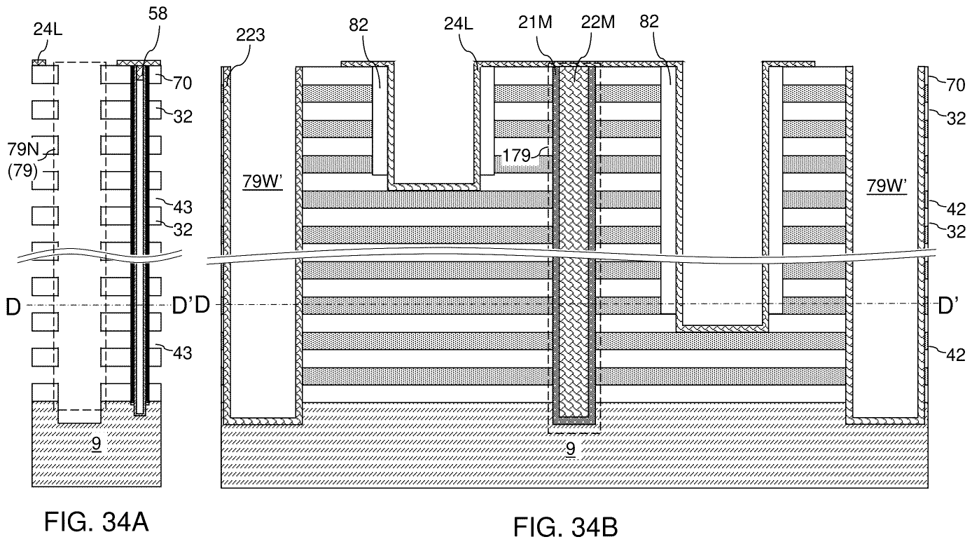

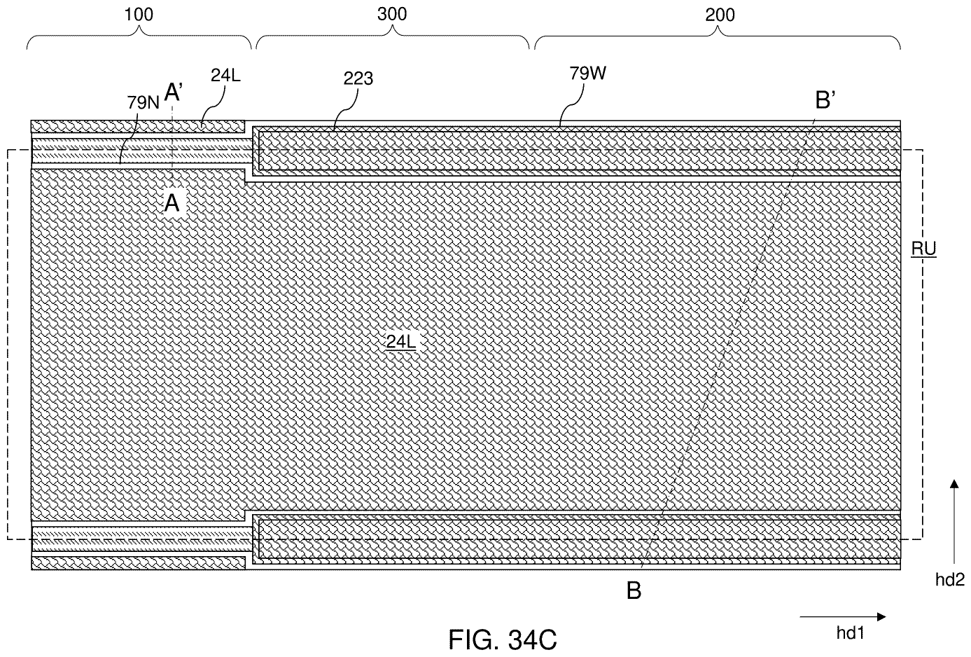

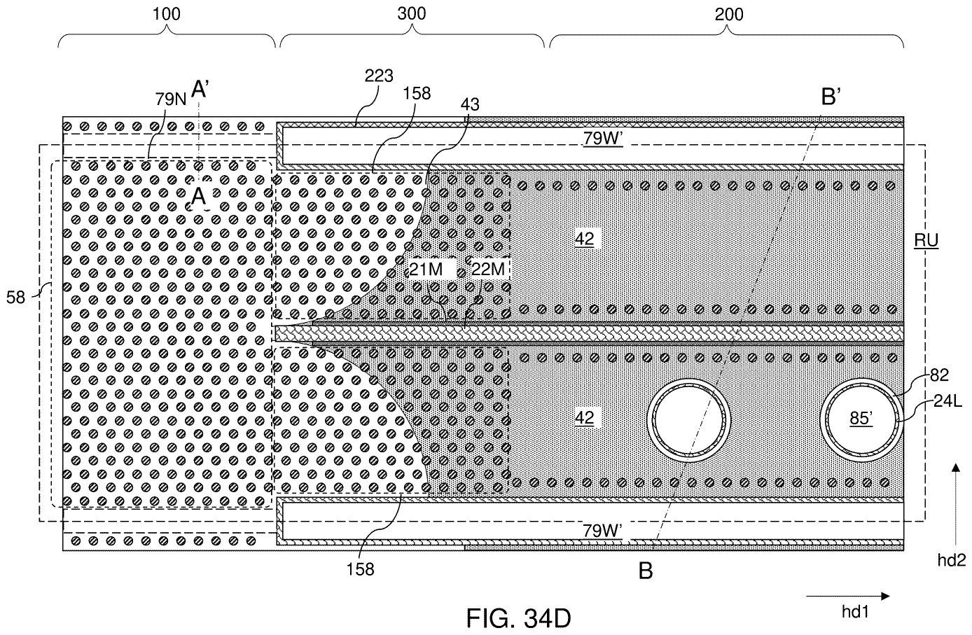

Referring to FIG. 34A-34D, the processing steps described with reference to FIG. 17A-17D can be performed. Specifically, a first selective isotropic etch process can be performed, which etches the materials of the sacrificial narrow trench liners 21N, the second sacrificial trench liners 224 and the sacrificial material layers 42. In one embodiment, the sacrificial narrower trench liners 21N, the second sacrificial trench liners 224 and the sacrificial material layers 42 may comprise the same material, such as silicon nitride. The first selective isotropic etch process removes the entirety of the sacrificial narrow trench liners 21N and the second sacrificial trench liners 224, laterally recesses physically exposed portions of the sacrificial material layers 42 by a first etch distance, and etches portions of the sacrificial access lateral isolation trench liners 21M. The first sacrificial trench liners (e.g., silicon liners) 223 remain in the wide lateral isolation trench sections 79W′.

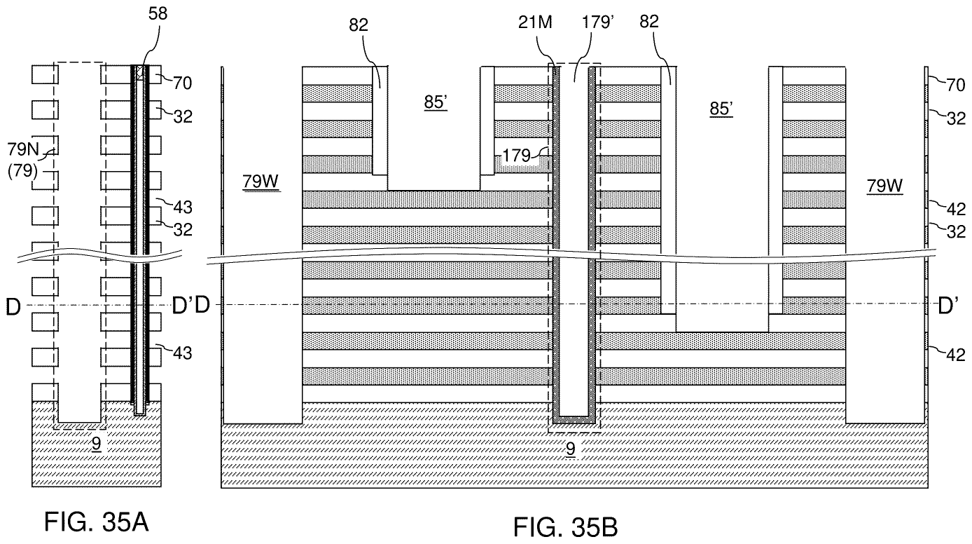

Referring to FIGS. 35A and 35B, an isotropic etch process can be performed to etch the sacrificial barrier liner 24L, the first sacrificial trench liners 223 and the sacrificial access lateral isolation trench fill structures 22M (i.e., the silicon liners and structures 24L, 223 and 22M) selectively to the materials of the sacrificial access lateral isolation trench liners 21M, the insulating layers 32, and the sacrificial material layers 42. Sidewalls of the sacrificial access lateral isolation trench liners 21M can be physically exposed around the wall-shaped voids within the access lateral isolation trenches 179. Further, top surface segments of the sacrificial material layers 42 may be exposed underneath the contact via cavities 85′.

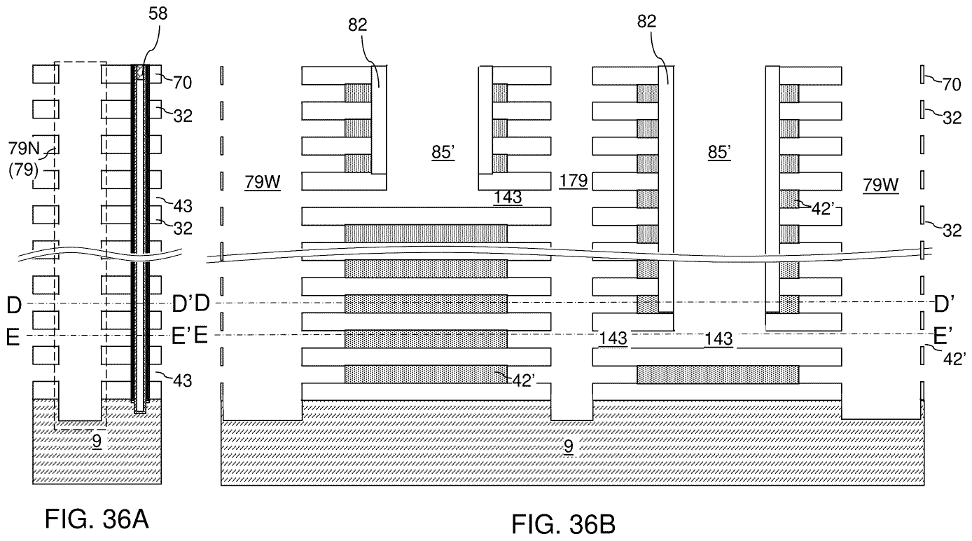

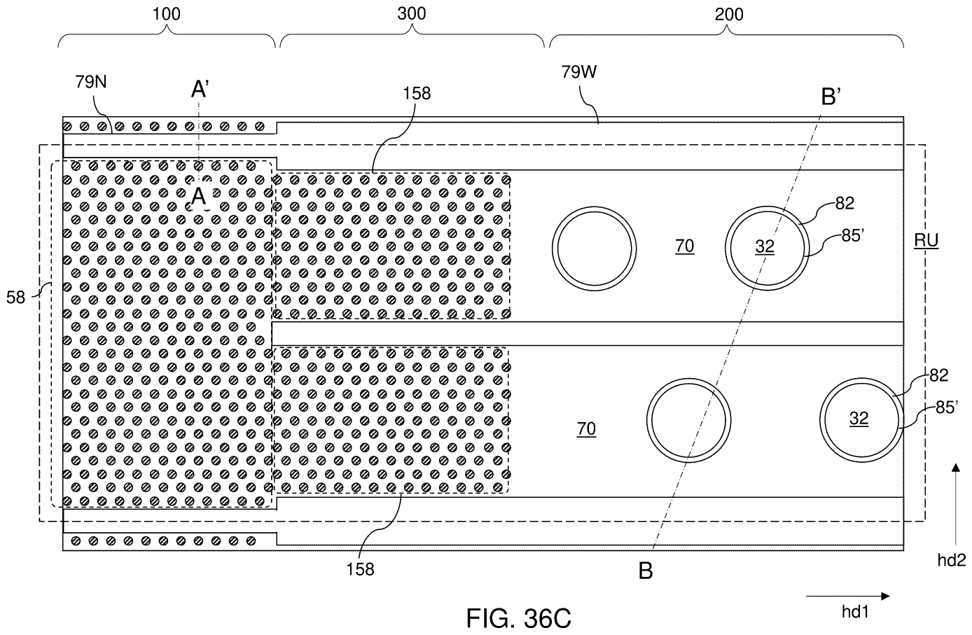

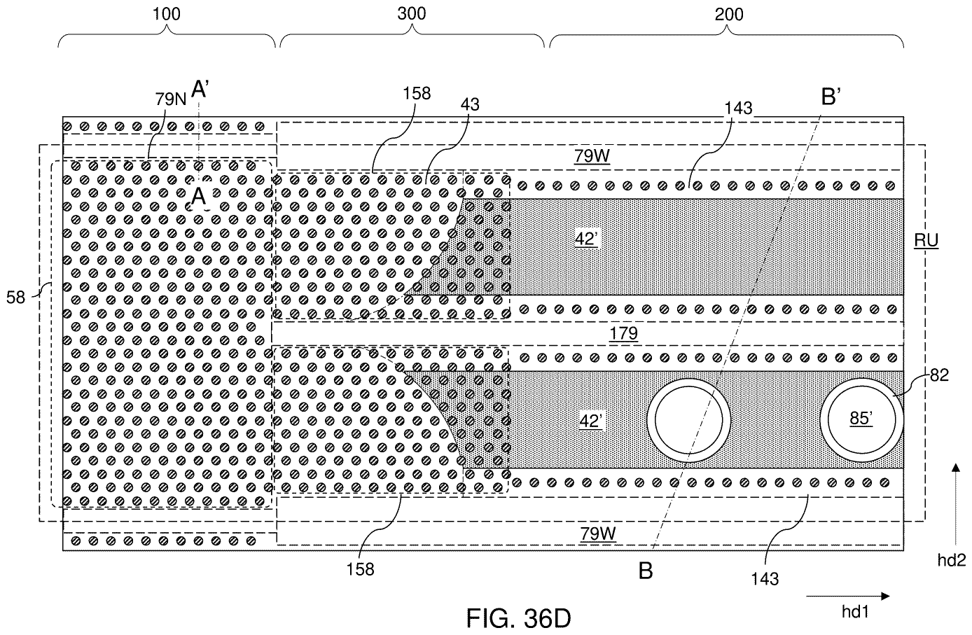

Referring to FIG. 36A-36E, a second selective isotropic etch process can be performed, which etches the materials of the sacrificial access lateral isolation trench liners 21M and the sacrificial material layers 42. The second selective isotropic etch process removes the entirety of the sacrificial access lateral isolation trench liners 21M, and laterally recesses physically exposed portions of the sacrificial material layers 42 by a second etch distance, which is less than the first etch distance. The second selective isotropic etch process etches portions of the sacrificial material layers 42 that are proximal to the wide lateral isolation trench sections 79W and further recesses the concave sidewalls of the sacrificial material layers 42 that are located in the connection region 300. Further, the second selective isotropic etch process etches portions of the sacrificial material layers 42 that are proximal to the contact via cavities 85′. Thus, the second selective isotropic etch process employs the dual-width lateral isolation trenches 79, the access lateral isolation trenches 179, and the contact via cavities 85′ as conduits for an isotropic etchant that etches the materials of the sacrificial access lateral isolation trench liners 21M and the sacrificial material layers 42. The lateral recessing of the portions of the sacrificial material layers 42 from underneath the contact via cavities 85′ is isotropic. The duration of the second selective isotropic etch process is selected such that each of the cavities formed by removal of portions of the sacrificial material layers 42 from underneath the contact via cavities 85′ merges with a respective cavity that is formed by removal of a contact via structure of a sacrificial material layer 42 around an access lateral isolation trench 179.

In the second embodiment, the sacrificial material layers 42 are isotropically recessed from around the dual-width lateral isolation trenches 79, the access lateral isolation trenches 179, and the contact via cavities 85′ by the second lateral etch distance selectively to the materials of the insulating layers 32, the insulating cap layer 70, the tubular insulating spacers 82, the semiconductor material layer 9, and the material of the outermost layers of the memory films 50. Further, the laterally-extending cavities 43 can be laterally expanded during the second selective isotropic etch process. Strip-shaped cavities 143 are formed in volumes from which the sacrificial material layers 42 are removed around the access lateral isolation trenches 179 and the contact via cavities 85′. The second lateral etch distance is less than the lateral spacing between neighboring pairs of a respective access lateral isolation trench 179 and a wide lateral isolation trench section 79W along the second horizontal direction hd2. Remaining portions of the sacrificial material layers 42 comprise dielectric material plates 42′.

The second selective isotropic etch process may comprise a wet etch process employing a wet etch solution, and/or may comprise a gas phase (dry) etch process in which the etchant is introduced in a vapor phase into the narrow lateral isolation trench sections 79N, the wide lateral isolation trench section 79W and the access lateral isolation trench 179. For example, if the sacrificial material layers 42 include silicon nitride, the etch process can be a wet etch process in which the second exemplary structure is immersed within a wet etch tank including phosphoric acid, which etches silicon nitride selective to silicon oxide, silicon, and various other materials employed in the art. The memory opening fill structures 58 provide structural support while the laterally-extending cavities 43 are present within volumes previously occupied by the sacrificial material layers 42. The dielectric material plates 42′ provide structural support to remaining portions of the insulating layers 32 in the contact region 200.

Each laterally-extending cavity 43 may be adjoined to a respective pair of strip-shaped cavities 143, as shown in FIGS. 36D and 36E. The second selective isotropic etch process isotropically recesses the sacrificial material layers 42 employing the dual-width lateral isolation trenches 79, the access lateral isolation trenches 179 and the contact via cavities 85′ as second conduits for a second selective isotropic etchant.

As shown in FIG. 36E, each of the strip-shaped cavities 143 may comprise a pair of strip cavity portions laterally extending along the first horizontal direction hd1 and having a respective uniform strip width along the second horizontal direction hd2 in the contact region 200. The uniform strip widths are less than the uniform word line width. Further, each of the strip-shaped cavities 143 may comprise a disc-shaped cavity portion that underlies a respective contact via cavity 85′ and is adjoined to the strip cavity portions. A vertical stack of dielectric material plates 42′ may be vertically interlaced with the insulating layers 32.

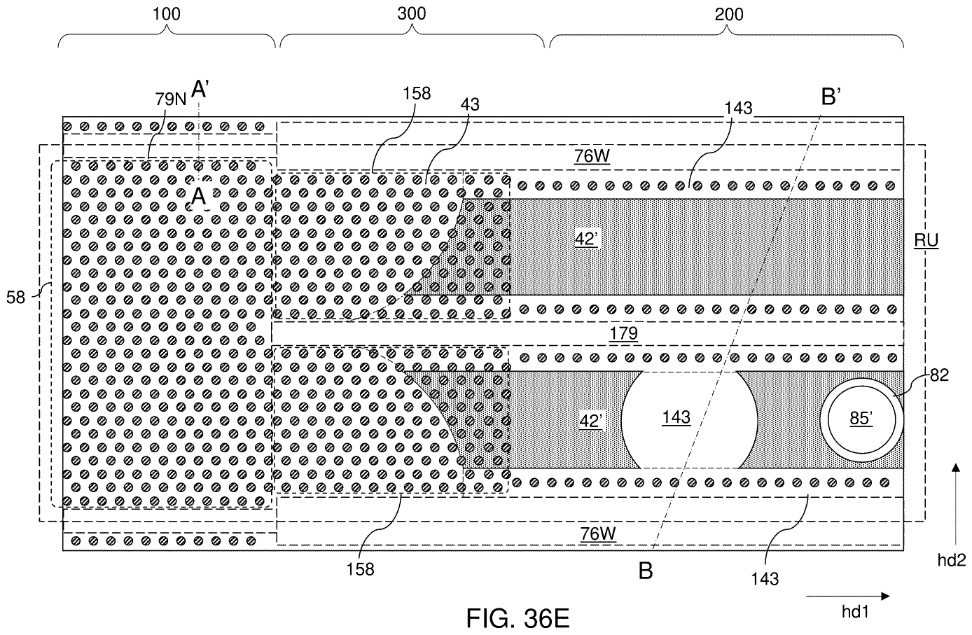

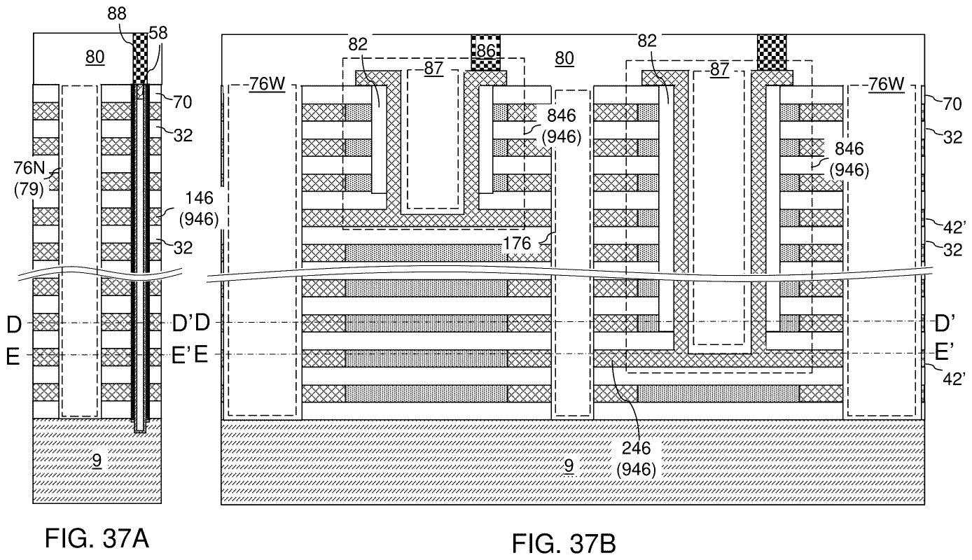

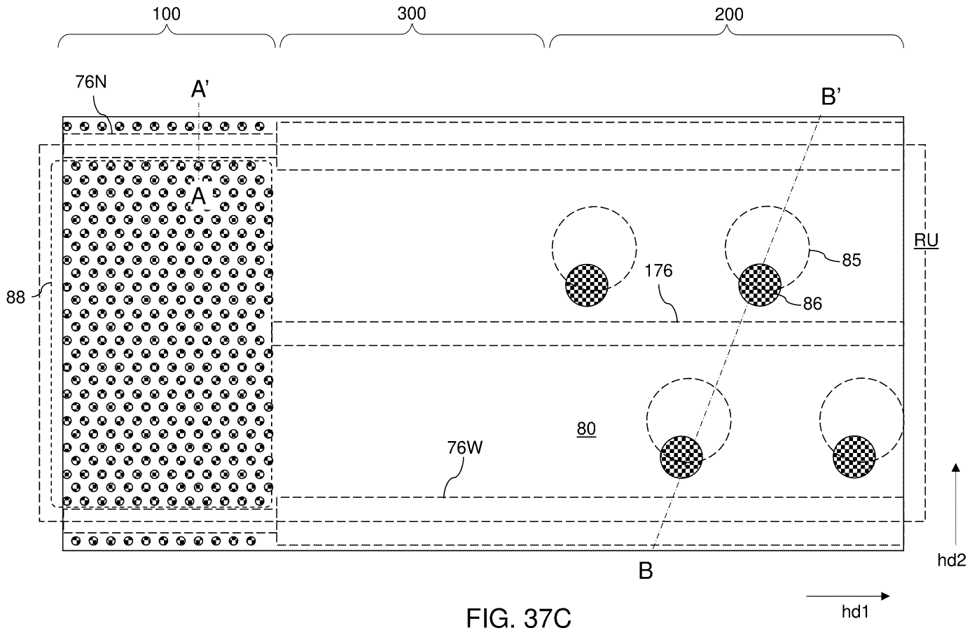

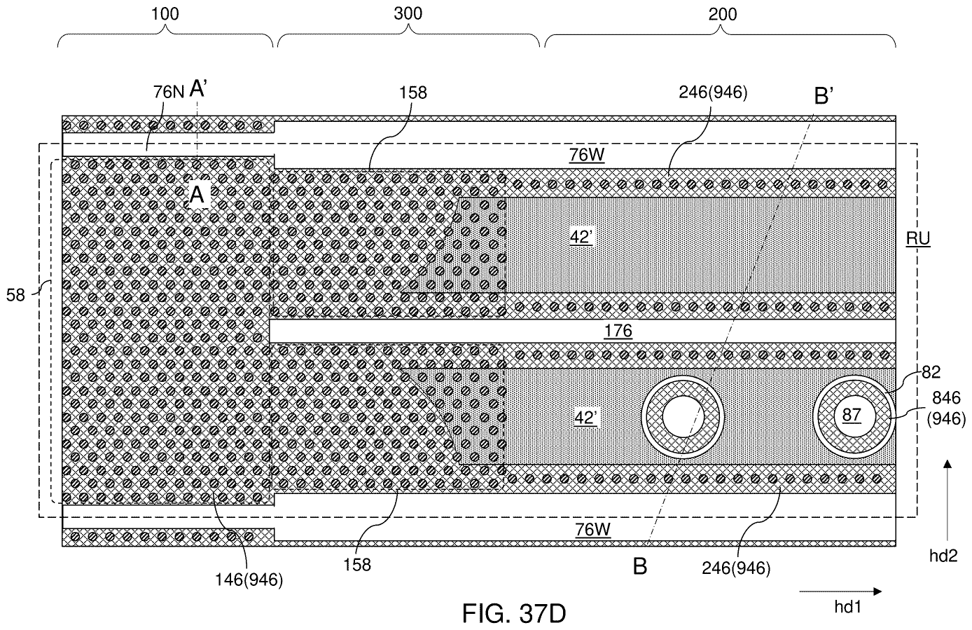

Referring to FIG. 37A-37E, the processing steps described with reference to FIG. 20A-23C can be performed to form integrated word line and contact via structures 946, a contiguous dielectric material portion (80, 76N, 76W, 87), and conductive via structures (88, 86). The integrated word line and contact via structures 946 are formed in the cavities (43, 143) that are formed by the first selective isotropic etch process and the second selective isotropic etch process. Each of the integrated word line and contact via structures 946 comprises a respective electrode layer 146, a respective contact via structure 846, and a respective pair of lateral connection strips 246 connecting the respective electrode layer 146 and the respective contact via structure 846.

The contiguous dielectric material portion (80, 76N, 76W, 87) comprises a dielectric fill material that is conformally deposited in the narrow lateral isolation trench sections 79N, in the wide lateral isolation trench sections 79W, in the access lateral isolation trenches 179, and over the insulating cap layer 70 to form a continuous dielectric material portion. The continuous dielectric material portion includes a contact-level dielectric layer 80 that is located above the insulating cap layer 79, lateral isolation trench fill structures (76N, 76W, 176) filling the lateral isolation trenches (79, 179), and dielectric pillar material portions 87 that are laterally surrounded by the contact via structures 846. Each of the vertically-extending tubular portions of the contact via structures 846 laterally encloses a respective dielectric pillar material portion 87.

In one embodiment, the contact-level dielectric layer 80 overlies the vertically alternating sequence (32, 146) and the vertically-extending tubular portions of the contact via structures 86. The contact-level dielectric layer 80 and the dielectric pillar material portions 87 are portions of a dielectric material having a uniform material composition throughout. Additional portions of the dielectric material comprise lateral isolation trench fill structures (76N, 76W, 176) contacting sidewalls of each of the insulating layers 32 and each of the electrode layers 146. The lateral isolation trench fill structures (76N, 76W, 176) comprise narrow lateral isolation trench fill structures 76N that are formed in the narrow lateral isolation trench sections 79N, wide lateral isolation trench fill structures 76W that are formed in the wide lateral isolation trench sections 79W, and access lateral isolation trench fill structures 176 that are formed in the access lateral isolation trenches 179.

In one embodiment, the lateral connection strips 246 of the integrated word line and contact via structures 946 are in direct contact with a vertically-extending portion (such as a wide lateral isolation trench fill structures 76W or an access lateral isolation trench fill structure 176) of the continuous dielectric material portion (80, 76N, 76W, 87).

In one embodiment, each access lateral isolation trench that 179 is laterally spaced from the dual-width lateral isolation trenches 79. Access isolation trench fill structures 176 can fill the access lateral isolation trenches 179. The lateral connection strips 246 of the integrated word line and contact via structures 946 are in contact with a sidewall of a respective one of the access isolation trench fill structures 176. In one embodiment, the lateral connection strips 246 of the integrated word line and contact via structures 946 are in contact with a sidewall of the vertically-extending portion (such as a of the continuous dielectric material portion (80, 76N, 76W, 87)).

The various conductive via structures (88, 86) can be formed through the contact-level dielectric layer 80. For example, drain contact via structures 88 can be formed through the contact-level dielectric layer 80 on the drain regions 63. Connection via structures 86 may be formed through the contact-level dielectric layer 80 on an annular top portion of a respective one of the contact via structures 846 that overlies the horizontal plane including the top surface of the insulating cap layer 70.

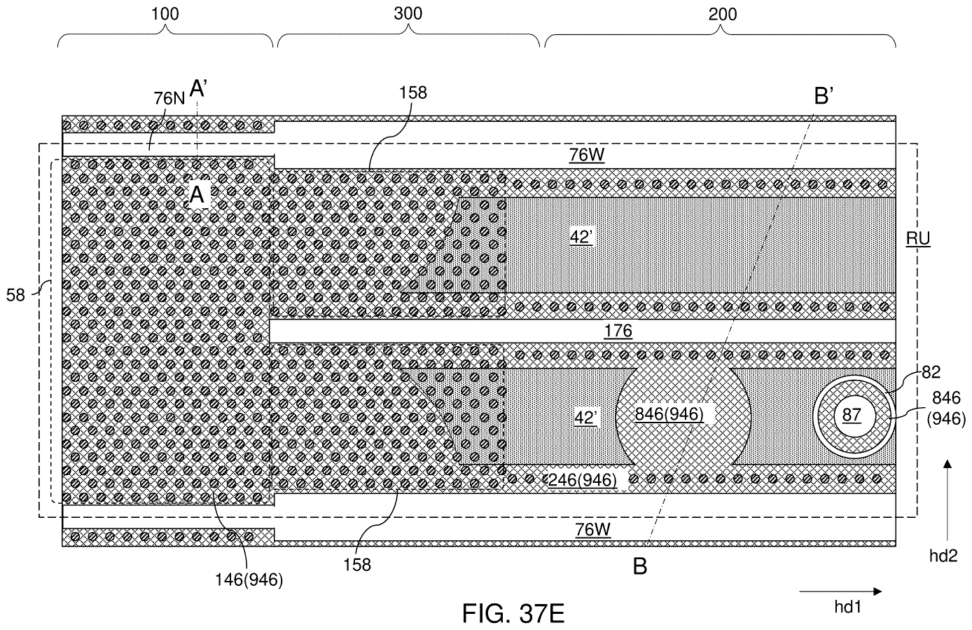

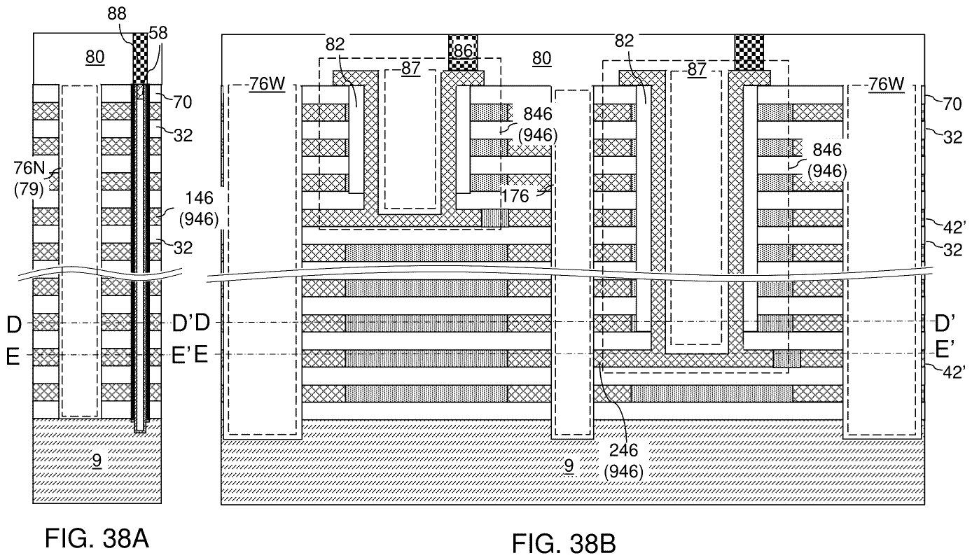

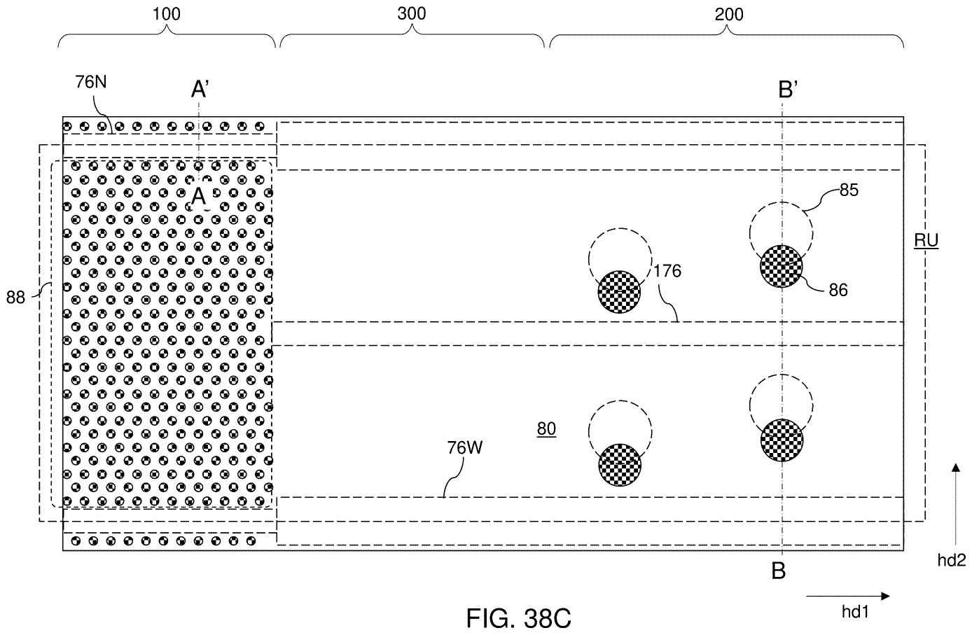

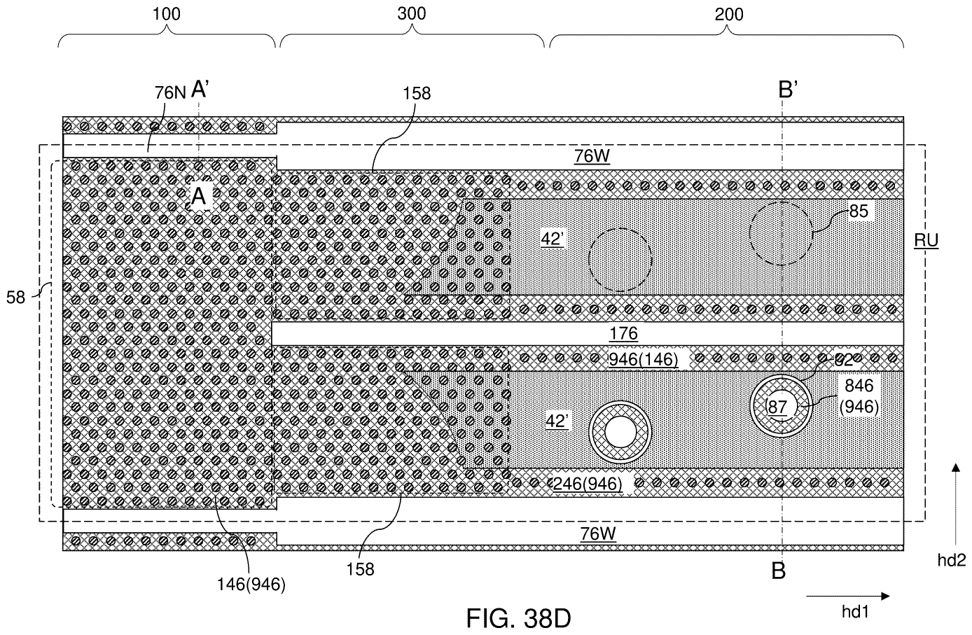

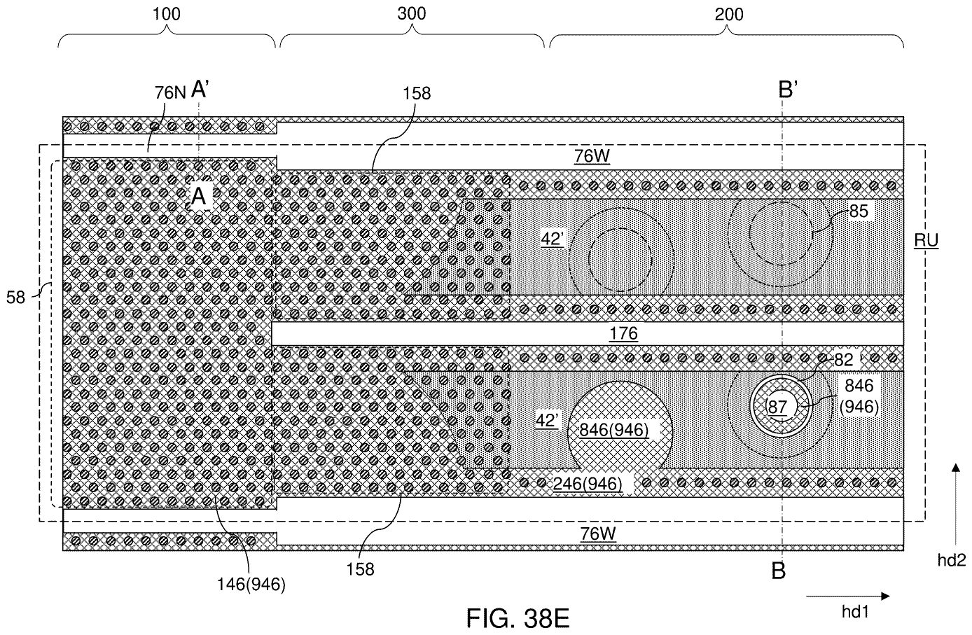

Referring to FIG. 38A-38E, a first alternative configuration of the second exemplary structure can be derived from the second exemplary structure described above by staggering the contact via openings 85 along the second horizontal direction hd2 such that each contact via structure 846 is in direct contact with only one lateral connection strip 246, as shown in FIG. 38E.

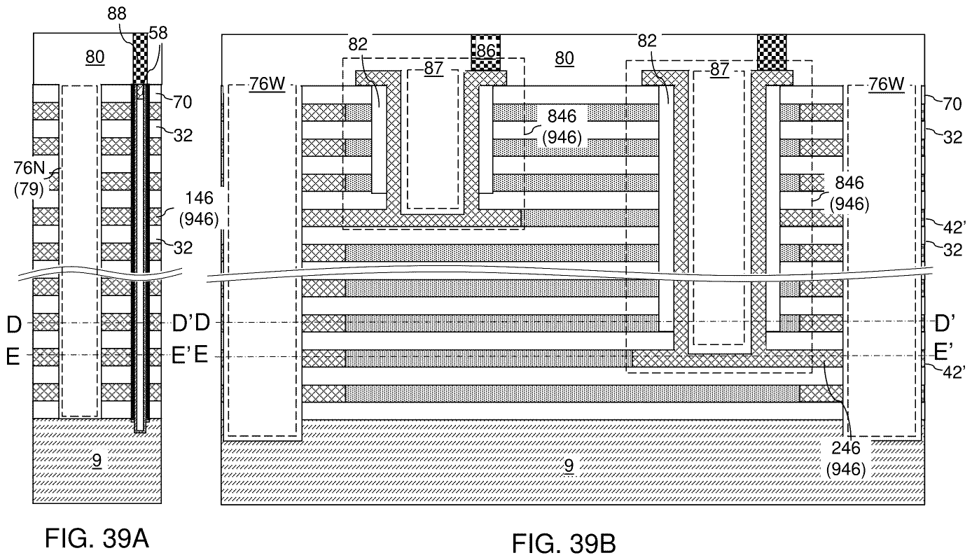

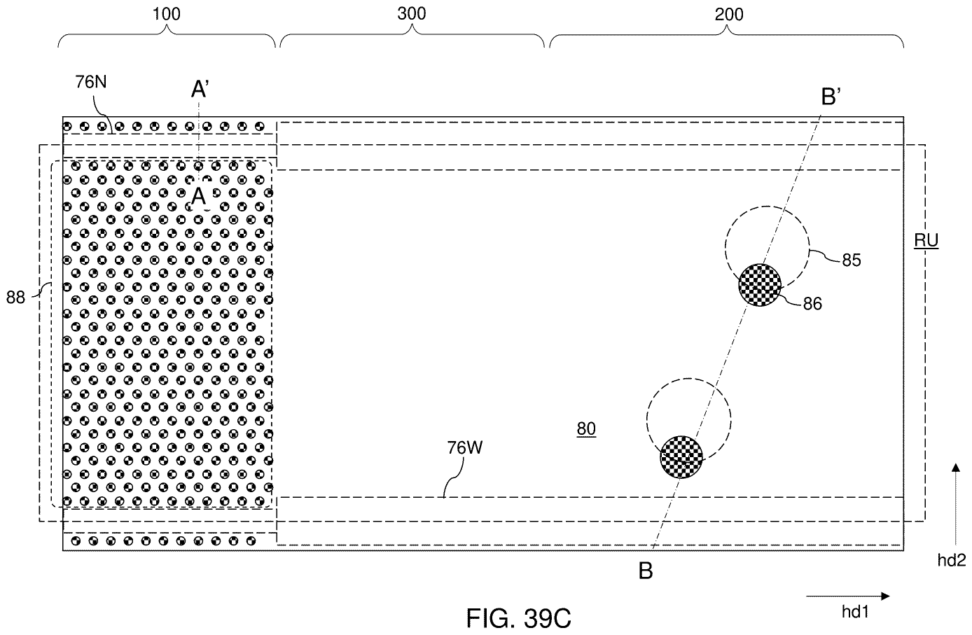

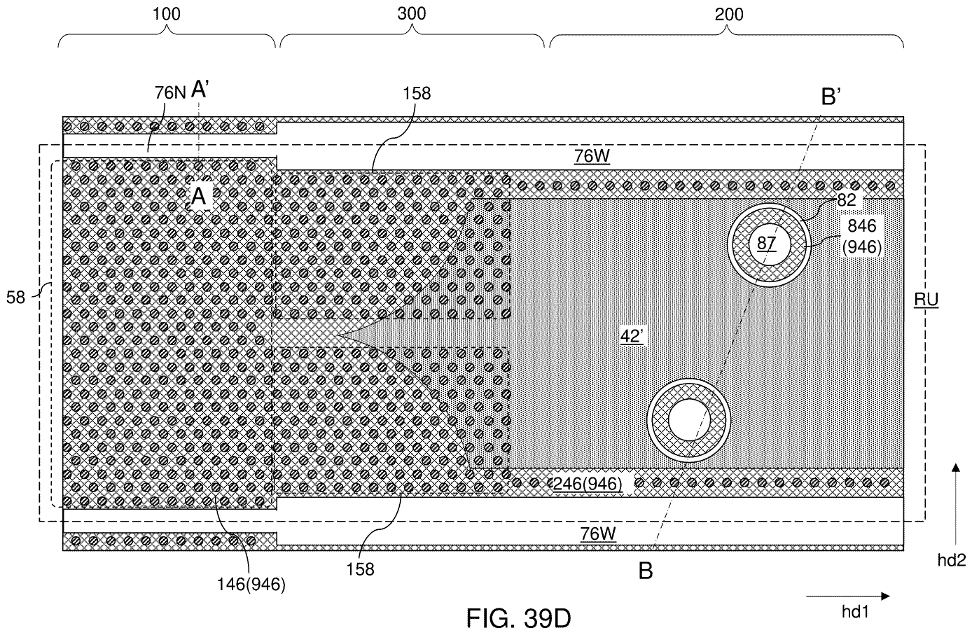

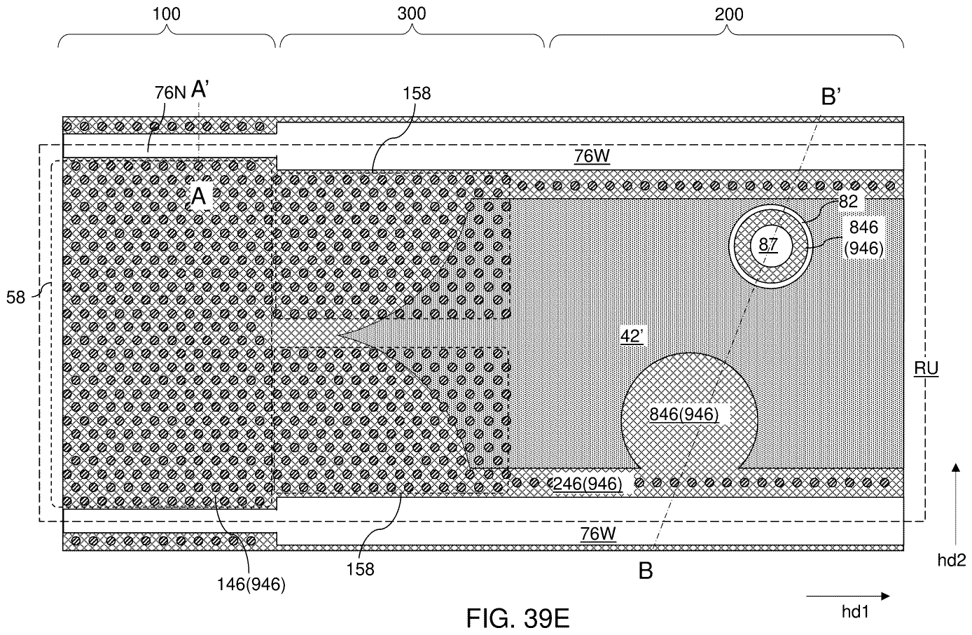

Referring to FIG. 39A-39E, a second alternative configuration of the second exemplary structure can be derived from the second exemplary structure by omitting formation of the access lateral isolation trenches 179. As a consequence, all structural components that are formed in the access lateral isolation trenches 179 in the second exemplary structure are absent in the second alternative configuration of the second exemplary structure. Further, each contact via structure 846 is in direct contact with only one lateral connection strip 246 that contacts a respective wide lateral isolation trench fill structure 76W.

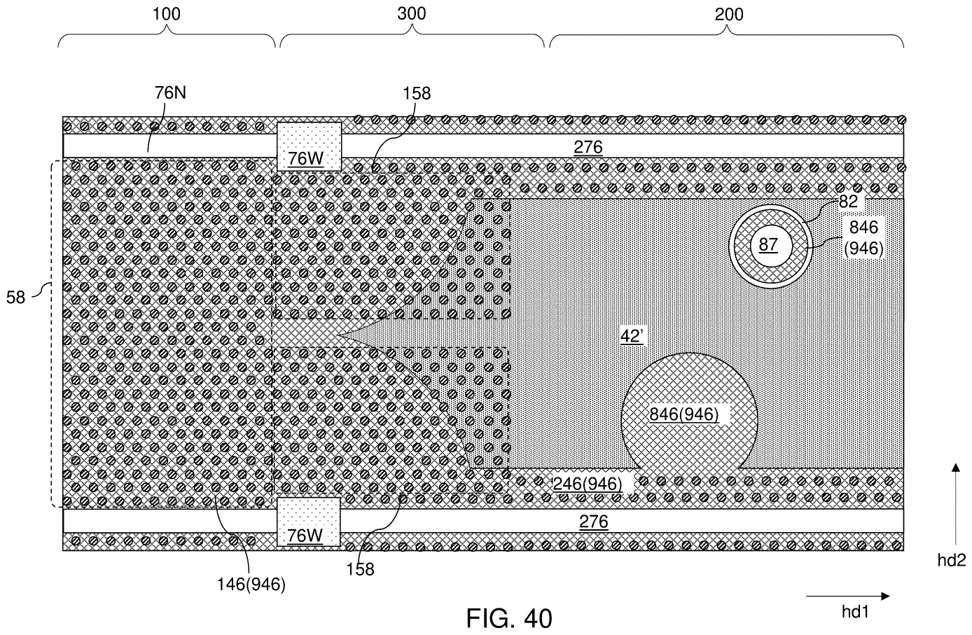

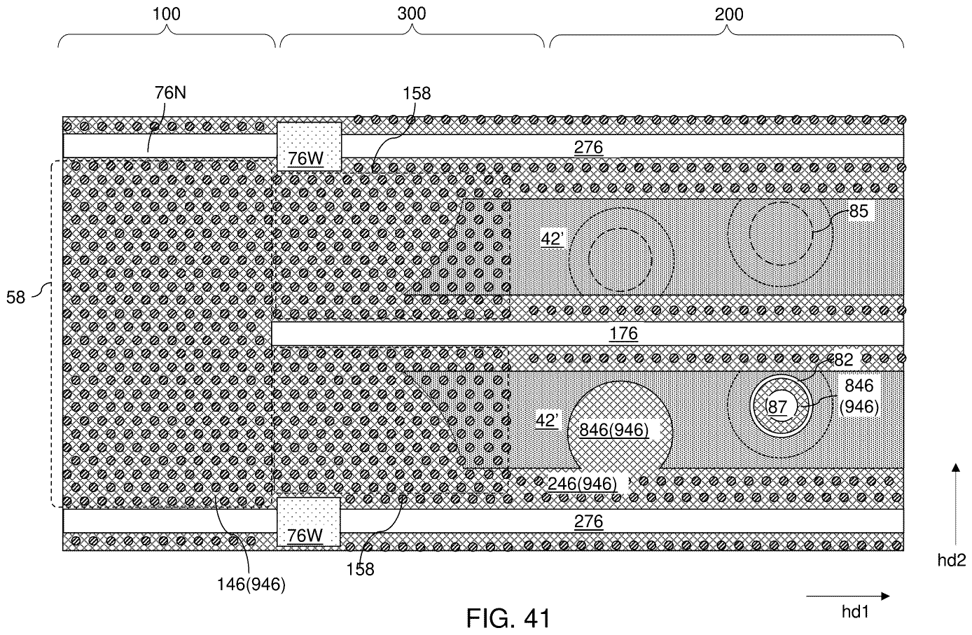

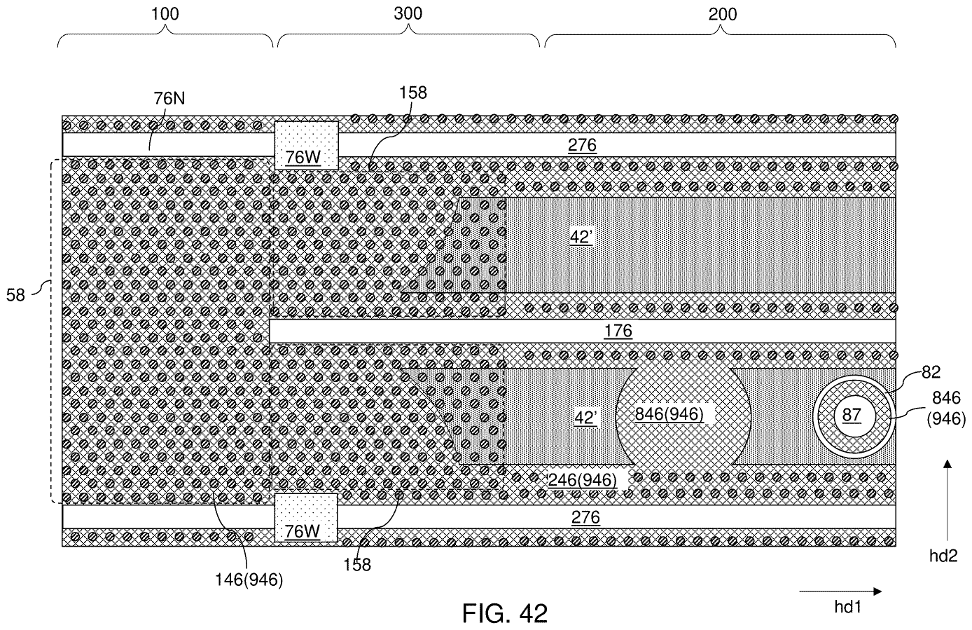

FIGS. 40, 41 and 42 are horizontal cross-sectional views of third, fourth and fifth alternative configurations of the second exemplary structure according to the second embodiment of the present disclosure. FIGS. 40, 41 and 42 are derived from FIGS. 39E, 38E and 37E, respectively. In the alternative configurations of FIGS. 40, 41 and 42, the wide lateral isolation trench fill structures 76W are formed separately from the narrow lateral isolation trench fill structures 76N as described above with respect to FIGS. 7A to 21E of the first embodiment. The wide lateral isolation trench fill structures 76W may be located in the connection region 300 and/or in the contact region 200. One or more of the wide lateral isolation trench fill structures 76W may be located at each boundary between adjacent memory blocks (e.g., repeating units RU).

In the alternative configurations of FIGS. 40, 41 and 42, the narrow lateral isolation trench sections 79N may be formed on two sides along the first horizontal direction (e.g., word line direction) hd1 of the wide lateral isolation trench section 79W that is filled with wide lateral isolation trench fill structure 76W. The narrow lateral isolation trench sections 79N in the memory array region 100 are filled with the narrow lateral isolation trench fill structures 76N, while the narrow lateral isolation trench sections 79N in the connection region 300 and/or the contact region 200 are filled with the additional lateral isolation trench fill structures 276. The narrow lateral isolation trench fill structures 76N and the additional lateral isolation trench fill structures 276 are formed at the same time.

The narrow lateral isolation trench fill structures 76N and the additional lateral isolation trench fill structures 276 may have the same width as each other or a different width from each other along the second horizontal direction (e.g., bit line direction) hd2. The narrow lateral isolation trench fill structures 76N and the additional lateral isolation trench fill structures 276 have a different (e.g., smaller) width along the second horizontal direction than the wide lateral isolation trench fill structures 76W. The narrow lateral isolation trench fill structure 76N contacts a first end of the wide lateral isolation trench fill structures 76W and the additional lateral isolation trench fill structure 276 contacts an opposing second end of the wide lateral isolation trench fill structures 76W along the first horizontal direction.

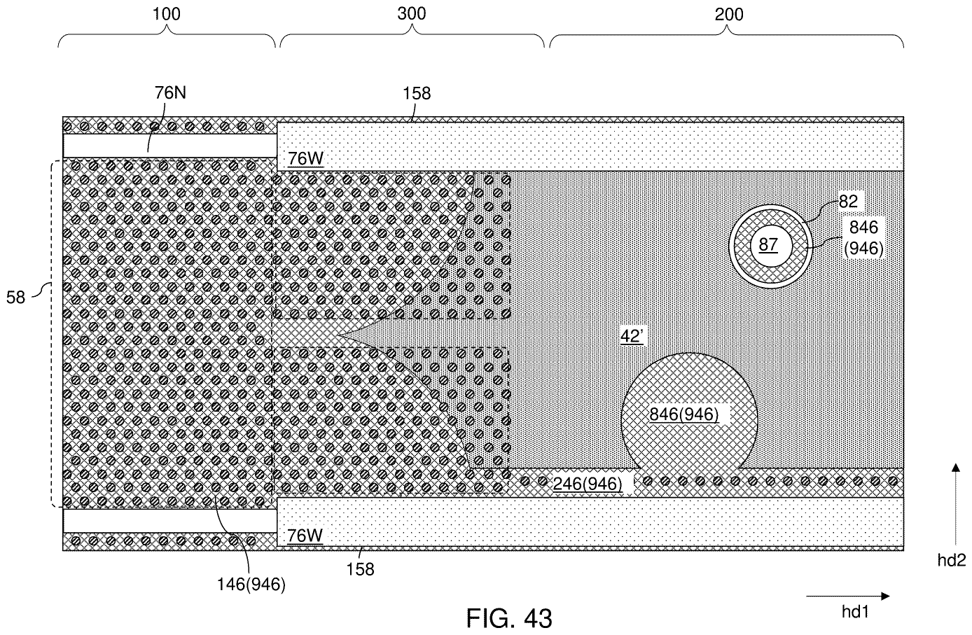

FIG. 43 is a horizontal cross-sectional view of the sixth alternative configuration of the second exemplary structure according to the second embodiment of the present disclosure that can be derived from the third alternative configuration shown in FIG. 40. In the sixth alternative configuration, the additional lateral isolation trench fill structures 276 are omitted and the wide lateral isolation trench fill structures 76W separate adjacent memory blocks in the connection regions 300 and the contact regions 200. In this configuration, the connection strips 246 are formed entirely through the contact via openings 85.

Referring to all drawings and according to various embodiments of the present disclosure, a memory device is provided, which comprises: integrated word line and contact via structures 946 each comprising a respective electrode layer 146, a respective contact via structure 846, and a respective lateral connection strip 246 connecting the respective electrode layer 146 and the respective contact via structure 846; insulating layers 32 vertically spaced apart from each other and interlaced with the electrode layers 146 to provide a vertically alternating sequence (32, 146) of the insulating layers 32 and the electrode layers 146; memory openings 49 vertically extending through the vertically alternating sequence (32, 146); and memory opening fill structures 58 located in the memory openings 49, wherein each of the memory opening fill structures 58 comprises a respective vertical stack of memory elements (which may comprise portions of memory material layers 54) located at levels of the electrode layers 146 and a vertical semiconductor channel 60.

In one embodiment, the electrode layers 146 laterally extend along a first horizontal direction hd1 and have a uniform word-line width along a second horizontal direction hd2 in a memory array region 100; the memory opening fill structures 58 are located in the memory array region 100; the lateral connection strips 246 laterally extend along the first horizontal direction hd1 and have a strip width along the second horizontal direction hd2 in a contact region 200, wherein the strip width is less than the uniform word line width; and the integrated word line and contact via structures 946 are located in the contact region 200.

In one embodiment, each of the electrode layers 146 has a laterally-convex sidewall section in a connection region 300 that is located between the memory array region 100 and the contact region 200. In one embodiment, each of the electrode layers 146 has a variable width that changes from the uniform word-line width to the strip width within the connection region 300 containing the laterally-convex sidewall sections.

In one embodiment, each of the contact via structures 846 has a respective bottom plate 846P and a respective vertically-extending tubular portion 846T having a bottom end that is connected to the respective bottom plate 846P. In one embodiment, a center portion of the respective bottom plate 846P has a uniform inner bottom plate thickness; the respective vertically-extending tubular portion 846T has a uniform lateral thickness between an inner sidewall and an outer sidewall; and the uniform lateral thickness is the same as the uniform inner bottom plate thickness.

In one embodiment, each of the vertically-extending tubular portions 846T of the contact via structures 846 laterally encloses a respective dielectric pillar material portion 87. In one embodiment, a contact-level dielectric layer 80 overlies the vertically alternating sequence (32, 146) and the vertically-extending tubular portions 846T. The contact-level dielectric layer 80 and the dielectric pillar material portions 87 are portions of a dielectric material having a uniform material composition throughout. In one embodiment, additional portions of the dielectric material comprise lateral isolation trench fill structures (76N, 76W, and/or 176) contacting sidewalls of each of the insulating layers 32 and each of the electrode layers 146.

In one embodiment, the memory device further comprises metal oxide outer blocking dielectric layers 44 which continuously extend along surfaces of the electrode layers 146, the lateral connection strips 246, the bottom plates 846P and the vertically-extending tubular portions 846T.

In one embodiment, the memory device further comprises: additional integrated word line and contact via structures 946 comprising a respective additional electrode layer 146, a respective additional contact via structure 846, and a respective additional lateral connection strip 246. The additional integrated word line and contact via structures 946 are located in a second memory block (e.g., additional repeating unit RU) which is laterally spaced along the second horizontal direction hd1 from a first memory block (e.g., the repeating unit RU) containing the integrated word line and contact via structures 946 and the vertically alternating sequence of the insulating layers 32 and the electrode layers 146. The memory device further comprises additional insulating layers 32 vertically spaced apart from each other and interlaced with the additional electrode layers 146 to provide an additional vertically alternating sequence (32, 146) of the additional insulating layers 32 and the additional electrode layers 146 located in the second memory block. The memory device further comprises a dual-width lateral isolation trench 79 extending along the first horizontal direction hd1 and laterally separating the first memory block from the second memory block, wherein the dual-width lateral isolation trench comprises a wide lateral isolation trench section 79W having a first width and located in the contact region 200 and further comprising a narrow lateral isolation trench section 79N having a second width and located in the memory array region 100, the first width being greater than the second width. A wide lateral isolation trench fill structure 76W fills the wide lateral isolation trench section 79W; and a narrow lateral isolation trench fill structure 76N fills the narrow lateral isolation trench section.

In the first embodiment, the narrow lateral isolation trench fill structure 76N comprises a part of a continuous dielectric material portion that has a uniform material composition throughout and further comprises a contact-level dielectric layer 80 overlying the vertically alternating sequence and the additional vertically alternating sequence; and the wide lateral isolation trench fill structure 76W is not part of the continuous dielectric material portion.

In the second embodiment, the narrow lateral isolation trench fill structure 76N and the wide lateral isolation structure 76W both comprise parts of a continuous dielectric material portion that has a uniform material composition throughout and further comprises a contact-level dielectric layer 80 overlying the vertically alternating sequence and the additional vertically alternating sequence.

In one embodiment, the lateral connection strips 246 of the integrated word line and contact via structures 946 are in contact with a sidewall of the wide lateral isolation trench fill structure 76W.

In the embodiments of FIG. 40-42, an additional lateral isolation trench fill structure 276 contacts a first end of the wide lateral isolation trench fill structure 76W, and the narrow lateral isolation trench fill structure 76N contacts a second end of the wide lateral isolation trench fill structure 76W opposite to the first end. The wide lateral isolation trench fill structure 76W has a greater width along the second horizontal direction hd2 than the narrow lateral isolation trench fill structure 76N and the additional lateral isolation trench fill structure 276.

In various embodiments, the memory device also comprises: an access lateral isolation trench 179 that is laterally spaced from the dual-width lateral isolation trench 79 along the second horizontal direction hd2; and an access isolation trench fill structure 176 filling the access lateral isolation trench 179. The lateral connection strips 246 of the integrated word line and contact via structures 946 are in contact with a sidewall of the access isolation trench fill structure 176. In one embodiment shown in FIG. 38A-38E, plural rows of the integrated word line and contact via structures 946 extending along the first horizontal direction are located between the access isolation trench 179 and the dual-width isolation trench 79.

In one embodiment, each of the integrated word line and contact via structures 946 comprises at least one electrically conductive material having a unform material composition throughout and is free of any material interface therein. In one embodiment, a vertical stack of dielectric material plates 42′ may be vertically interlaced with the insulating layers 32. Each of the dielectric material plates 42′ is in contact with a sidewall of the electrode layer 146, a sidewall of the lateral connection strip 246, and a sidewall of the contact via structure 846 of a respective one of the integrated word line and contact via structures 946.

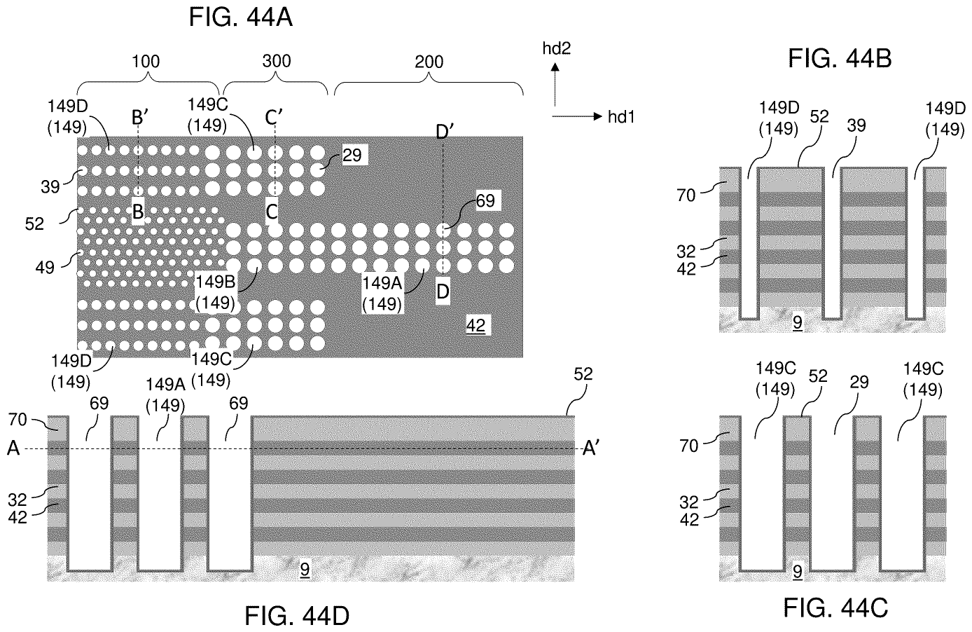

Referring to FIG. 44A-44D, a third exemplary structure may be derived from the first exemplary structure illustrated in FIG. 1 by performing the sequence of processing steps described with reference to FIG. 2A-2C with modifications in the pattern of an etch mask layer. Generally, an alternating stack (32, 42) of insulating layers 32 and sacrificial material layers 42 can be formed over a substrate, such as the above described semiconductor material layer 9. An insulating cap layer 70 may be formed over the alternating stack (32, 42). An etch mask layer containing mask openings can be formed over the alternating stack (32, 42). An anisotropic opening etch process can be performed to transfer a pattern of the mask openings through the alternating stack (32, 42). The anisotropic opening etch process simultaneously etches various openings (49, 149, 29, 39, 69) through the alternating stack (32, 42). The various openings (49, 149, 29, 39, 69) may comprise memory openings 49 that are formed in the memory array region 100, the dummy memory openings 149 that are formed across various regions, connection-region isolation openings 29 that are formed in a connection region 300, memory-region isolation openings 39 that are formed in the memory array region 100, and discrete access openings 69 that are formed in the contact region 200. The contact region 200 may be laterally spaced from the memory array region 100 along a first horizontal direction hd1, and the connection region 300 may be located between the memory array region 100 and the contact region 200 along the first horizontal direction hd1. A second horizontal direction hd2 is perpendicular to the first horizontal direction hd2. Generally, the various openings (49, 149, 29, 39, 69) may have respective circular or non-circular horizontal cross-sectional shapes. Exemplary non-circular horizontal cross-sectional shapes that may be employed include ellipsoids and rounded rectangles. The patterns of the various openings (49, 149, 29, 39, 69) may vary depending on the layout of the three-dimensional memory array to be formed, the layout of the various lateral isolation trenches to be formed, and the contact scheme to be employed to provide electrical contact to word lines.

The memory openings 49 are subsequently employed to form memory opening fill structures 58 described above. The dummy memory openings 149 are subsequently employed to form dummy memory opening fill structures 158 described above. In the third exemplary structure, the dummy memory openings 149 may comprise first dummy memory openings 149A that are formed in the contact region 200 and interlaced with a first subset of the discrete access openings 69 located in the contact region 200, second dummy memory openings 149B that are formed in the connection region 300 and interlaced with a second subset of the discrete access openings 69 located in the connection region 300, third dummy memory openings 149C that are formed in the connection region 300 adjacent to the connection-region isolation openings 29, and fourth dummy memory openings 149D that are formed in the memory array region 100 adjacent to the memory-region isolation openings 39. In one embodiment, the first dummy memory openings 149A and the second dummy memory openings 149B may be formed such that a first dummy memory opening 149A or a second dummy memory opening 149B is more proximal to at least one and/or each of the discrete access openings 69, thereby providing an “interlaced” configuration in which at least a subset of the discrete access openings 69 is surrounded by a respective plurality of the first dummy memory openings 149A and/or the second dummy memory openings 149B on at least two sides, such as on two to four sides.

In one embodiment, the connection-region isolation openings 29 may be generally arranged along the first horizontal direction hd1, with or without stagger along the second horizontal direction hd2. The third dummy memory openings 149C may be generally arranged along the first horizontal direction hd1 to be subsequently filled with dummy memory opening fill structures that support the insulating layers 32 after subsequent removal of the sacrificial material layers 42 around the connection-region isolation openings 29.

In one embodiment, the array-region isolation openings 39 may be generally arranged along the first horizontal direction hd1, with or without stagger along the second horizontal direction hd2. The fourth dummy memory openings 149D may be generally arranged along the first horizontal direction hd1 to be subsequently filled with dummy memory opening fill structures that support the insulating layers 32 after subsequent removal of the sacrificial material layers 42 around the connection-region isolation openings 29.

In one embodiment, the discrete access openings 69 may be generally arranged along the first horizontal direction hd1, preferably with stagger along the second horizontal direction hd2. The stagger of the discrete access openings 69 along the second horizontal direction hd2 leads to an increase of the effective width of lateral connection strips of electrically conductive layers to be subsequently formed. In one embodiment, multiple rows of discrete access openings 69 may be formed such that each row of discrete access openings 69 is arranged along the first horizontal direction hd1 (i.e., in a straight line), and the multiple rows are laterally spaced apart from each other along the second horizontal direction hd2. As discussed above, the first dummy memory openings 149A and the second dummy memory openings 149B may be interlaced with the discrete access openings 69. The dummy memory openings are subsequently filled with dummy memory opening fill structures support the insulating layers 32 upon subsequent removal of the sacrificial material layers 42 around the discrete access openings 69.

The etch mask layer is removed after formation of the various openings (49, 149, 29, 39, 69) through the alternating stack (32, 42). Optionally, the blocking dielectric layer 52 described above may be formed as a continuous material layer after removal of the etch mask layer. Alternatively, formation of the blocking dielectric layer 52 may be performed immediately before deposition of a memory material layer.

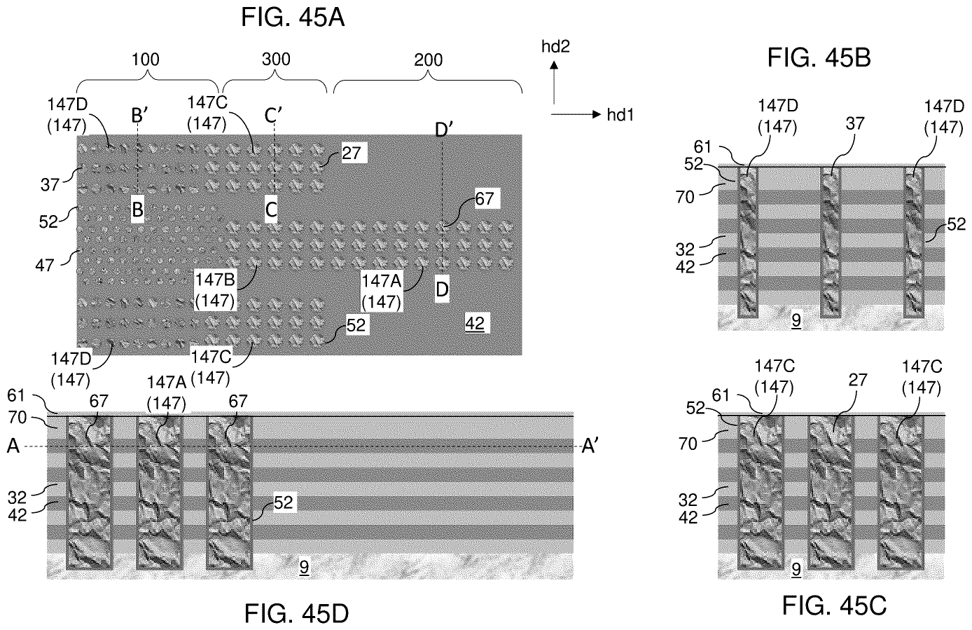

Referring to FIG. 45A-45D, a sacrificial opening fill material, such as amorphous carbon, diamond-like carbon, or a polymer material, may be deposited in the various openings (49, 149, 29, 39, 69). Excess portions of the sacrificial opening fill material may be removed from above the insulating cap layer 70 by a planarization process, such as a recess etch process. Each remaining portion of the sacrificial opening fill material comprises a sacrificial opening fill structure (47, 147, 27, 37, 67). The various sacrificial opening fill structures (47, 147, 27, 37, 67) may comprise sacrificial memory opening fill structures 47 that are formed memory openings 49, sacrificial dummy memory opening fill structures 147 that are formed in the dummy memory openings 149, sacrificial connection-region isolation opening fill structures 27 that are formed in the connection-region isolation openings 29, sacrificial memory-region isolation opening fill structures 37 that are formed in the memory-region isolation openings 39, and sacrificial discrete access opening fill structures 67 that are formed in the discrete access openings 69. The sacrificial dummy memory opening fill structures 147 may comprise first sacrificial dummy memory opening fill structures 147A that are formed in the first dummy memory openings 149A, second sacrificial dummy memory opening fill structures 147B that are formed in the second dummy memory openings 149B, third sacrificial dummy memory opening fill structures 147C that are formed in the dummy memory openings 149C, and fourth sacrificial dummy memory opening fill structures 147D that are formed in the dummy memory openings 149D.

A sacrificial cover dielectric layer 61 may be formed over the alternating stack (32, 42), the insulating cap layer 70, and the various sacrificial opening fill structures (47, 147, 27, 37, 67). In one embodiment, the sacrificial cover dielectric layer 61 may comprise a dielectric material such as silicon oxide, silicon oxynitride, silicon carbonitride, and/or a dielectric metal oxide material. In one embodiment, the sacrificial cover dielectric layer 61 comprises undoped silicate glass (i.e., silicon oxide) or a doped silicate glass. In one embodiment, the thickness of the sacrificial cover dielectric layer 61 may be in a range from 10 nm to 100 nm, although lesser or greater thicknesses may also be employed.

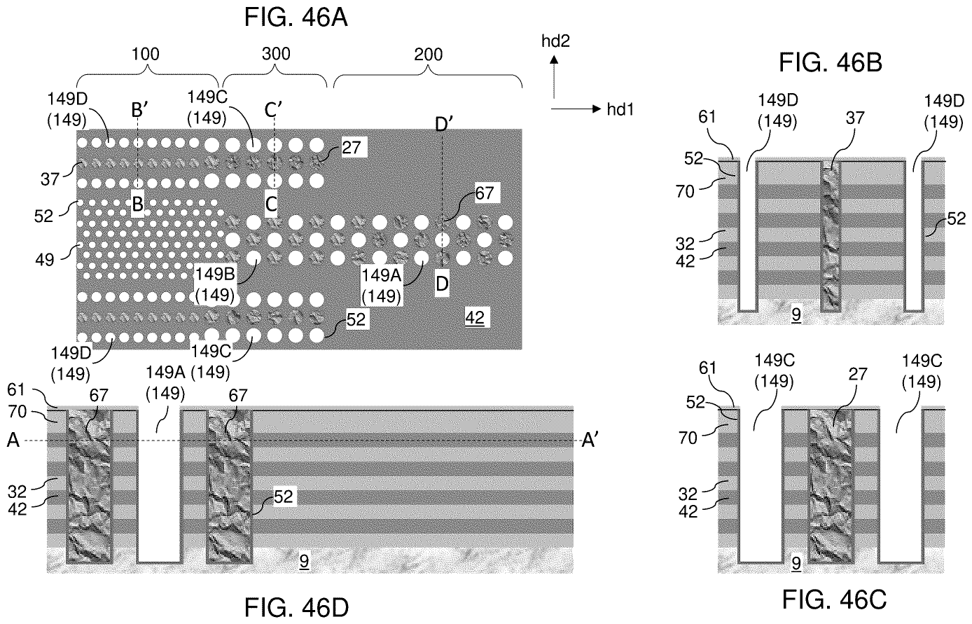

Referring to FIG. 46A-46D, a photoresist layer (not shown) may be applied over the sacrificial cover dielectric layer 61, and may be lithographically patterned to form openings over the area of the sacrificial memory opening fill structures 47 and the sacrificial dummy memory opening fill structures 147. An anisotropic etch process can be performed to transfer the pattern of the openings in the photoresist layer through the sacrificial cover dielectric layer 61. A selective sacrificial material removal process may be performed to remove the sacrificial memory opening fill structures 47 and the sacrificial dummy memory opening fill structures 147 selectively to the blocking dielectric layer 52 (if the blocking dielectric layer 52 is present) or selectively to the materials of the alternating stack (32, 42) and the substrate (if the blocking dielectric layer 52 is not present at this processing step). For example, if the sacrificial memory opening fill structures 47 and the sacrificial dummy memory opening fill structures 147 comprise amorphous carbon, an ashing process may be performed to remove the sacrificial memory opening fill structures 47 and the sacrificial dummy memory opening fill structures 147. Cavities are formed within the volumes of the memory openings 49 and the dummy memory openings 149 that are not occupied by portions of the blocking dielectric layer 52.

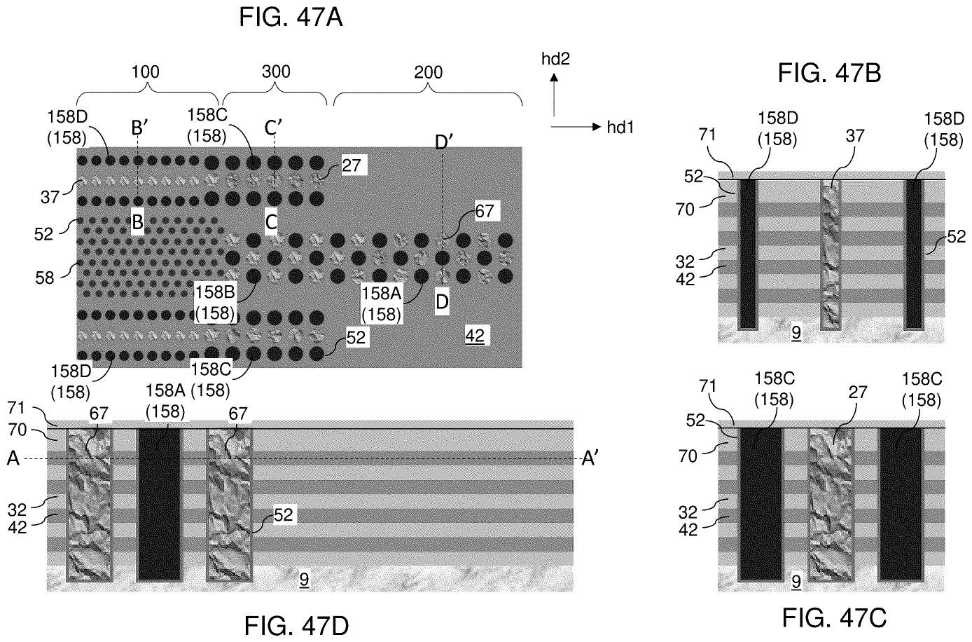

Referring to FIG. 47A-47D, the processing steps described with reference to FIGS. 3B-3F may be performed to form a memory opening fill structure 58 within each memory opening 49, and to form a dummy memory opening fill structure 158 within each dummy memory opening 149. If the blocking dielectric layer 52 is present after the processing steps described with reference to FIG. 46A-46D, the processing step for depositing a blocking dielectric layer as described with reference to FIG. 3B may be fully or partially omitted. The sacrificial cover dielectric layer 61 may be removed during a planarization process described with reference to FIG. 3F. Thus, the top surfaces of the drain regions 63 may be formed within the same horizontal plane as the top surfaces of the sacrificial connection-region isolation opening fill structures 27, the sacrificial memory-region isolation opening fill structures 37, and the sacrificial discrete access opening fill structures 67.

The dummy memory opening fill structure 158 may comprise first dummy memory opening fill structures 158A that are formed in the first dummy memory openings 149A, second dummy memory opening fill structures 158B that are formed in the second dummy memory openings 149B, third dummy memory opening fill structures 158C that are formed in the third dummy memory openings 149C, and fourth dummy memory opening fill structures 158D that are formed in the fourth dummy memory openings 149D. While a blocking dielectric layer 52 is shown separately around each memory opening fill structure 58 and each dummy memory opening fill structure 158, it is understood that the blocking dielectric layer 52 is a component of a memory opening fill structure 58 or a dummy memory opening fill structure 158 as illustrated in FIG. 3F.

Generally, the memory opening fill structures 58 and the dummy memory opening fill structures 158 are formed in the memory openings 49 and in the dummy memory openings 149, respectively, while portions of the sacrificial opening fill material are present in the connection-region isolation openings 29, the memory-region isolation openings 39, and the discrete access openings 69. In other words, the memory opening fill structures 58 and the dummy memory opening fill structures 158 are formed in the memory openings 49 and in the dummy memory openings 149, respectively, while the sacrificial connection-region isolation opening fill structures 27, the sacrificial memory-region isolation opening fill structures 37, and the sacrificial discrete access opening fill structures 67 are present in the connection-region isolation openings 29, the memory-region isolation openings 39, and the discrete access openings 69, respectively.

In one embodiment, each of the memory opening fill structures 58 and the dummy memory opening fill structures 158 comprises a respective memory film 50, a respective vertical semiconductor channel 60, and a respective drain region 63 contacting an end portion of the respective vertical semiconductor channel 60. Generally, each of the memory opening fill structures 58 comprises a respective vertical stack of memory elements, which may comprise portions of the memory material layers 54 located at the levels of the sacrificial material layers 42.

A cover dielectric layer 71 may be formed over the alternating stack (32, 42), the insulating cap layer 70, the memory opening fill structures 58, the dummy memory opening fill structures 158, and various sacrificial opening fill structures (27, 37, 67). In one embodiment, the cover dielectric layer 71 may comprise a dielectric material such as silicon oxide, silicon oxynitride, silicon carbonitride, and/or a dielectric metal oxide material. In one embodiment, the cover dielectric layer 71 comprises undoped silicate glass or a doped silicate glass. In one embodiment, the thickness of the cover dielectric layer 71 may be in a range from 10 nm to 100 nm, although lesser or greater thicknesses may also be employed.

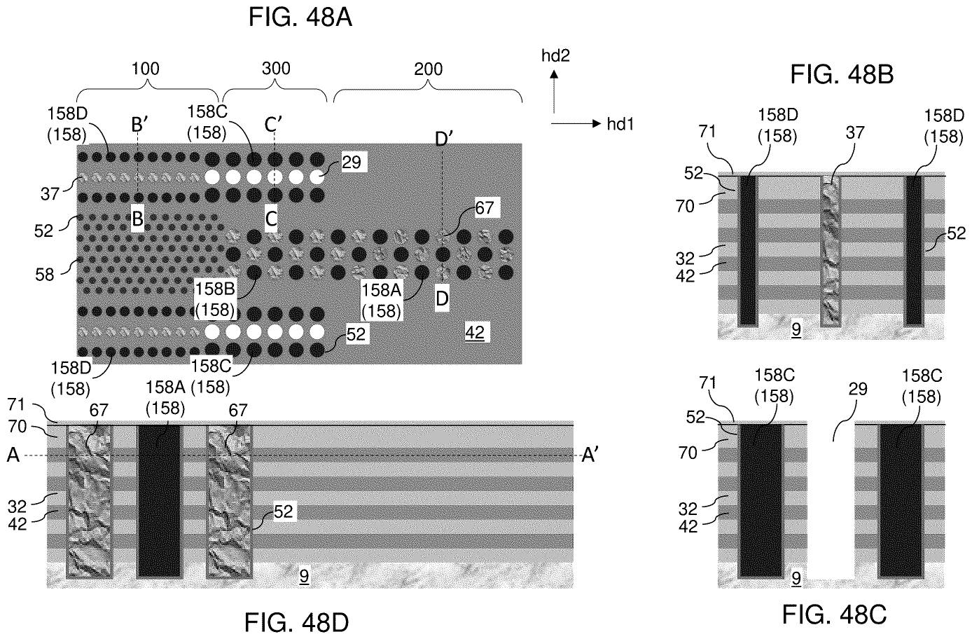

Referring to FIG. 48A-48D, a photoresist layer (not shown) can be applied over the cover dielectric layer 71, and can be lithographically patterned to form openings over the areas of the sacrificial connection-region isolation opening fill structures 27. An anisotropic etch process may be performed to transfer the pattern of the openings in the photoresist layer through the cover dielectric layer 71. A selective sacrificial material removal process may be performed to remove the sacrificial connection-region isolation opening fill structures 27 selectively to the blocking dielectric layer 52 (if the blocking dielectric layer 52 is present) or selectively to the materials of the alternating stack (32, 42) and the substrate (if the blocking dielectric layer 52 is not present at this processing step). For example, if the sacrificial connection-region isolation opening fill structures 27 comprise amorphous carbon, an ashing process may be performed to remove the sacrificial connection-region isolation opening fill structures 27. Cavities are formed within the volumes of the connection-region isolation opening 29 that are not occupied by portions of the blocking dielectric layer 52. If blocking dielectric layers 52 are present in peripheral regions of the connection-region isolation openings 29, a timed isotropic etch process (such as a wet etch process) may be performed to remove the blocking dielectric layers 52 from the peripheral regions of the connection-region isolation openings 29.

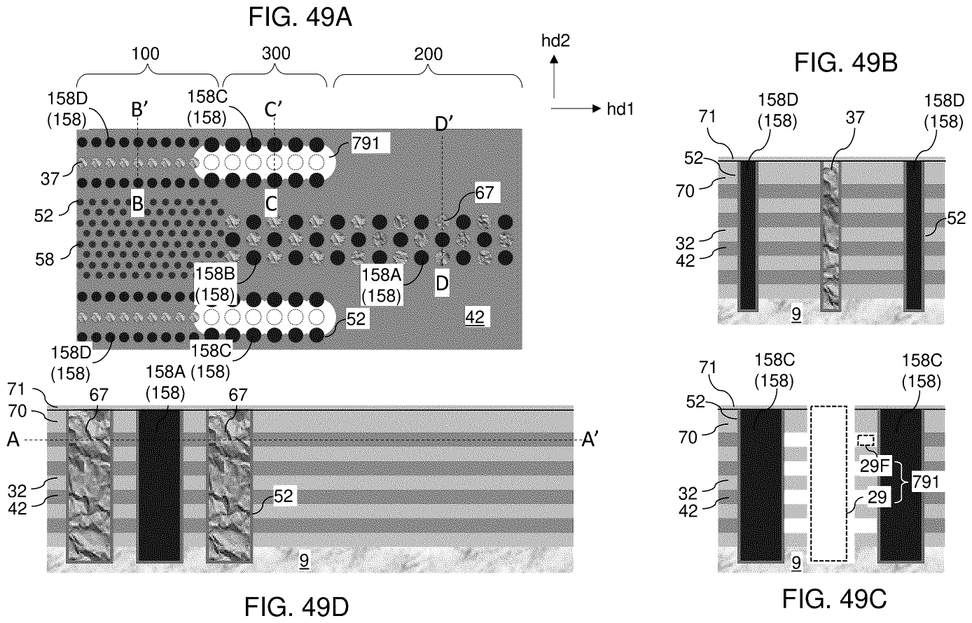

Referring to FIG. 49A-49D, a first selective isotropic etch process can be performed to isotropically etch portions of the sacrificial material layers 42 that are proximal to the connection-region isolation openings 29. For example, if the sacrificial material layers 42 comprise silicon nitride, the first selective isotropic etch process may comprise a wet etch process employing hot phosphoric acid. In one embodiment, the duration of the first selective isotropic etch process can be selected such that voids formed by removal of portions of the sacrificial material layers 42 merge to form laterally-extending voids 29F at the levels of the sacrificial material layers 42. Each contiguous volume formed by interconnection of the connection-region isolation openings 29 and the laterally-extending voids 29F constitutes a connection-region isolation trench 791.

Generally, the connection-region isolation trenches 791 can be formed by laterally expanding and merging subsets of the connection-region isolation openings 29 through formation of the laterally-extending voids 29F. Thus, each of the connection-region isolation trenches 791 comprises a respective subset of vertically-extending voids having volumes of the connection-region isolation openings 29, and further comprises a respective vertical stack of laterally-extending voids 29F formed at levels of the sacrificial material layers 42 and connecting the respective subset of vertically-extending voids.

The duration of the first selective isotropic etch process may be selected such that sidewall surface segments of the third dummy memory opening fill structures 158C are physically exposed to the connection-region isolation trenches 791 at the levels of the sacrificial material layers 42. Further, a sidewall surface segment of a sacrificial memory-region isolation opening fill structure 37 or a blocking dielectric layer 52 surrounding the structure 37 may be physically exposed to a connection-region isolation trench 791. The sidewalls of the laterally-extending voids 29F at levels of the sacrificial material layers 42 are laterally offset from the sidewalls of the connection-region isolation openings 29 at the levels of the insulating layers 32 by a first uniform lateral offset distance, which is the etch distance of the first selective isotropic etch process for the material of the sacrificial material layers 42. The first uniform lateral offset distance may be in a range from 100 nm to 1,000 nm, although lesser or greater dimensions may also be employed.

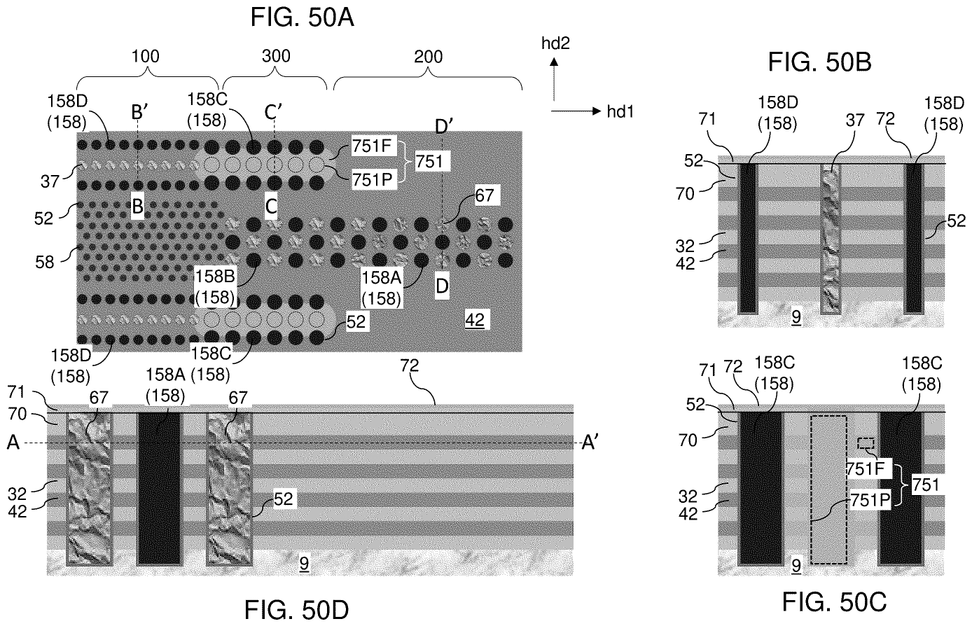

Referring to FIG. 50A-50D, a dielectric fill material, such as undoped silicate glass or a doped silicate glass, may be conformally deposited in the connection-region isolation trenches 791 by a conformal deposition process. Each portion of the dielectric fill material that fills a respective connection-region isolation trench 791 constitutes a finned dielectric wall structure 751. A horizontally-extending portion of the dielectric fill material that is deposited over the cover dielectric layer 791 constitutes a planar dielectric material layer 72.

In one embodiment, each of the finned dielectric wall structures 751 comprises a respective set of dielectric pillar portions 751P that fill volumes of connection-region isolation openings 29 and a respective vertical stack of dielectric fin portions 751F formed at levels of the sacrificial material layers 42 and adjoined to each dielectric pillar portion 751P within the respective set of dielectric pillar portions 751P. Each of the finned dielectric wall structures 751 may laterally extend along the first horizontal direction hd1. The finned dielectric wall structures 751 may be laterally spaced apart along the second horizontal direction hd2. Each of the finned dielectric wall structures 751 may comprise a respective set of dielectric pillar portions 751P arranged along the first horizontal direction hd1 and a respective vertical stack of dielectric fin portions 751F located at levels of the electrically conductive layers (146, 246) and adjoined to each dielectric pillar portion 751P within the respective set of dielectric pillar portions 751P.

In one embodiment, sidewall surface segments of the dielectric fin portions 751F of the finned dielectric wall structures 751 are laterally spaced from a respective most proximal sidewall surface segment of the dielectric pillar portions 751P of the finned dielectric wall structures 751 by the first uniform lateral offset distance, which is the etch distance of the first selective isotropic etch process that forms the laterally-extending voids 29F of the connection-region isolation trenches 791.

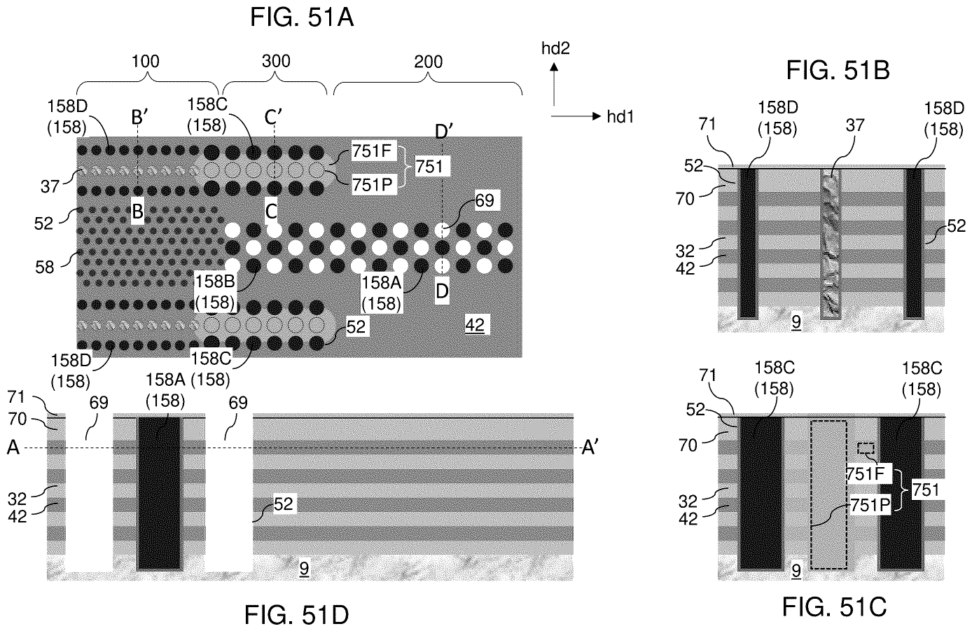

Referring to FIG. 51A-51D, the planar dielectric material layer (which functions as a second cover dielectric material layer) 72 may be removed, for example, by performing a recess etch process. A photoresist layer (not shown) may be applied over the top surface of the cover dielectric layer 71, and can be lithographically patterned to form openings over the areas of the sacrificial discrete access opening fill structures 67. An anisotropic etch process may be performed to transfer the pattern of the openings in the photoresist layer through the cover dielectric layer 71. A selective sacrificial material removal process may be performed to remove the sacrificial discrete access opening fill structures 67 selectively to the blocking dielectric layer 52 (if the blocking dielectric layer 52 is present) or selectively to the materials of the alternating stack (32, 42) and the substrate (if the blocking dielectric layer 52 is not present at this processing step). For example, if the sacrificial discrete access opening fill structures 67 comprise amorphous carbon, an ashing process may be performed to remove the sacrificial discrete access opening fill structures 67. Cavities are formed within the volumes of the discrete access opening 69 that are not occupied by portions of the blocking dielectric layer 52. If blocking dielectric layers 52 are present in peripheral regions of the discrete access opening 69, a timed isotropic etch process (such as a wet etch process) may be performed to remove the blocking dielectric layers 52 from the peripheral regions of the discrete access opening 69. Generally, sidewall surface segments of the sacrificial material layers 42 are exposed around the discrete access openings 69.

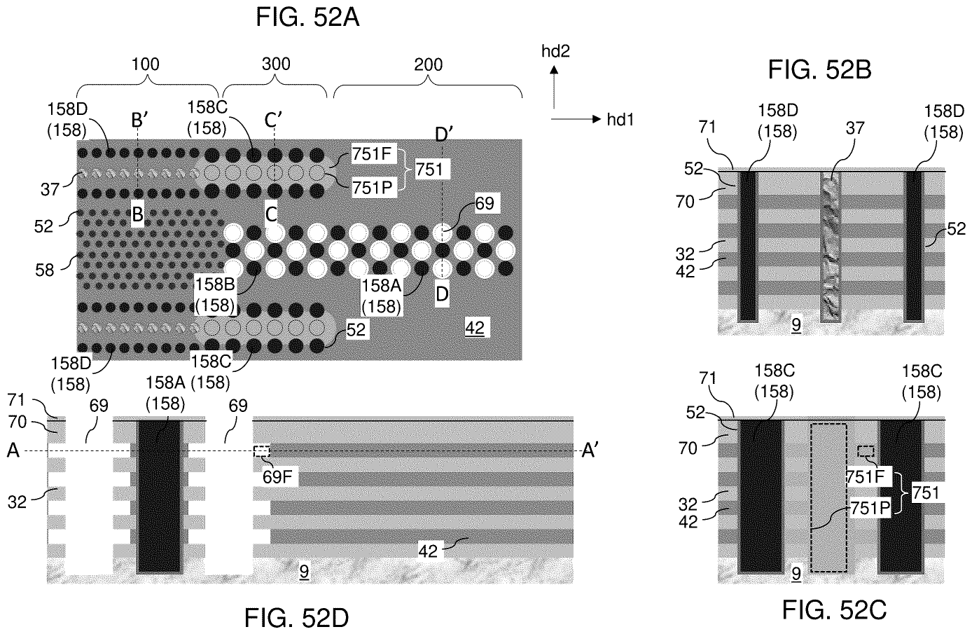

Referring to FIG. 52A-52D, a second selective isotropic etch process can be performed to isotropically etch portions of the sacrificial material layers 42 that are proximal to the discrete access openings 69. For example, if the sacrificial material layers 42 comprise silicon nitride, the second selective isotropic etch process may comprise a wet etch process employing hot phosphoric acid. Annular recesses 69F are formed around the discrete access openings 69 in the volumes form which proximal portions of the sacrificial material layers 42 are removed. Generally, the annular recesses 69F are formed by isotropically recessing the sidewall surface segments of the sacrificial material layers 42 around the discrete access openings 69.

In one embodiment, the duration of the second selective isotropic etch process may be selected such that the first dummy memory opening fill structures 158A and the second dummy memory opening fill structures 158B are not physically exposed to the annular recesses 69F. Alternatively, the duration of the second selective isotropic etch process may be selected such that the first dummy memory opening fill structures 158A and the second dummy memory opening fill structures 158B are physically exposed to the annular recesses 69F provided that the sagging of unsupported portions of the insulating layers 32 stays within design tolerance. The sidewalls of the annular recesses 69F at the levels of the sacrificial material layers 42 are laterally offset from the sidewalls of the discrete access openings 69 at the levels of the insulating layers 32 by a second uniform lateral offset distance, which is the etch distance of the second selective isotropic etch process for the material of the sacrificial material layers 42. The second uniform lateral offset distance may be in a range from 30 nm to 250 nm, although lesser or greater dimensions may also be employed.

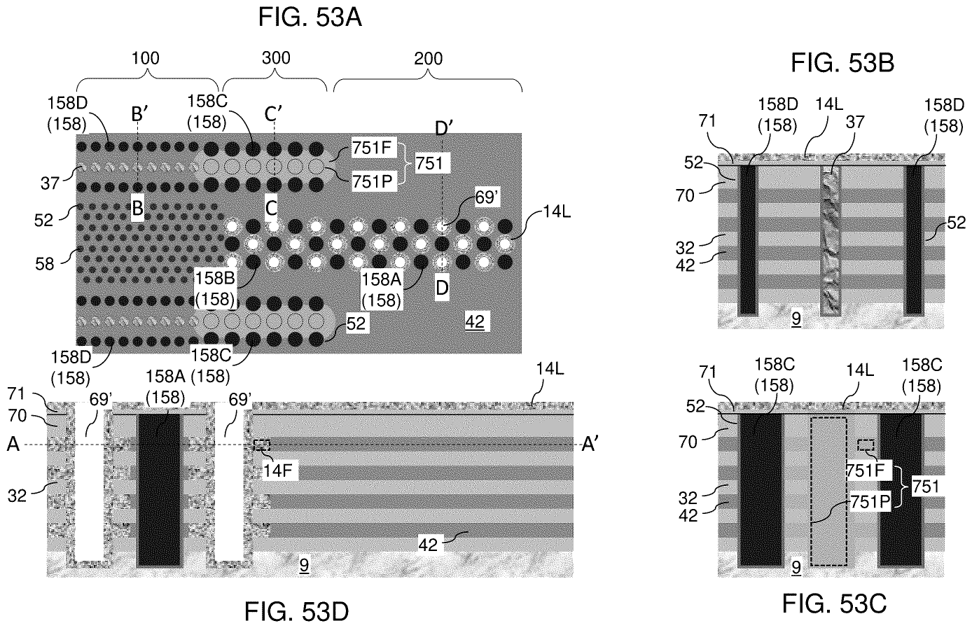

Referring to FIG. 53A-53D, a first etch-stop material layer 14L may be conformally deposited in the annular recesses 69F, in peripheral regions of the discrete access openings 69, and over the cover dielectric layer 71. The first etch-stop material layer 14L comprises a material that is resistant to the at least one etch chemistry to be subsequently employed to etch the materials of the insulating layers 32 and the sacrificial material layers 42. For example, the first etch-stop material layer 14L may comprise a semiconductor material such as amorphous silicon or polysilicon, and/or a metallic material such as Mo, W, WN, etc. The material of the first etch-stop material layer 14L may be selected among materials that are resistant to the etch chemistries to be subsequently employed to isotropically etch the sacrificial material layers 42. The thickness of the first etch-stop material layer 14L is greater than one half of the thickness of each sacrificial material layer 42, such that etch-stop fin portions 14F of the first etch-stop material layer 14L fill the annular recesses 69F. The thickness of the first etch-stop material layer 14L may be in a range from 20 nm to 100 nm, although lesser or greater thicknesses may also be employed. Discrete access cavities 69′ remain within the discrete access openings 69.

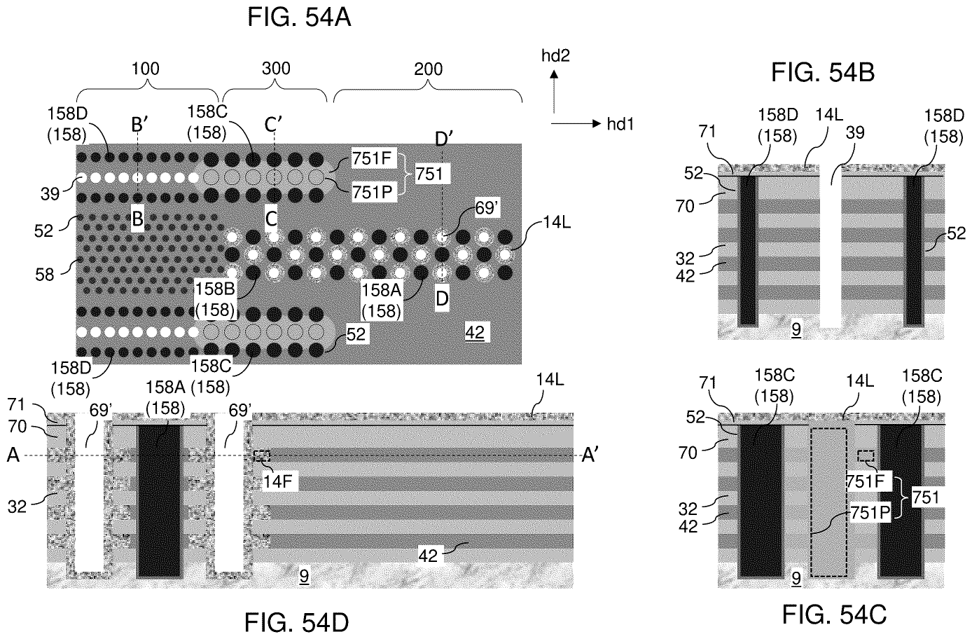

Referring to FIG. 54A-54D, a photoresist layer (not shown) may be applied over the first etch-stop material layer 14L, and can be lithographically patterned to form openings over the areas of the sacrificial memory-region isolation opening fill structures 37. An anisotropic etch process may be performed to transfer the pattern of the openings in the photoresist layer through the first etch-stop material layer 14L and the cover dielectric layer 71. A selective sacrificial material removal process may be performed to remove the sacrificial memory-region isolation opening fill structures 37 selectively to the blocking dielectric layer 52 (if the blocking dielectric layer 52 is present) or selectively to the materials of the alternating stack (32, 42) and the substrate (if the blocking dielectric layer 52 is not present at this processing step). For example, if the sacrificial memory-region isolation opening fill structures 37 comprise amorphous carbon, an ashing process may be performed to remove the sacrificial memory-region isolation opening fill structures 37. Cavities are formed within the volumes of the memory-region isolation openings 39 that are not occupied by portions of the blocking dielectric layer 52. If blocking dielectric layers 52 are present in peripheral regions of the memory-region isolation openings 39, a timed isotropic etch process (such as a wet etch process) may be performed to remove the blocking dielectric layers 52 from the peripheral regions of the memory-region isolation openings 39. Generally, sidewall surface segments of the sacrificial material layers 42 are exposed around the memory-region isolation openings 39.

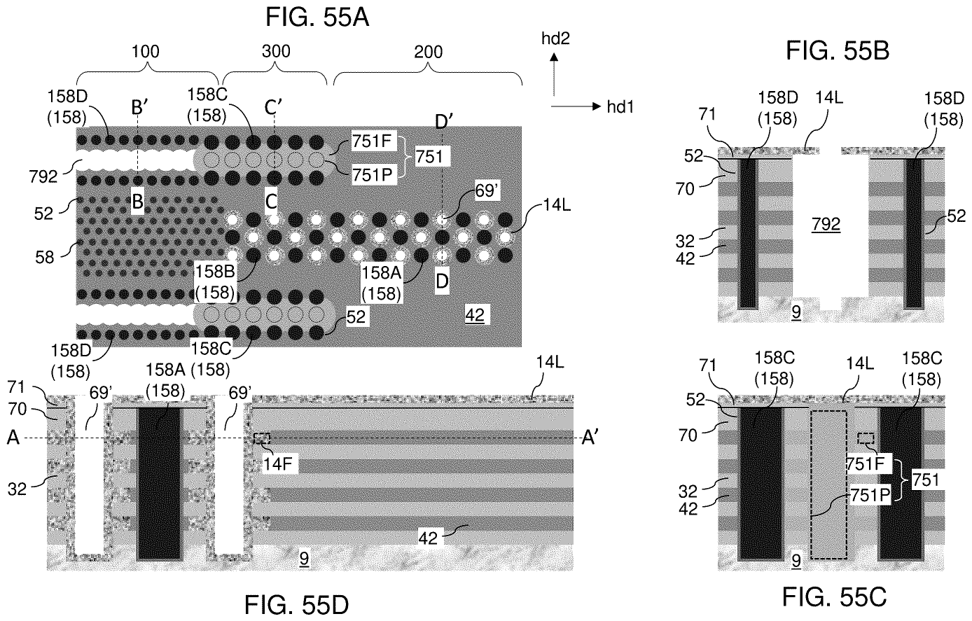

Referring to FIG. 55A-55D, at least one selective isotropic etch process may be performed to remove portions of the sacrificial material layers 42 and the insulating layers 32 that are proximal to the memory-region isolation openings 39. For example, a first selective isotropic etch process may be performed to isotropically etch portions of the sacrificial material layers 42 that are proximal to the memory-region isolation openings 39 such that each set of memory-region isolation openings 39 arranged in a respective row is interconnected with each other at the levels of the sacrificial material layers 42. Subsequently, a second selective isotropic etch process may be performed to isotropically etch portions of the insulating layers 32 that are proximal to the memory-region isolation openings 39 such that each set of memory-opening isolation openings 39 arranged in a respective row is interconnected with each other at the levels of the insulating layers 32. Each contiguous void that includes volumes of a respective row of memory-region isolation openings 39, volumes from which portions of the sacrificial material layers 42 are removed, and volumes from which portions of the insulating layers 32 are removed constitutes an array-region isolation trench 792.

Each array-region isolation trench 792 vertically extends through the alternating stack (32, 42) in the memory array region 100. Each array-region isolation trench 792 comprises a respective pair of lengthwise sidewalls that generally extend along the first horizontal direction hd1 and having lateral undulations along the second horizontal direction hd2. In one embodiment, each lengthwise sidewall of the array-region isolation trenches 792 may comprise laterally concave and vertically straight surface segments that are adjoined to each other along vertically-extending edges. As used herein, a laterally concave surface refers to a surface having a concave profile in a horizontal cross-sectional view. As used herein, a vertically straight surface refers to a surface having a straight profile in a vertical cross-sectional view. Each array-region isolation trench 792 may laterally extend through the entirety of the memory array region 100 along the first horizontal direction hd1. In one embodiment, the maximum lateral extent of each array-region isolation trench 792 along the second horizontal direction hd2 may be in a range from 150% to 400% of the lateral dimension of a memory-opening isolation opening 39 as formed at the processing steps described with reference to FIG. 44A-44D.

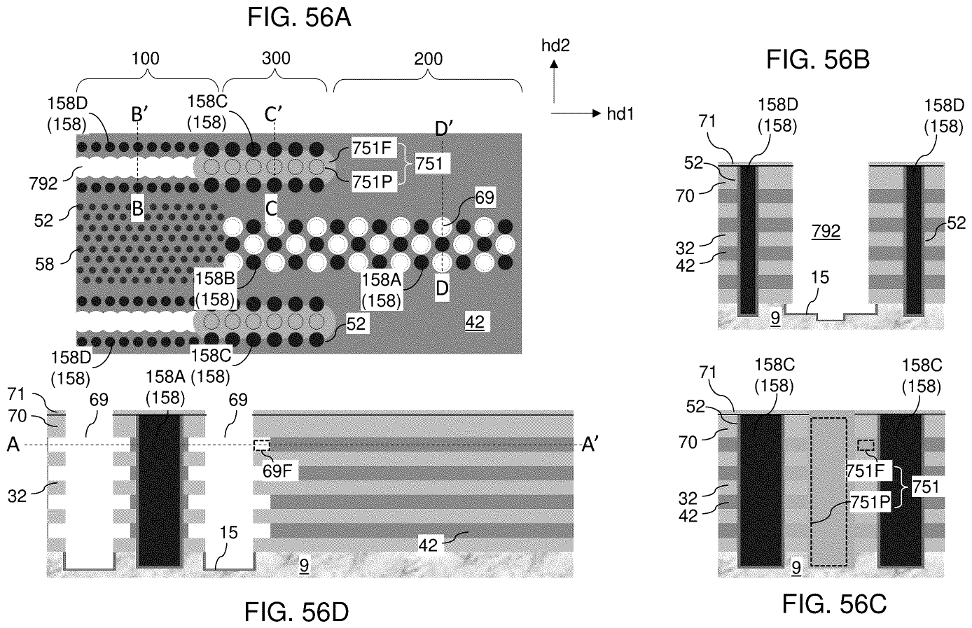

Referring to FIGS. 56A-56D, the first etch-stop material layer 14L may be removed selective to the materials of the insulating layers 32 and the sacrificial material layers 42 by performing a selective isotropic etch process. For example, if the first etch-stop material layer 14L comprises amorphous silicon or polysilicon, a timed wet etch process employing trimethyl-2 hydroxyethyl ammonium hydroxide (TMY), potassium hydroxide or tetramethylammonium hydroxide may be performed to isotropically etch the first etch-stop material layer 14L selectively to the materials of the insulating layers 32 and the sacrificial material layers 42. The etch-stop fin portions 14F of the first etch-stop material layer 14L are removed from inside the annular recesses 69F and the first etch-stop material layer 14L is removed from peripheral regions of the discrete access openings 69. Portions of the semiconductor material layer 9 that underlie the array-region isolation trenches 792 may be collaterally etched during the selective isotropic etch process.

A surface conversion process, such as a surface oxidation process and/or a surface nitridation process, may be performed to convert physically exposed surface portions of the semiconductor material layer 9 that are located underneath the array-region isolation trenches 792 and the discrete access openings 69 by exposing them to an oxygen or nitrogen containing ambient or plasma at a suitable temperature. Dielectric isolation liners 15 are formed on the surface portions of the semiconductor material layer 9 that are converted into a dielectric semiconductor compound material, which may comprise a semiconductor oxide material, a semiconductor nitride material, or a semiconductor oxynitride material. In one embodiment, the dielectric isolation liners 15 may comprise silicon oxide. The thickness of the dielectric isolation liners 15 may be in a range from 3 nm to 10 nm, although lesser or greater thicknesses may also be employed.

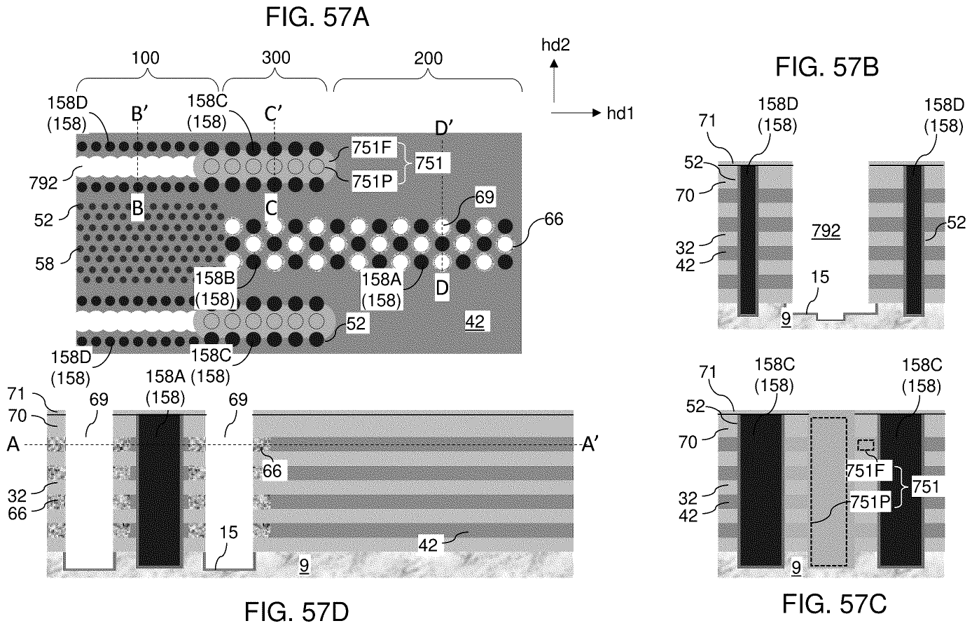

Referring to FIG. 57A-57D, a second etch-stop material layer (not shown) may be conformally deposited in the annular recesses 69F, in peripheral regions of the discrete access openings 69, and in peripheral regions of the array-region isolation trenches 792. The second etch-stop material layer comprises a material that can effectively function as an etch-stop material during subsequent isotropic etching of the sacrificial material layers 42 and the insulating layers 32. For example, the second etch-stop material layer may comprise a semiconductor material such as amorphous silicon or polysilicon, and/or a metallic material such as Mo, W, WN, etc. The thickness of the second etch-stop material layer is greater than one half of the thickness of each sacrificial material layer 42.

An etch back process may be performed to remove portions of the second etch-stop material layer that are located outside the volumes of the annular recesses 69F. The etch back process may comprise an anisotropic etch process. Each remaining portion of the second etch-stop material layer that remains in a respective annular recess 69F constitutes an etch-stop ring 66. Generally, the etch-stop rings 66 can be formed in the annular recesses 69F by filling the annular recesses 69F with an etch stop material. The etch-stop rings 66 prevent etching of the sacrificial material layers 42 around the discrete access openings 69 during a subsequent selective isotropic etch process that forms laterally-extending cavities. In one embodiment, the etch-stop rings 66 comprise a semiconductor material, such as amorphous silicon or polysilicon.

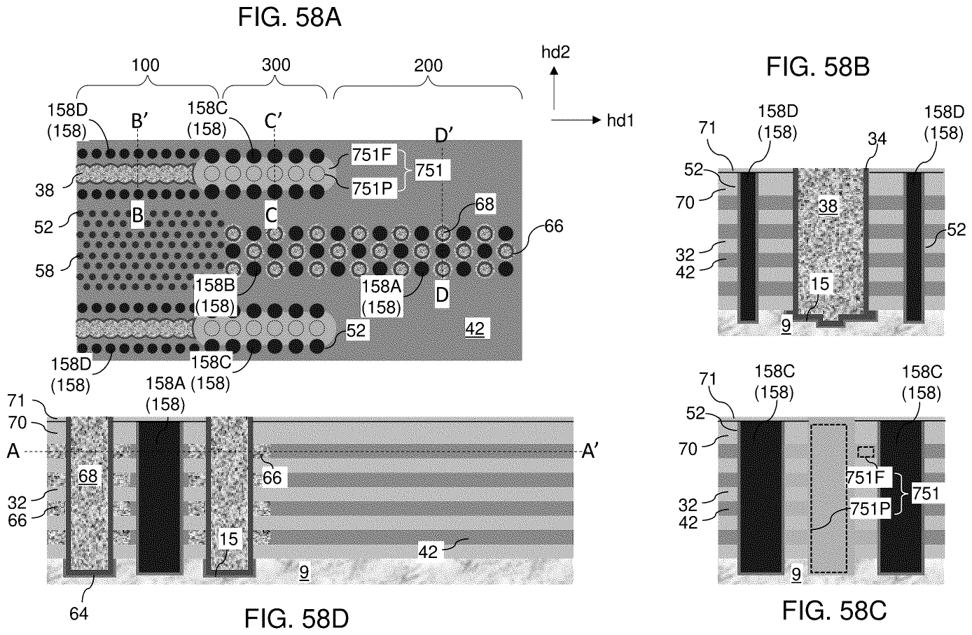

Referring to FIG. 58A-58D, an interim liner material layer and an interim fill material layer are sequentially deposited in the discrete access openings 69 and the array-region isolation trenches 792. The interim fill material layer comprises a material that can function as an etch-stop material during subsequent removal of portions of the sacrificial material layers 42. The interim liner material layer comprises a material that is different from the material of the interim fill material layer. The interim liner material layer may comprise silicon nitride, and the interim fill material layer may comprise a semiconductor material, such as amorphous silicon or polysilicon.

A planarization process, such as a chemical mechanical polishing process, may be performed to remove portions of the interim liner material layer and the interim fill material layer that overlie the horizontal plane including the top surface of the cover dielectric layer 71. Each remaining portion of the interim liner material liner that remains in a peripheral region of a respective discrete access opening 69 constitutes an interim access opening liner 64. Each remaining portion of the interim fill material layer that remains in a center region of a respective discrete access opening 69 constitutes an interim access opening fill structure 68. Each remaining portion of the interim liner material liner that remains in a peripheral region of a respective array-region isolation trench 792 constitutes an interim isolation trench liner 34. Each remaining portion of the interim fill material layer that remains in a center region of a respective array-region isolation trench 792 constitutes an interim isolation trench fill structure 38. Generally, at least one interim fill material may be deposited in the array-region isolation trenches 792 and in the discrete access openings 69 to form various interim fill structures {(34, 38), (64, 68)} in the array-region isolation trenches 792 and in the discrete access openings 69.

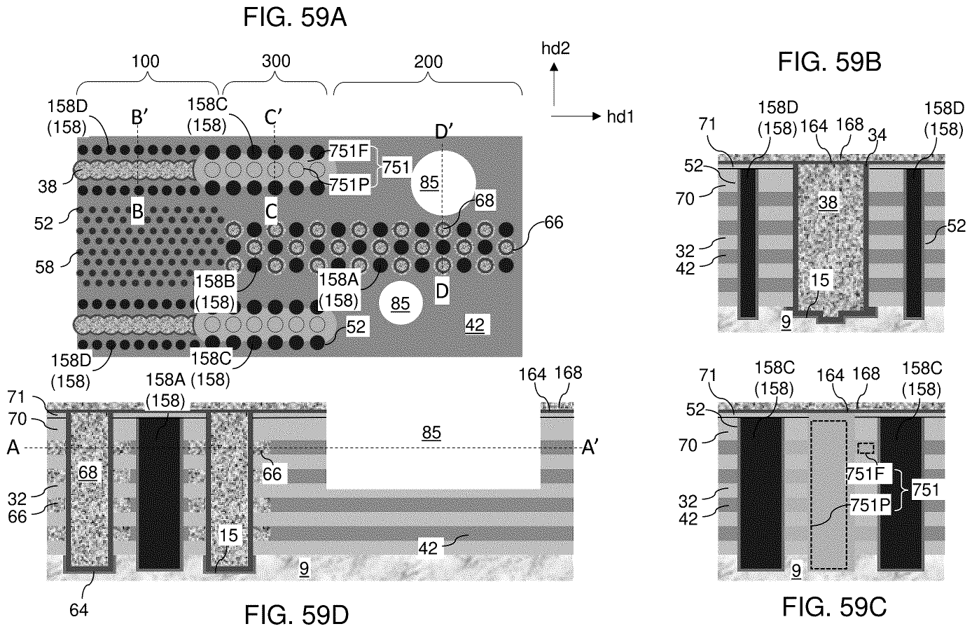

Referring to FIG. 59A-59D, contact via openings 85 having different depths may be formed in the contact region 200. Generally, the processing steps described with reference to FIG. 9A-9C may be performed to form various contact via openings 85 having different depth. Alternative patterning methods may also be used.

In one embodiment, a hard mask may be deposited over the cover dielectric layer 71. The hard mask may comprise a sacrificial liner 164 and an etch mask layer 168 that are sequentially deposited over the cover dielectric layer 71. In one embodiment, the sacrificial liner 164 may comprise silicon nitride, and may have a thickness in a range from 10 nm to 40 nm, although lesser or greater thicknesses may also be employed. The etch mask layer 168 may comprise a semiconductor material, such as amorphous silicon or polysilicon, and may have a thickness in a range from 30 nm to 300 nm, although lesser or greater thicknesses may also be employed. A photoresist layer (not shown) may be applied over the etch mask layer 168, and may be lithographically patterned to form openings in all areas in which the contact via openings 85 are to be subsequently formed. An anisotropic etch process may be performed to transfer the pattern of the openings in the photoresist layer through the etch mask layer 168 and the sacrificial liner 164. The etch mask layer 168 with openings therethrough functions as an hardmask for a set of etch processes to be subsequently performed.

A series of via-extension anisotropic etch processes may be performed employing a set of patterned block-level photoresist layers. Each via-extension anisotropic etch process may anisotropically etch a different number of pairs of an insulating layer 32 and a sacrificial material layer 42 underneath a respective subset of openings in the etch mask layer 168 that is not covered by a respective patterned block-level photoresist layer. The unmasked area of each patterned block-level photoresist layer may be selected such that each sacrificial material layer 42 comprises a region that is vertically spaced from a respective overlying contact via opening 85 by no more than a single insulating layer 32 (or for the case of the topmost sacrificial material layer 42, by no more than a portion of an insulating cap layer 70). Generally, the contact via openings 85 are formed such that each of the contact via openings 85 vertically extends through a respective subset of layers within the alternating stack (32, 42).

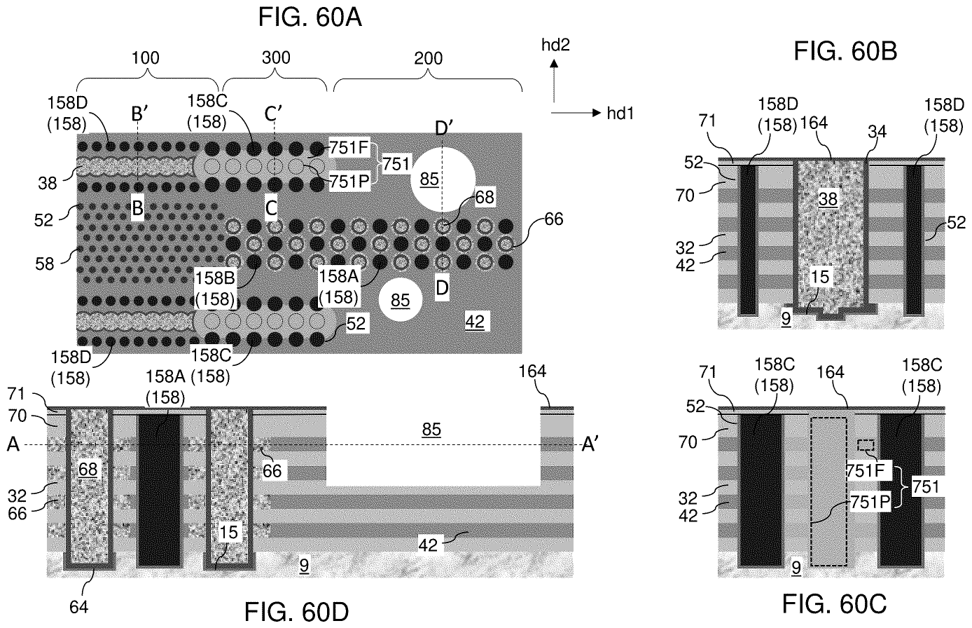

Referring to FIG. 60A-60D, the etch mask layer 168 may be removed selectively to the materials of the insulating layers 32, the sacrificial material layer 42, and the sacrificial liner 164. For example, if the etch mask layer 168 comprises a semiconductor material, a wet etch process employing TMY, potassium hydroxide or tetramethylammonium hydroxide may be performed to remove the etch mask layer 168.

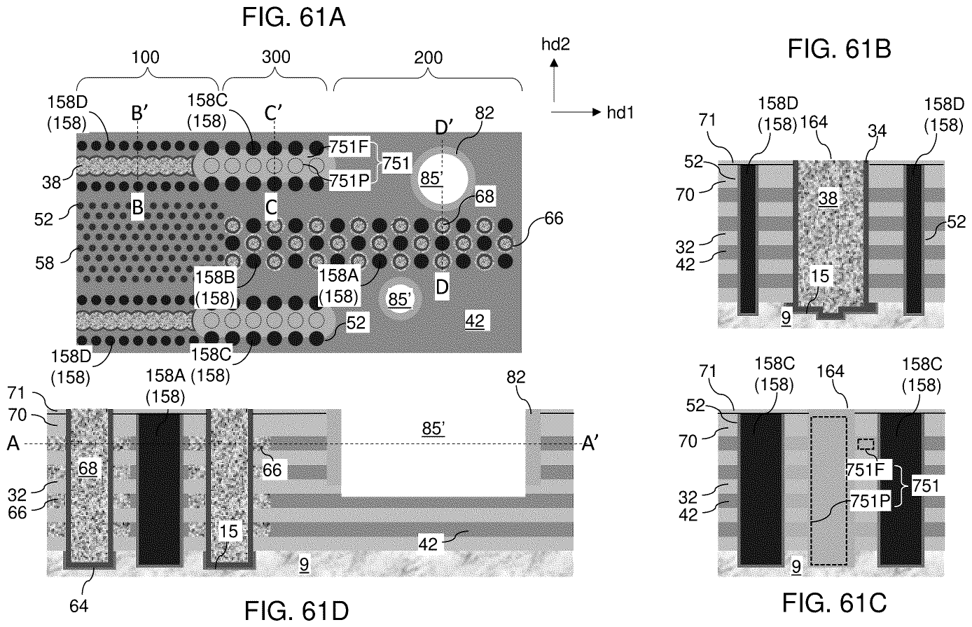

Referring to FIG. 61A-61D, the processing steps described with reference to FIGS. 10A and 10B may be performed to form tubular insulating spacers 82 in peripheral regions of the contact via openings 85. The tubular insulating spacers 82 comprise an etch-stop dielectric material having a higher etch resistance than the material of the sacrificial material layers 42 during subsequent selective isotropic etch processes that etch the material of the sacrificial material layers 42. For example, the sacrificial material layers 42 may comprise silicon nitride, and the tubular insulating spacers 82 may comprise silicon oxide. An insulating material layer may be conformally deposited and anisotropically etched to form the tubular insulating spacers 82. Remaining unfilled volumes of the contact via openings 85 comprise contact via cavities 85′. The tubular insulating spacers 82 may have a lateral thickness (as measured between an inner sidewall and an outer sidewall) in a range from 30 nm to 100 nm, although lesser or greater thicknesses may also be employed.

Generally, the tubular insulating spacers 82 may be formed such that each of the tubular insulating spacers 82 laterally surrounds a respective one of the contact via cavities 85′. In one embodiment, the tubular insulating spacers 82 comprises a dielectric material, such as undoped silicate glass or a doped silicate glass. In one embodiment, the anisotropic etch process that forms the tubular insulating spacers 82 may be extended to etch unmasked portions of insulating layers 32 that immediately underlie the contact via openings 85, and top surface segments of underlying sacrificial material layers 42 may be physically exposed underneath the contact via cavities 85′. In this case, the anisotropic etch process may vertically extend the contact via cavities 85′ after formation of the tubular insulating spacers 82 so that a top surface segment of a respective sacrificial material layer 42 is physically exposed underneath each of the contact via cavities 85′. The sacrificial liner 164 may be collaterally removed during the anisotropic etch process, or may be removed in a subsequent processing step that isotropically etches unmasked portions of the sacrificial material layers 42 underneath the contact via cavities 85′.

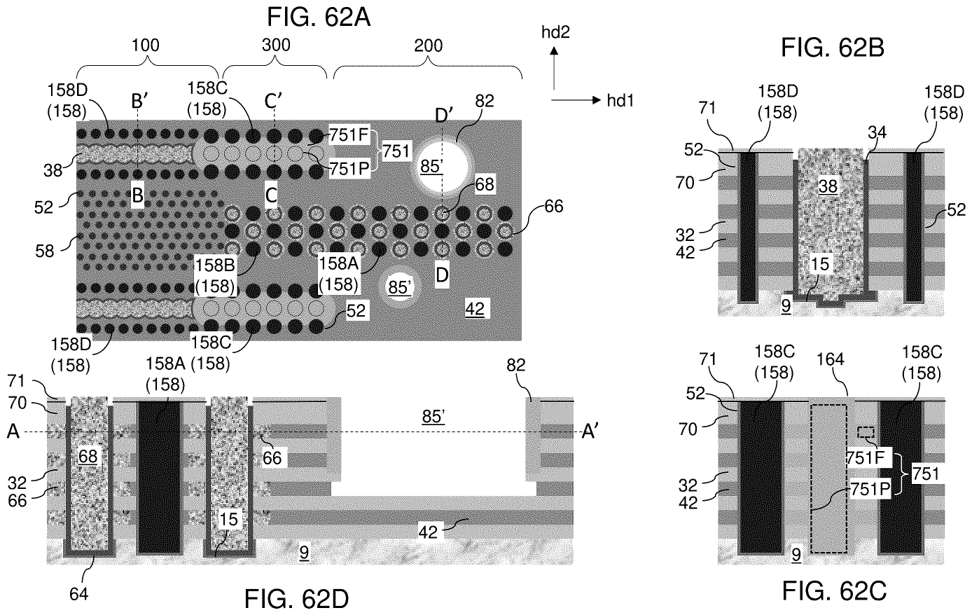

Referring to FIG. 62A-62D, a selective isotropic etch process can be performed to etch portions of the sacrificial material layers 42 that are exposed underneath the contact via cavities 85′. Each sacrificial material layer 42 may have a respective physically exposed cylindrical sidewall that is exposed a bottom portion of a respective one of the contact via cavities 85′ and underlies, or is recessed outward relative to, a respective overlying tubular insulating spacer 82. In one embodiment, portions of the sacrificial material layers 42 that underlie the contact via cavities 85′ may be isotropically etched such that via-bottom lateral annular recesses 85F (e.g., fin-shaped cavity extension) are formed underneath the tubular insulating spacers 82. Top portions of the interim access opening liners 64 and the interim isolation trench liners 34 may be collaterally etched during the selective isotropic etch process. The lateral etch distance of the selective isotropic etch process for the material of the sacrificial material layers 42 may be in a range from 15 nm to 60 nm, such as from 20 nm to 45 nm, although lesser or greater lateral etch distances may also be employed.

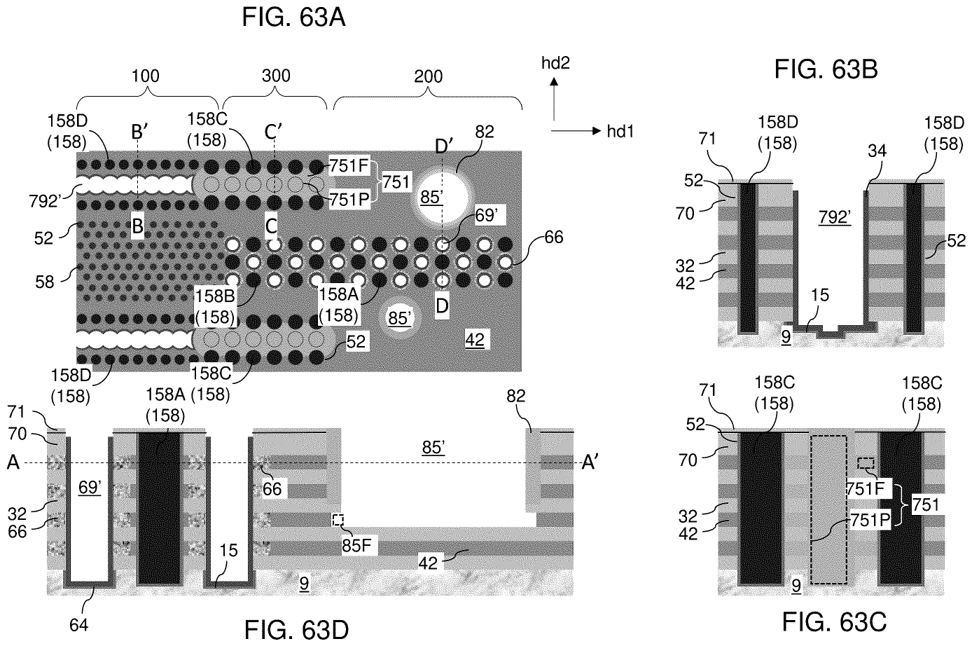

Referring to FIG. 63A-63D, the interim access opening fill structures 68 and the interim isolation trench fill structures 38 may be removed by performing a selective etch process. The selective etch process etches the materials of the interim access opening fill structures 68 and the interim isolation trench fill structures 38 selectively to the materials of the interim access opening liners 64 and the interim isolation trench liners 34 and selectively to the materials of the insulating layers 32, the sacrificial material layers 42, and the tubular insulating spacers 82. For example, if the interim access opening fill structures 68 and the interim isolation trench fill structures 38 comprise a semiconductor material, such as amorphous silicon or polysilicon, the selective etch process may comprise a wet etch process employing TMY, potassium hydroxide or tetramethylammonium hydroxide. Array-region isolation cavities 792′ are formed in the voids within the array-region isolation trenches 792. Discrete access cavities 69′ are reformed in the voids within the discrete access openings 69.

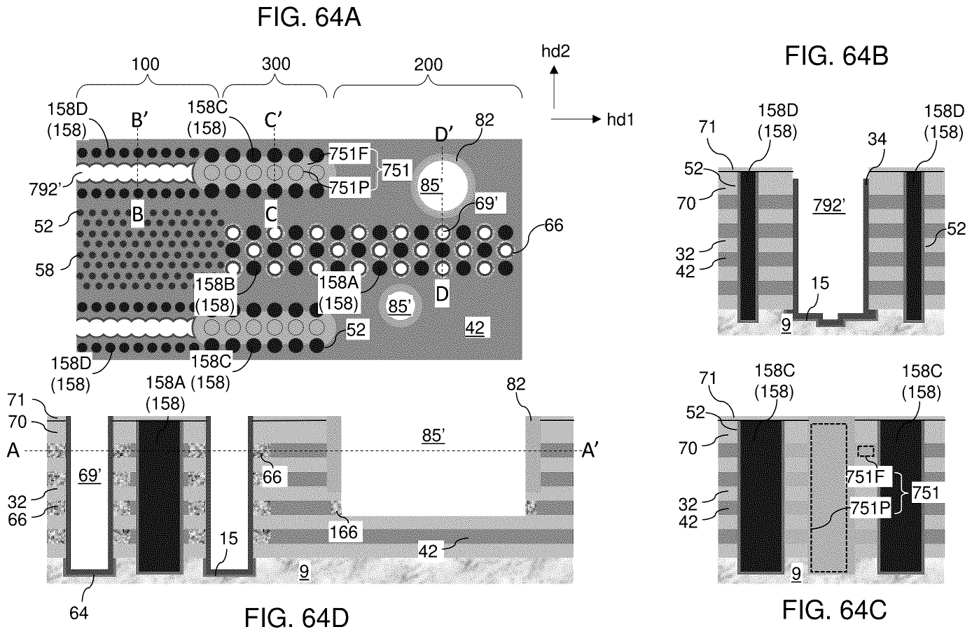

Referring to FIG. 64A-64D, a third etch-stop material layer (not shown) may be conformally deposited over the third exemplary structure. The third etch-stop material layer is deposited in the via-bottom lateral annular recesses (e.g., fin-shaped cavity extension) 85F around the bottom portions of the contact via cavities 85′. The third etch-stop material layer comprises a material that can effectively function as an etch-stop material during subsequent isotropic etching of the sacrificial material layers 42 and the insulating layers 32. For example, the third etch-stop material layer may comprise a semiconductor material such as amorphous silicon or polysilicon, and/or a metallic material such as Mo, W, WN, etc. The thickness of the third etch-stop material layer is greater than one half of the thickness of each sacrificial material layer 42.

An etch back process may be performed to remove portions of the third etch-stop material layer that are located outside the volumes of the via-bottom lateral annular recesses 85F. The etch back process may comprise an anisotropic etch process. Each remaining portion of the third etch-stop material layer that remains in a respective via-bottom lateral annular recess 85F constitutes a via-bottom annular etch-stop structure 166. Generally, the via-bottom annular etch-stop structures 166 can be formed in the via-bottom lateral annular recesses 85F by filling the via-bottom lateral annular recesses with an etch stop material. The via-bottom annular etch-stop structures 166 prevent etching of the sacrificial material layers 42 around the contact via cavities 85′ during a subsequent selective isotropic etch process that forms laterally-extending cavities. In one embodiment, the via-bottom annular etch-stop structures 166 comprise a semiconductor material, such as amorphous silicon or polysilicon. The via-bottom annular etch-stop structures 166 may comprise the same material or may comprise a different material from the etch-stop rings 66.

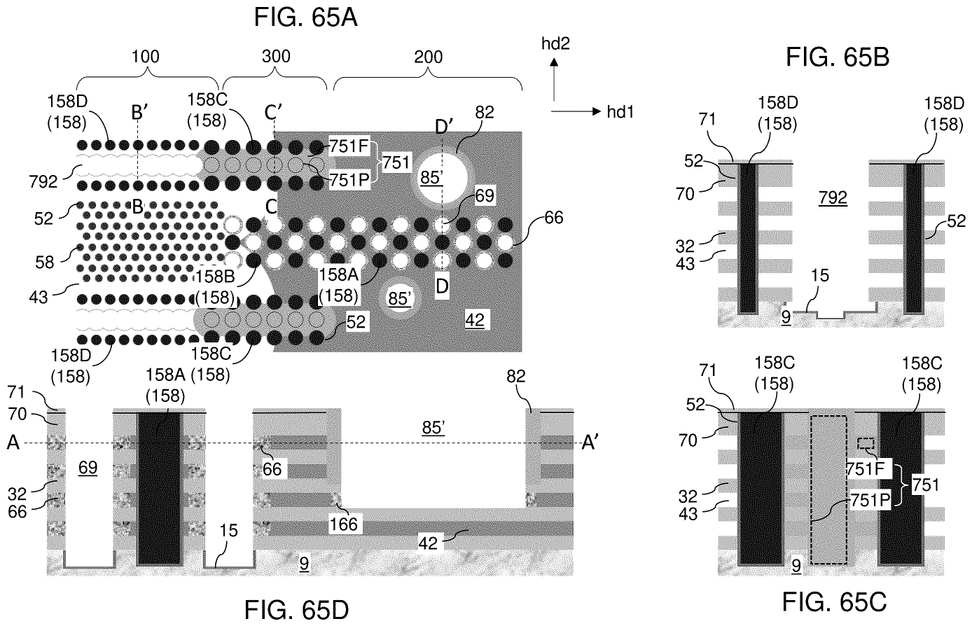

Referring to FIG. 65A-65D, a first selective isotropic etch process can be performed to etch the interim access opening liners 64 and the interim isolation trench liners 34 and to etch portions of the sacrificial material layers 42 that are proximal to the array-region isolation trenches 792 to form laterally-extending cavities 43. In one embodiment, the etch chemistry of the first selective isotropic etch process may be the same as the first selective isotropic etch process described with reference to FIG. 17A-17D. In one embodiment, the interim access opening liners 64 and the interim isolation trench liners 34 may comprise the same material as the sacrificial material layers 42.

The first selective isotropic etch process isotropically recesses first portions of the sacrificial material layers 42 around the array-region isolation trenches 792 to form the laterally-extending cavities 43. According to an aspect of the present disclosure, the etch-stop rings 66 and the via-bottom annular etch-stop structures 166 function as etch-stop structures during the first selective isotropic etch process. Generally, the laterally-extending cavities 43 can be formed by performing a first selective isotropic etch process that isotropically recesses first portions of the sacrificial material layers 42 around the array-region isolation trenches 792 while the etch-stop rings 66 are present within the annular recesses 69F and the via-bottom annular etch-stop structures 166 are present in the via-bottom annular lateral recesses 85F. Thus, portions of the sacrificial material layers 42 that are proximal to the contact via cavities 85′ or proximal to the discrete access openings 69 but are distal from the array-region isolation trenches 792 are not etched during the first selective isotropic etch process.

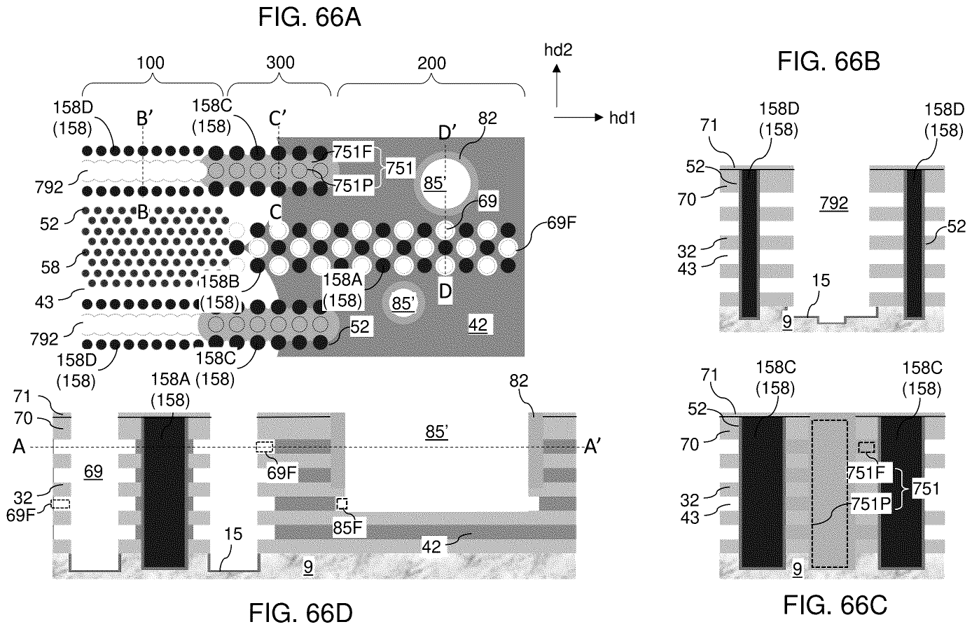

Referring to FIG. 66A-66D, the etch-stop rings 66 and the via-bottom annular etch-stop structures 166 may be removed selectively to the materials of the insulating layers 32 and the sacrificial material layers 42 by performing a selective etch process. For example, if the etch-stop rings 66 and the via-bottom annular etch-stop structures 166 comprise a semiconductor material such as amorphous silicon or polysilicon, a wet etch process employing potassium hydroxide or tetramethylammonium hydroxide may be performed to remove the etch-stop rings 66 and the via-bottom annular etch-stop structures 166.

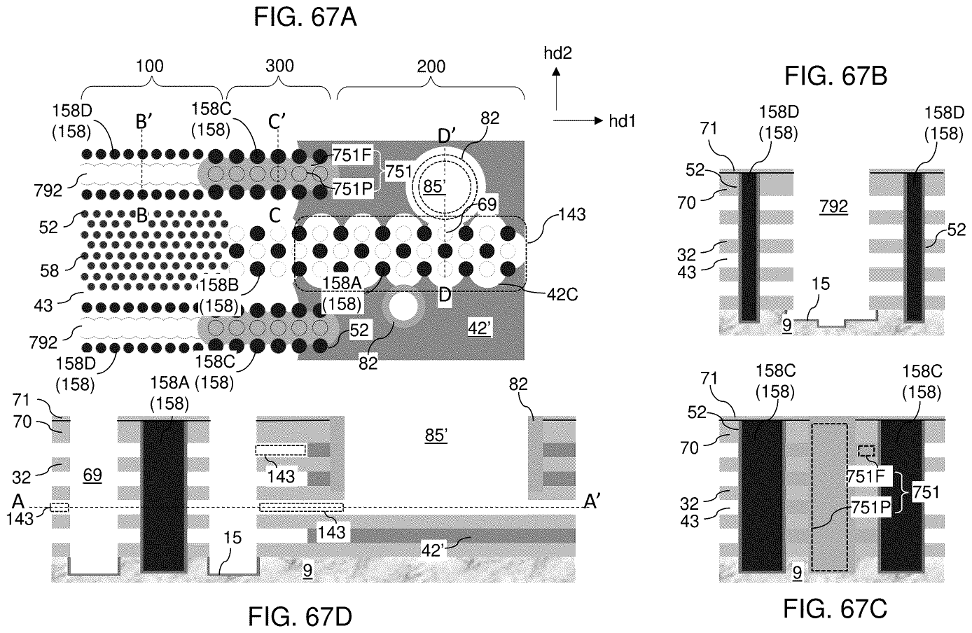

Referring to FIG. 67A-67D, a second selective isotropic etch process can be performed to etch portions of the sacrificial material layers 42 that are proximal to the laterally-extending cavities 43, the array-region isolation trenches 792, and the discrete access openings 69. In one embodiment, the etch chemistry of the second selective isotropic etch process may be the same as the second selective isotropic etch process described with reference to FIG. 19A 19E. The second selective isotropic etch process isotropically recesses second portions of the sacrificial material layers 42 around the laterally-extending cavities 43, the annular recesses 69F around the discrete access openings 69, and the via-bottom annular lateral recesses 85F at the bottom portions of the contact via cavities 85′.

The second selective isotropic etch process forms the strip-shaped cavities 143 in the contact region 200 and in a first segment of the connection region 300. Each of the strip-shaped cavities 143 is adjoined to a respective one of the laterally-extending cavities 43. The strip-shaped cavities 143 are formed in proximity to the contact via cavities 85′. The second selective isotropic etch process isotropically recesses portions of the sacrificial material layers 42 around bottom regions of the contact via cavities 85′ such that each of the contact via cavities 85′ is directly connected to a respective one of the respective strip-shaped cavities 143.

The second selective isotropic etch process forms respective strip-shaped cavities 143 around the discrete access openings 69 such that the discrete access openings 69 are laterally interconnected to each other by the respective strip-shaped cavities 143. Each of the respective strip-shaped cavities 143 is connected to a respective one of the laterally-extending cavities 43 after the second selective isotropic etch process. Generally, the second selective isotropic etch process isotropically etches portions of the sacrificial material layers 42 around the discrete isolation openings 69 to form strip-shaped cavities 143 each located between a respective vertically neighboring pair of the insulating layers 32 and each interconnecting a respective subset of the discrete access openings 69. The second selective isotropic etch process directly connects each of the contact via cavities 85′ to a respective one of the respective strip-shaped cavities 143.

Remaining portions of the sacrificial material layers 42 constitute vertical stack of dielectric material plates 42′. Each of the strip-shaped cavities 143 may be laterally bounded by laterally-undulating sidewalls of a pair of dielectric material plates 42′. Each laterally-undulating sidewall of a dielectric material plate 42′ may comprise a respective set of laterally-concave and vertically-straight surface segments 42C that are adjoined to each other at vertically-extending edges.

In one embodiment, each of the strip-shaped cavities 143 may laterally surround a respective subset of first dummy memory opening fill structures 158A and a respective subset of the second dummy memory opening fill structures 158B. In one embodiment, each strip-shaped cavity 143 may be formed between a first vertical stack of first dielectric material plates 42′ and a second vertical stack of second dielectric material plates 42′ that are laterally spaced apart along the second horizontal direction hd2.

In one embodiment, each laterally-extending cavity 43 may be formed between a first finned dielectric wall structure 751 and a second finned dielectric wall structure 751. In one embodiment, the first finned dielectric wall structure 751 is in direct contact with the first dielectric material plates 42′, and the second finned dielectric wall structure 751 is in direct contact with the second dielectric material plates 42′.

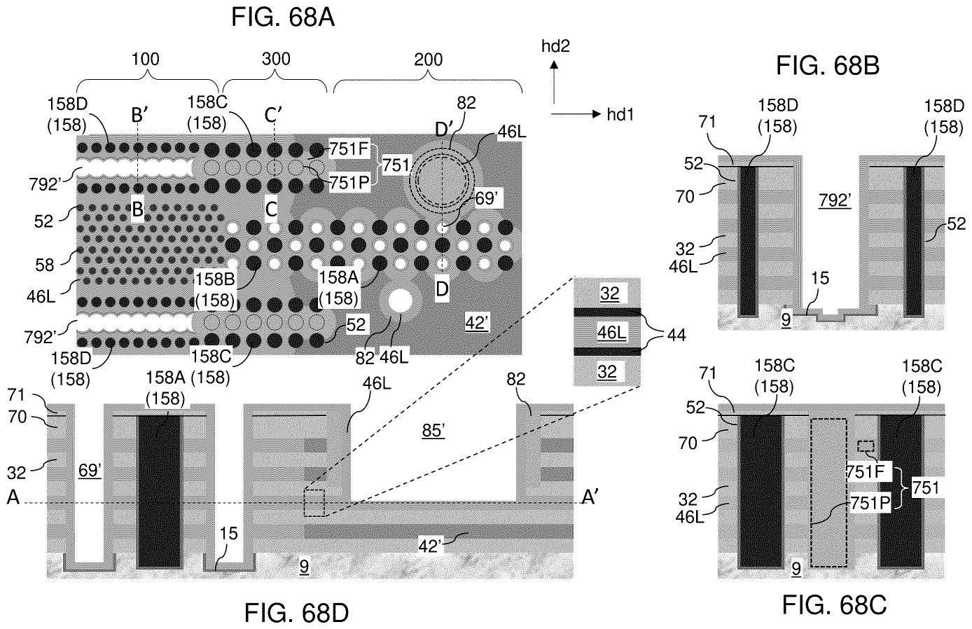

Referring to FIG. 68A-68D, an outer blocking dielectric layer 44 may be conformally deposited on the physically exposed surfaces of the third exemplary structure. The outer blocking dielectric layer 44 may have the same material composition and the thickness range as described with reference to FIG. 20A-20E.

A continuous conductive material layer 46L can be conformally deposited in the remaining volumed of the laterally-extending cavities 43 and the strip-shaped cavities 143, in peripheral regions of the contact via cavities 85′, the array-region isolation trenches 792, and the discrete access openings 69, and over the cover dielectric layer 71. At least one conductive material described with reference to FIG. 20A-20E may be conformally deposited in the voids that are formed by the first selective isotropic etch process and the second selective isotropic etch process, in the peripheral volumes of the contact via cavities 85′, the array-region isolation trenches 792, and the discrete access openings 69, and over the cover dielectric layer 71 to form the continuous conductive material layer 46L.

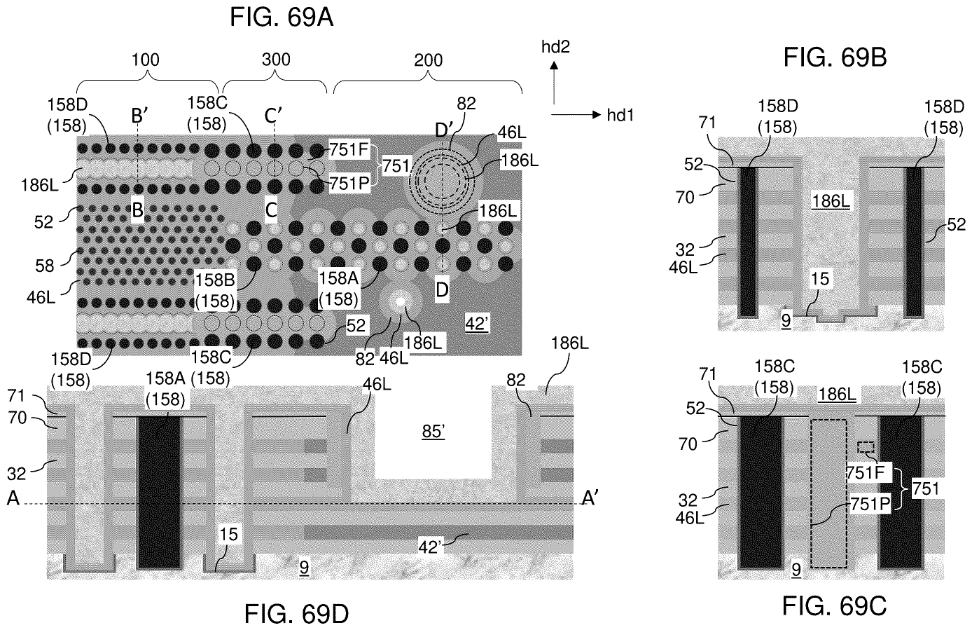

Referring to FIG. 69A-69D, a continuous semiconductor material layer 186L may be deposited over the continuous conductive material layer 46L. The continuous semiconductor material layer 186L may comprise a heavily doped semiconductor material. For example, the continuous semiconductor material layer 186L may comprise doped silicon including electrical dopants at an atomic concentration in a range from 5.0×10¹⁸/cm³ to 2.0×10²¹/cm³, although lesser or greater atomic concentrations may also be employed. The electrical dopants may comprise n-type electrical dopants or p-type electrical dopants. For example, the electrical dopants may comprise P, As, Sb, or B. In one embodiment, the electrical dopants may comprise phosphorus. The thickness of the continuous semiconductor material layer 186L may be selected such that the continuous semiconductor material layer 186L fills discrete isolation cavities 69′ (i.e., unfilled volumes of the discrete isolation openings 69) and the array-region isolation cavities 792′ (i.e., unfilled volumes of the array-region isolation trenches 792). According to an aspect of the present disclosure, a reduced diameter contact via cavity 85′ (i.e., an unfilled volume of a contact via opening 85) may be present within at least one or all of the contact via openings 85 after deposition of the continuous semiconductor material layer 186L. Thus, the continuous semiconductor material layer 186L does not completely fill the unfilled volume of a contact via opening 85.

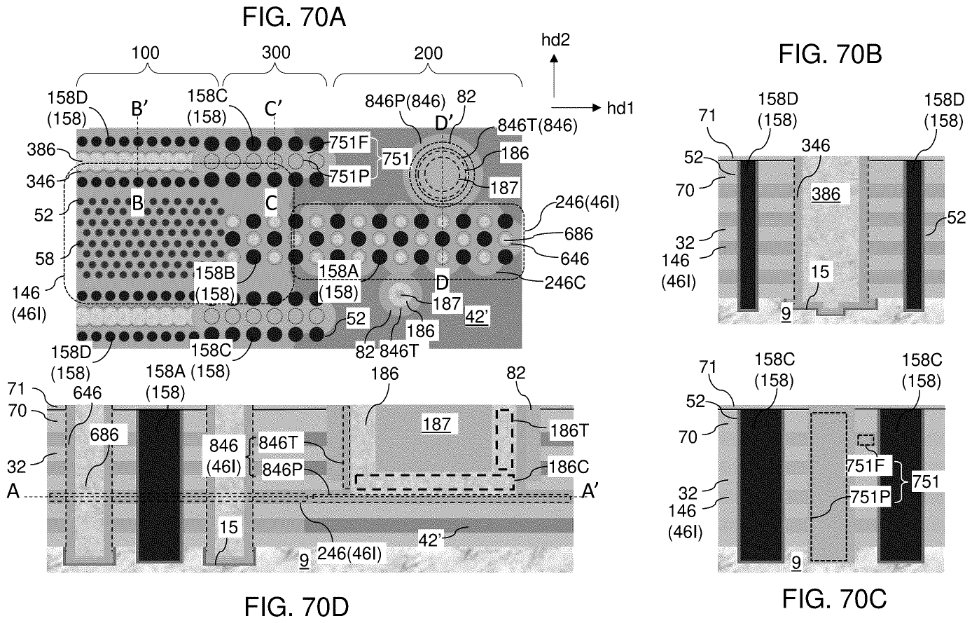

Referring to FIG. 70A-70D, a dielectric fill material layer may be deposited to fill the voids of the contact via cavities 85′. The dielectric fill material layer may comprise undoped silicate glass or a doped silicate glass. The dielectric fill material layer is deposited in the volumes of voids within the contact via cavities 85′ over the continuous semiconductor material layer 186L.

A planarization process, such as a chemical mechanical polishing process, may be performed to remove portions of the dielectric fill material layer, the continuous semiconductor material layer 186L, the continuous conductive material layer 46L, and the outer blocking dielectric layer 44 that overlie a horizontal plane including the top surface of the cover dielectric layer 71. The horizontal plane generally overlies the topmost insulating layer 32 of the insulating layers 32. Remaining portions of the dielectric fill material in the contact via openings 85 comprise dielectric via structures 187. Remaining portions of the at least one conductive material layer 46L that are located outside the volumes of the array-region isolation trenches 792 and outside the volumes of the discrete access openings 69 comprise integrated conductive line and via structures 46I. Remaining portions of the dielectric fill material in the contact via openings 85 comprise dielectric via structures 187.

Remaining portions of the continuous semiconductor material layer 186L in the contact via openings 85 comprise capped tubular semiconductor structures 186. As used herein, the term “capped tubular” includes hollow cylindrical structures in which the central opening is capped on the bottom (e.g., at the base) with a horizontal bottom cap portion. Thus, each of the capped tubular semiconductor structures 186 comprises a respective semiconductor tubular portion 186T contacting an inner sidewall of a respective one of the vertically-extending via portions 846 and an outer sidewall of the respective dielectric via structure 187, and further comprises a respective semiconductor bottom cap portion 186C adjoined to a bottom end (i.e., the base) of the respective semiconductor tubular portion 186T.

Each of the integrated conductive line and via structures 46I comprise remaining portions of the at least one conductive material layer 46L that are located outside the volumes of the array-region isolation trenches 792 and outside the volumes of the discrete access openings 69. Each of the integrated conductive line and via structures 46I includes a respective electrically conductive layer (146, 246) and a respective vertically-extending via portion 846. Each electrically conductive layer (146, 246) comprises a respective electrode layer (e.g., word line/control gate layer or select gate electrode layer) 146 and a respective lateral connection strip 246. The vertically-extending via portion 846 extends upward from the respective lateral connection strip 246 of the electrically conductive layer (146, 246) through a respective subset of the insulating layers 32. The electrode layer 146 is located in a memory array region 100 and in a first portion of a connection region 300, while the lateral connection strip 246 is located in a contact region 200 and in a second portion of the connection region 300. The electrically conductive layers (146, 246) of the integrated conductive line and via structures 46I are vertically interlaced within the insulating layers 32 to provide a vertically alternating sequence {32, (146, 246)} of the insulating layers 32 and the electrically conductive layers (146, 246).

In one embodiment, each of the lateral connection strips 246 comprises a respective pair of laterally-undulating sidewalls, each comprising a respective set of laterally-convex and vertically-straight surface segments 246C that are adjoined to each other at vertically-extending edges. Each semiconductor bottom cap portion 186C contacts a segment of a respective lateral connection strip 246.

Remaining portions of the continuous semiconductor material layer 186L in the array-region isolation trenches 792 comprise semiconductor isolation trench fill material portions 386. Remaining portions of the at least one conductive material layer 46L in the array-region isolation trenches 792 comprise conductive trench liners 346.

Remaining portions of the continuous semiconductor material layer 186L in the discrete access openings 69 comprise semiconductor opening fill material portions 686. Remaining portions of the at least one conductive material layer 46L in the discrete access openings 69 comprise conductive opening liners 646.

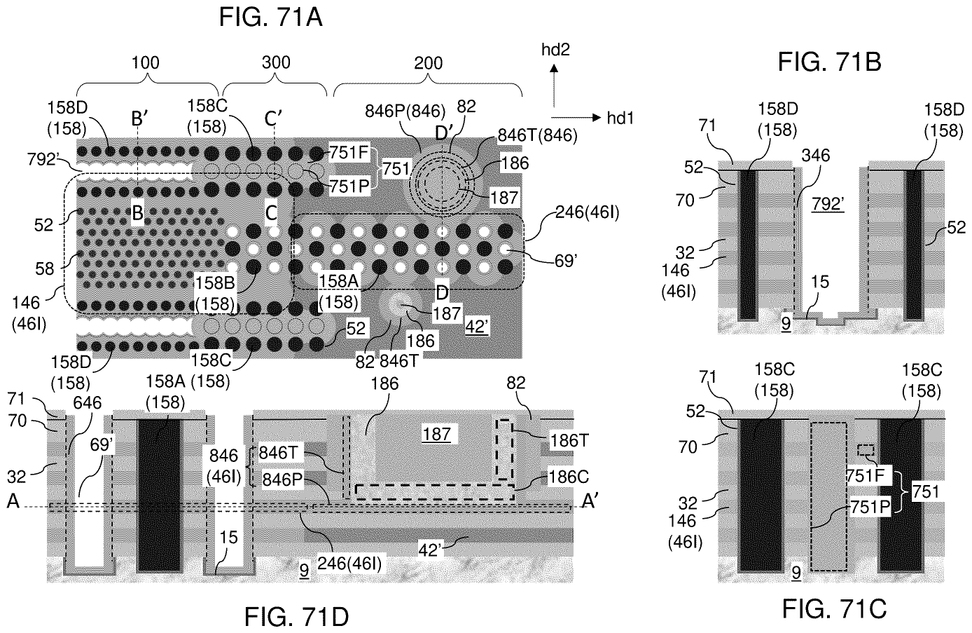

Referring to FIG. 71A-71D, a photoresist layer (not shown) can be applied to cover the areas of the contact via openings 85 without covering the areas of the array-region isolation trenches 792 and the discrete access openings 69. A selective etch process can be performed to remove the semiconductor isolation trench fill material portions 386 and the semiconductor opening fill material portions 686.

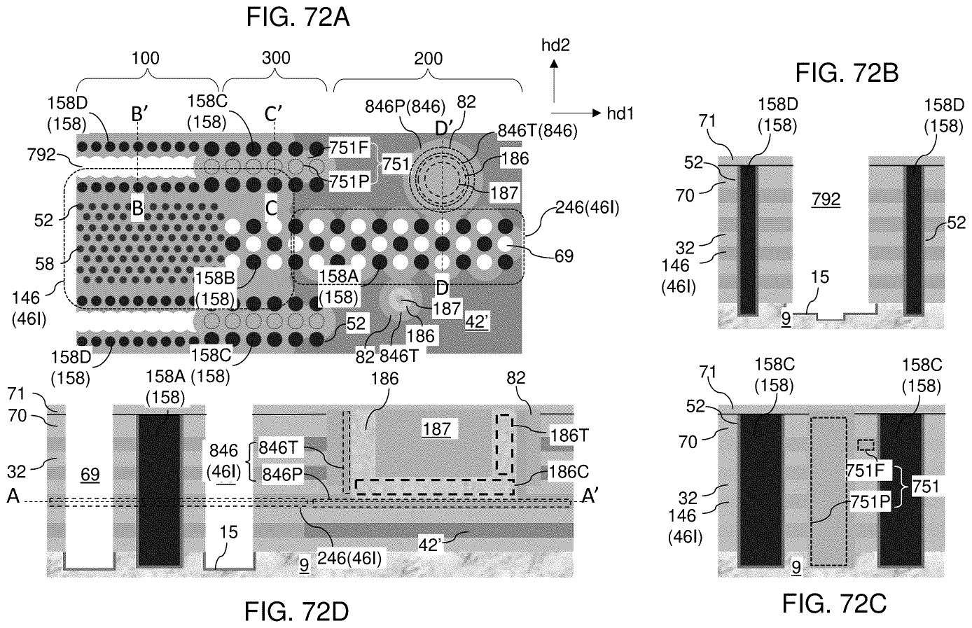

Referring to FIG. 72A-72D, an additional selective etch process can be performed to remove the conductive trench liners 346 and the conductive opening liners 646 selectively to the materials of the insulating layers 32 and the integrated conductive line and via structures 46I and to expand the diameter of the discrete access cavities 69′ to reform the discrete access openings 69.

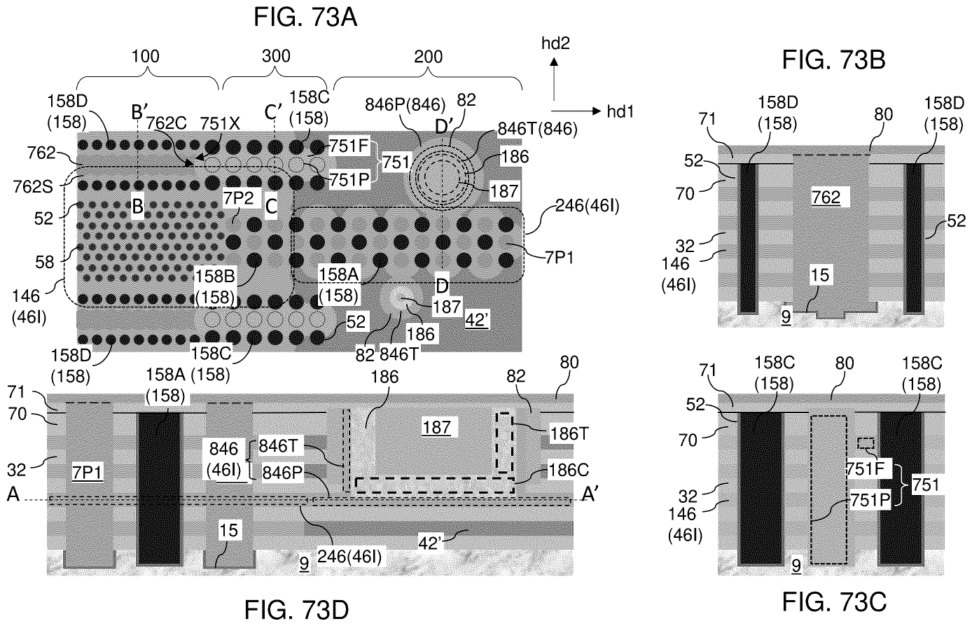

Referring to FIG. 73A-73D, a dielectric material may be deposited in the array-region isolation trenches 792 and the discrete access openings 69 and over the cover dielectric layer 72 to form a continuous dielectric material structure (80, 7P1, 7P2, 762). The dielectric material may comprise undoped silicate glass or a doped silicate glass. The continuous dielectric material structure (80, 7P1, 7P2, 762) may have a homogeneous material composition throughout. The continuous dielectric material structure (80, 7P1, 7P2, 762) comprises a horizontally-extending portion (comprising a contact-level dielectric layer 80) that overlies the vertically alternating sequence {32, (146, 246)}. The continuous dielectric material structure (80, 7P1, 7P2, 762) comprises first dielectric support pillar portions 7P1 that vertically extend through the lateral connection strips 246 of the integrated conductive line and via structures 46I, and second dielectric support pillar portions 7P2 that vertically extend through the electrode layers 146 of the integrated conductive line and via structures 46I. In one embodiment, the horizontally-extending portion which comprises a contact-level dielectric layer 80 of the continuous dielectric material structure (80, 7P1, 7P2, 762) is vertically offset from and overlies the tubular insulating spacers 82.

In one embodiment, a first fin-less dielectric wall structure comprising the array-region dielectric wall structure 762 contacts each of the electrically conductive layers (146, 246) of a vertically alternating sequence {32, (146, 246)} of insulating layers 32 and electrically conductive layers (146, 246), and contacts a first finned dielectric wall structure 751. A second fin-less dielectric wall structure comprising another array-region dielectric wall structure 762 contacts each of the electrically conductive layers (146, 246) of the vertically alternating sequence {32, (146, 246)} and contacts a second finned dielectric wall structure 751. In one embodiment, each of the first fin-less dielectric wall structure and the second fin-less dielectric wall structure comprises a respective pair of laterally-undulating dielectric sidewalls 762S that laterally extend along the first horizontal direction hd1.

In one embodiment, the first fin-less dielectric wall structure 762 comprises first laterally concave sidewall segments 762C that contact laterally convex sidewall segments 751X of the first finned dielectric wall structure 751, and the second fin-less dielectric wall structure 762 comprises second laterally concave sidewall segments 762C that contact laterally convex sidewall segments 751X of the second finned dielectric wall structure 751. In one embodiment, each of the first fin-less dielectric wall structure 762 and the second fin-less dielectric wall structure 762 comprises a respective pair of planar lengthwise sidewalls 762S that laterally extend along the first horizontal direction hd1.

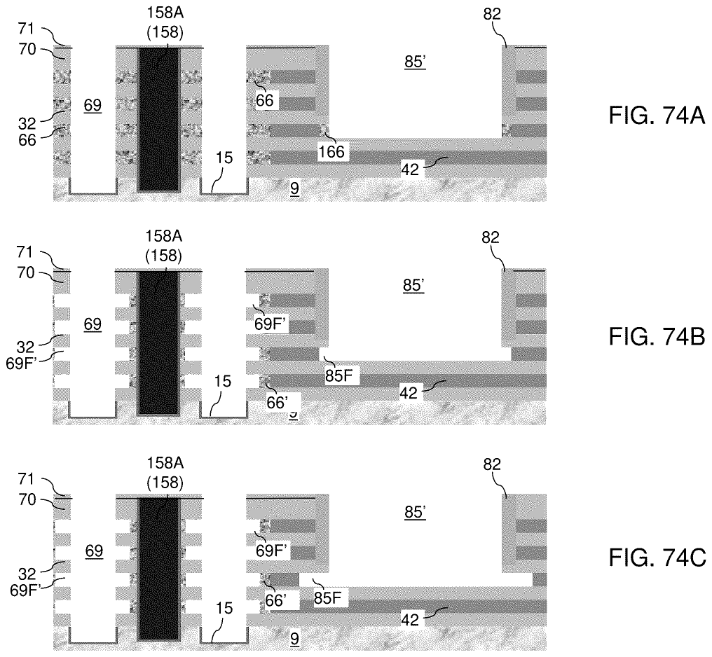

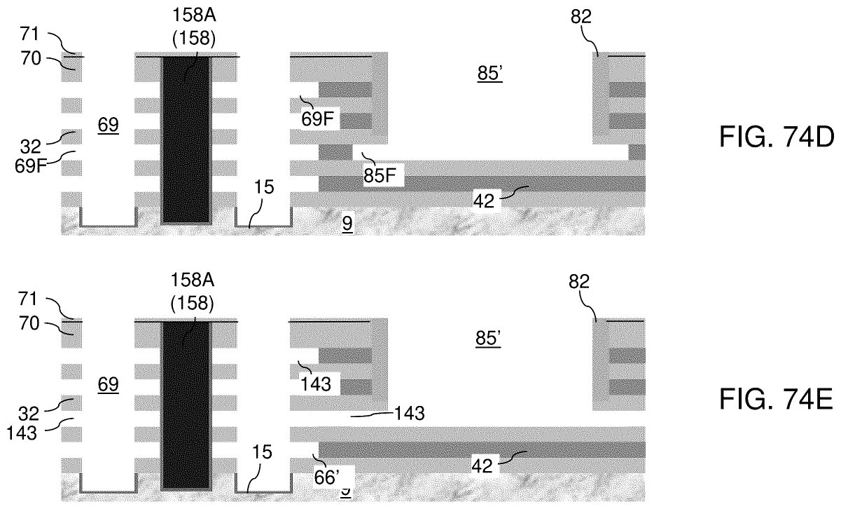

FIG. 74A-74E are vertical cross-sectional views illustrating a first alternative configuration of the third exemplary structure during formation of respective strip-shaped cavities 143 according to the third embodiment of the present disclosure.

Referring to FIG. 74A, the first alternative configuration of the third exemplary structure may be the same as the third exemplary structure illustrated in FIG. 65A-65D. In the first alternative configuration, the lateral dimension (as measured between an inner sidewall and an outer sidewall) of each via-bottom annular etch-stop structure 166 is less than the lateral dimension (as measured between an inner sidewall and an outer sidewall) of each etch-stop ring 66.

Referring to FIG. 74B, a first selective etch process may be performed to remove the via-bottom annular etch-stop structure 166 entirely while only partially removing the etch-stop rings 66. The remaining portion of each etch-stop ring 66 is herein referred to as a thinned etch-stop ring 66′. Miniature annular recesses 69F′ having lesser volumes than the annular recesses 69F are formed in the volumes from which inner portions of the etch-stop rings 66 are etched.

Referring to FIG. 74C, an auxiliary selective isotropic etch process may be performed to isotropically etch proximal portions of the sacrificial material layers 42 around the bottom regions of the contact via cavities 85′. The auxiliary selective isotropic etch process may be employed to laterally extend the volumes of the via-bottom lateral annular recesses 85F which comprise voids at a respective bottom level at which the contact via cavity 85′ is subsequently adjoined to a respective strip-shaped cavity 143.

Referring to FIG. 74D, a second selective etch process may be performed to remove the thinned etch-stop rings 66′.

Referring to FIG. 74E, the processing steps described with reference to FIG. 66A-66D may be performed.

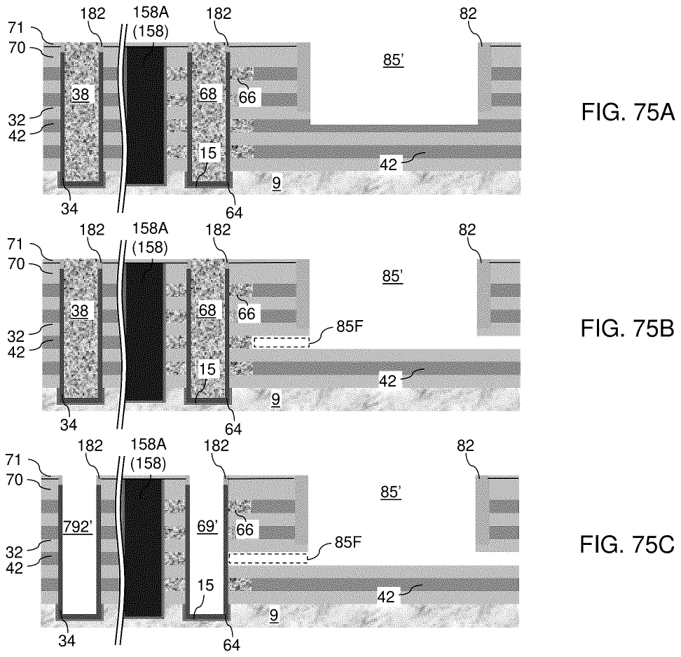

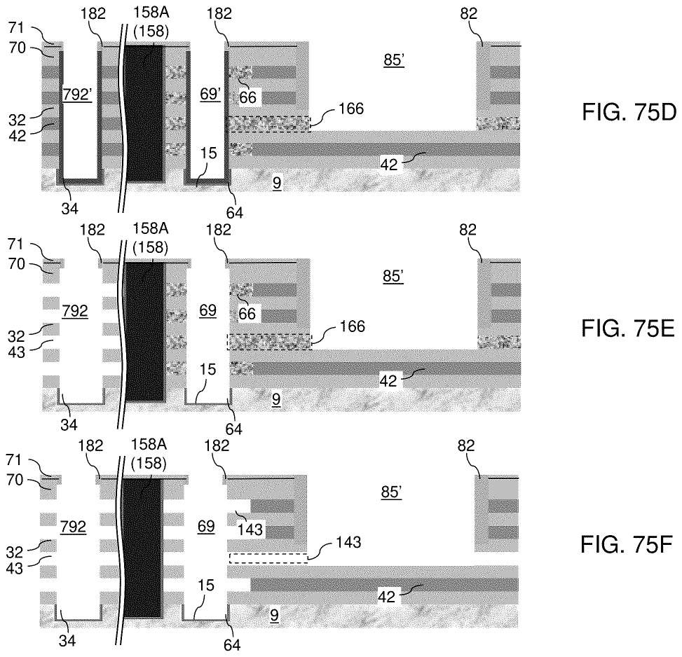

FIG. 75A-75F are vertical cross-sectional views illustrating a second alternative configuration of the third exemplary structure during formation of respective strip-shaped cavities 143 according to the third embodiment of the present disclosure.

Referring to FIG. 75A, the second alternative configuration of the third exemplary structure may be derived from the third exemplary structure illustrated in FIG. 60A-60D by vertically recessing the interim isolation trench liners 34 and the interim access opening lines 64 prior to formation of the tubular insulating liners 82. Divots are formed in the volumes from which the materials of the interim isolation trench liners 34 and the interim access opening lines 64 are etched. Divot-fill insulating spacers 182 are formed in the volumes of the divots during formation of the tubular insulating liners 82. The divot-fill insulating spacers 182 may comprise the same material as the tubular insulating liners 82.

Referring to FIG. 75B, the processing steps described with reference to FIG. 62A-62D may be performed with a modification in the duration of the selective etch process so that portions of the sacrificial material layers 42 that are exposed to the contact via cavities 85′ are etched up to sidewalls of a respective proximal one of the etch-stop rings 66. A fin-shaped cavity extension 85F may be formed around the bottom portion of each contact via cavity 85′.

Referring to FIG. 75C, the processing steps described with reference to FIG. 63A-63D may be performed to remove the interim access opening fill structures 68 and the interim isolation trench fill structures 38. Array-region isolation cavities 792′ are formed in the voids within the array-region isolation trenches 792. Discrete access cavities 69′ are formed in the voids within the discrete access openings 69. The etch-stop rings 66 that are exposed to the fin-shaped cavity extensions 85F may be collaterally removed during the selective isotropic etch process.

Referring to FIG. 75D, the processing steps described with reference to FIG. 64A 64D may be performed to form via-bottom annular etch-stop structures 166. In the second alternative configuration, each via-bottom annular etch-stop structures 166 may continuous extend from underneath an inner sidewall of a tubular insulating spacer 82 to a boundary of a respective discrete access opening 69, and may contact a respective interim access opening liner 64.

Referring to FIG. 75E, the processing steps described with reference to FIG. 65A-65D may be performed to form laterally-extending cavities 43.

Referring to FIG. 75F, the processing steps described with reference to FIG. 66A-67D may be performed to form strip-shaped cavities 143.

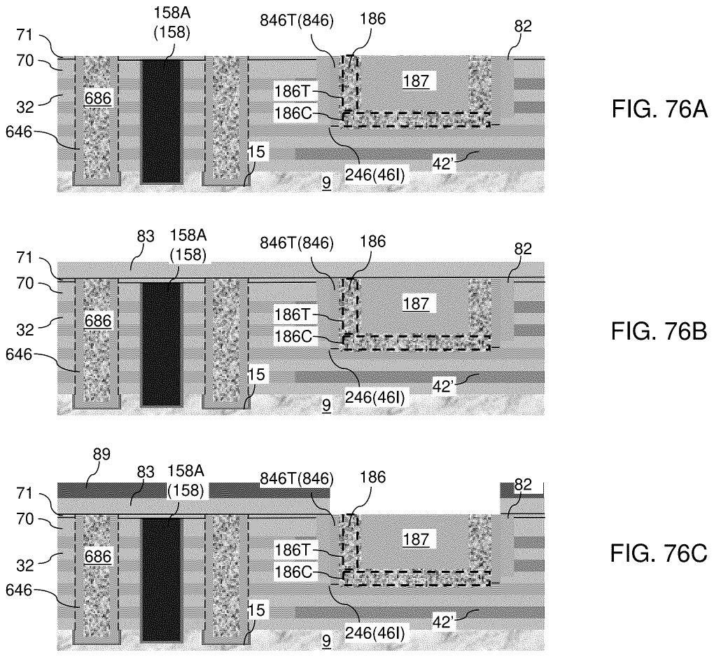

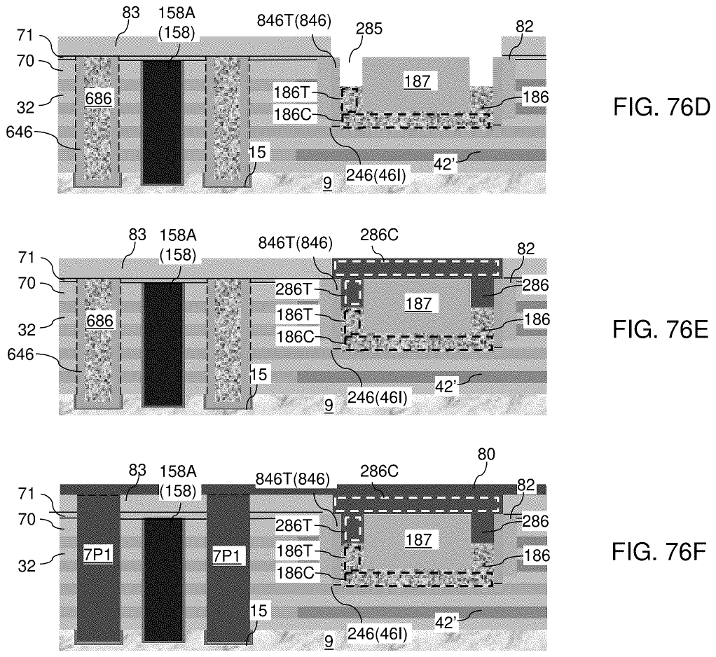

FIG. 76A-76F are vertical cross-sectional views illustrating a third alternative configuration of the third exemplary structure during formation of capped tubular metallic structures 286 according to the third embodiment of the present disclosure.

Referring to FIG. 76A, the third alternative configuration of the third exemplary structure may be the same as the third exemplary structure described with reference to FIG. 70A-70D.

Referring to FIG. 76B, a dielectric matrix layer 83 can be deposited over the cover dielectric layer 72. The dielectric matrix layer 83 comprises a dielectric material, such as undoped silicate glass or a doped silicate glass, and may have a thickness in a range from 50 nm to 400 nm, although lesser or greater thicknesses may also be employed.

Referring to FIG. 76C, an etch mask layer 89, such as a photoresist layer, may be applied over the dielectric matrix layer 83, and may be patterned to form openings over the areas of the contact via openings 85, i.e., over the areas of the dielectric via structures 187, the capped tubular semiconductor structures 186, and the vertically-extending via portions 846. An anisotropic etch process can be performed to transfer the pattern of the openings in the etch mask layer 89 through the dielectric matrix layer 83. Top surfaces of the dielectric via structures 187, the capped tubular semiconductor structures 186, and the vertically-extending via portions 846 may be exposed underneath the openings in the dielectric matrix layer 83.

Referring to FIG. 76D, another anisotropic etch process may be performed with a change in the etch chemistry to etch the material of the capped tubular semiconductor structures 186 selectively to the materials of the dielectric via structures 187 and the vertically-extending via portions 846 of the integrated conductive line and via structures 46I. Tubular cavities 285 are formed in the volumes from which the upper portions of the semiconductor tubular portions 186T of the capped tubular semiconductor structures 186 are removed. Generally, the tubular cavities 285 may be formed by vertically recessing semiconductor tubular portions 186T of the capped tubular semiconductor structures 186 selectively to the dielectric via structures 187 and the vertically-extending via portions 846.

Referring to FIG. 76E, at least one electrically conductive material, such as a combination of a metallic barrier liner material (e.g., TiN, TaN, WN, and/or MoN) and a metal fill material (e.g., W, Cu, Ti, Ta, etc.), may be deposited in the tubular cavities 285 and in the openings in the dielectric matrix layer 83. A planarization process, such as a chemical mechanical polishing process, may be performed to remove portions of the at least one electrically conductive material from above the horizontal plane including the top surface of the dielectric matrix layer 83. Each remaining portion of the at least one electrically conductive material contacting a respective dielectric via structure 187, a respective capped tubular semiconductor structure 186, and a respective vertically-extending via portion 846 comprises a capped tubular metallic structure 286.

Each capped tubular metallic structure 286 comprises a metallic tubular portion 286T that is formed within a respective tubular cavity 285, and a respective metallic cap portion 286C located over the metallic tubular portion 286T. Each capped tubular metallic structure 286 is formed directly on a respective capped tubular semiconductor structure 186. The width of each metallic tubular portion 286T, as measured between an inner sidewall thereof and an outer sidewall thereof, may be the same as the width of a respective underlying semiconductor tubular portion 186T, as measured between an inner sidewall thereof and an outer sidewall thereof. The inner sidewall of each metallic tubular portion 286T may be vertically coincident with the inner sidewall of a respective underlying semiconductor tubular portion 186T. The outer sidewall of each metallic tubular portion 286T may be vertically coincident with the outer sidewall of a respective underlying semiconductor tubular portion 186T.

Each of the dielectric via structures 187 is laterally surrounded by a respective one of the capped tubular semiconductor structures 186 and by a respective one of the capped tubular metallic structures 286. The metallic cap portions 286C of the capped tubular metallic structures 286 are formed above the horizontal plane including top surfaces of the dielectric via structures 187.

Referring to FIG. 76F, a photoresist layer (not shown) may be applied over the dielectric matrix layer 83, and can be lithographically patterned to form openings over the areas of the array-region isolation trenches 792 and the discrete access openings 69, i.e., over the areas of the semiconductor isolation trench fill material portions 386, the conductive trench liners 346, the semiconductor opening fill material portions 686, and the conductive opening liners 646. An anisotropic etch process may be performed to transfer the pattern of the openings in the photoresist layer though the dielectric matrix layer 83. The photoresist layer may be subsequently removed, for example, by ashing. Subsequently, the processing steps described with reference to FIG. 70A-73D may be performed.

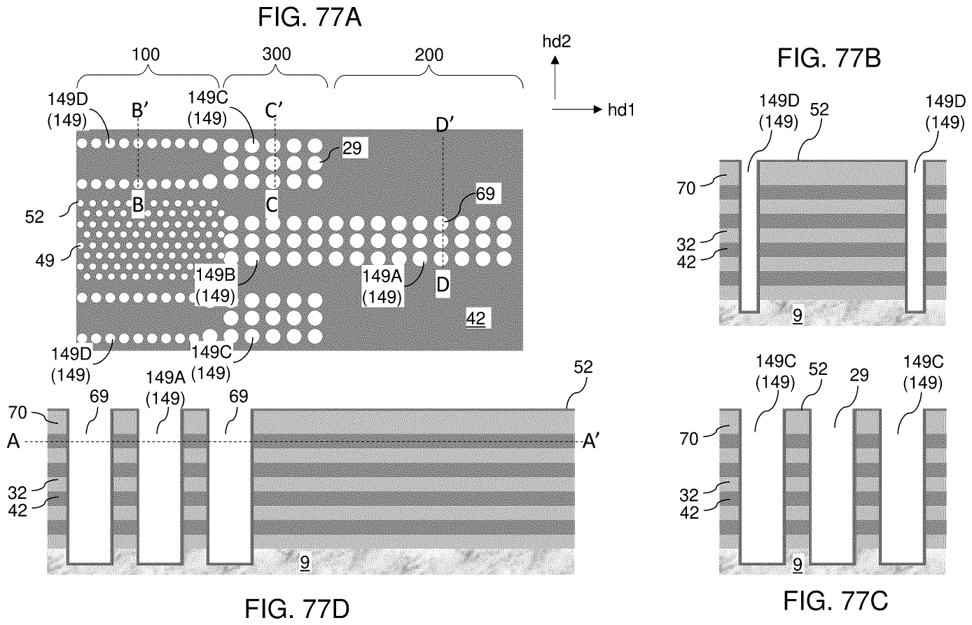

Referring to FIG. 77A-77D, a fourth exemplary structure according to a fourth embodiment of the present disclosure may be derived from the third exemplary structure described with reference to FIG. 44A-44D by omitting formation of the memory-region isolation openings 39.

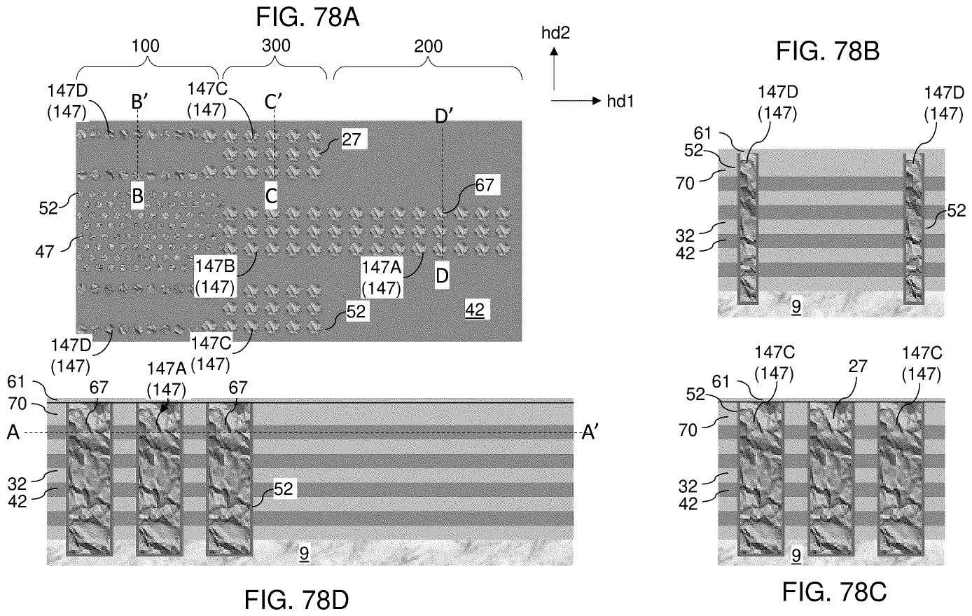

Referring to FIG. 78A-78D, the processing steps described with reference to FIG. 45A-45B may be performed. The sacrificial memory-region isolation opening fill structures 37 in the third exemplary structure of FIG. 45A-45D are absent in the fourth exemplary structure of FIG. 78A-78D.

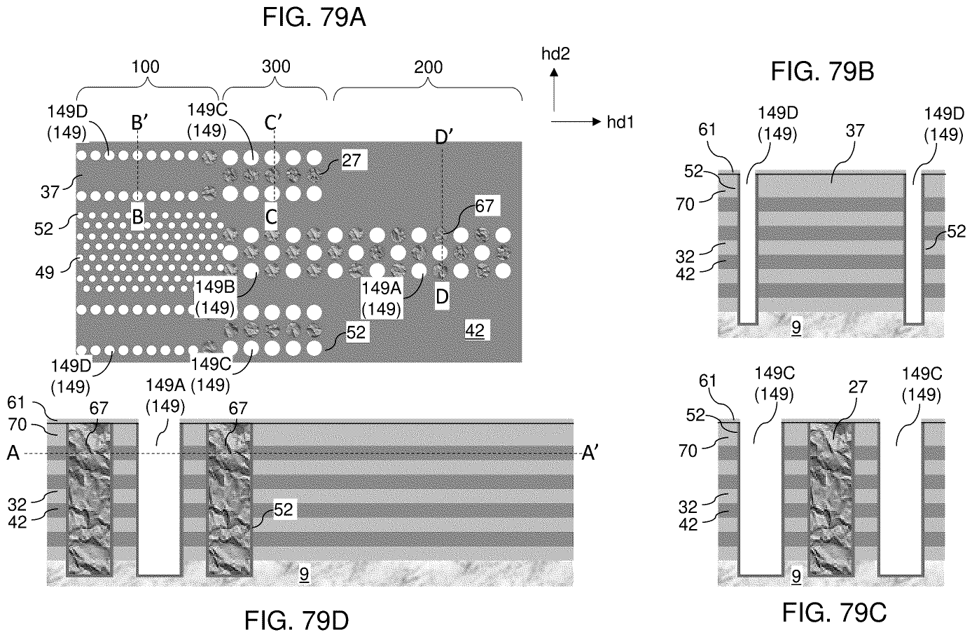

Referring to FIG. 79A-79D, the processing steps described with reference to FIG. 46A-46D may be performed.

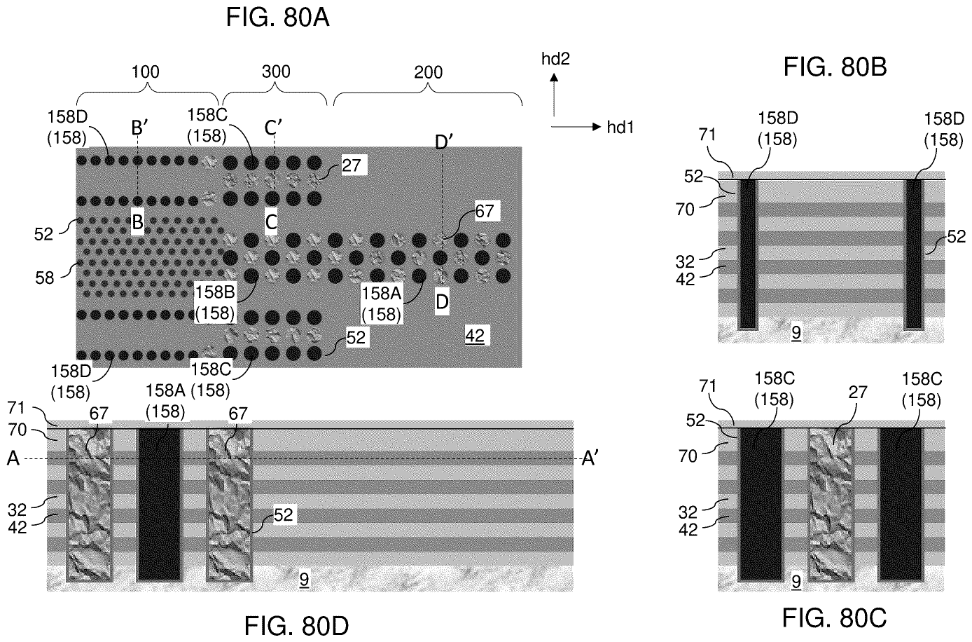

Referring to FIG. 80A-80D, the processing steps described with reference to FIG. 47A-47D may be performed.

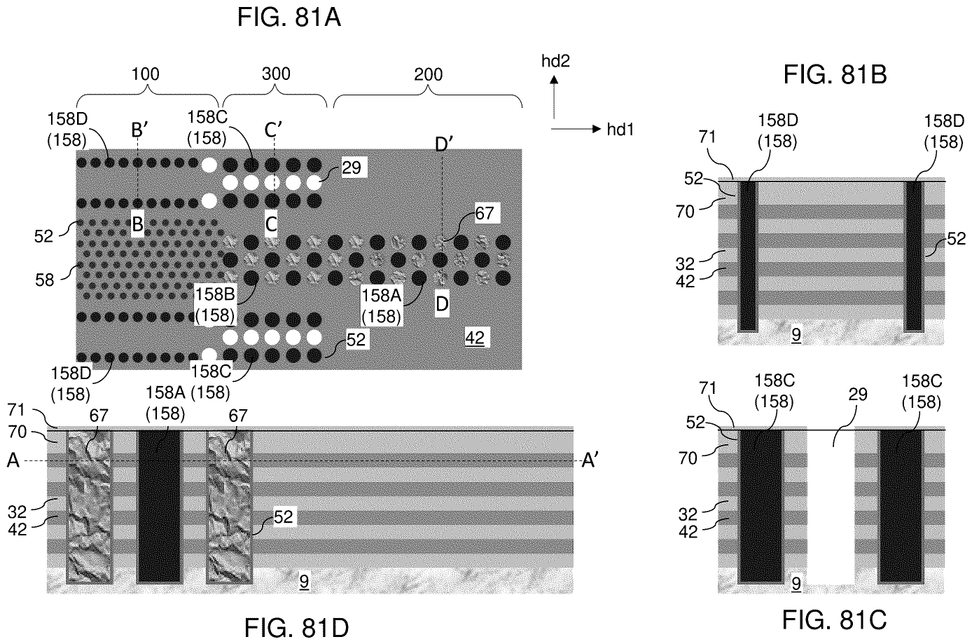

Referring to FIG. 81A-81D, the processing steps described with reference to FIG. 48A-48D may be performed.

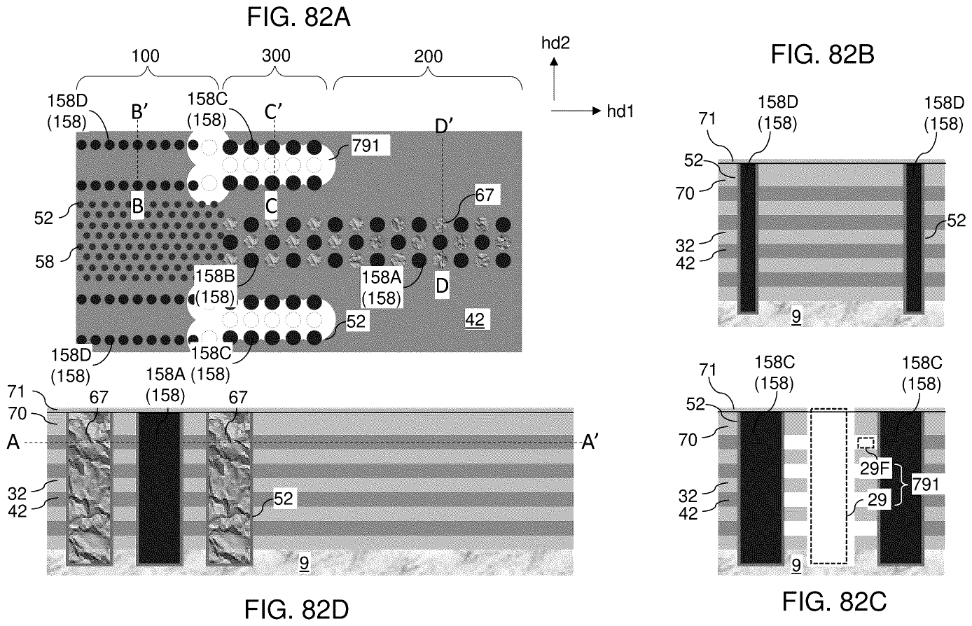

Referring to FIG. 82A-82D, the processing steps described with reference to FIG. 49A-49D may be performed.

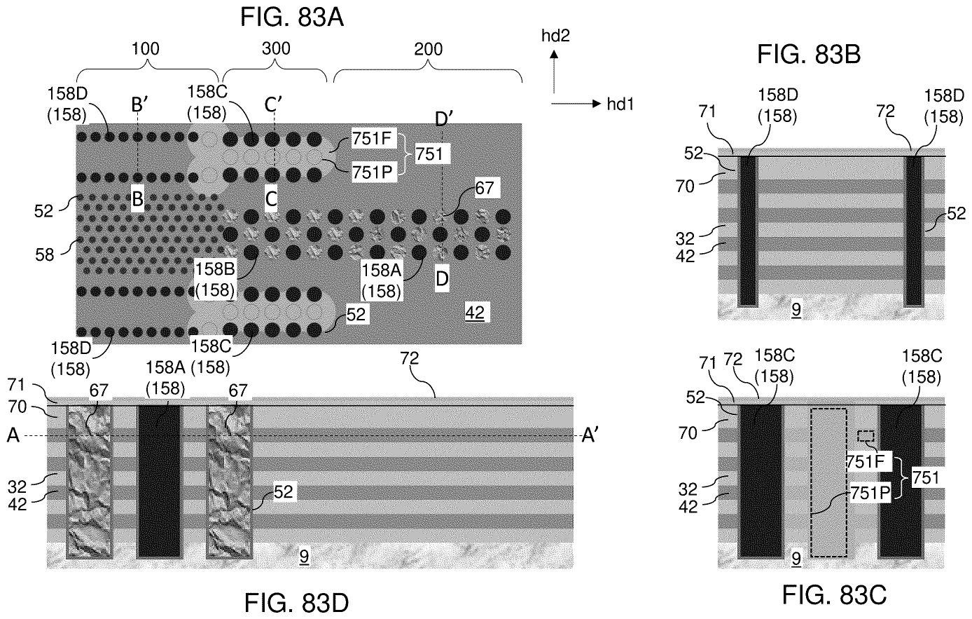

Referring to FIG. 83A-83D, the processing steps described with reference to FIG. 50A-50D may be performed.

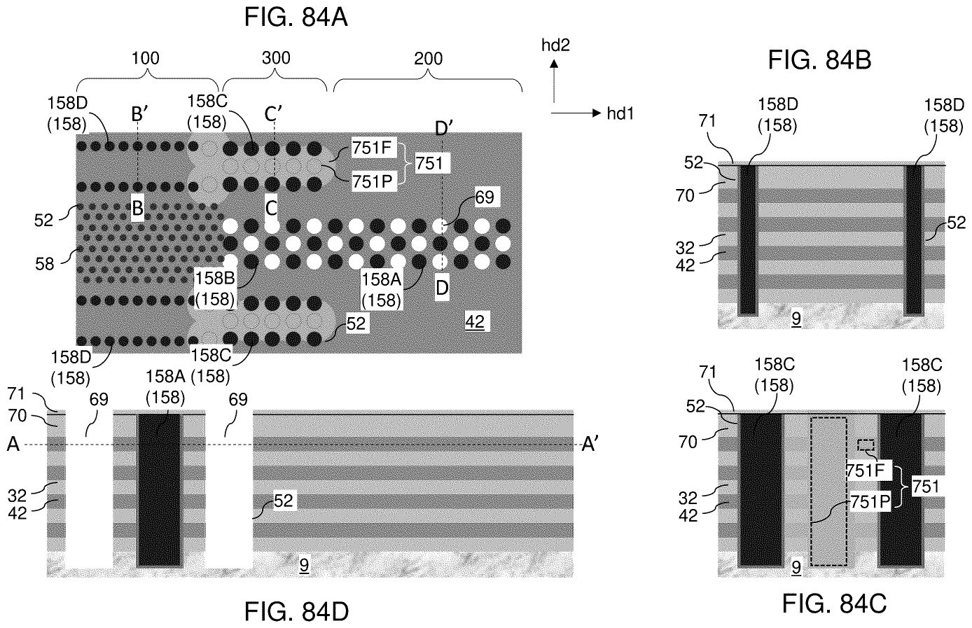

Referring to FIG. 84A-84D, the processing steps described with reference to FIG. 51A-51D may be performed.

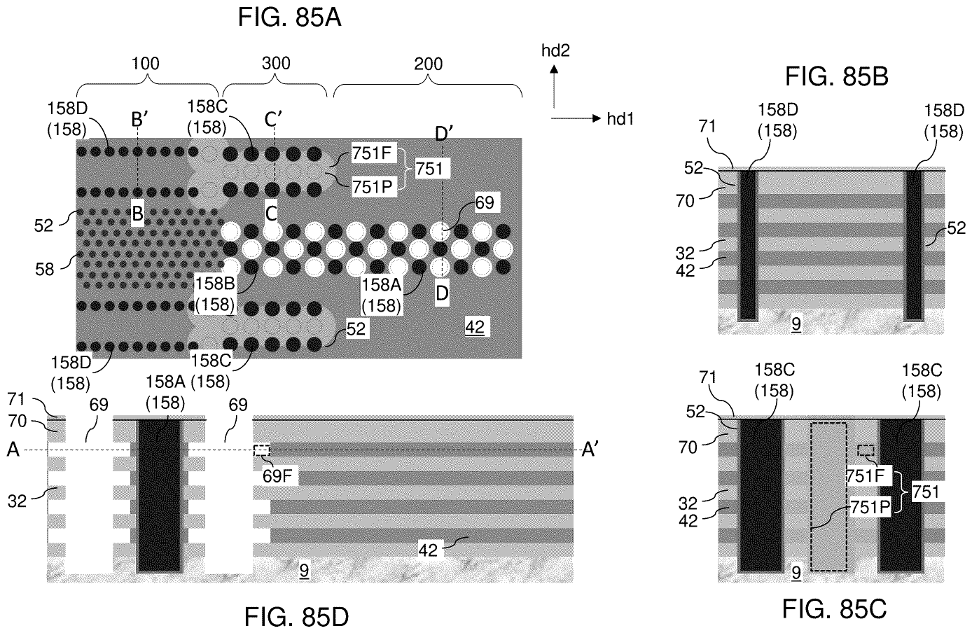

Referring to FIG. 85A-85D, the processing steps described with reference to FIG. 52A-52D may be performed.

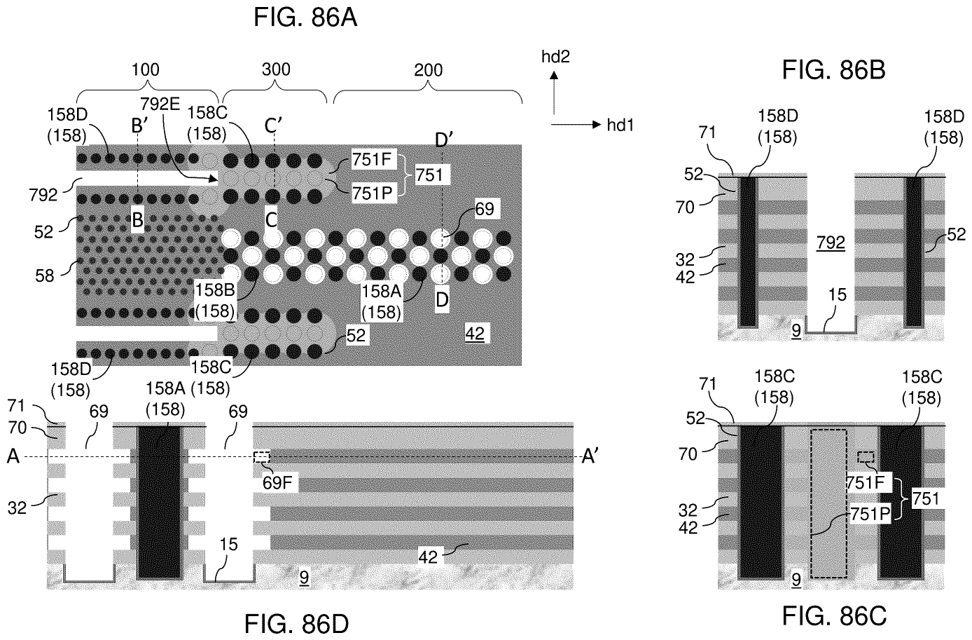

Referring to FIG. 86A-86D, a photoresist layer (not shown) may be applied over the cover dielectric layer 71, and can be lithographically patterned to form openings in areas that correspond to the regions of the memory-region isolation openings 39 in the third exemplary structure. In one embodiment, each opening in the photoresist layer may laterally extend continuously through the memory array region 100 along the first horizontal direction hd1. In one embodiment, the openings in the photoresist layer may have a rectangular horizontal cross-sectional shape with a pair of lengthwise edges that are parallel to the first horizontal direction hd1, and a pair of widthwise edges that are parallel to the second horizontal direction hd2.

An anisotropic etch process can be performed to transfer the pattern of the openings in the photoresist layer through the cover dielectric layer 71, the insulating cap layer 70, and the alternating stack (32, 42) of the insulating layers 32 and the sacrificial material layers 42. Array-region isolation trenches 792 can be formed such that each array-region isolation trench 792 has an end portion 792E that cuts into a respective one of the finned dielectric wall structures 751. Thus, each sacrificial material layer 42 is cut into multiple disjoined finger portions in the memory array region 100.

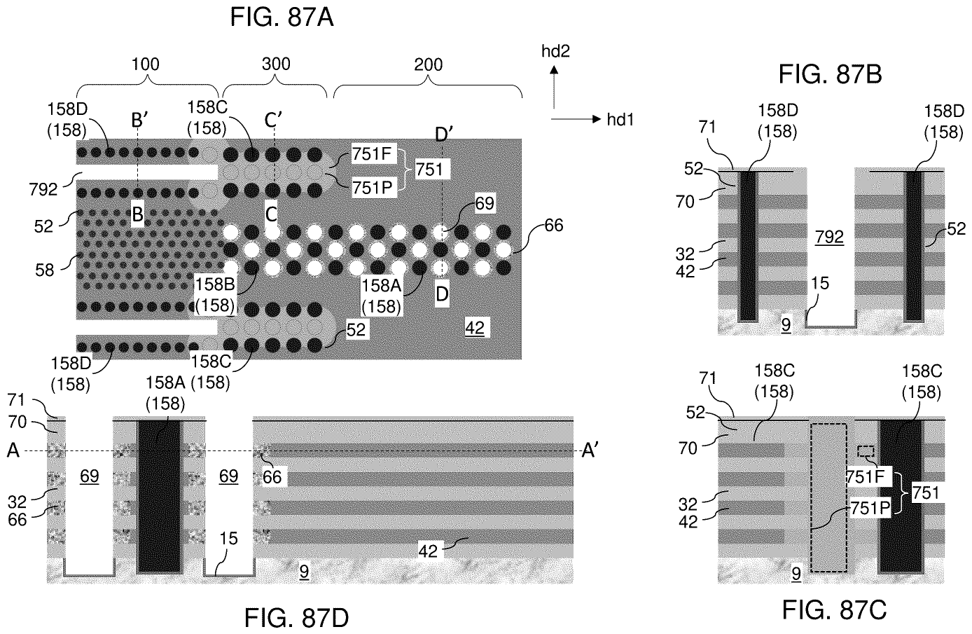

Referring to FIG. 87A-87D, the processing steps described with reference to FIG. 57A-57D may be performed to form etch-stop rings 66.

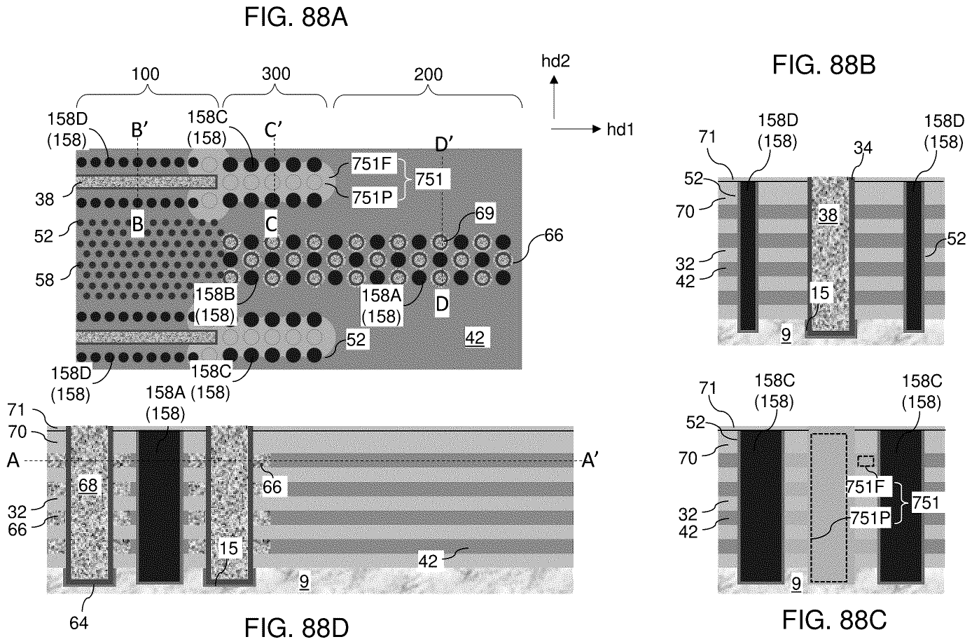

Referring to FIG. 88A-88D, the processing steps described with reference to FIG. 58A-58D may be performed to form interim access opening liners 64, interim access opening fill structures 68, interim isolation trench liners 34, and interim isolation trench fill structures 38. The interim access opening liners 64, and the interim access opening fill structures 68 are formed in the discrete access openings 69. The interim isolation trench liners 34 and the interim isolation trench fill structures 38 are formed in the array-region isolation trenches 792.

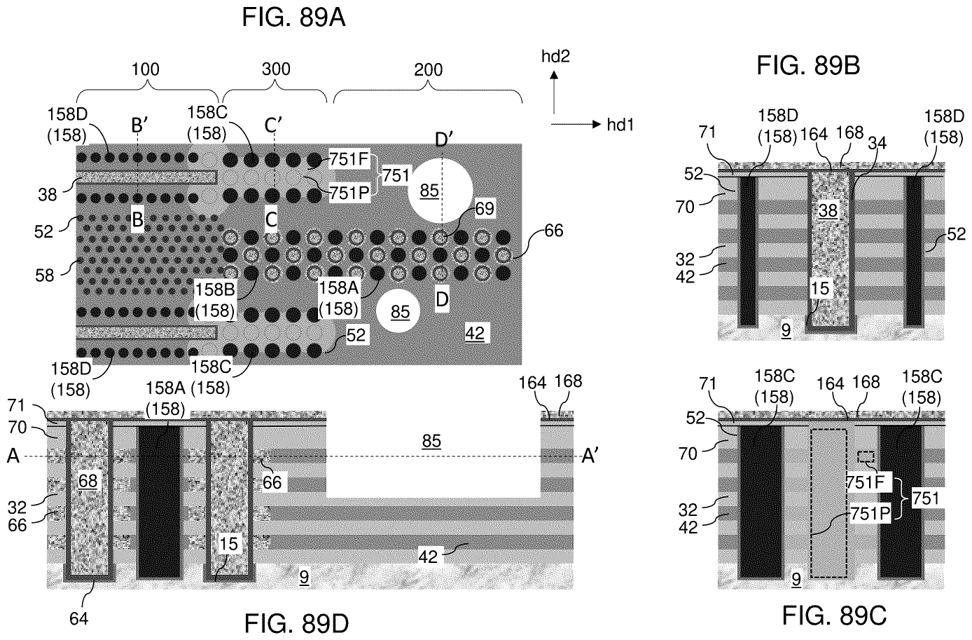

Referring to FIG. 89A-89D, the processing steps described with reference to FIG. 59A-59D may be performed.

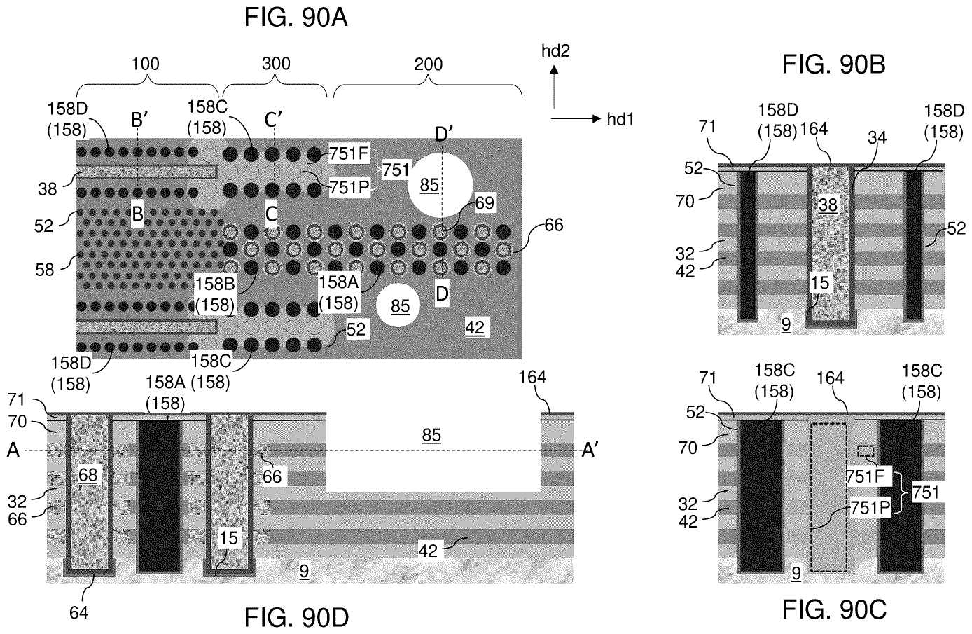

Referring to FIG. 90A-90D, the processing steps described with reference to FIG. 60A-60D may be performed.

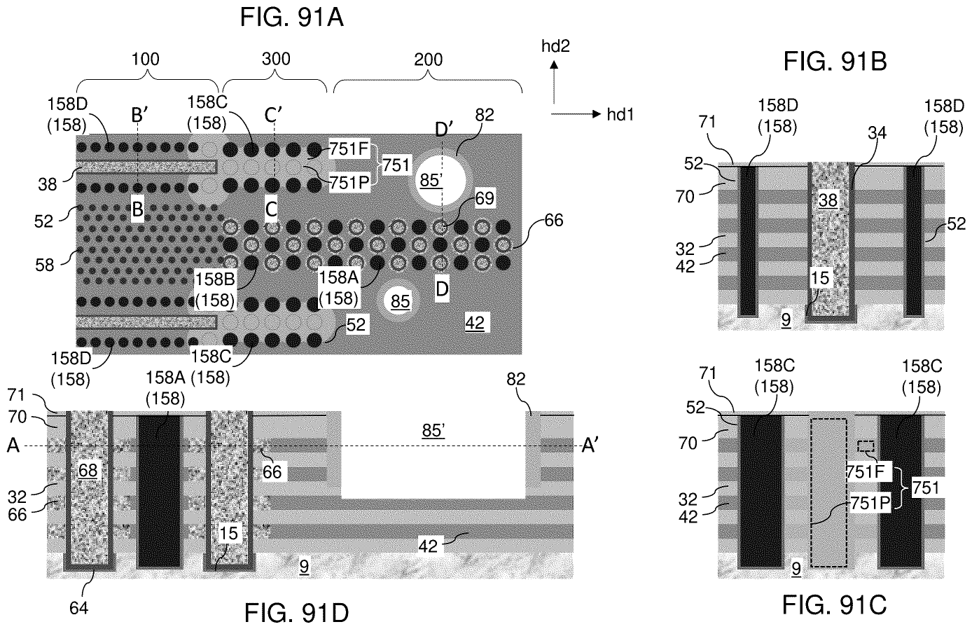

Referring to FIG. 91A-91D, the processing steps described with reference to FIG. 61A-61D may be performed.

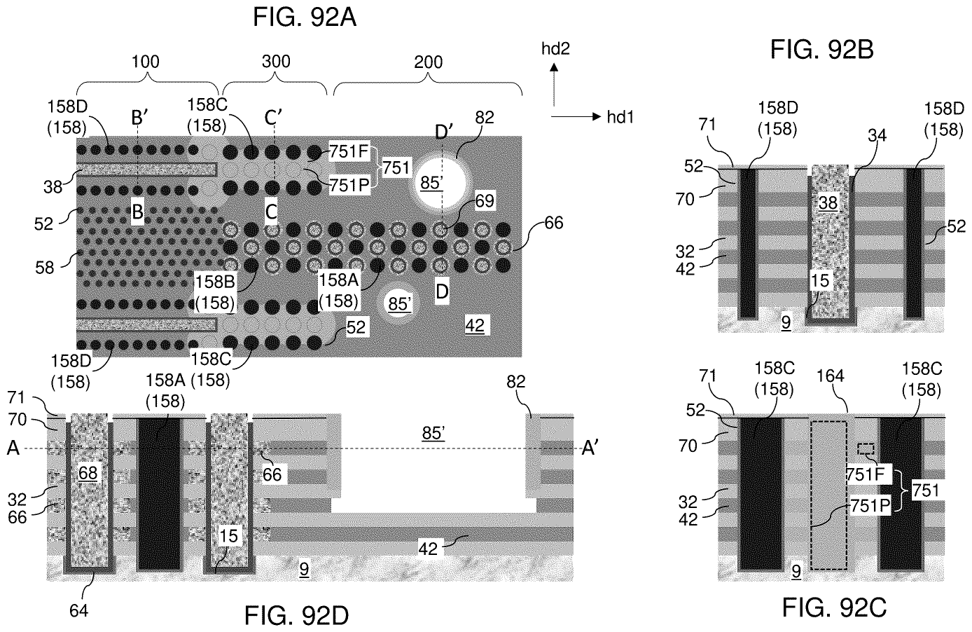

Referring to FIG. 92A-92D, the processing steps described with reference to FIG. 62A-62D may be performed.

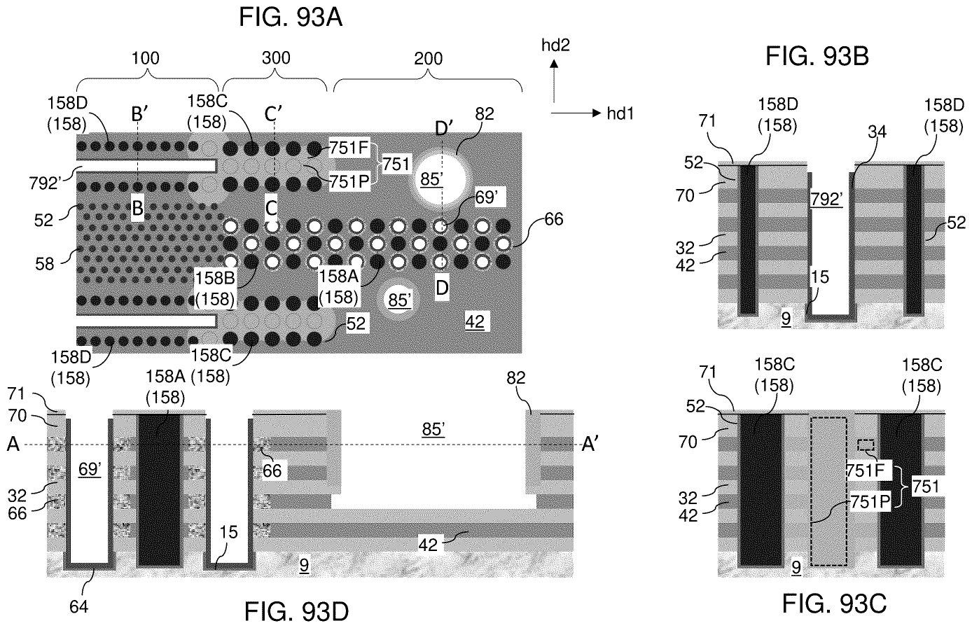

Referring to FIG. 93A-93D, the processing steps described with reference to FIG. 63A-63D may be performed.

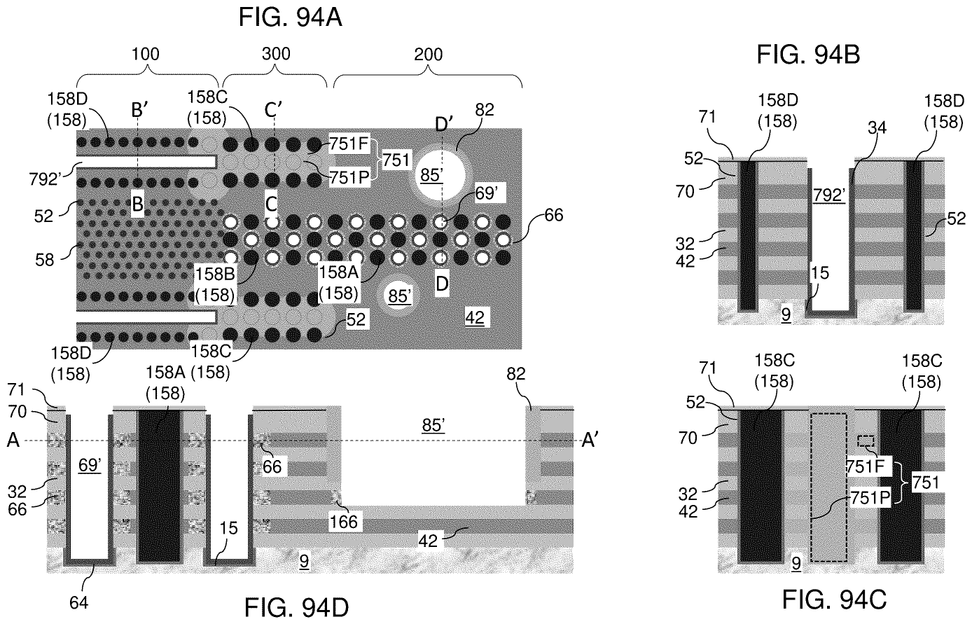

Referring to FIG. 94A-94D, the processing steps described with reference to FIG. 64A-64D may be performed.

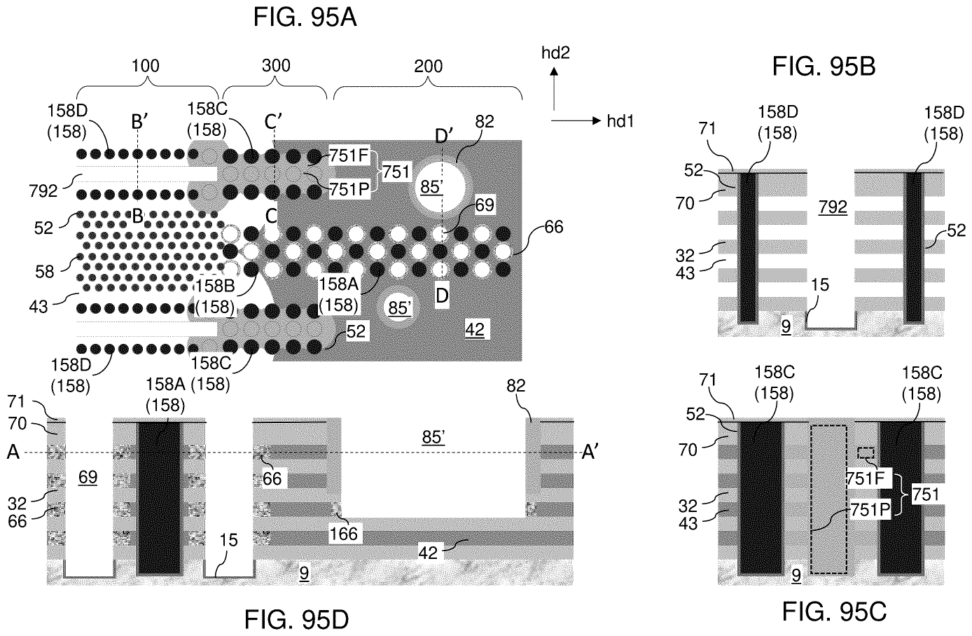

Referring to FIG. 95A-95D, the processing steps described with reference to FIG. 65A-65D may be performed.

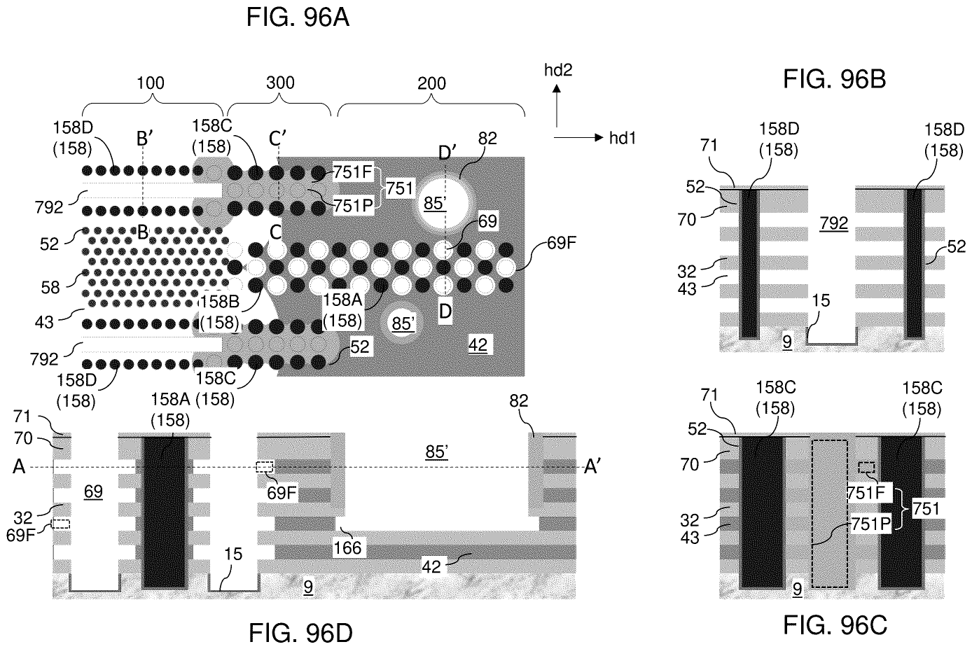

Referring to FIG. 96A-96D, the processing steps described with reference to FIG. 66A-66D may be performed.

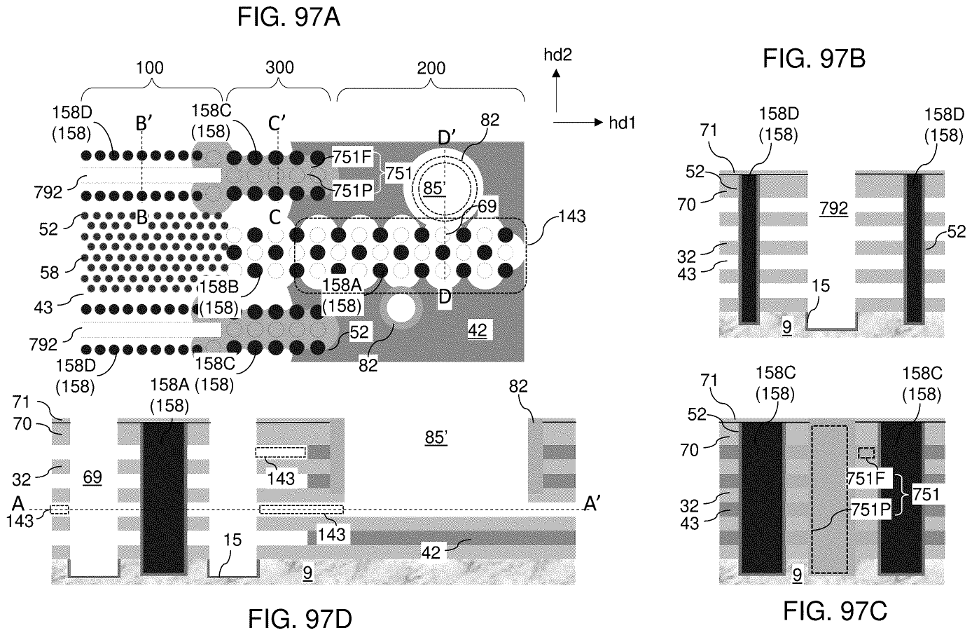

Referring to FIG. 97A-97D, the processing steps described with reference to FIG. 67A-67D may be performed.

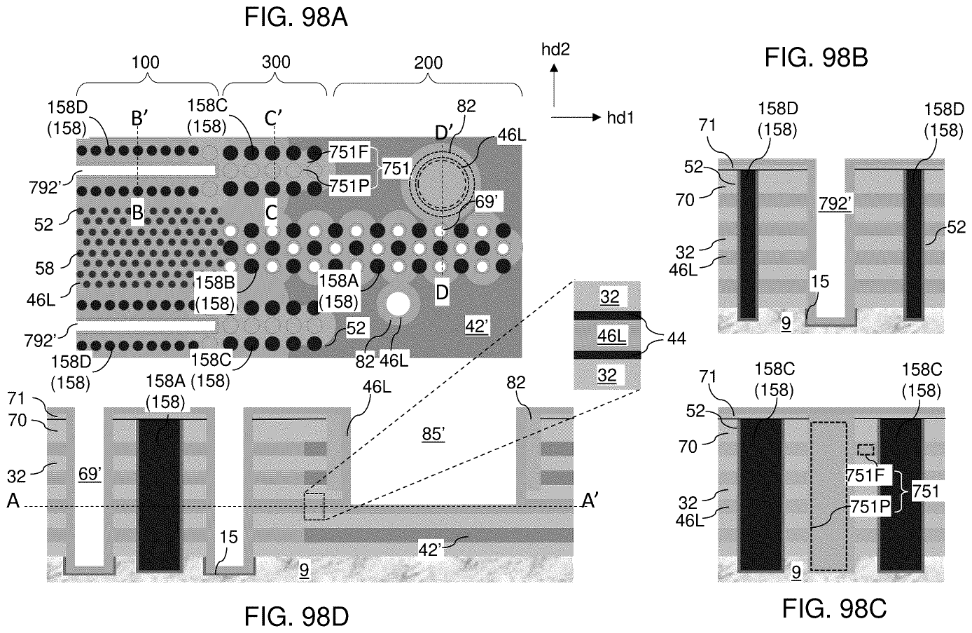

Referring to FIG. 98A-98D, the processing steps described with reference to FIG. 68A-68D may be performed.

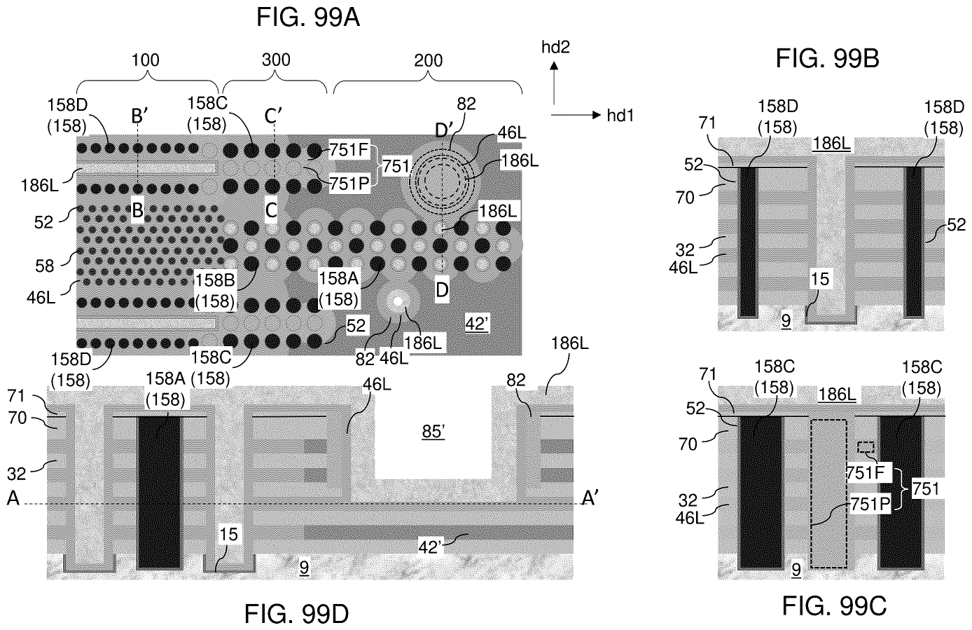

Referring to FIG. 99A-99D, the processing steps described with reference to FIG. 69A-69D may be performed.

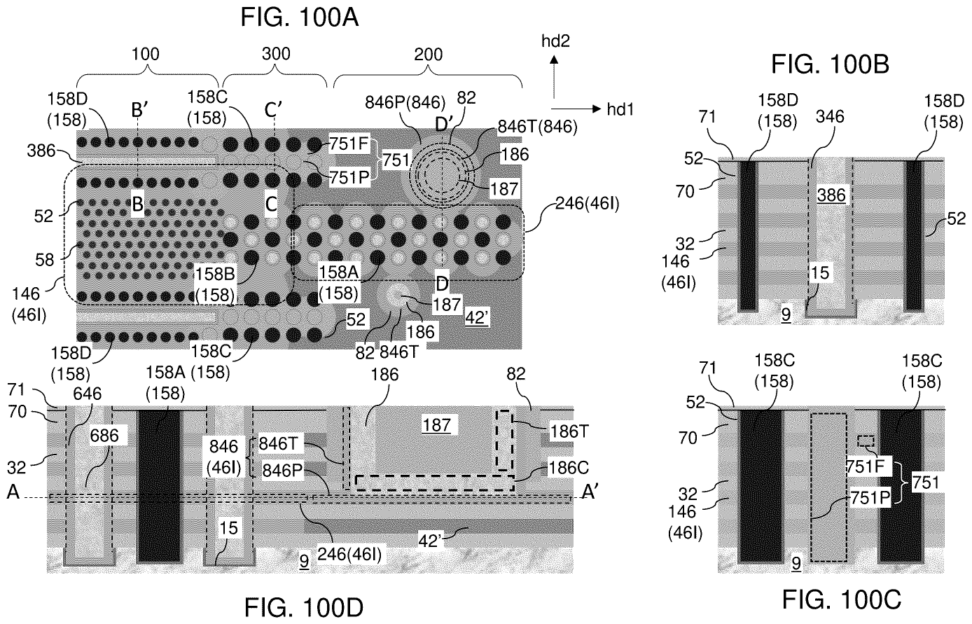

Referring to FIG. 100A-100D, the processing steps described with reference to FIG. 70A-70D may be performed.

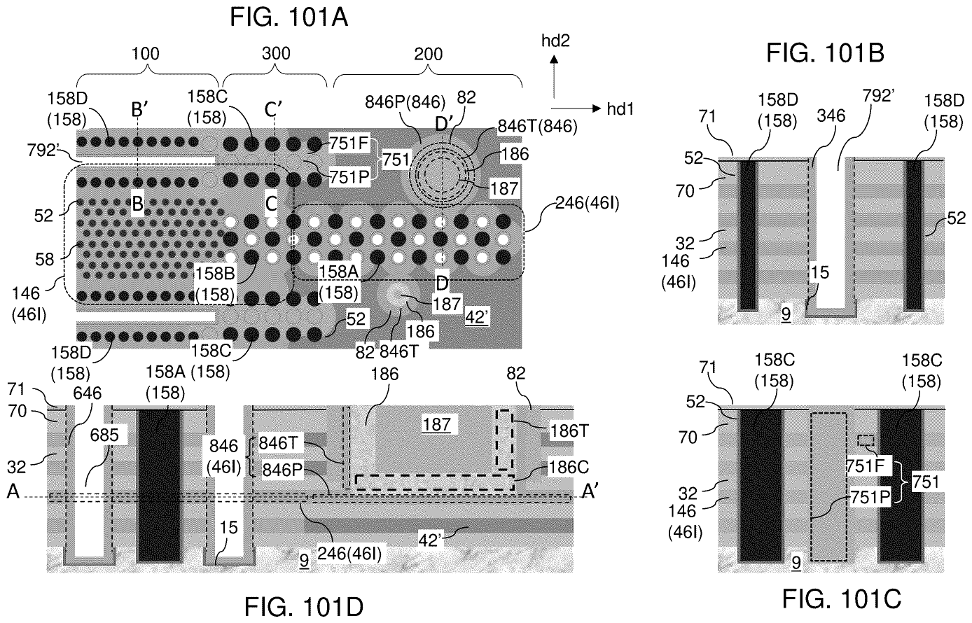

Referring to FIG. 101A-101D, the processing steps described with reference to FIG. 71A-71D may be performed.

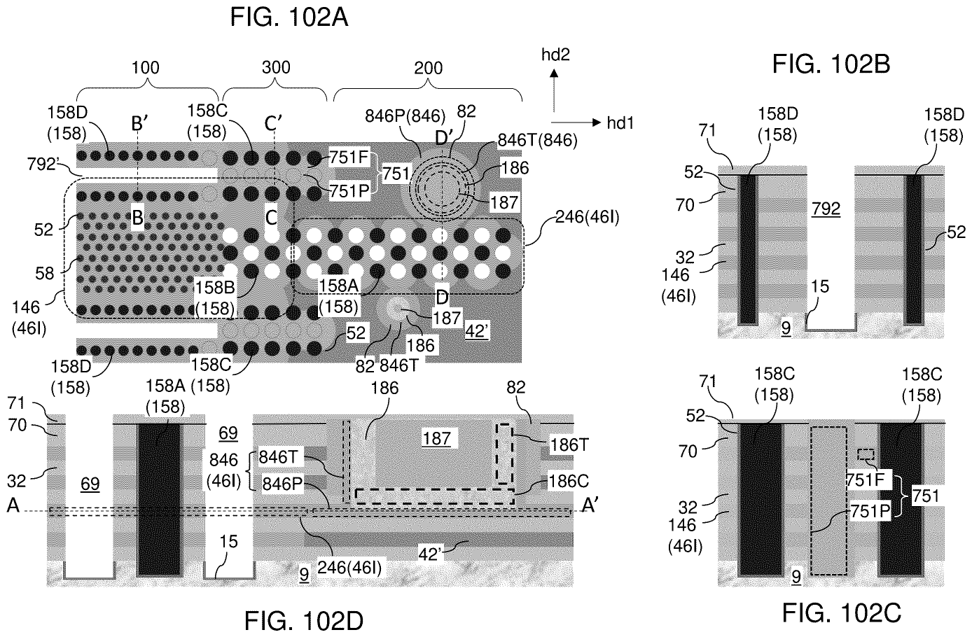

Referring to FIG. 102A-102D, the processing steps described with reference to FIG. 72A-72D may be performed.

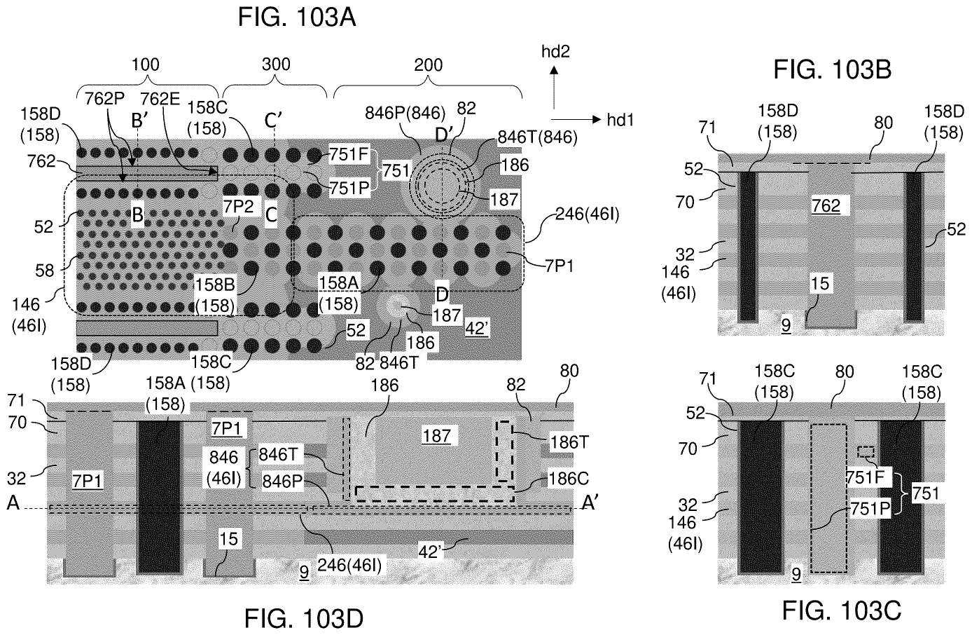

Referring to FIG. 103A-103D, the processing steps described with reference to FIG. 73A-73D may be performed.

As shown in FIG. 103A, in the fourth embodiment, each planar lengthwise sidewall 762P of the first fin-less dielectric wall structure 762 contacts the first finned dielectric wall structure 751; each planar lengthwise sidewall 762P of the second fin-less dielectric wall structure 762 contacts the second finned dielectric wall structure 751; the first fin-less dielectric wall structure 762 comprises a first planar end wall 762E that is parallel to the second horizontal direction hd2, is perpendicular to the first horizontal direction hd1 and contacts the first finned dielectric wall structure 751; and the second fin-less dielectric wall structure 762 comprises a second planar end wall 762E that is perpendicular to the first horizontal direction hd1 and contacts the second finned dielectric wall structure 751.

Generally, the alternative configurations described with reference to FIG. 74A-76F may also be employed for the fourth exemplary structure.

In the third and fourth exemplary structures, the connection-region isolation trenches 791 are formed by expanding and merging discrete adjacent connection-region isolation openings 29 at the levels of the sacrificial material layers 42. This permits an easier differentiation and separate formation of the array-region isolation trenches 792. It also reduces potential electrically conductive layer (146, 246) lateral incline or deflection and reduced misalignment between the dummy memory openings 149 and the connection-region isolation openings 29. It may also reduce bottom punch through during vertical etching and improve die strength due to discontinuous void formation.

Furthermore, by using discrete access openings 69 instead of a continuous trench, reduces potential connection strip portion 246 lateral incline or deflection in the contact region 200. It also reduces the sacrificial layer 42 recess distance while ensuring a continuous strip portion 246 with a sufficient width along the second horizontal direction hd2 to provide a low resistance electrical connection between the electrode layer 146 and the via portion 846.

Still further, photoresist depletion (e.g., thinning due to flow) and cracking issues may be reduced or eliminated by performing the methods of the third and fourth embodiments. Specifically, photoresist patterns do not have to be deposited into deep trenches or wide openings (which may cause depletion or cracking) by using the etch-stop rings 66 and annular etch-stop structures 166. Furthermore, by filling trenches with the continuous semiconductor material layer 186L and the dielectric material used to form the dielectric via structures 187, the photoresist layer is located on these materials rather than being deposited into the trenches at the step shown in FIG. 101A-101D.

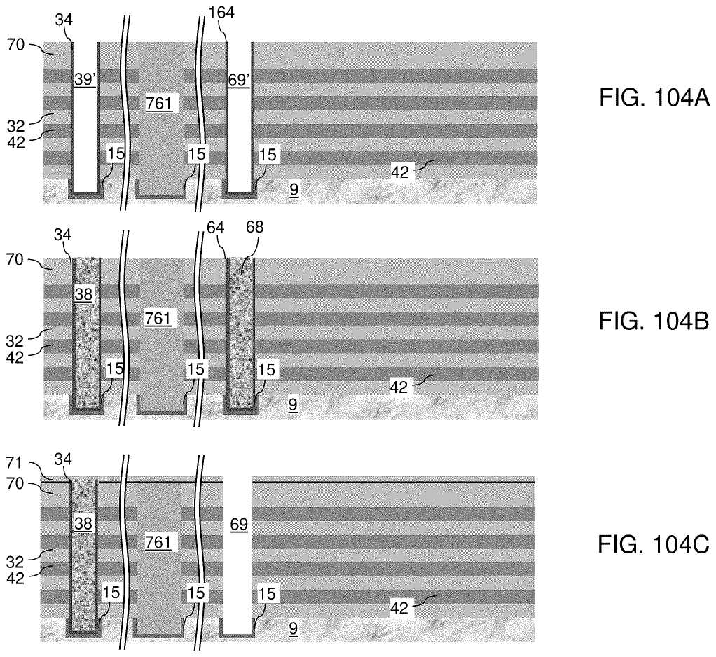

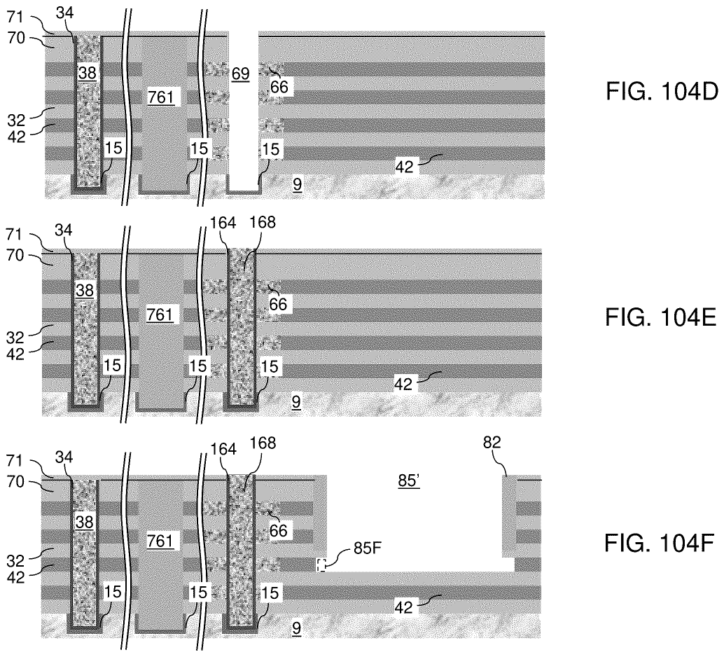

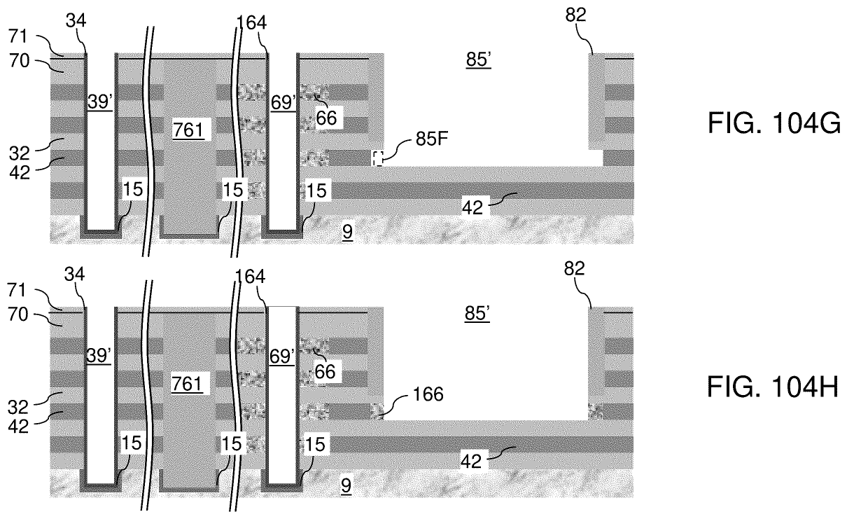

FIG. 104A-104H are sequential vertical cross-sectional views of a fifth exemplary structure during formation of connection-region dielectric wall structures 761 and contact via cavities 85′ according to a fifth embodiment of the present disclosure.

Referring to FIG. 104A, the fifth exemplary structure according to the fifth embodiment of the present disclosure may be derived from the third exemplary structure illustrated in FIG. 44A-44D or the fourth exemplary structure illustrated in FIG. 77A-77D by forming fin-less connection-region isolation trenches that laterally extend along the first horizontal direction hd1 in lieu of connection-region isolation openings 29 in the connection region 300. The fin-less connection-region isolation trenches can be filled with a dielectric fill material, such as undoped silicate glass or a doped silicate glass, to form fin-less dielectric isolation structures 761 instead of finned dielectric wall structures 751. Subsequently, the processing steps described with reference to FIG. 45A-57D or the processing steps described with reference to FIG. 78A 87D may be performed.

Referring to FIG. 104B, the processing steps described with reference to FIG. 58A 58D or FIG. 88A-88D may be performed to form various interim fill structures {(34, 38), (64, 68)} in the array-region isolation trenches 792 and in the discrete access openings 69.

Referring to FIG. 104C, a patterned mask layer (such as a patterned photoresist layer) (not shown) may be formed above the dielectric layer 70 to cover the areas of the interim isolation trench liners 34 and the interim isolation trench fill structures 38 without covering the interim access opening liners 64 or the interim access opening fill structures 68. Selective etch processes may be performed to remove the interim access opening liners 64 and the interim access opening fill structures 68. Voids (i.e., discrete access cavities) 69′ are formed in the volumes of the discrete access openings 69.

Referring to FIG. 104D, the processing steps described with reference to FIG. 52A 52D may be performed to form annular recesses 69F around the discrete access openings 69. An etch-stop material, such as amorphous silicon or polysilicon, may be conformally deposited and anisotropically etched to form etch-stop rings 66 in the annular recesses 69F around the discrete access openings 69.

Referring to FIG. 104E, a dielectric liner material and a trench fill material may be deposited in the discrete isolation openings 69, and excess portions of the dielectric liner material and the trench fill material may be removed from above the horizontal plane including the top surface of the cover dielectric layer 71. Remaining portions of the dielectric liner material and the trench fill material comprise replacement access opening liners 164 and replacement access opening fill structures 168. In one embodiment, the replacement access opening liners 164 may comprise the same material as and may have the same thickness as the interim isolation trench liners 34. In one embodiment, the replacement access opening fill structures 168 may comprise the same material as and may have the same thickness as the interim isolation trench fill structures 38.

Referring to FIG. 104F, the processing steps described with reference to FIG. 59A 62D may be performed to form contact via openings 85 and tubular insulating spacers 82, and to isotropically recess portions of the sacrificial material layers 42 that underlie the tubular insulating spacers 82. A fin-shaped cavity extension 85F may be formed around the bottom portion of each contact via cavity 85′.

Referring to FIG. 104G, the interim isolation trench fill structures 38 and the replacement access opening fill structures 168 may be removed selectively to the materials of the interim isolation trench liners 34, the replacement access opening liners 164, the insulating layers 32, and the sacrificial material layers 42.

Referring to FIG. 104H, the processing steps described with reference to FIG. 64A 64D may be performed to form via-bottom annular etch-stop structures 166.

Subsequently, the processing steps described with reference to FIG. 65A-73D may be performed.

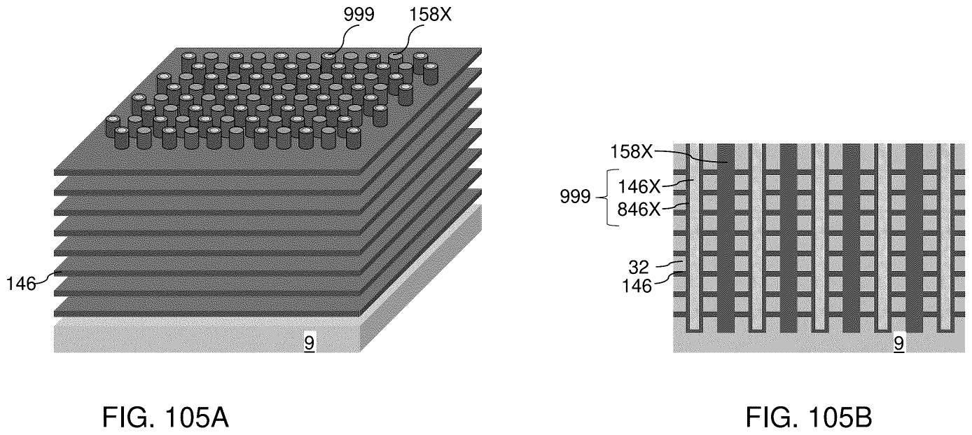

FIGS. 105A and 105B are perspective and vertical cross-sectional views, respectively, of power connections 999 according to various embodiments of the present disclosure. The power connections 999 each comprise a vertically-extending power via portions 846X surrounding a capped tubular semiconductor power structure 186X. In this embodiment, the power connections 999 may be formed in a peripheral region of the memory device at the same time as the vertically-extending via portions 846 and the capped tubular semiconductor structures 186 are formed in the contact region 200, by forming the vertically-extending power via portions 846X at the same time as the vertically-extending via portions 846, and forming the capped tubular semiconductor power structures 186X at the same time as the capped tubular semiconductor structures 186. The power connections 999 may be electrically isolated from the electrically conductive layers (146, 246) by dielectric material plates 42′ described above.

The power connections 999 and peripheral dummy memory opening structures 158X may alternate along a first horizontal direction hd1 in a plurality of rows that extend along the first horizontal direction, and the peripheral dummy memory openings fill structures 158X and the power connections 999 in a first one of the plurality of rows are offset along the first horizontal direction from the respective peripheral dummy memory openings fill structures 158X and the power connections 999 in an adjacent second one of the plurality of rows that is offset from the first one of the plurality of rows along a second horizontal direction hd2 perpendicular to the first horizontal direction. The peripheral dummy memory opening structures 158X may have the same materials and structure as the other dummy memory opening structures 158 in regions (100, 200, 300), and may be formed at the same time as the as the other dummy memory opening structures 158.

The power connections 999 may electrically connect a power pad under the substrate or over the memory device to a peripheral (e.g., driver) circuit of the memory device. The power pad may be connected to an external power connection, and the peripheral circuit may be located next to, below or above the memory device. In one embodiment, the memory device may be located in a memory die, and the peripheral circuit may be located in a logic die that is bonded to the memory die by bonding pads. The two dies may be formed on different substrates.

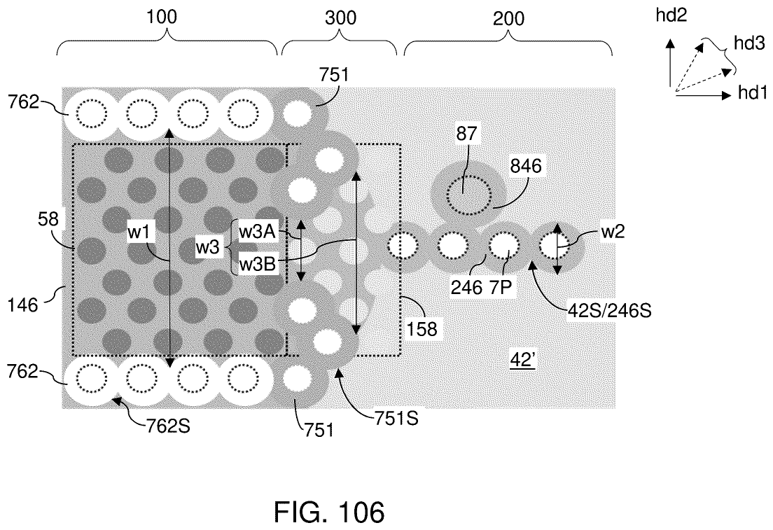

FIG. 106 is a horizontal cross-sectional view of a sixth exemplary structure according to the sixth embodiment of the present disclosure. The sixth exemplary structure is similar to the first through fifth exemplary structures described above. Therefore, only the differences will be described below.

Similar to the first through fifth exemplary structures described above, the sixth exemplary structure also includes the insulating layers 32 that are vertically spaced apart from each other, and the integrated conductive line and via structures (46I, 946). Each of the integrated conductive line and via structures includes a respective electrically conductive layer (146, 246) and a respective vertically-extending via portion 846 that vertically extends upward from the respective electrically conductive layer through a respective subset of the insulating layers 32. The electrically conductive layers (146, 246) of the integrated conductive line and via structures (46I, 946) are vertically interlaced within the insulating layers 32 to provide a vertically alternating sequence {32, (146, 246)} of the insulating layers and the electrically conductive layers. Each of the electrically conductive layers (146, 246) comprises a respective electrode layer (e.g., word line or select gate electrode) 146 located in a memory array region 100 and a respective lateral connection strip 246 located in a contact region 200 and in a connection region 300 located between the memory array region 100 and the contact region 200 along the first horizontal direction (e.g., word line direction) hd1.

The sixth exemplary structure also includes the first and second array-region dielectric wall structures 762 located in the memory array region 100. The first and second array-region dielectric wall structures 762 extend along the first horizontal direction hd1, and are spaced apart from each other along the second horizontal direction (e.g., bit line direction) hd2 perpendicular to the first horizontal direction hd1.

The sixth exemplary structure also includes the first and second connection-region dielectric wall structures 751 located in the connection region 300. The first and second connection-region dielectric wall structures 751 contact the respective first and second array-region dielectric wall structures 762. For example, an end surface of each connection-region dielectric wall structure 751 may contact an end surface of the respective array-region dielectric wall structure 762. The first and second connection-region dielectric wall structures 751 extend at least partially along a third direction hd3 that is not parallel to the first horizontal direction hd1. The first and second connection-region dielectric wall structures 751 are spaced apart from each other along the second horizontal direction hd2.

The sixth exemplary structure also includes the memory openings 49 vertically extending through the vertically alternating sequence {32, (146, 246)} in the memory array region 100, and the memory opening fill structures 58 located in the memory openings 49. Each of the memory opening fill structures 58 comprises a respective vertical semiconductor channel 60 and a vertical stack of memory elements (e.g., portions of the memory film 50) located at levels of the electrically conductive layers (146, 246).

In one embodiment, each of the first and second connection-region dielectric wall structures 751 may comprise a respective pair of laterally-undulating sidewalls 751S each comprising a respective set of laterally-convex and vertically-straight surface segments that are adjoined to each other at vertically-extending edges. Specifically, as described above, the connection-region dielectric wall structures 751 may be formed by laterally expanding and merging subsets of the connection-region isolation openings 29 to form connection-region isolation trenches 791 with laterally-undulating sidewalls, followed by forming connection-region dielectric wall structures 751 with the laterally-undulating sidewalls 751S in the connection-region isolation trenches 791.

In one embodiment, each of the first and second array-region dielectric wall structures 762 comprises a respective pair of laterally-undulating sidewalls 762S each comprising a respective set of laterally-convex and vertically-straight surface segments that are adjoined to each other at vertically-extending edges. Alternatively, the array-region dielectric wall structures 762 may have planar sidewalls 762P, as shown in FIG. 103A.

In one embodiment, each of the lateral connection strips 246 also comprises a respective pair of laterally-undulating sidewalls 246S each comprising a respective set of laterally-convex and vertically-straight surface segments that are adjoined to each other at vertically-extending edges, as described above.

Each of the electrode layers 146 located in the memory array region 100 extends between the first and the second array-region dielectric wall structures 762 along the second horizontal direction hd2, and has a first lateral width w1 along the second horizontal direction hd2. The first lateral width w1 may undulate along the first horizontal direction hd1 if the array-region dielectric wall structures 762 (as well as the electrode layers 146) have laterally-undulating sidewalls 762S. Alternatively, the first lateral width w1 may be constant along the first horizontal direction hd1 if the array-region dielectric wall structures 762 (as well as the electrode layers 146) have planar sidewalls 762P, as shown in FIG. 103A.

Each of the lateral connection strips 246 has a second lateral width w2 in the contact region 200 along the second horizontal direction hd2 that is smaller than the first width w1. The second lateral width w2 may undulate along the first horizontal direction hd1 if the lateral connection strips 246 have laterally-undulating sidewalls 246S.

Each of the lateral connection strips 246 also has a third lateral width w3 in the connection region 300 along the second horizontal direction hd2 that is smaller than the first lateral width w1 (e.g., smaller than the minimum value of undulating first lateral width w1) and greater than the second lateral width w2 (e.g., larger than the maximum value of undulating second lateral width w2). In one embodiment, the third lateral width w3 comprises a variable width which increases from a narrowest width w3A along the second horizontal direction hd2 at the closest point between first and second connection-region dielectric wall structures 751 in the connection region 300, to a widest width w3B laterally spaced along the first horizontal direction hd1 from the narrowest width w3A, and then decreases from the widest width w3B to the second lateral width w2 in the contact region 200.

In one embodiment, the sixth exemplary structure also includes the vertical stack of the dielectric material plates 42′ located at the levels of the electrically conductive layers (146, 246) and vertically interlaced with the insulating layers 32. Each of the dielectric material plates 42′ has a respective laterally undulating dielectric sidewall 42S that comprises an adjoined set of multiple laterally-concave and vertically-straight surface segments, and that contacts the laterally undulating sidewall 246S of the lateral connection strips 246. Each of the lateral connection strips 246 is laterally located at least in the contact region 200 between first and second portions of at least one of the dielectric material plates 42′ that are spaced apart from each other along the second horizontal direction hd2.

In one embodiment, the dielectric support pillar portions 7P vertically extend through the lateral connection strips 246 in the contact region 200. Each of the dielectric support pillar portions 7P comprises a straight sidewall that extends from a bottommost insulating layer of the insulating layers 32 to a topmost insulating layer of the insulating layers 32.

In one embodiment, the dummy memory opening fill structures 158 vertically extend through the lateral connection strips 246 in the connection region 300 and comprise a same set of materials as the memory opening fill structures 58. The dummy memory opening fill structures 158 are electrically floating (i.e., not electrically connected to bit lines). For example, each of the dummy memory opening fill structures 158 may comprise a dummy vertical semiconductor channel and a vertical stack of dummy memory elements (e.g., portions of a dummy memory film). A lateral current path through the lateral connection strip 246 in the connection region 300 meanders between the dummy memory opening fill structures 158, and has at least a portion extending in the third horizontal direction hd3.

In one embodiment, each of the first and connection array-region dielectric wall structures 751 comprises a finned dielectric wall structure 751 comprising a respective set of dielectric pillar portions 751P and a respective vertical stack of dielectric fin portions 751F located at levels of the electrically conductive layers (146, 246) and adjoined to each of the dielectric pillar portions 751P, as described above with respect to FIG. 50A-50D.

In one embodiment, each of the vertically-extending via portions 846 surrounds a respective dielectric pillar material portion 87, as described above with respect to FIG. 22B. In an alternative embodiment, each of the vertically-extending via portions 846 surrounds a respective capped tubular semiconductor structure 186, and the respective capped tubular semiconductor structure 186 surrounds a respective cylindrical dielectric via structure 187, as described above with respect to FIG. 70A-70D.

In one embodiment, the third horizontal direction hd3 comprises a zig-zag direction having segments that are not parallel to the first horizontal direction hd1 or the second horizontal directions hd2. For example, the segments may extend at an angle between 10 and 80 degrees, such as 30 to 60 degrees relative to the first and second horizontal directions. In an alternative embodiment, the third horizontal direction hd3 may be parallel or substantially parallel (e.g., within 5 degrees of) to the second horizontal direction hd2.

The method of forming the sixth exemplary structure may be similar to the methods of forming the first through fifth exemplary structures. The method includes forming an alternating stack (32, 42) of insulating layers 32 and sacrificial material layers 42 that alternate along a vertical direction, followed by forming memory openings 49 through the alternating stack (32, 42) in the memory array region 100 and forming connection-region isolation openings 29 through the alternating stack (32, 42) in the connection region 300. The memory openings 49 extend in rows along the first horizontal direction hd1, and the rows are spaced apart from each other in the second horizontal direction hd2 perpendicular to the first horizontal direction hd1. The connection-region isolation openings 29 extend at least partially along the third direction hd3 that is not parallel to the first horizontal direction hd1, as shown in FIGS. 77A and 81A.

The method also includes forming memory opening fill structures 58 in the memory openings 49, as shown in FIG. 80A. Each of the memory opening fill structures 58 comprises a vertical semiconductor channel 60 and a respective vertical stack of memory elements (e.g., portions of the memory film 50).

The method also includes forming connection-region isolation trenches 791 by laterally expanding and merging subsets of the connection-region isolation openings 29, and forming the connection-region dielectric wall structures 751 in the connection-region isolation trenches 791, as shown in FIGS. 82A and 83A. These steps may be carried out after formation of the memory opening fill structures 58.

The method also includes forming the array-region isolation trenches 792 through the alternating stack (32, 42). In one embodiment, step of forming the array-region isolation trenches 792 through the alternating stack comprises forming memory-region isolation openings 39 in the memory array region 100, and laterally expanding and merging subsets of the memory-region isolation openings 39 after the step of forming the connection-region dielectric wall structures 751 and before performing the above described first selective isotropic etch process, as shown in FIGS. 44A, 54A and 55A. Alternatively, the array-region isolation trenches 792 may have planar sidewalls and may be formed as described above with respect to FIG. 86A.

After forming the array-region isolation trenches 792, the first selective isotropic etch process is performed to isotropically recess the sacrificial material layers 42 around the array-region isolation trenches 792 to form the laterally-extending cavities 43, as shown in FIG. 95A. Since the connection-region dielectric wall structures 751 extend at least partially in the third horizontal direction hd3, they partially block the isotropic etchant that flows along the first horizontal direction hd1 from the array-region isolation trenches 792. Thus, the lateral extent of the laterally-extending cavities 43 along the first horizontal direction hd1 into the connection region 300 is reduced. This reduces the lateral extent of the connection region 300 and thus increases the device density. Otherwise, the contact region 200 containing the vertically-extending via portions 846 would have to be laterally offset further from the memory array region 100 along the first horizontal direction hd1 to prevent the vertically-extending via portion 846 nearest to the memory array region 100 from contacting and short circuiting all of the electrode layers 146 in the memory array region 100.

The method also includes performing the second selective isotropic etch process that forms the strip-shaped cavities 143 in the contact region 200, as shown in FIG. 97A. Each of the strip-shaped cavities 143 is adjoined to a respective one of the laterally-extending cavities 43. Subsequently, the electrically conductive material is deposited in voids that are formed by the first selective isotropic etch process and the second selective isotropic etch process (as well as in the contact via cavities 85′) to form the integrated conductive line and via structures (46I, 946).

In one embodiment, the second selective isotropic etch process forms strip-shaped cavities 143 around the discrete access openings 69 such that the discrete access openings 69 are laterally interconnected to each other by the strip-shaped cavities. Each of the strip-shaped cavities 143 is connected to a respective one of the laterally-extending cavities 43 after the second selective isotropic etch process.

In one embodiment, the method also includes forming annular recesses around the discrete access openings 69 by laterally recessing sidewalls of the sacrificial material layers 42 around the discrete access openings 69, and forming the above described etch-stop rings 66 in the annular recesses by filling the annular recesses with an etch stop material. The etch-stop rings prevent 66 etching of the sacrificial material layers 42 around the discrete access openings 69 during the first selective isotropic etch process. The method also includes removing the etch-stop rings 66 prior to performing the second selective isotropic etch process.

In one embodiment, the method also includes forming the dummy memory openings 149 in the connection region 300 at the same time as forming the memory openings 49, and forming the dummy memory opening fill structures 158 in the dummy memory openings 149 at the same time as forming the memory opening fill structures 58 in the memory openings 49. The dummy memory opening fill structures 158 comprise a same set of materials as the memory opening fill structures 58.

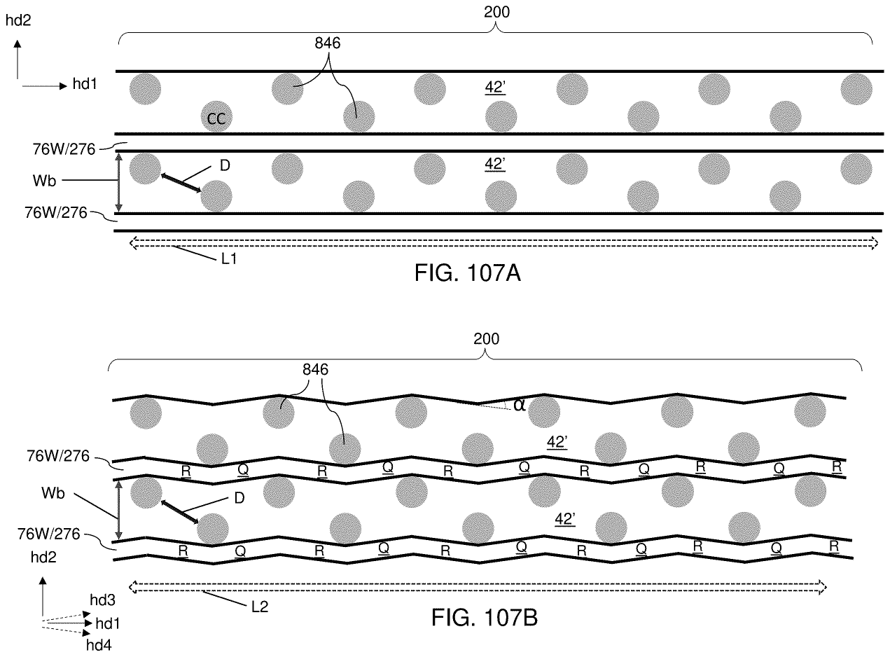

FIGS. 107A and 107B are horizontal cross-sectional views of a comparative embodiment lateral isolation trench fill structure and a seventh exemplary lateral isolation trench fill structure according to a seventh embodiment of the present disclosure, respectively. The comparative embodiment and the seventh exemplary lateral isolation trench fill structures are similar to the lateral isolation trench fill structures of the first and second embodiments described above. Therefore, only the differences will be described below.

Referring to FIG. 107A, a portion of the contact region 200 of the comparative exemplary structure according to the comparative embodiment is shown. Two rows of respective contact via structures 846 are located between a pair of adjacent lateral isolation trench fill structures. The lateral isolation trench fill structures in the contact region 200 may comprise the wide lateral isolation trench fill structures 76W or the additional lateral isolation trench fill structures 276, as described above with respect to the first and second embodiments. In the seventh embodiment, the access lateral isolation trench fill structures 176 may be omitted, similar to the configurations shown in FIG. 39A-39E, 40 and 43.

The lateral isolation trench fill structures (76W, 276) extend straight along the first horizontal direction (e.g., the word line direction) hd1 and have horizontally straight (i.e., linear) sidewalls. Thus, the dielectric plates 42′ and the lateral connection strips 246 (not shown in FIG. 107A) also have straight (i.e., linear) sidewalls along the first horizontal direction.

The adjacent lateral isolation trench fill structures (76W, 276) are spaced apart along the second horizontal direction (e.g., the bit line direction) hd2 by a width Wb (e.g., memory block width). The two rows of the contact via structures 846 in the memory block are spaced apart from each other along the second horizontal direction hd2. The contact via structures 846 in a first one of the two rows are laterally offset from the closest contact via structures 846 in a second one of the two rows along the first horizontal direction hd1. Each contact via structure 846 has a nearest neighbor contact via structure 846 located in a different row. Therefore, each contact via structure 846 is spaced from a nearest neighbor contact via structure 846 in the same memory block by a nearest neighbor distance D. The distance D extends diagonally (e.g., at a 45 degree angle) between the first and the second horizontal directions (hd1, hd2). The contact via structures 846 in each row may be spaced apart from each other by a constant lateral distance along the first horizontal direction hd1. For example, a first minimum lateral distance L1 along the first horizontal direction hd1 may be required to fit six contact via structure 846 in one row.

Referring to FIG. 107B, a portion of the contact region 200 of the seventh exemplary structure is shown. The contact region 200 of the seventh exemplary structure is similar to that of the comparative embodiment shown in FIG. 107A and described above. Therefore, only the differences will be described below.

In the seventh exemplary structure, the lateral isolation trench fill structures (76W, 276) do not extend straight (i.e., they extend non-linearly) along the first horizontal direction hd1 and do not have horizontally straight sidewalls (i.e., they have non-linear sidewalls). Thus, the dielectric plates 42′ and the lateral connection strips 246 (not shown in FIG. 107B) also have non-straight (i.e., non-linear) sidewalls that extend generally along the first horizontal direction hd1.

The lateral isolation trench fill structures (76W, 276) in the contact region 200 extend at least partially along third and fourth horizontal directions (hd3, hd4) that are not parallel to the first or the second horizontal directions hd1 and hd2. For example, the third and fourth horizontal directions hd3 and hd4 deviate from the first horizontal direction hd1 by 3 to 20 degrees, such as by 5 to 10 degrees. As shown in FIG. 107B, the lateral isolation trench fill structures (76W, 276) in the contact region 200 have alternating segments Q and R that extend along the third horizontal direction hd3 and the fourth horizontal direction hd4, respectively. The segments Q and R are inclined with respect to each other by an angle α between the third horizontal direction hd3 and the fourth horizontal direction hd4 of at least 5 degrees. For example, the angle α ranges from 6 to 40 degrees, such as from 10 to 20 degrees.

Thus, the dielectric plates 42′ and the lateral connection strips 246 also have sidewalls comprising alternating segments that extend along the third horizontal direction hd3 and the fourth horizontal direction hd4, respectively, and are inclined with respect to each other by an angle α between the third horizontal direction hd3 and the fourth horizontal direction hd4 of at least 5 degrees. For example, the angle α ranges from 6 to 40 degrees, such as from 10 to 20 degrees. The sidewalls of the lateral connection strips 246 contact the sidewalls of the first and second lateral isolation trench fill structures (76W, 276).

In the seventh embodiment, the adjacent lateral isolation trench fill structures (76W, 276) are spaced apart along the second horizontal direction (e.g., the bit line direction) hd2 by the same width Wb (e.g., memory block width) as in the comparative exemplary structure. The two rows of the contact via structures 846 in the memory block are also spaced apart from each other along the second horizontal direction hd2. The contact via structures 846 in a first one of the two rows are also laterally offset from the closest contact via structures 846 in a second one of the two rows along the first horizontal direction hd1. Each contact via structure 846 has a nearest neighbor contact via structure 846 located in a different row. Therefore, each contact via structure 846 is spaced from a nearest neighbor contact via structure 846 in the same memory block by the same nearest neighbor distance D as in the comparative exemplary structure of FIG. 107A. The distance D extends diagonally (e.g., at a 45 degree angle) between the first and the second horizontal directions. However, the contact via structures 846 in each row may be spaced apart from each other by a constant lateral distance along the first horizontal direction hd1 that is smaller than in the comparative exemplary structure of FIG. 107A due to the non-linearity of the lateral isolation trench fill structures (76W, 276). For example, a second minimum lateral distance L2 along the first horizontal direction hd1 may be required to fit six contact via structure 846 in one row. The second minimum lateral distance L2 shown in FIG. 107B is smaller than the first minimum lateral distance L1 by at least 10%, such as by 20 to 35%, including by 30 to 32%. Therefore, the contact region 200 of the seventh embodiment may be shorter along the first horizontal direction hd1 than in the comparative embodiment without reducing the number of the contact via structures 846, which increases the device density and permits more devices to be formed on the same substrate.

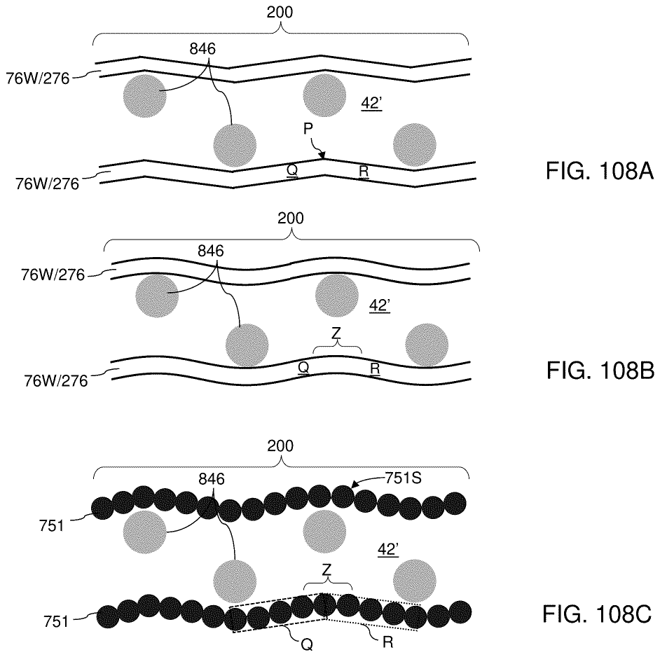

FIGS. 108A, 108B and 108C are horizontal cross-sectional views of alternative dielectric isolation structures according to the seventh embodiment of the present disclosure. Referring to FIG. 108A, the alternating segments Q and R form a zig-zag configuration, similar to that shown in FIG. 107B. In this configuration, sidewalls of adjacent segments Q and R adjoin each other at a discrete point P.

Referring to FIG. 108B, the alternating segments Q and R form a wavy configuration. In this configuration, there is a continuous, curved transition zone Z between adjacent segments Q and R instead of a discrete point as in the zig-zag configuration of FIG. 108A. In the configurations illustrated in FIGS. 108A and 108B, the alternating segments of the lateral isolation trench fill structures (76W, 276) have straight horizontal sidewalls that extend along the third and fourth horizontal directions (hd3, hd4), respectively.

Referring to FIG. 108C, the lateral isolation trench fill structures (76W, 276) of FIGS. 108A and 108B are replaced by a pair of dielectric wall structures 751, each having a respective pair of laterally-undulating sidewalls 751S each comprising a respective set of laterally-convex and vertically-straight surface segments that are adjoined to each other at vertically-extending edges. The dielectric wall structures 751 may comprise the above described finned dielectric wall structures 751 that also extend into the contact region 200 from the connection region 300. In this configuration, the dielectric wall structures 751 also include the above described alternating segments Q and R that form the wavy configuration having the continuous, curved transition zone Z between adjacent segments Q and R.

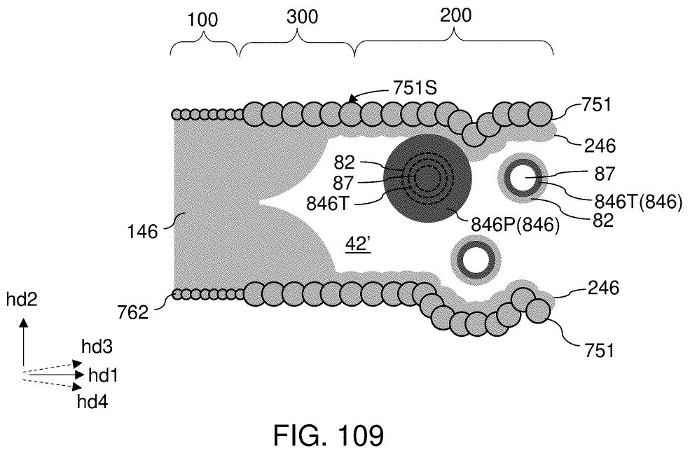

FIG. 109 is a horizontal cross-sectional view an alternative configuration of the seventh exemplary structure according to the seventh embodiment of the present disclosure. In this configuration, the dielectric wall structures 751 may extend linearly along the second horizontal direction in the connection region 300 and have the above described wavy or zig-zag configuration in the contact region 200. Thus, the dielectric plates 42′ and the lateral connection strips 246 also have straight (i.e., linear) sidewalls that extend along the first horizontal direction hd1 in the connection region 300, and non-straight (i.e., non-linear) sidewalls that extend generally along the first horizontal direction hd1 in the contact region 200.

As shown in FIG. 109, each of the electrode layers 146 has a first lateral width in the memory array region 100 along the second horizontal direction hd2; each of the lateral connection strips 246 has a second lateral width in the contact region 200 along the second horizontal direction hd2 that is smaller than the first width; and each of the lateral connection strips 246 has a third lateral width in the connection region 300 along the second horizontal direction hd2 that is smaller than the first lateral width and greater than the second lateral width.

The third lateral width comprises a variable width which increases from the contact region 200 to the memory array region 100. Each of the lateral connection strips 246 is laterally located at least in the contact region 200 between a respective one of the dielectric material plates 42′ and one of the dielectric wall structures 751 along the second horizontal direction hd2.

In summary, the dielectric isolation structures (e.g., the lateral isolation trench fill structures (76W, 276) or the dielectric wall structures 751) have a zig-zag or wavy shape that include alternating segments Q and R that extend along the third horizontal direction hd3 and the fourth horizontal direction hd4, respectively. These configurations permit the adjacent contact via structures 846 in each row to be spaced closer together along the first horizontal direction hd1. This permits the contact region 200 to be more compact, which increases the device density.

Although the foregoing refers to particular preferred embodiments, it will be understood that the claims are not so limited. It will occur to those of ordinary skill in the art that various modifications may be made to the disclosed embodiments and that such modifications are intended to be within the scope of the claims. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the claims may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

1. A device structure, comprising:
insulating layers that are vertically spaced apart from each other;
integrated conductive line and via structures, wherein each of the integrated conductive line and via structures comprises a respective electrically conductive layer and a respective vertically-extending via portion that vertically extends upward from the respective electrically conductive layer through a respective subset of the insulating layers, wherein the electrically conductive layers of the integrated conductive line and via structures are vertically interlaced within the insulating layers to provide a vertically alternating sequence of the insulating layers and the electrically conductive layers, and wherein each of the electrically conductive layers comprises a respective electrode layer located in a memory array region and a respective lateral connection strip located in a contact region and in a connection region located between the memory array region and the contact region along a first horizontal direction;
first and second dielectric isolation structures located in the contact region, extending generally and non-linearly along the first horizontal direction, and spaced apart from each other along the second horizontal direction perpendicular to the first horizontal direction;
memory openings vertically extending through the vertically alternating sequence in the memory array region; and
memory opening fill structures located in the memory openings, wherein each of the memory opening fill structures comprises a respective vertical semiconductor channel and a vertical stack of memory elements located at levels of the electrically conductive layers.

2. The device structure of claim 1, wherein the first and second dielectric isolation structures extend at least partially along third and fourth horizontal directions that are not parallel to the first or the second horizontal directions.

3. The device structure of claim 2, wherein the third and fourth horizontal directions deviate from the first horizontal direction by 3 to 20 degrees.

4. The device structure of claim 3, wherein the third and fourth horizontal directions deviate from the first horizontal direction by 5 to 10 degrees.

5. The device structure of claim 2, wherein each of the first and second dielectric isolation structures comprises alternating first and second segments that extend along the third horizontal direction and the fourth horizontal direction, respectively.

6. The device structure of claim 5, wherein the first and second segments are inclined with respect to each other by an angle of at least 5 degrees.

7. The device structure of claim 6, wherein the lateral connection strips have sidewalls comprising alternating segments that extend along the third horizontal direction and the fourth horizontal direction, respectively, and are inclined with respect to each other by the angle of at least 5 degrees.

8. The device structure of claim 7, wherein:
the sidewalls of the lateral connection strips contact sidewalls of the first and second dielectric isolation structures; and
the angle ranges from 6 to 40 degrees.

9. The device structure of claim 5, wherein the first and second alternating segments form a zig-zag configuration in which sidewalls of the first and second segments adjoin each other at a discrete point.

10. The device structure of claim 5, wherein the first and second alternating segments form a wavy configuration in which sidewalls of the first and second segments adjoin each other at a continuous, curved transition zone.

11. The device structure of claim 5, wherein:
the first and second dielectric isolation structures comprise lateral isolation trench fill structures; and
the first and second alternating segments have straight horizontal sidewalls that extend along the third and fourth horizontal directions, respectively.

12. The device structure of claim 5, wherein:
the first and second dielectric isolation structures comprise dielectric wall structures;
each of the first and second dielectric wall structures comprises a respective pair of laterally-undulating sidewalls each comprising a respective set of laterally-convex and vertically-straight surface segments that are adjoined to each other at vertically-extending edges; and
the first and second alternating segments have the laterally-undulating horizontal sidewalls that extend along the third and fourth horizontal directions, respectively.

13. The device structure of claim 12, wherein each of the lateral connection strips comprises a respective pair of laterally-undulating sidewalls each comprising a respective set of laterally-convex and vertically-straight surface segments that are adjoined to each other at vertically-extending edges.

14. The device structure of claim 13, wherein:
each of the electrode layers has a first lateral width in the memory array region along the second horizontal direction;
each of the lateral connection strips has a second lateral width in the contact region along the second horizontal direction that is smaller than the first width; and
each of the lateral connection strips has a third lateral width in the connection region along the second horizontal direction that is smaller than the first lateral width and greater than the second lateral width.

15. The device structure of claim 14, wherein the third lateral width comprises a variable width which increases from the contact region to the memory array region.

16. The device structure of claim 15, further comprising a vertical stack of dielectric material plates located at the levels of the electrically conductive layers and vertically interlaced with the insulating layers, wherein each of the dielectric material plates has a respective laterally undulating dielectric sidewall that comprises an adjoined set of multiple laterally-concave and vertically-straight surface segments.

17. The device structure of claim 16, wherein each of the lateral connection strips is laterally located in the contact region between a respective one of the dielectric material plates and one of the dielectric wall structures along the second horizontal direction.

18. The device structure of claim 12, wherein each of the dielectric wall structures comprises a finned dielectric wall structure comprising a respective set of dielectric pillar portions and a respective vertical stack of dielectric fin portions located at levels of the electrically conductive layers and adjoined to each of the dielectric pillar portions.

19. The device structure of claim 1, further comprising dummy memory opening fill structures vertically extending through the lateral connection strips in the connection region and comprising a same set of materials as the memory opening fill structures, wherein the dummy memory opening fill structures are electrically floating.

20. The device structure of claim 19, wherein:
each of the dummy memory opening fill structures comprises a dummy vertical semiconductor channel and a vertical stack of dummy memory elements; and
each of the vertically-extending via portions surrounds a respective dielectric pillar material portion.
